(19) United States
(12) Patent Application Publication
(10) Pub. No.: US 2025/0204253 A1
(43) Pub. Date: Jun. 19, 2025

(54) LIGHT EMITTING ELEMENT, POLYCYCLIC COMPOUND FOR THE SAME, AND DISPLAY DEVICE INCLUDING THE SAME

(71) Applicant: Samsung Display Co., Ltd., Yongin-si (KR)

(72) Inventors: Yuuki MIYAZAKI, Yokohama (JP); Yoshiro SUGITA, Yokohama (JP)

(73) Assignee: Samsung Display Co., Ltd., Yongin-si (KR)

(21) Appl. No.: 18/969,602

(22) Filed: Dec. 5, 2024

(30) Foreign Application Priority Data
Dec. 15, 2023 (KR) 10-2023-0183039

(51) Int. Cl. H10K 85/60; H10K 50/115; H10K 85/30; H10K 85/40; H10K 101/20

(52) U.S. Cl. CPC H10K 85/658; H10K 50/115; H10K 85/342; H10K 85/346; H10K 85/40; H10K 85/615; H10K 85/633; H10K 85/636; H10K 85/654; H10K 85/6572; H10K 85/6574; H10K 2101/20

(57) ABSTRACT

Embodiments provide a polycyclic compound, a light emitting element that includes polycyclic compound, and a display device that includes the light emitting element. The light emitting element includes a first electrode, a second electrode disposed on the first electrode, and an emission layer disposed between the first electrode and the second electrode, wherein the emission layer includes the polycyclic compound. The polycyclic compound is represented by Formula 1, which is explained in the specification.

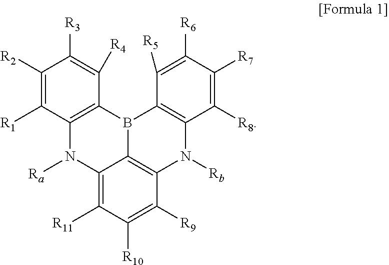

### CROSS-REFERENCE TO RELATED APPLICATION(S)

This application claims priority to and benefits of Korean Patent Application No. 10-2023-0183039 under 35 U.S.C. § 119, filed on Dec. 15, 2023, in the Korean Intellectual Property Office, the entire contents of which are incorporated herein by reference.

### BACKGROUND

### 1. Technical Field

The disclosure relates to a light emitting element, a polycyclic compound used therein, and a display device including the light emitting element.

### 2. Description of the Related Art

Ongoing development continues for organic electroluminescence display devices as image display devices. An organic electroluminescence display device includes a so-called self-luminescent light emitting element in which holes and electrons respectively injected from a first electrode and a second electrode recombine in an emission layer, so that a luminescent material in the emission layer emits light to achieve display.

In the application of a light emitting element to a display device, there is a persistent demand for a light emitting element having improved light efficiency and improved service life. Continuous development is required on materials for a light emitting element that are capable of stably achieving such characteristics.

In order to implement a highly efficient light emitting element, technologies pertaining to phosphorescence emission, which uses triplet state energy, or pertaining to delayed fluorescence, which uses triplet-triplet annihilation (TTA) in which singlet excitons are generated by collision of triplet excitons, are being developed. Research and development are presently directed to thermally activated delayed fluorescence (TADF) materials that use delayed fluorescence phenomenon.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a light emitting element in which luminous efficiency and a service life are improved.

The disclosure also provides a polycyclic compound that contributes to an improvement in the quantum efficiency and the material stability.

The disclosure also provides a display device including the light emitting element in which luminous efficiency and service life are improved, thereby having excellent display quality.

According to an embodiment, a polycyclic compound may be represented by Formula 1:

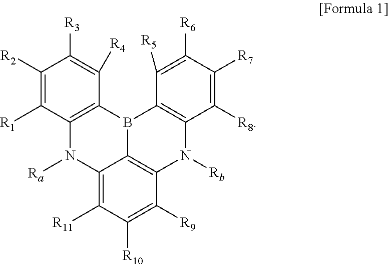

In Formula 1, at least one of R₁ to R₈ may each independently be a first substituent represented by Formula 2; at least one of the remainder of R₁ to R₈ that is not the first substituent may each independently be a second substituent represented by Formula 3; and the remainder of R₁ to R₈ that are not the first substituent or the second substituent, R₉ to R₁₁, Rₐ, and R_{b} may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

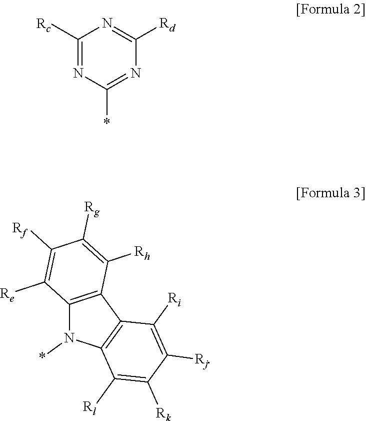

In Formula 2 and Formula 3, R_{c} to Rₗ may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and [symbol] represents a position linked to Formula 1.

In an embodiment, the polycyclic compound may be represented by Formula 1-1 or Formula 1-2.

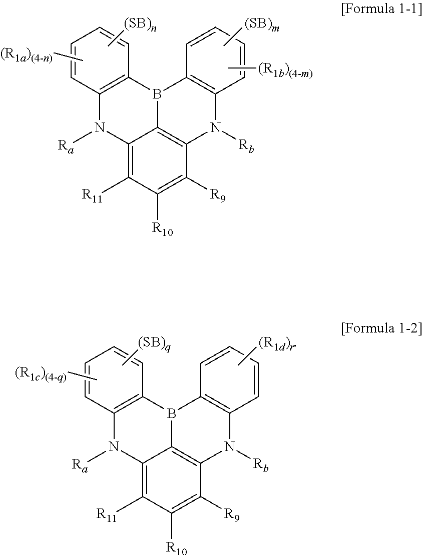

In Formula 1-1 and Formula 1-2, SB may each independently be the first substituent or the second substituent, provided that at least one SB may be the first substituent and at least one SB may be the second substituent; R₁ₐ to R_{1d} may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, provided that R₁ₐ to R_{1d} are not a triazine group or a carbazole group. In Formula 1-1 and Formula 1-2, n and m may each independently be an integer from 1 to 3; q may be an integer from 2 to 4; r may be an integer from 1 to 4; and R₉ to R₁₁, Rₐ, and R_{b} are each the same as defined in Formula 1.

In an embodiment, in Formula 1, R₉ to R₁₁ may not include a triazine group or a carbazole group.

In an embodiment, in Formula 2, R_{c} and R_{d} may each independently be a substituted or unsubstituted phenyl group, a substituted or unsubstituted biphenyl group, a substituted or unsubstituted terphenyl group.

In an embodiment, in Formula 1 to Formula 3, at least one hydrogen atom may be substituted with a deuterium atom.

In an embodiment, the polycyclic compound may be a blue emission dopant.

In an embodiment, the polycyclic compound may be a thermally activated delayed fluorescence material.

In an embodiment, the polycyclic compound may be selected from Compound Group 1, which is explained below.

According to an embodiment, a light emitting element may include: a first electrode; a second electrode disposed on the first electrode; and an emission layer disposed between the first electrode and the second electrode, wherein the emission layer may include a first compound represented by Formula 1, which is explained herein.

In an embodiment, the emission layer may further include at least one of a second compound represented by Formula HT-1 and a third compound represented by Formula ET-1:

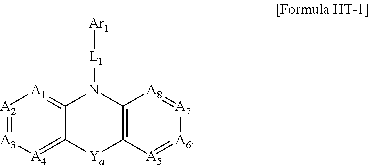

In Formula HT-1, A₁ to A₈ may each independently be N or C(R₅₁); L₁ may be a direct linkage, a substituted or unsubstituted arylene group having 6 to 30 ring-forming carbon atoms, or a substituted or unsubstituted heteroarylene group having 2 to 30 ring-forming carbon atoms; Yₐ may be a direct linkage, C(R₅₂)(R₅₃), or Si(R₅₄)(R₅₅); Ar₁ may be a substituted or unsubstituted aryl group having 6 to 30 ring-forming carbon atoms or a substituted or unsubstituted heteroaryl group having 2 to 30 ring-forming carbon atoms; and R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring:

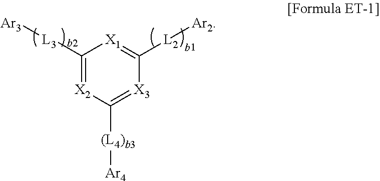

In Formula ET-1, at least one of X1 to X3 may each be N; the remainder of X₁ to X₃ may each independently be C(R₅₆); R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms; b1 to b3 may each independently be an integer from 0 to 10; Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; and L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms.

In an embodiment, the emission layer may further include a fourth compound represented by Formula D-1:

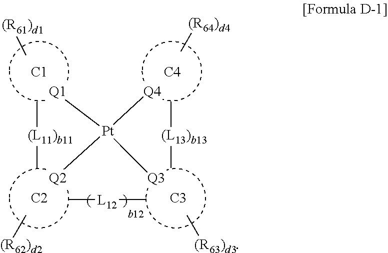

In Formula D-1, Q₁ to Q₄ may each independently be C or N; and C1 to C4 may each independently be a substituted or unsubstituted hydrocarbon ring having 5 to 30 ring-forming carbon atoms or a substituted or unsubstituted heterocycle having 2 to 30 ring-forming carbon atoms. In Formula D-1, L₁ to L₁₃ may each independently be a direct linkage,

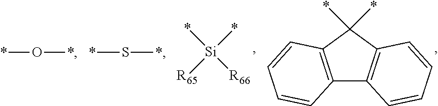

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In Formula D-1, b11 to b13 may each independently be 0 or 1; R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms; and d1 to d4 may each independently be an integer from 0 to 4.

In an embodiment, the emission layer may include the first compound, the second compound, the third compound, and the fourth compound.

In an embodiment, the emission layer may emit delayed fluorescence.

In an embodiment, the emission layer may emit blue light.

In an embodiment, the first compound may be represented by Formula 1-1 or Formula 1-2, which are explained herein.

In an embodiment, in the first compound, at least one hydrogen atom may be substituted with a deuterium atom.

In an embodiment, the first compound may be selected from Compound Group 1, which is explained below.

According to an embodiment, a display device may include: a circuit layer disposed on a base layer; and a display element layer disposed on the circuit layer and including a light emitting element, wherein
the light emitting element may include a first electrode, a second electrode disposed on the first electrode, and an emission layer disposed between the first electrode and the second electrode; and the emission layer includes a polycyclic compound represented by Formula 1, which is explained herein.

In an embodiment, the light emitting element may emit blue light.

In an embodiment, the display device may further include a light control layer that includes a quantum dot.

It is to be understood that the embodiments above are described in a generic and explanatory sense only and not for the purposes of limitation, and the disclosure is not limited to the embodiments described above.

### BRIEF DESCRIPTION OF THE DRAWINGS

The accompanying drawings are included to provide a further understanding of the embodiments, and are incorporated in and constitute a part of this specification. The drawings illustrate embodiments of the disclosure and principles thereof. The above and other aspects and features of the disclosure will become more apparent by describing in detail embodiments thereof with reference to the accompanying drawings, in which:

FIG. 1 is a schematic plan view of a display device according to an embodiment;

FIG. 2 is a schematic cross-sectional view of a portion of a display device taken along virtual line I-I′ of FIG. 1;

FIG. 3 is a schematic cross-sectional view of a light emitting element of an embodiment;

FIG. 4 is a schematic cross-sectional view of a light emitting element of an embodiment;

FIG. 5 is a schematic cross-sectional view of a light emitting element of an embodiment;

FIG. 6 is a schematic cross-sectional view of a light emitting element of an embodiment;

FIG. 7 is a schematic cross-sectional view of a light emitting element of an embodiment;

FIG. 8 is a schematic cross-sectional view of a display device according to an embodiment;

FIG. 9 is a schematic cross-sectional view of a display device according to an embodiment;

FIG. 10 is a schematic cross-sectional view of a display device according to an embodiment;

FIG. 11 is a schematic cross-sectional view of a display device according to an embodiment; and

FIG. 12 is a schematic diagram of an interior of a vehicle in which display devices according to embodiments are disposed.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like reference numbers and reference characters refer to like elements throughout.

In the specification, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the specification, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group consisting of” for the purpose of its meaning and interpretation. For example, “at least one of A, B, and C” may be understood to mean A only, B only, C only, or any combination of two or more of A, B, and C, such as ABC, ACC, BC, or CC. When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element. Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within ±20%, ±10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

In the specification, the term “substituted or unsubstituted” may describe a group that is substituted or unsubstituted with at least one substituent selected from the group consisting of a deuterium atom, a halogen atom, a cyano group, a nitro group, an amino group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. Each of the substituents listed above may itself be substituted or unsubstituted. For example, a biphenyl group may be interpreted as an aryl group, or it may be interpreted as a phenyl group substituted with a phenyl group.

In the specification, the phrase “bonded to an adjacent group to form a ring” may refer to a group that is bonded to an adjacent group to form a substituted or unsubstituted hydrocarbon ring or a substituted or unsubstituted heterocycle. A hydrocarbon ring may be aliphatic or aromatic. A heterocycle may be aliphatic or aromatic. The hydrocarbon ring and the heterocycle may each independently be monocyclic or polycyclic. A ring that is formed by adjacent groups being bonded to each other may itself be connected to another ring to form a spiro structure.

In the specification, the term “adjacent group” may be interpreted as a substituent that is substituted for an atom which is directly linked to an atom substituted with a corresponding substituent, as another substituent that is substituted for an atom which is substituted with a corresponding substituent, or as a substituent that is sterically positioned at the nearest position to a corresponding substituent. For example, two methyl groups in 1,2-dimethylbenzene may be interpreted as “adjacent groups” to each other, and two ethyl groups in 1,1-diethylcyclopentane may be interpreted as “adjacent groups” to each other. For example, two methyl groups in 4,5-dimethylphenanthrene may be interpreted as “adjacent groups” to each other.

In the specification, examples of a halogen atom may include a fluorine atom, a chlorine atom, a bromine atom, and an iodine atom.

In the specification, an alkyl group may be linear or branched. The number of carbon atoms in an alkyl group may be 1 to 50, 1 to 30, 1 to 20, 1 to 10, or 1 to 6. Examples of an alkyl group may include a methyl group, an ethyl group, an n-propyl group, an isopropyl group, an n-butyl group, an s-butyl group, a t-butyl group, an i-butyl group, a 2-ethylbutyl group, a 3,3-dimethylbutyl group, an n-pentyl group, an i-pentyl group, a neopentyl group, a t-pentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments are not limited thereto.

In the specification, a cycloalkyl group may be a cyclic alkyl group. The number of carbon atoms in a cycloalkyl group may be 3 to 50, 3 to 30, 3 to 20, or 3 to 10. Examples of a cycloalkyl group may include a cyclopropyl group, a cyclobutyl group, a cyclopentyl group, a cyclohexyl group, a 4-methylcyclohexyl group, a 4-t-butylcyclohexyl group, a cycloheptyl group, a cyclooctyl group, a cyclononyl group, a cyclodecyl group, a norbornyl group, a 1-adamantyl group, a 2-adamantyl group, an isobornyl group, a bicycloheptyl group, etc., but embodiments are not limited thereto.

In the specification, an alkenyl group may be a hydrocarbon group that includes at least one carbon-carbon double bond in the middle or at a terminus of an alkyl group having 2 or more carbon atoms. An alkenyl group may be linear or branched. The number of carbon atoms in an alkenyl group is not particularly limited, and may be 2 to 30, 2 to 20, or 2 to 10. Examples of an alkenyl group may include a vinyl group, a 1-butenyl group, a 1-pentenyl group, a 1,3-butadienyl aryl group, a styrenyl group, a styryl vinyl group, etc., but embodiments are not limited thereto.

In the specification, an alkynyl group may be a hydrocarbon group that includes at least one carbon-carbon triple bond in the middle or at a terminus of an alkyl group having 2 or more carbon atoms. An alkynyl group may be linear or branched. The number of carbon atoms in an alkynyl group is not particularly limited, and may be 2 to 30, 2 to 20, or 2 to 10. Examples of an alkynyl group may include an ethynyl group, a propynyl group, etc., but embodiments are not limited thereto.

In the specification, a hydrocarbon ring group may be any functional group or substituent derived from an aliphatic hydrocarbon ring. For example, a hydrocarbon ring group may be a saturated hydrocarbon ring group having 5 to 20 ring-forming carbon atoms.

In the specification, an aryl group may be any functional group or substituent derived from an aromatic hydrocarbon ring. An aryl group may be monocyclic or polycyclic. The number of ring-forming carbon atoms in an aryl group may be 6 to 30, 6 to 20, or 6 to 15. Examples of an aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments are not limited thereto.

In the specification, a fluorenyl group may be substituted, and two substituents may be bonded to each other to form a spiro structure. Examples of a substituted fluorenyl group may include the groups shown below. However, embodiments are not limited thereto.

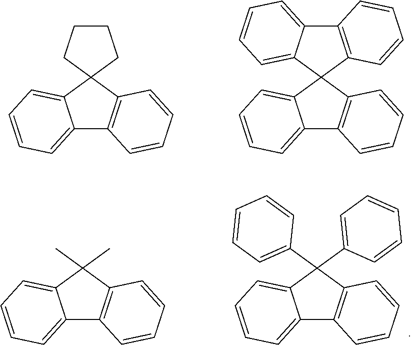

In the specification, a heterocyclic group may be any functional group or substituent derived from a ring that includes at least one of B, O, N, P, Si, S, and Se as a heteroatom. A heterocyclic group may be aliphatic or aromatic. An aromatic heterocyclic group may be a heteroaryl group. An aliphatic heterocycle and an aromatic heterocycle may each independently be monocyclic or polycyclic.

If a heterocyclic group includes two or more heteroatoms, the two or more heteroatoms may be the same as or different from each other. The number of ring-forming carbon atoms in a heterocyclic group may be 2 to 30, 2 to 20, or 2 to 10.

Examples of an aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments are not limited thereto.

Examples of a heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments are not limited thereto.

In the specification, the above description of an aryl group may be applied to an arylene group, except that an arylene group is a divalent group. In the specification, the above description of a heteroaryl group may be applied to a heteroarylene group, except that a heteroarylene group is a divalent group.

In the specification, a silyl group may be an alkylsilyl group or an arylsilyl group. Examples of a silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments are not limited thereto.

In the specification, the number of carbon atoms in a carbonyl group is not particularly limited, and may be 1 to 40, 1 to 30, or 1 to 20. For example, a carbonyl group may have one of the following structures, but embodiments are not limited thereto.

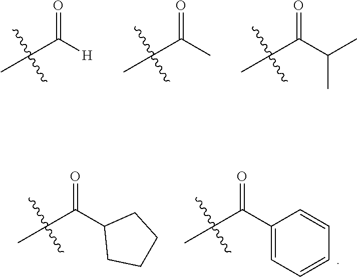

In the specification, the number of carbon atoms in a sulfinyl group or a sulfonyl group is not particularly limited, and may be 1 to 30. A sulfinyl group may be an alkyl sulfinyl group or an aryl sulfinyl group. A sulfonyl group may be an alkyl sulfonyl group or an aryl sulfonyl group.

In the specification, a thio group may be an alkylthio group or an arylthio group. A thio group may be a sulfur atom that is bonded to an alkyl group or an aryl group as defined above. Examples of a thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but embodiments are not limited thereto.

In the specification, an oxy group may be an oxygen atom that is bonded to an alkyl group or an aryl group as defined above. An oxy group may be an alkoxy group or an aryl oxy group. An alkoxy group may be linear, branched, or cyclic. The number of carbon atoms in an alkoxy group is not particularly limited, and may be, for example, 1 to 20 or 1 to 10. Examples of an oxy group may include a methoxy group, an ethoxy group, an n-propoxy group, an isopropoxy group, a butoxy group, a pentyloxy group, a hexyloxy group, an octyloxy group, a nonyloxy group, a decyloxy group, a benzyloxy group, etc., but embodiments are not limited thereto.

In the specification, a boron group may be a boron atom that is bonded to an alkyl group or an aryl group as defined above. A boron group may be an alkyl boron group or an aryl boron group. Examples of a boron group may include a dimethylboron group, a trimethylboron group, a t-butyldimethylboron group, a diphenylboron group, a phenylboron group, etc., but embodiments are not limited thereto.

In the specification, the number of carbon atoms in an amine group is not particularly limited, and may be 1 to 30. An amine group may be an alkyl amine group or an aryl amine group. Examples of an amine group may include a methylamine group, a dimethylamine group, a phenylamine group, a diphenylamine group, a naphthylamine group, a 9-methyl-anthracenylamine group, etc., but embodiments are not limited thereto.

In the specification, an alkyl group within an alkylthio group, an alkylsulfoxy group, an alkylaryl group, an alkylamino group, an alkyl boron group, an alkyl silyl group, or an alkyl amine group may be the same as an example of an alkyl group as described above.

In the specification, an aryl group within an aryloxy group, an arylthio group, an arylsulfoxy group, an arylamino group, an arylboron group, an arylsilyl group, or an arylamine group may be the same as an example of an aryl group as described above.

In the specification, a direct linkage may be a single bond.

In the specification, the symbols

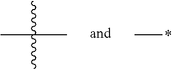

each represent a bond to a neighboring atom in a corresponding formula or moiety.

Hereinafter, embodiments will be described with reference to the accompanying drawings.

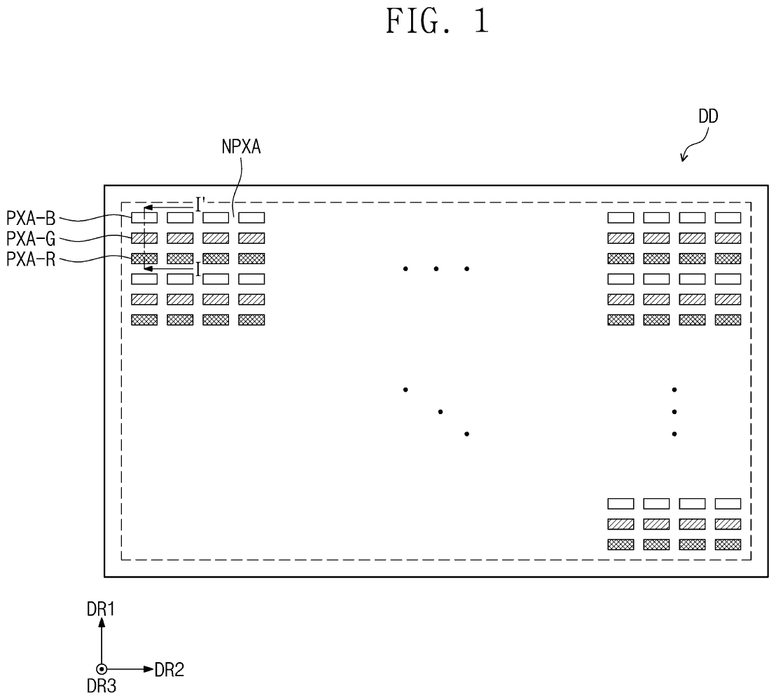

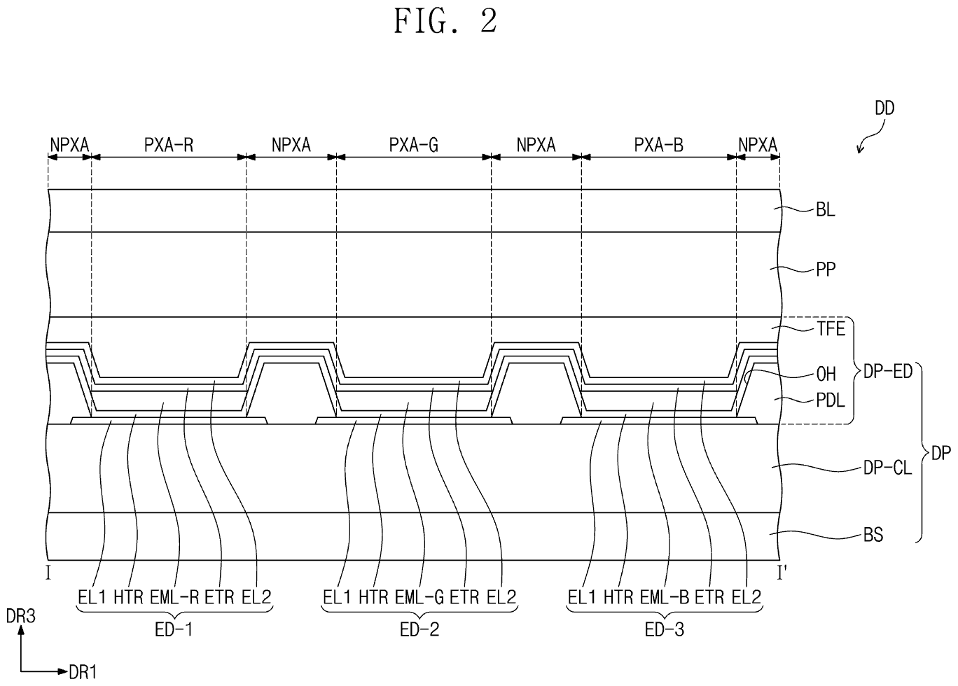

FIG. 1 is a schematic plan view of a display device DD according to an embodiment. FIG. 2 is a schematic cross-sectional view of a display device DD according to the embodiment. FIG. 2 is a schematic cross-sectional view of a portion of the display device DD taken along virtual line I-I′ in FIG. 1.

The display device DD may include a display panel DP and an optical layer PP disposed on the display panel DP. The display panel DP includes light emitting elements ED-1, ED-2, and ED-3. The display device DD may include multiples of each of the light emitting elements ED-1, ED-2, and ED-3. The optical layer PP may be disposed on the display panel DP to control light that is reflected at the display panel DP from an external light. The optical layer PP may include, for example, a polarization layer or a color filter layer. Although not shown in the drawings, in an embodiment, the optical layer PP may be omitted from the display device DD.

A base substrate BL may be disposed on the optical layer PP. The base substrate BL may provide a base surface on which the optical layer PP is disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

The display device DD according to an embodiment may further include a filling layer (not shown). The filling layer (not shown) may be disposed between a display element layer DP-ED and the base substrate BL. The filling layer (not shown) may be an organic material layer. The filling layer (not shown) may include at least one of an acrylic-based resin, a silicone-based resin, and an epoxy-based resin.

The display panel DP may include a base layer BS, a circuit layer DP-CL provided on the base layer BS, and the display element layer DP-ED. The display element layer DP-ED may include a pixel defining layer PDL, light emitting elements ED-1, ED-2, and ED-3 disposed between portions of the pixel defining layer PDL, and an encapsulation layer TFE disposed on the light emitting elements ED-1, ED-2, and ED-3.

The base layer BS may provide a base surface on which the display element layer DP-ED is disposed. The base layer BS may be a glass substrate, a metal substrate, a plastic substrate, etc. However, embodiments are not limited thereto, and the base layer BS may include an inorganic layer, an organic layer, or a composite material layer.

In an embodiment, the circuit layer DP-CL is disposed on the base layer BS, and the circuit layer DP-CL may include transistors (not shown). The transistors (not shown) may each include a control electrode, an input electrode, and an output electrode. For example, the circuit layer DP-CL may include a switching transistor and a driving transistor for driving the light emitting elements ED-1, ED-2, and ED-3 of the display element layer DP-ED.

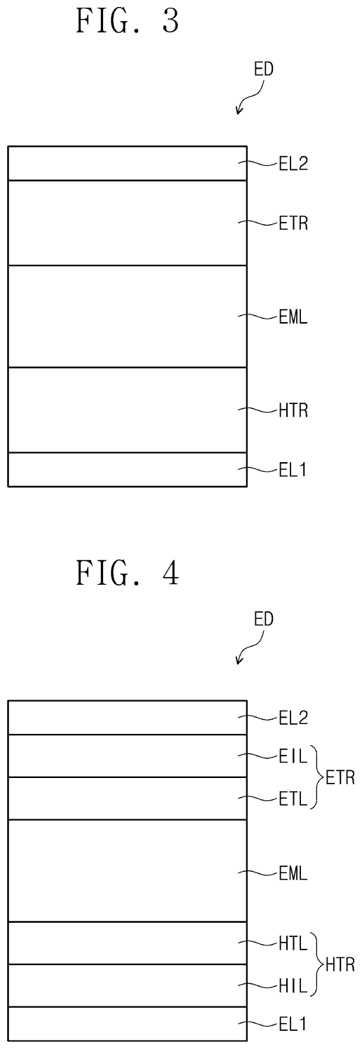

The light emitting elements ED-1, ED-2, and ED-3 may each have a structure of a light emitting element ED of an embodiment according to any of FIGS. 3 to 7, which will be described later. The light emitting elements ED-1, ED-2, and ED-3 may each include a first electrode EL1, a hole transport region HTR, emission layers EML-R, EML-G, and EML-B, an electron transport region ETR, and a second electrode EL2.

FIG. 2 illustrates an embodiment in which the emission layers EML-R, EML-G, and EML-B of the light emitting elements ED-1, ED-2, and ED-3 are disposed in openings OH defined in the pixel defining layer PDL, and the hole transport region HTR, the electron transport region ETR, and the second electrode EL2 are each provided as a common layer for the light emitting elements ED-1, ED-2, and ED-3. However, embodiments are not limited thereto. Although not shown in FIG. 2, the hole transport region HTR and the electron transport region ETR may each be provided by being patterned in the openings OH defined in the pixel defining layer PDL. For example, in an embodiment, the hole transport region HTR, the emission layers EML-R, EML-G, and EML-B, and the electron transport region ETR of the light emitting elements ED-1, ED-2, and ED-3 may each be provided by being patterned through an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be formed of a single layer or of multiple layers. The encapsulation layer TFE may include at least one insulation layer. The encapsulation layer TFE according to an embodiment may include at least one inorganic film (hereinafter, an encapsulation-inorganic film). In an embodiment, the encapsulation layer TFE may include at least one organic film (hereinafter, an encapsulation-organic film) and at least one encapsulation-inorganic film.

The encapsulation-inorganic film protects the display element layer DP-ED from moisture and/or oxygen, and the encapsulation-organic film protects the display element layer DP-ED from foreign substances such as dust particles. The encapsulation-inorganic film may include silicon nitride, silicon oxynitride, silicon oxide, titanium oxide, aluminum oxide, or the like, but embodiments are not limited thereto. The encapsulation-organic film may include an acrylic-based compound, an epoxy-based compound, or the like. The encapsulation-organic film may include a photopolymerizable organic material, but embodiments are not limited thereto.

The encapsulation layer TFE may be disposed on the second electrode EL2 and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region that emits light respectively generated by the light emitting elements ED-1, ED-2, and ED-3. The light emitting regions PXA-R, PXA-G, and PXA-B may be spaced apart from each other in a plan view.

The light emitting regions PXA-R, PXA-G, and PXA-B may be regions that are separated from each other by the pixel defining layer PDL. The non-light emitting regions NPXA may be areas between the adjacent light emitting regions PXA-R, PXA-G, and PXA-B, and which may correspond to the pixel defining layer PDL. In an embodiment, the light emitting regions PXA-R, PXA-G, and PXA-B may each correspond to a pixel. The pixel defining layer PDL may separate the light emitting elements ED-1, ED-2, and ED-3. The emission layers EML-R, EML-G, and EML-B of the light emitting elements ED-1, ED-2, and ED-3 may be disposed in openings OH defined in the pixel defining layer PDL and separated from each other.

The light emitting regions PXA-R, PXA-G, and PXA-B may be arranged into groups according to the color of light generated from the light emitting elements ED-1, ED-2, and ED-3. In the display device DD according to an embodiment illustrated in FIGS. 1 and 2, three light emitting regions PXA-R, PXA-G, and PXA-B, which respectively emit red light, green light, and blue light, are illustrated as an example. For example, the display device DD may include a red light emitting region PXA-R, a green light emitting region PXA-G, and a blue light emitting region PXA-B, which are distinct from each other.

In the display device DD according to an embodiment, the light emitting elements ED-1, ED-2, and ED-3 may emit light having wavelengths that are different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may respectively correspond to the first light emitting element ED-1, the second light emitting element ED-2, and the third light emitting element ED-3.

However, embodiments are not limited thereto, and the first to third light emitting elements ED-1, ED-2, and ED-3 may emit light in a same wavelength range, or at least one light emitting element may emit light in a wavelength range that is different from the remainder. For example, the first to third light emitting elements ED-1, ED-2, and ED-3 may each emit blue light.

The light emitting regions PXA-R, PXA-G, and PXA-B in the display device DD according to an embodiment may be arranged in a stripe configuration. Referring to FIG. 1, the red light emitting regions PXA-R, the green light emitting regions PXA-G, and the blue light emitting regions PXA-B may be respectively arranged along a second directional axis DR2. In another embodiment, the red light emitting region PXA-R, the green light emitting region PXA-G, and the blue light emitting region PXA-B may be arranged in this repeating order along a first directional axis DR1.

FIGS. 1 and 2 illustrate that the light emitting regions PXA-R, PXA-G, and PXA-B all have a similar area, but embodiments are not limited thereto. In an embodiment, the light emitting regions PXA-R, PXA-G, and PXA-B may be different in size or shape from each other, according to a wavelength range of emitted light. The areas of the light emitting regions PXA-R, PXA-G, and PXA-B may be areas in a plan view that are defined by the first directional axis DR1 and the second directional axis DR2.

An arrangement of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are arranged may be provided in various combinations, according to the display quality characteristics that are required for the display device DD. For example, the light emitting regions PXA-R, PXA-G, and PXA-B may be arranged in a pentile configuration (such as PenTile®) or in a diamond configuration (such as Diamond Pixel®).

The areas of the light emitting regions PXA-R, PXA-G, and PXA-B may be different in size from each other. For example, in an embodiment, an area of a green light emitting region PXA-G may be smaller than an area of a blue light emitting region PXA-B, but embodiments are not limited thereto.

Hereinafter, FIGS. 3 to 7 are each a schematic cross-sectional view of a light emitting element according to an embodiment. Embodiments provide a light emitting element ED that may include a first electrode EL1, a hole transport region HTR, an emission layer EML, an electron transport region ETR, and a second electrode EL2, which may be stacked in that order.

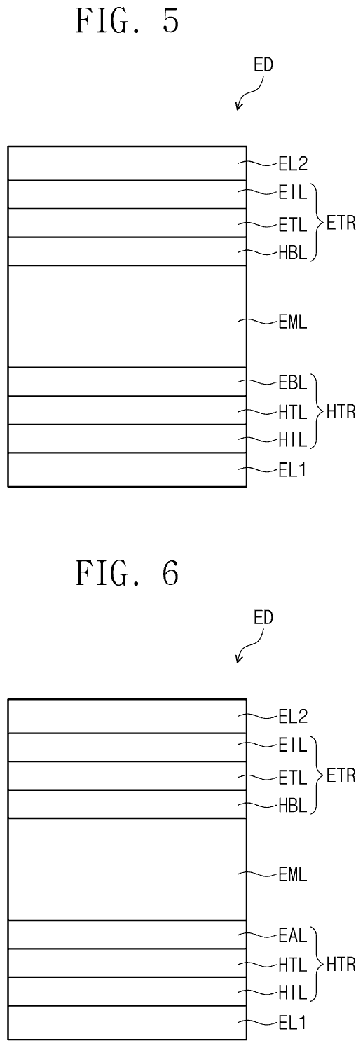

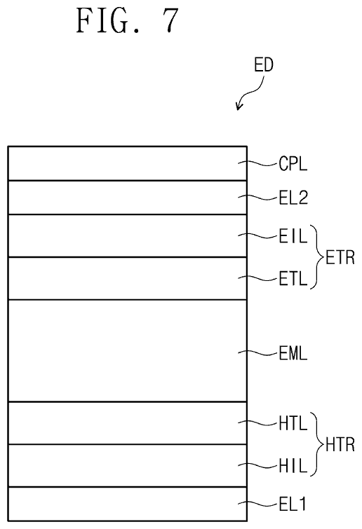

In comparison to FIG. 3, FIG. 4 is a schematic cross-sectional view of a light emitting element ED according to an embodiment, in which a hole transport region HTR includes a hole injection layer HIL and a hole transport layer HTL, and an electron transport region ETR includes an electron injection layer EIL and an electron transport layer ETL. In comparison to FIG. 3, FIG. 5 is a schematic cross-sectional view of a light emitting element ED according to an embodiment, in which a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. In comparison to FIG. 3, FIG. 6 is a schematic cross-sectional view of a light emitting element ED according to an embodiment, in which a hole transport region HTR includes a hole injection layer HIL, a hole transport layer HTL, and an emission-auxiliary layer EAL, and an electron transport region ETR includes an electron injection layer EIL, an electron transport layer ETL, and a hole blocking layer HBL. In comparison to FIG. 4, FIG. 7 is a schematic cross-sectional view of a light emitting element ED according to an embodiment that further includes a capping layer CPL disposed on a second electrode EL2.

The first electrode EL1 has conductivity. The first electrode EL1 may be formed of a metal material, a metal alloy, or a conductive compound. The first electrode EL1 may be an anode or a cathode. However, embodiments are not limited thereto. In an embodiment, the first electrode EL1 may be a pixel electrode. The first electrode EL1 may be a transmissive electrode, a transflective electrode, or a reflective electrode. The first electrode EL1 may include at least one of Ag, Mg, Cu, Al, Pt, Pd, Au, Ni, Nd, Ir, Cr, Li, Ca, LiF, Mo, Ti, W, In, Sn, Zn, an oxide thereof, a compound thereof, or a mixture thereof.

If the first electrode EL1 is a transmissive electrode, the first electrode EL1 may include a transparent metal oxide such as indium tin oxide (ITO), indium zinc oxide (IZO), zinc oxide (ZnO), or indium tin zinc oxide (ITZO). If the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In another embodiment, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layered structure of ITO/Ag/ITO, but embodiments are not limited thereto. In an embodiment, the first electrode EL1 may include the above-described metal materials, combinations of at least two metal materials of the above-described metal materials, oxides of the above-described metal materials, or the like. A thickness of the first electrode EL1 may be in a range of about 700 Å to about 10,000 Å. For example, the thickness of the first electrode EL1 may be in a range of about 1,000 Å to about 3,000 Å.

The hole transport region HTR may be provided on the first electrode EL1. The hole transport region HTR may include at least one of a hole injection layer HIL, a hole transport layer HTL, an emission-auxiliary layer EAL, and an electron blocking layer EBL. A thickness of the hole transport region HTR may be, for example, in a range of about 50 Å to about 15,000 Å. In an embodiment, the emission-auxiliary layer EAL may serve as a buffer layer.

The hole transport region HTR may have a structure consisting of a layer consisting of a single material, a structure consisting of a layer including different materials, or a structure including multiple layers including different materials.

In embodiments, the hole transport region HTR may have a single layer structure of a hole injection layer HIL or a hole transport layer HTL, or may have a single layer structure formed of a hole injection material and a hole transport material. In embodiments, the hole transport region HTR may have a single layer structure formed of different materials, or may have a structure in which a hole injection layer HIL/hole transport layer HTL, a hole injection layer HIL/hole transport layer HTL/emission-auxiliary layer EAL, a hole injection layer HIL/emission-auxiliary layer EAL, a hole transport layer HTL/emission-auxiliary layer EAL, or a hole injection layer HIL/hole transport layer HTL/electron blocking layer EBL are stacked in its respective stated order from the first electrode EL1, but embodiments are not limited thereto. In an embodiment, the hole transport layer HTL may be a single layer or may be a structure including multiple layers.

The hole transport region HTR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the hole transport region HTR may include the compound represented by Formula H-1:

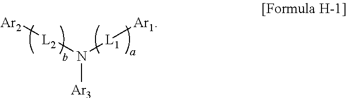

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. In Formula H-1, a and b may each independently be an integer from 0 to 10. When a or b is 2 or greater, multiple L₁ groups or multiple L₂ groups may each independently be a substituted or unsubstituted arylene group having 6 to 30 ring-forming carbon atoms or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. In Formula H-1, Ar₃ may be a substituted or unsubstituted aryl group having 6 to 30 ring-forming carbon atoms or a substituted or unsubstituted heteroaryl group having 2 to 30 ring-forming carbon atoms.

In an embodiment, the compound represented by Formula H-1 may be a monoamine compound. In another embodiment, the compound represented by Formula H-1 may be a diamine compound in which at least one of Ar₁ to Ar₃ includes an amine group as a substituent. In an embodiment, the compound represented by Formula H-1 may be a carbazole-based compound in which at least one of Ar₁ and Ar₂ includes a substituted or unsubstituted carbazole group, or may be a fluorene-based compound in which at least one of Ar₁ and Ar₂ includes a substituted or unsubstituted fluorene group.

The compound represented by Formula H-1 may be any compound selected from Compound Group H. However, the compounds listed in Compound Group H are only examples, and the compound represented by Formula H-1 is not limited to Compound Group H:

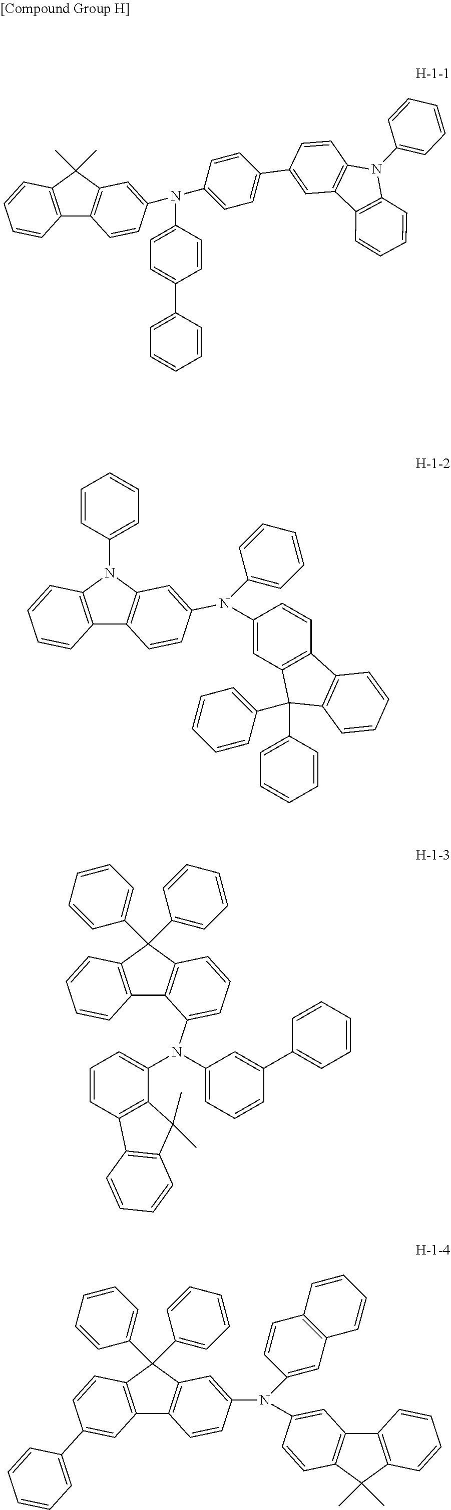

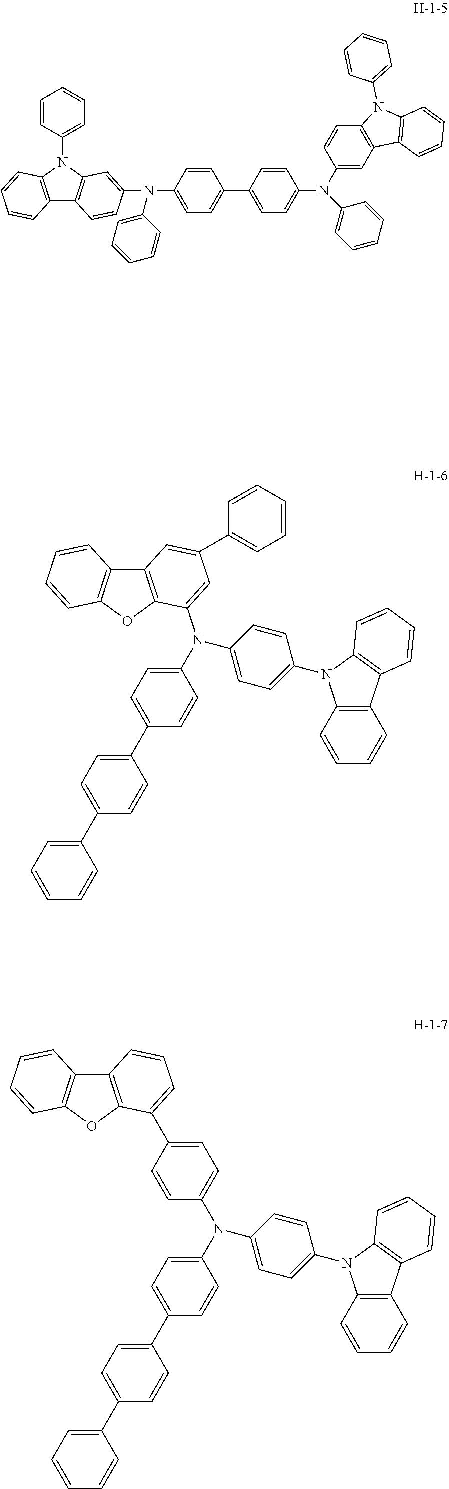 [SMILES: c1ccc(N(c2ccc(-c3ccc(N(c4ccccc4)c4ccc5c6ccccc6n(-c6ccccc6)c5c4)cc3)cc2)c2ccc3c(c2)c2ccccc2n3-c2ccccc2)cc1 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; c1ccc(-c2ccc(-c3ccc(N(c4ccc(-c5cccc6c5oc5ccccc56)cc4)c4ccc(-n5c6ccccc6c6ccccc65)cc4)cc3)cc2)cc1]

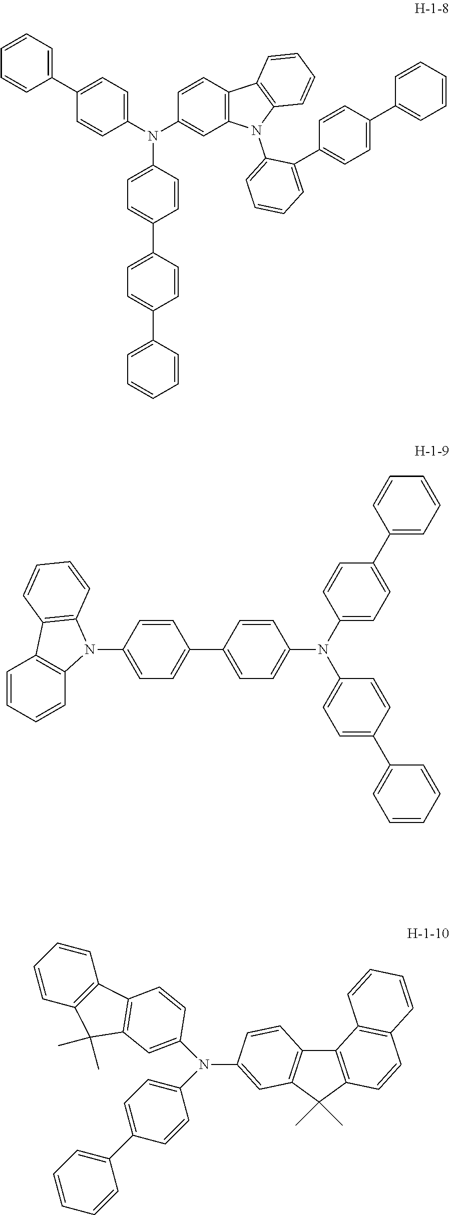 [SMILES: c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21]

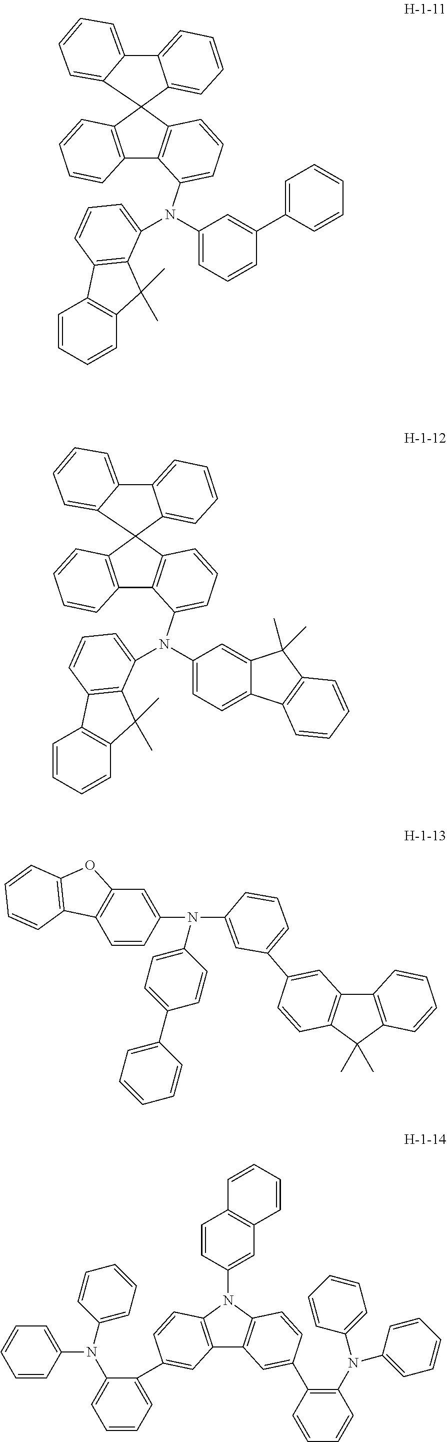 [SMILES: CC1(C)c2ccccc2-c2cccc(N(c3cccc(-c4ccccc4)c3)c3cccc4c3-c3ccccc3C43c4ccccc4-c4ccccc43)c21 ; CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1]

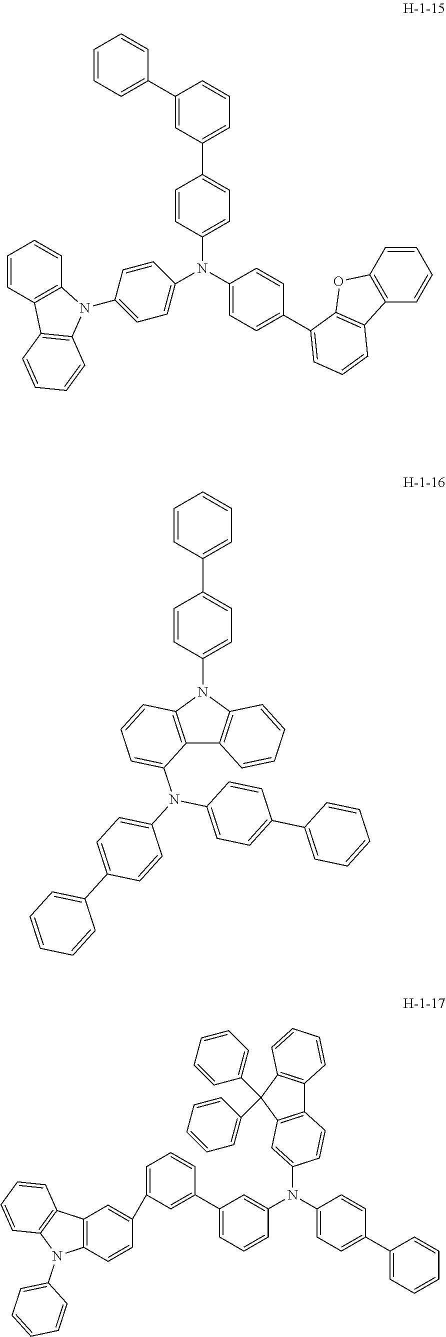 [SMILES: c1ccc(-c2cccc(-c3ccc(N(c4ccc(-c5cccc6c5oc5ccccc56)cc4)c4ccc(-n5c6ccccc6c6ccccc65)cc4)cc3)c2)cc1 ; c1ccc(-c2ccc(N(c3ccc(-c4ccccc4)cc3)c3cccc4c3c3ccccc3n4-c3ccc(-c4ccccc4)cc3)cc2)cc1 ; c1ccc(-c2ccc(N(c3cccc(-c4cccc(-c5ccc6c(c5)c5ccccc5n6-c5ccccc5)c4)c3)c3ccc4c(c3)C(c3ccccc3)(c3ccccc3)c3ccccc3-4)cc2)cc1]

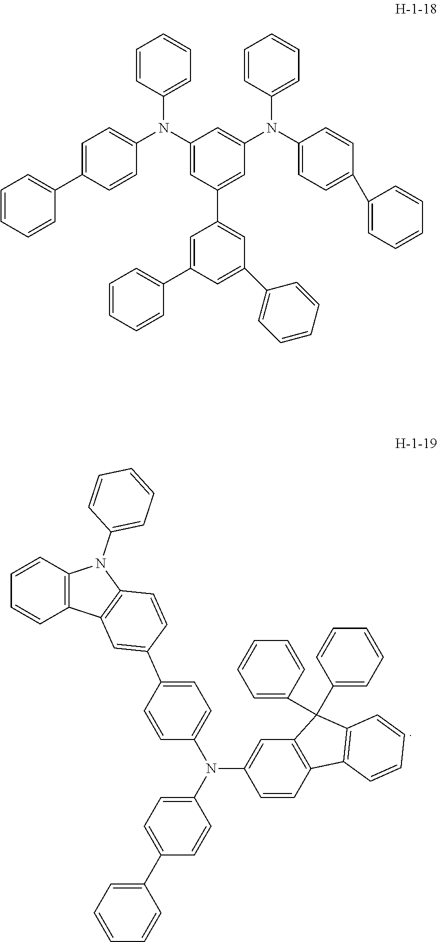 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may further include a phthalocyanine compound such as copper phthalocyanine, N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris[N (2-naphthyl)-N-phenylamino]-triphenylamine (2-TNATA), poly(3,4-ethylenedioxythiophenc)/poly(4-styrenesulfonate) (PEDOT/PSS), polyaniline/dodecylbenzene sulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyether ketone (TPAPEK), 4-Isopropyl-4′-methyldiphenyliodonium [tetrakis(pentafluorophenyl)borate], dipyrazino[2,3-f:2′,3′-h]quinoxaline-2,3,6,7,10,11-hexacarbonitrile (HATCN), or the like.

The hole transport region HTR may further include a carbazole-based derivative such as N-phenylcarbazole or polyvinylcarbazole, a fluorene-based derivative, a triphenylamine-based derivative such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl)benzenamine] (TAPC), 4,4′-bis[N,N′-(3-tolyl)amino]-3,3′-dimethylbiphenyl (HMTPD), (1,3-bis(N-carbazolyl)benzene (mCP), or the like.

In an embodiment, the hole transport region HTR may further include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), or the like.

The hole transport region HTR may include the above-described compounds of the hole transport region in at least one of a hole injection layer HIL, a hole transport layer HTL, an emission-auxiliary layer EAL, and an electron blocking layer EBL.

A thickness of the hole transport region HTR may be in a range of about 100 Å to about 10,000 Å. For example, the thickness of the hole transport region HTR may be in a range of about 100 Å to about 5,000 Å. When the hole transport region HTR includes a hole injection layer HIL, a thickness of the hole injection layer HIL may be, for example, in a range of about 30 Å to about 1,000 Å. When the hole transport region HTR includes a hole transport layer HTL, a thickness of the hole transport layer HTL may be in a range of about 30 Å to about 1,000 Å. When the hole transport region HTR includes an electron blocking layer EBL, a thickness of the electron blocking layer EBL may be in a range of about 10 Å to about 1,000 Å. When the thicknesses of the hole transport region HTR, the hole injection layer HIL, the hole transport layer HTL, and the electron blocking layer EBL satisfy the above-described ranges, satisfactory hole transport properties may be obtained without a substantial increase in driving voltage.

The hole transport region HTR may further include a charge generating material to improve conductivity, in addition to the above-mentioned materials. The charge generating material may be uniformly or non-uniformly dispersed in the hole transport region HTR. The charge generating material may be, for example, a p-dopant. The p-dopant may include at least one of a metal halide, a quinone derivative, a metal oxide, or a cyano group-containing compound, but embodiments are not limited thereto. For example, the p-dopant may be a metal halide such as CuI and RbI, a quinone derivative such as tetracyanoquinodimethane (TCNQ) and 2,3,5,6-tetrafluoro-7,7′,8,8′-tetracyanoquinodimethane (F4-TCNQ), a metal oxide such as a tungsten oxide and a molybdenum oxide, a cyano group-containing compound such as dipyrazino[2,3-f:2′,3′-h] quinoxaline-2,3,6,7,10,11-hexacarbonitrile (HATCN) and 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), and the like, but embodiments are not limited thereto.

As described above, the hole transport region HTR may further include at least one of an emission-auxiliary layer EAL and an electron blocking layer EBL, in addition to a hole injection layer HIL and a hole transport layer HTL. The emission-auxiliary layer EAL may increase light emission efficiency by compensating for a resonance distance according to a wavelength of light emitted from the emission layer EML, and by controlling hole charge balance. The emission-auxiliary layer EAL may also prevent electron injection into the hole transport region HTR. A material that may be included in the hole transport region HTR may be included in the emission-auxiliary layer EAL. The electron blocking layer EBL may prevent injection of electrons from an electron transport region ETR to the hole transport region HTR.

The emission layer EML of the light emitting element ED according to an embodiment may include a polycyclic compound according to an embodiment. In the light emitting element ED, the emission layer EML may include a first compound, which is the polycyclic compound according to an embodiment, and at least one of a second compound and a third compound. In an embodiment, the light emitting element ED, the emission layer EML may further include a fourth compound. The second compound may include a tricyclic fused ring containing a nitrogen atom as a ring-forming atom. The third compound may include a hexagonal ring group containing at least one nitrogen atom as a ring-forming atom. The fourth compound may include an organometallic complex. The second compound, the third compound, and the fourth compound will be described in more detail later.

In the specification, the first compound may be referred to as a polycyclic compound. The polycyclic compound according to an embodiment includes a fused ring core that includes boron. The polycyclic compound according to an embodiment, which is the first compound, includes, as a central structure, a pentacyclic fused ring core that includes boron and nitrogen as ring-forming atoms. The polycyclic compound according to an embodiment includes at least one electron withdrawing group and at least one electron donating group as substituents of the fused ring core. The electron withdrawing group and the electron donating group may each be bonded to at least one of two sterically adjacent benzene rings in the fused ring core.

In an embodiment, the electron withdrawing group may be a substituted or unsubstituted triazine group. At least one substituted or unsubstituted triazine group that is directly bonded to a benzene ring of the fused ring core may be referred to as a first substituent. In an embodiment, the electron donating group may be a substituted or unsubstituted carbazole group. At least one substituted or unsubstituted carbazole group that is directly bonded to a benzene ring of the fused ring core may be referred to as a second substituent.

The polycyclic compound an embodiment may include a pentacyclic fused ring core that includes boron as a central structure, and may include an electron withdrawing group and an electron donating group that are each directly bonded to the fused ring core, thereby generating reverse intersystem crossing (RISC). The polycyclic compound according to an embodiment may exhibit thermally activated delayed fluorescence (TADF) emission characteristics by RISC.

The polycyclic compound according to an embodiment may emit light in a blue wavelength region due to such a structure in which the first substituent and the second substituent are each bonded at a specific position of the fused ring core. In the polycyclic compound according to an embodiment, the electron withdrawing group and the electron donating group may be bonded to a same benzene ring or may be bonded to sterically adjacent benzene rings, thereby exhibiting excellent material stability. In the polycyclic compound according to an embodiment, the carbazole group, which is the second substituent, is bonded to a benzene ring at a position that is relatively adjacent to the triazine group, which is the first substituent having high planarity, so that intermolecular reactions that contribute to material degradation may be prevented. Accordingly, the light emitting element that includes the polycyclic compound according to an embodiment may exhibit high luminous efficiency and long service life characteristics.

The light emitting element ED according to an embodiment may include the polycyclic compound according to an embodiment. The polycyclic compound according to an embodiment may be represented by Formula 1:

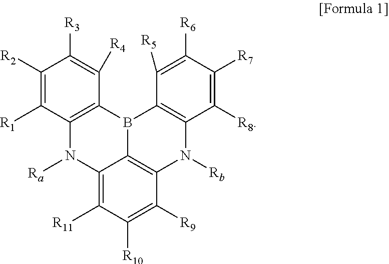

In Formula 1, at least one of R₁ to R₈ may each independently be a first substituent represented by Formula 2; and at least one of the remainder of R₁ to R₈ that is not the first substituent may each independently be a second substituent represented by Formula 3. The first substituent may be a substituted or unsubstituted triazine group, and the second substituent may be a substituted or unsubstituted carbazole group. For example, the first substituent and the second substituent may be bonded to a same benzene ring, or may each be bonded to adjacent benzene rings.

In Formula 1, the remainder of R₁ to R₈ that are not the first substituent or the second substituent are substituted may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula 1, R₉ to R₁₁ may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, in Formula 1, R₉ to R₁₁ may each independently be a hydrogen atom, a deuterium atom, a substituted or unsubstituted alkyl group having 1 to 10 carbon atoms, or a substituted or unsubstituted aryl group having 6 to 18 ring-forming carbon atoms. In an embodiment, in Formula 1, R₉ to R₁₁ may not include a triazine group or a carbazole group.

In Formula 1, Rₐ and R_{b} may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Rₐ and R_{b} may each independently be a substituted or unsubstituted aryl group having 6 to 30 ring-forming carbon atoms. For example, in an embodiment, Rₐ and R_{b} may each independently be a substituted or unsubstituted phenyl group, a substituted or unsubstituted biphenyl group, or a substituted or unsubstituted terphenyl group.

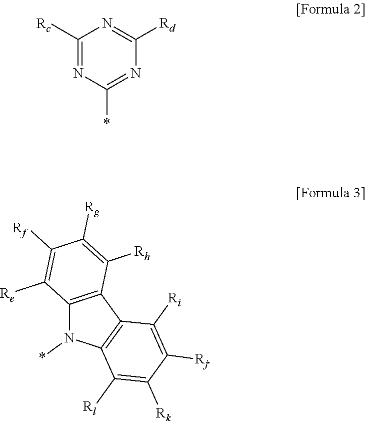

In Formula 2 and Formula 3, R_{c} to Rₗ may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula 2 and Formula 3, [symbol] represents a position linked to Formula 1.

In an embodiment, R_{c} and R_{d} may be the same as each other. However, embodiments are not limited thereto.

In an embodiment, at least one first substituent represented by Formula 2 and at least one third substituent represented by Formula 3 may be bonded to at least one of Ar1 and Ar2 in a fused ring core represented by Formula A. For example, the first substituent and the second substituent may both be bonded to Ar1 or Ar2, the first substituent or the second substituent may be bonded to Ar1 and the other may be bonded to Ar2, or the first substituent or the second substituent may be bonded to Ar2 and the other may be bonded to Ar1:

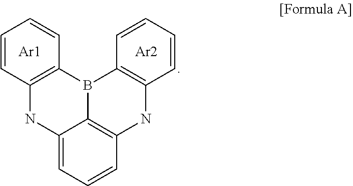

In an embodiment, in the polycyclic compound, at least one hydrogen may be substituted with a deuterium atom. In an embodiment, at least one of the remainder of R₁ to R₈ that are not the first substituent or the second substituent in Formula 1, R₉ to R₁₁ in Formula 1, R_{c} and R_{d} in Formula 2, and R_{d} to Rₗ in Formula 3 may be a deuterium atom, or may be a substituents that includes a deuterium atom.

In an embodiment, the polycyclic compound represented by Formula 1 may be represented by Formula 1-1 or Formula 1-2. In Formula 1-1 and Formula 1-2, SB corresponds to the first substituent or the second substituent.

Formula 1-1 represents a case where at least one first substituent and/or at least one second substituent is bonded to a benzene ring that is different from the remainder, and Formula 1-2 represents a case where the first substituent and the second substituent are bonded to a same benzene ring:

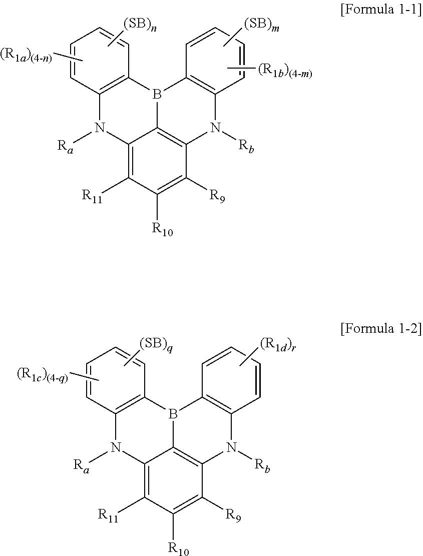

In Formula 1-1 and Formula 1-2, SB may each independently be a first substituent represented by Formula 2 or a second substituent represented by Formula 3, provided that at least one SB is the first substituent and at least one SB is the second substituent.

In Formula 1-1 and Formula 1-2, R₁ₐ to R_{1d} may each independently be a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, provided that R₁ₐ to R_{1d} may not be a triazine group or a carbazole group.

In Formula 1-1, n and m may each independently be an integer from 1 to 3. When n is 1 or 2, multiple R_{1b} groups may be all the same or at least one thereof may be different from the remainder. When m is 1 or 2, multiple Rib groups may be all the same or at least one thereof may be different from the remainder.

In Formula 1-1, SB in the number of a sum of m and n may include at least one first substituent and at least one second substituent.

In Formula 1-2, q may be an integer from 2 to 4, and r may be an integer from 1 to 4. When q is 2 or greater, multiple R_{1c} groups may be all the same or at least one thereof may be different from the remainder. When r is 2 or greater, multiple R_{1d} groups may be all the same or at least one thereof may be different from the remainder. In Formula 1-2, SB in the number of q may include at least one first substituent and at least one second substituent.

In Formula 1-1 and Formula 1-2, R₉ to R₁₁, Rₐ, and R_{b} are each the same as defined in Formula 1.

In an embodiment, the polycyclic compound represented by Formula 1 may be any compound selected from Compound Group 1. In an embodiment, in the light emitting element ED, the emission layer EML may include at least one compound selected from Compound Group 1. In Compound Group 1, D represents a deuterium atom:

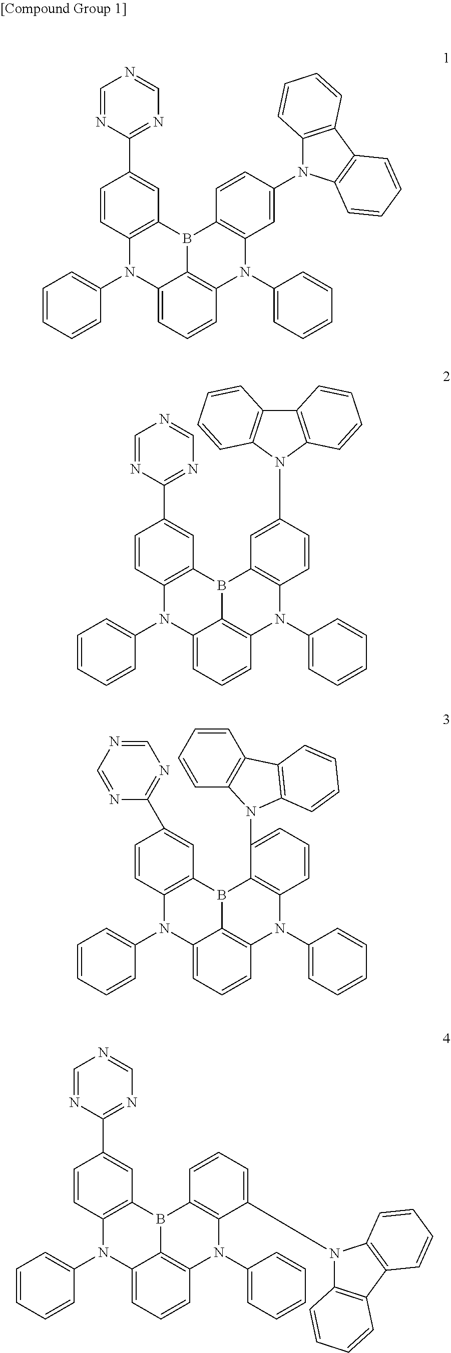

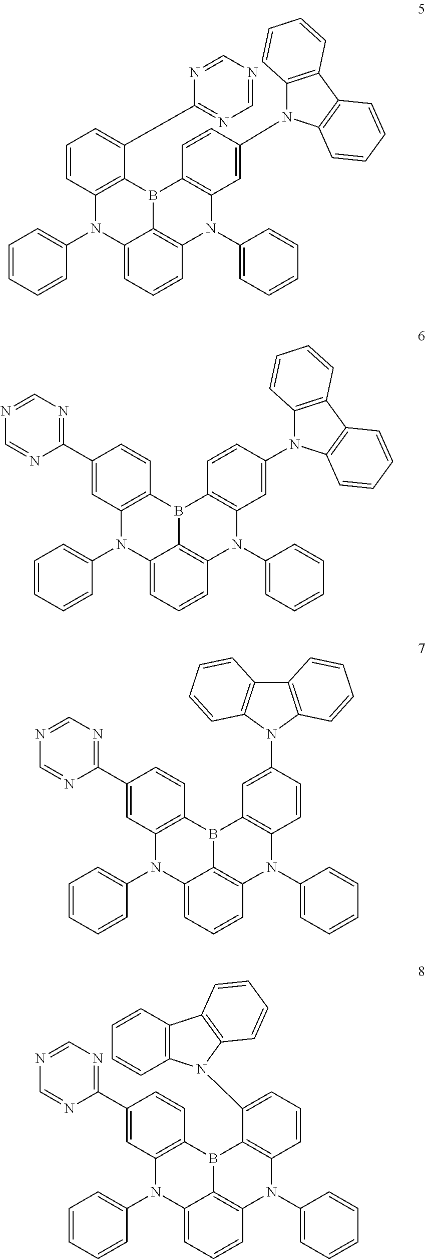 [SMILES: c1ccc(N2c3cc(-n4c5ccccc5c5ccccc54)ccc3B3c4c(-c5ncncn5)cccc4N(c4ccccc4)c4cccc2c43)cc1 ; c1ccc(N2c3cc(-c4ncncn4)ccc3B3c4ccc(-n5c6ccccc6c6ccccc65)cc4N(c4ccccc4)c4cccc2c43)cc1 ; c1ccc(N2c3ccc(-n4c5ccccc5c5ccccc54)cc3B3c4ccc(-c5ncncn5)cc4N(c4ccccc4)c4cccc2c43)cc1 ; c1ccc(N2c3cc(-c4ncncn4)ccc3B3c4c2cccc4N(c2ccccc2)c2cccc(-n4c5ccccc5c5ccccc54)c23)cc1]

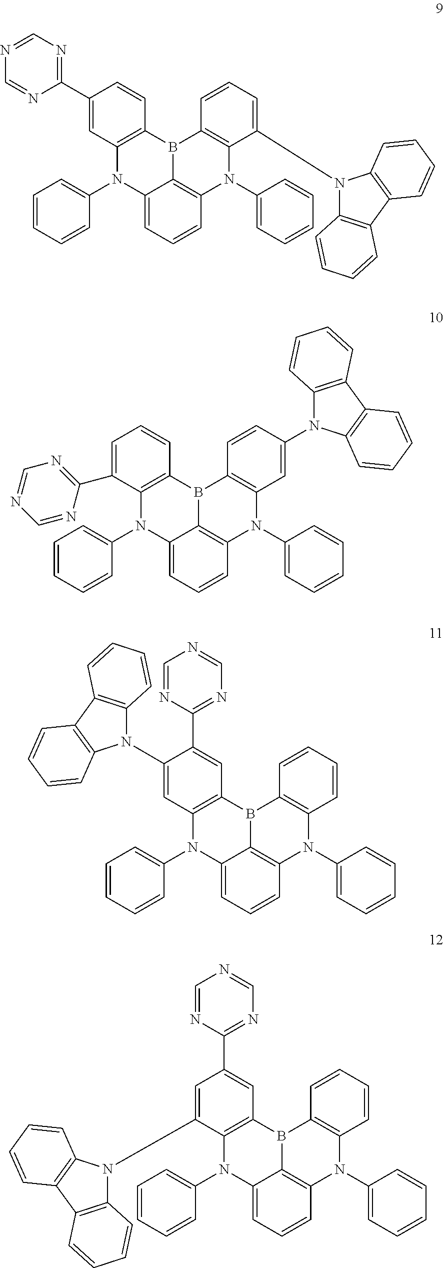 [SMILES: c1ccc(N2c3cc(-c4ncncn4)ccc3B3c4cccc(-n5c6ccccc6c6ccccc65)c4N(c4ccccc4)c4cccc2c43)cc1 ; c1ccc(N2c3cc(-n4c5ccccc5c5ccccc54)ccc3B3c4cccc(-c5ncncn5)c4N(c4ccccc4)c4cccc2c43)cc1 ; c1ccc(N2c3ccccc3B3c4cc(-c5ncncn5)c(-n5c6ccccc6c6ccccc65)cc4N(c4ccccc4)c4cccc2c43)cc1 ; c1ccc(N2c3ccccc3B3c4cc(-c5ncncn5)cc(-n5c6ccccc6c6ccccc65)c4N(c4ccccc4)c4cccc2c43)cc1]

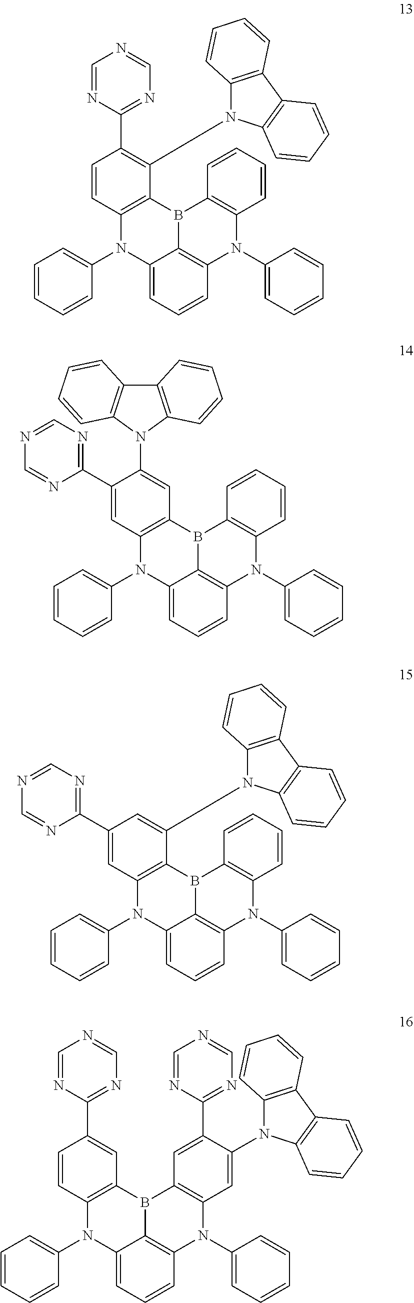

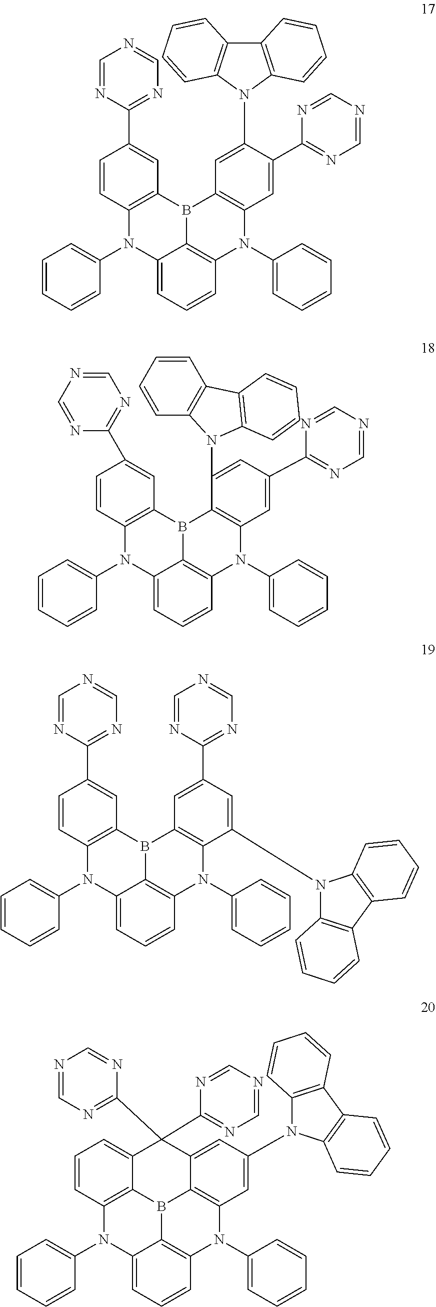 [SMILES: c1ccc(N2c3ccc(-c4ncncn4)cc3B3c4cc(-n5c6ccccc6c6ccccc65)c(-c5ncncn5)cc4N(c4ccccc4)c4cccc2c43)cc1 ; c1ccc(N2c3ccc(-c4ncncn4)cc3B3c4c2cccc4N(c2ccccc2)c2cc(-c4ncncn4)cc(-n4c5ccccc5c5ccccc54)c23)cc1 ; c1ccc(N2c3ccc(-c4ncncn4)cc3B3c4cc(-c5ncncn5)cc(-n5c6ccccc6c6ccccc65)c4N(c4ccccc4)c4cccc2c43)cc1 ; c1ccc(N2c3cccc4c3B3c5c2cccc5C(c2ncncn2)(c2ncncn2)c2cc(-n5c6ccccc6c6ccccc65)cc(c23)N4c2ccccc2)cc1]

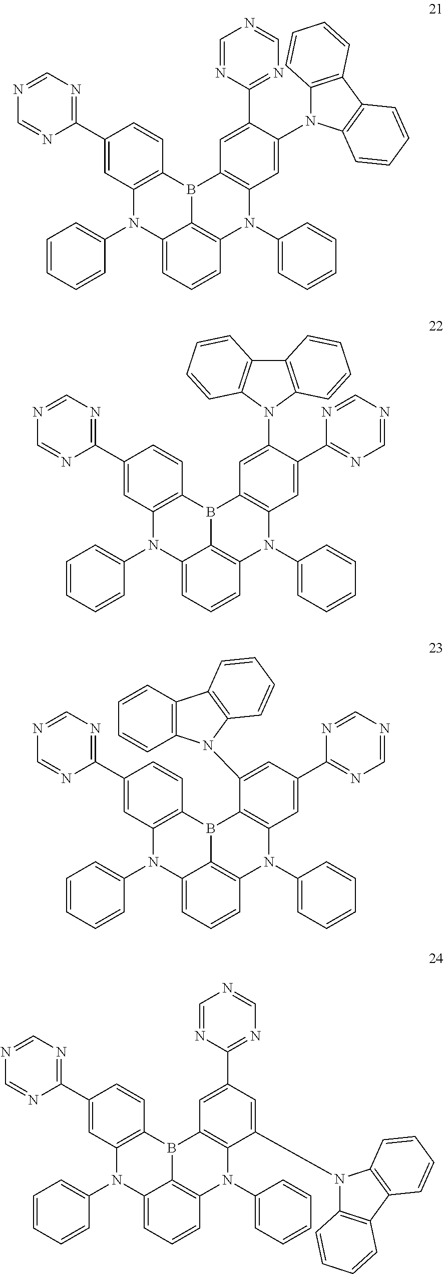

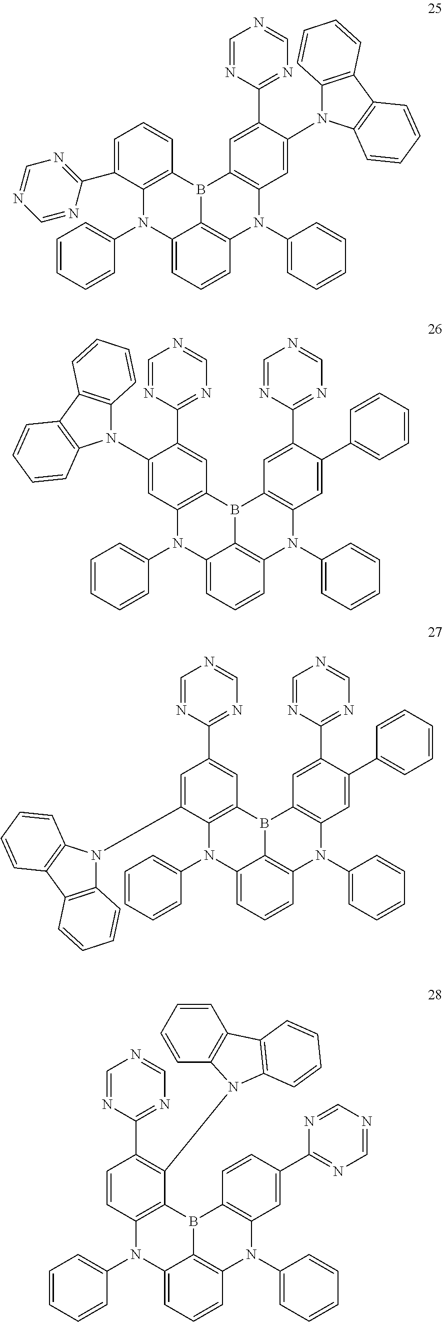 [SMILES: c1ccc(N2c3cc(-n4c5ccccc5c5ccccc54)c(-c4ncncn4)cc3B3c4cccc(-c5ncncn5)c4N(c4ccccc4)c4cccc2c43)cc1 ; c1ccc(-c2cc3c(cc2-c2ncncn2)B2c4cc(-c5ncncn5)c(-n5c6ccccc6c6ccccc65)cc4N(c4ccccc4)c4cccc(c42)N3c2ccccc2)cc1 ; c1ccc(-c2cc3c(cc2-c2ncncn2)B2c4cc(-c5ncncn5)cc(-n5c6ccccc6c6ccccc65)c4N(c4ccccc4)c4cccc(c42)N3c2ccccc2)cc1 ; c1ccc(N2c3cc(-c4ncncn4)ccc3B3c4c2cccc4N(c2ccccc2)c2ccc(-c4ncncn4)c(-n4c5ccccc5c5ccccc54)c23)cc1]

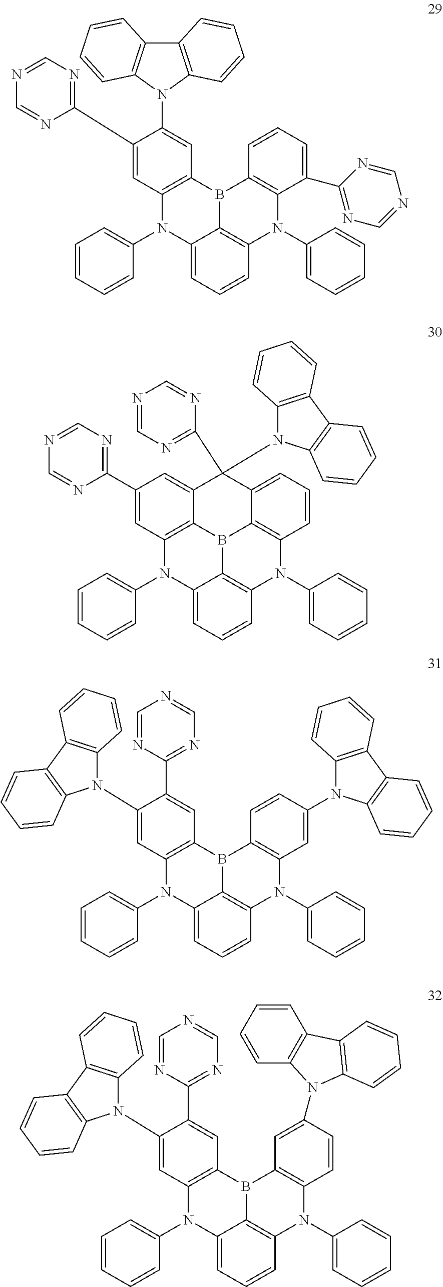 [SMILES: c1ccc(N2c3cc(-c4ncncn4)c(-n4c5ccccc5c5ccccc54)cc3B3c4cccc(-c5ncncn5)c4N(c4ccccc4)c4cccc2c43)cc1 ; c1ccc(N2c3cccc4c3B3c5c2cccc5C(c2ncncn2)(n2c5ccccc5c5ccccc52)c2cc(-c5ncncn5)cc(c23)N4c2ccccc2)cc1 ; c1ccc(N2c3cc(-n4c5ccccc5c5ccccc54)ccc3B3c4cc(-c5ncncn5)c(-n5c6ccccc6c6ccccc65)cc4N(c4ccccc4)c4cccc2c43)cc1 ; c1ccc(N2c3ccc(-n4c5ccccc5c5ccccc54)cc3B3c4cc(-c5ncncn5)c(-n5c6ccccc6c6ccccc65)cc4N(c4ccccc4)c4cccc2c43)cc1]

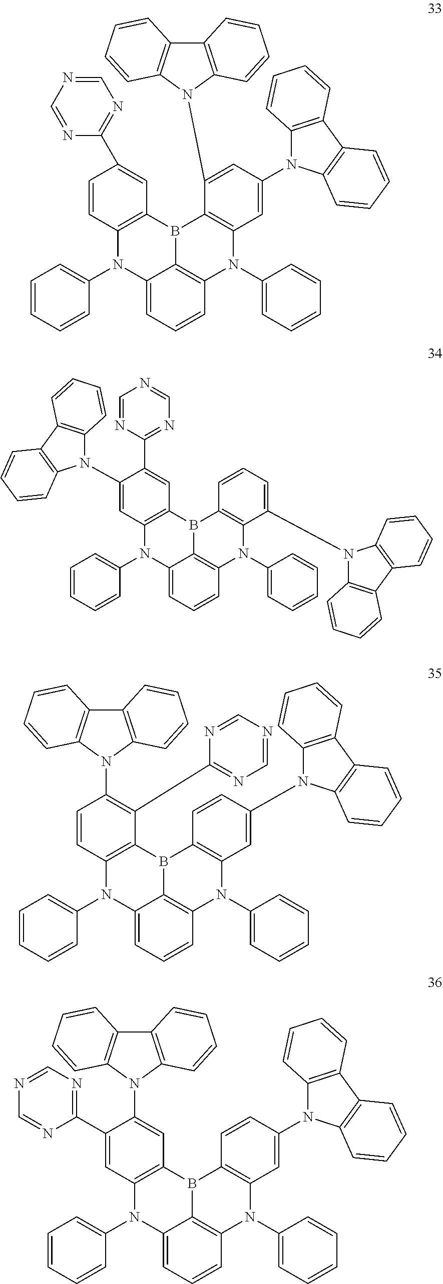 [SMILES: c1ccc(N2c3ccc(-c4ncncn4)cc3B3c4c2cccc4N(c2ccccc2)c2cc(-n4c5ccccc5c5ccccc54)cc(-n4c5ccccc5c5ccccc54)c23)cc1 ; c1ccc(N2c3cc(-n4c5ccccc5c5ccccc54)c(-c4ncncn4)cc3B3c4cccc(-n5c6ccccc6c6ccccc65)c4N(c4ccccc4)c4cccc2c43)cc1 ; c1ccc(N2c3cc(-n4c5ccccc5c5ccccc54)ccc3B3c4c2cccc4N(c2ccccc2)c2ccc(-n4c5ccccc5c5ccccc54)c(-c4ncncn4)c23)cc1 ; c1ccc(N2c3cc(-n4c5ccccc5c5ccccc54)ccc3B3c4cc(-n5c6ccccc6c6ccccc65)c(-c5ncncn5)cc4N(c4ccccc4)c4cccc2c43)cc1]

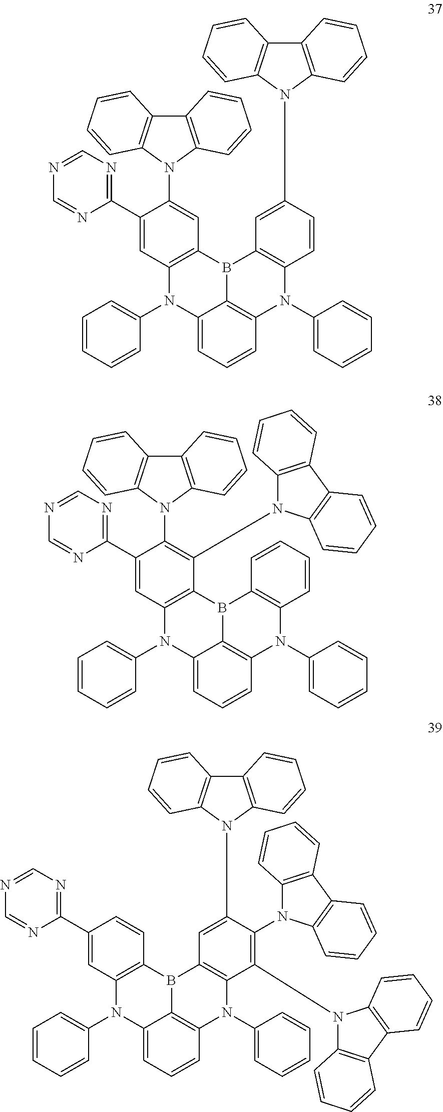 [SMILES: c1ccc(N2c3ccc(-n4c5ccccc5c5ccccc54)cc3B3c4cc(-n5c6ccccc6c6ccccc65)c(-c5ncncn5)cc4N(c4ccccc4)c4cccc2c43)cc1 ; c1ccc(N2c3ccccc3B3c4c2cccc4N(c2ccccc2)c2cc(-c4ncncn4)c(-n4c5ccccc5c5ccccc54)c(-n4c5ccccc5c5ccccc54)c23)cc1 ; c1ccc(N2c3cc(-c4ncncn4)ccc3B3c4cc(-n5c6ccccc6c6ccccc65)c(-n5c6ccccc6c6ccccc65)c(-n5c6ccccc6c6ccccc65)c4N(c4ccccc4)c4cccc2c43)cc1]

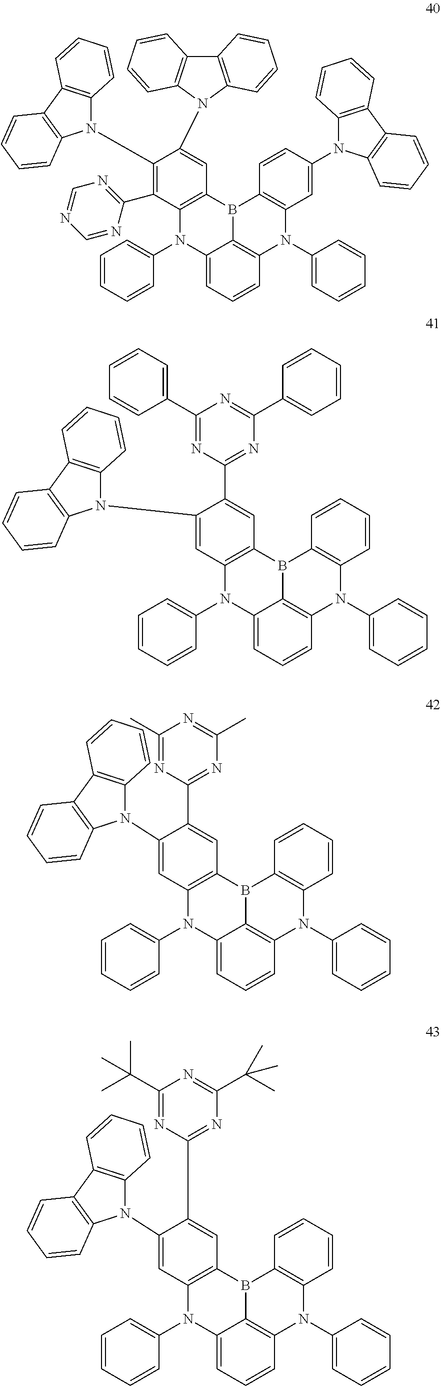 [SMILES: c1ccc(N2c3cc(-n4c5ccccc5c5ccccc54)ccc3B3c4cc(-n5c6ccccc6c6ccccc65)c(-n5c6ccccc6c6ccccc65)c(-c5ncncn5)c4N(c4ccccc4)c4cccc2c43)cc1 ; c1ccc(-c2nc(-c3ccccc3)nc(-c3cc4c(cc3-n3c5ccccc5c5ccccc53)N(c3ccccc3)c3cccc5c3B4c3ccccc3N5c3ccccc3)n2)cc1 ; Cc1nc(C)nc(-c2cc3c(cc2-n2c4ccccc4c4ccccc42)N(c2ccccc2)c2cccc4c2B3c2ccccc2N4c2ccccc2)n1 ; CC(C)(C)c1nc(-c2cc3c(cc2-n2c4ccccc4c4ccccc42)N(c2ccccc2)c2cccc4c2B3c2ccccc2N4c2ccccc2)nc(C(C)(C)C)n1]

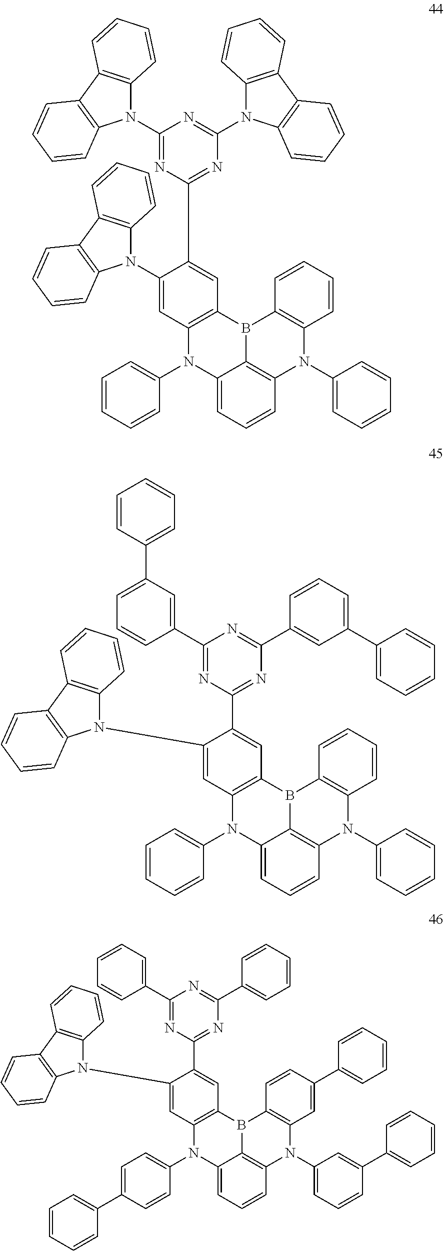 [SMILES: c1ccc(N2c3ccccc3B3c4cc(-c5nc(-n6c7ccccc7c7ccccc76)nc(-n6c7ccccc7c7ccccc76)n5)c(-n5c6ccccc6c6ccccc65)cc4N(c4ccccc4)c4cccc2c43)cc1 ; c1ccc(-c2cccc(-c3nc(-c4cccc(-c5ccccc5)c4)nc(-c4cc5c(cc4-n4c6ccccc6c6ccccc64)N(c4ccccc4)c4cccc6c4B5c4ccccc4N6c4ccccc4)n3)c2)cc1 ; c1ccc(-c2ccc(N3c4cc(-n5c6ccccc6c6ccccc65)c(-c5nc(-c6ccccc6)nc(-c6ccccc6)n5)cc4B4c5ccc(-c6ccccc6)cc5N(c5cccc(-c6ccccc6)c5)c5cccc3c54)cc2)cc1]

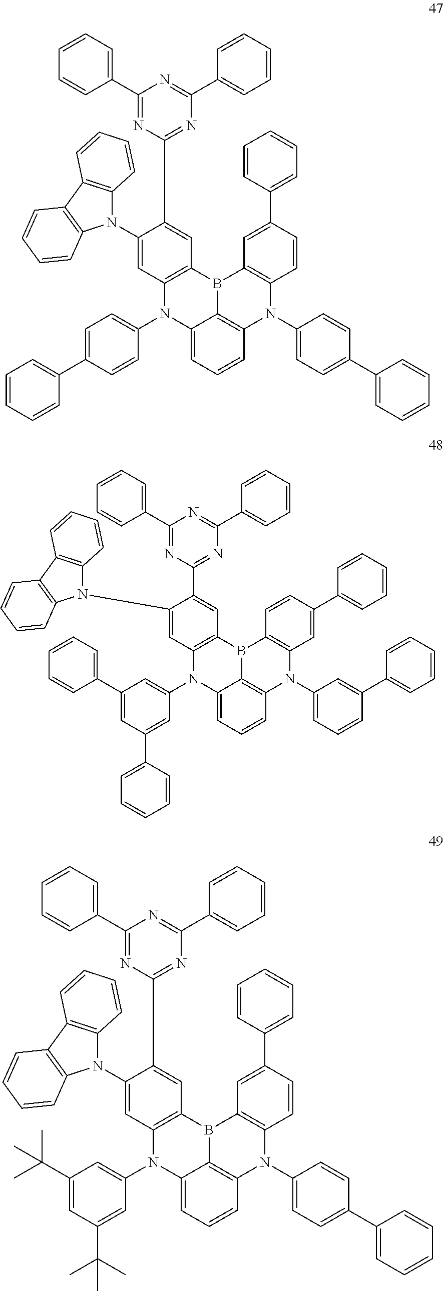 [SMILES: c1ccc(-c2ccc(N3c4ccc(-c5ccccc5)cc4B4c5cc(-c6nc(-c7ccccc7)nc(-c7ccccc7)n6)c(-n6c7ccccc7c7ccccc76)cc5N(c5ccc(-c6ccccc6)cc5)c5cccc3c54)cc2)cc1 ; c1ccc(-c2cccc(N3c4cc(-c5ccccc5)ccc4B4c5cc(-c6nc(-c7ccccc7)nc(-c7ccccc7)n6)c(-n6c7ccccc7c7ccccc76)cc5N(c5cc(-c6ccccc6)cc(-c6ccccc6)c5)c5cccc3c54)c2)cc1 ; CC(C)(C)c1cc(N2c3cc(-n4c5ccccc5c5ccccc54)c(-c4nc(-c5ccccc5)nc(-c5ccccc5)n4)cc3B3c4cc(-c5ccccc5)ccc4N(c4ccc(-c5ccccc5)cc4)c4cccc2c43)cc(C(C)(C)C)c1]

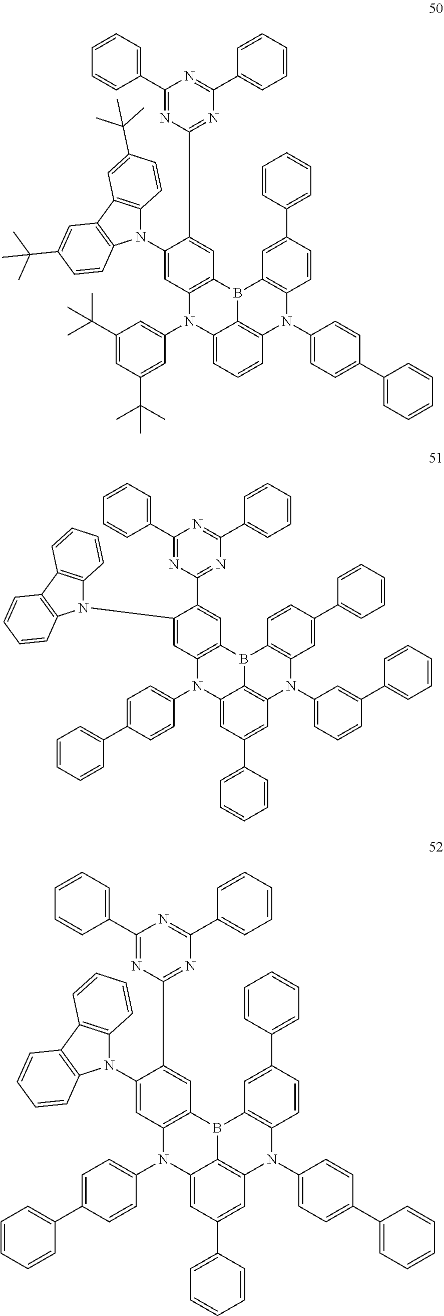 [SMILES: CC(C)(C)c1cc(N2c3cc(-n4c5ccc(C(C)(C)C)cc5c5cc(C(C)(C)C)ccc54)c(-c4nc(-c5ccccc5)nc(-c5ccccc5)n4)cc3B3c4cc(-c5ccccc5)ccc4N(c4ccc(-c5ccccc5)cc4)c4cccc2c43)cc(C(C)(C)C)c1 ; c1ccc(-c2ccc(N3c4cc(-n5c6ccccc6c6ccccc65)c(-c5nc(-c6ccccc6)nc(-c6ccccc6)n5)cc4B4c5ccc(-c6ccccc6)cc5N(c5cccc(-c6ccccc6)c5)c5cc(-c6ccccc6)cc3c54)cc2)cc1 ; c1ccc(-c2ccc(N3c4ccc(-c5ccccc5)cc4B4c5cc(-c6nc(-c7ccccc7)nc(-c7ccccc7)n6)c(-n6c7ccccc7c7ccccc76)cc5N(c5ccc(-c6ccccc6)cc5)c5cc(-c6ccccc6)cc3c54)cc2)cc1]

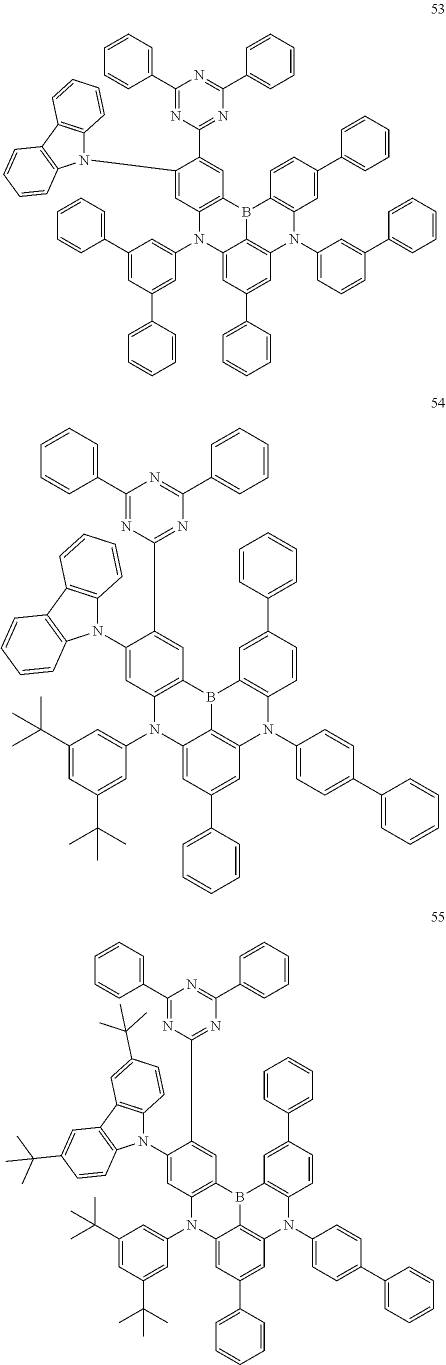

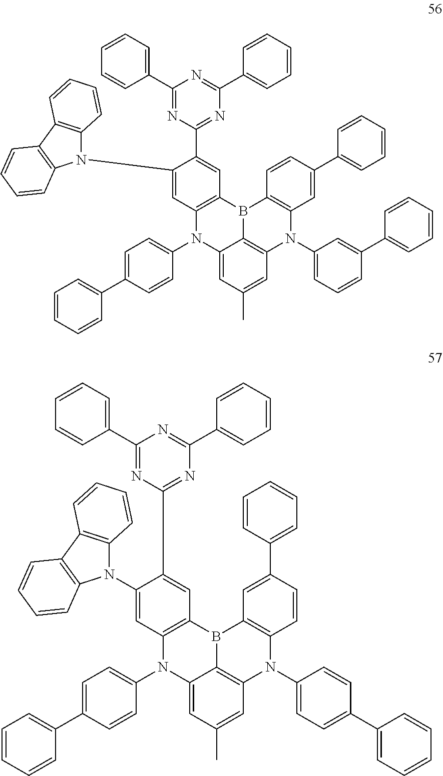 [SMILES: Cc1cc2c3c(c1)N(c1ccc(-c4ccccc4)cc1)c1cc(-n4c5ccccc5c5ccccc54)c(-c4nc(-c5ccccc5)nc(-c5ccccc5)n4)cc1B3c1ccc(-c3ccccc3)cc1N2c1cccc(-c2ccccc2)c1 ; Cc1cc2c3c(c1)N(c1ccc(-c4ccccc4)cc1)c1cc(-n4c5ccccc5c5ccccc54)c(-c4nc(-c5ccccc5)nc(-c5ccccc5)n4)cc1B3c1cc(-c3ccccc3)ccc1N2c1ccc(-c2ccccc2)cc1]

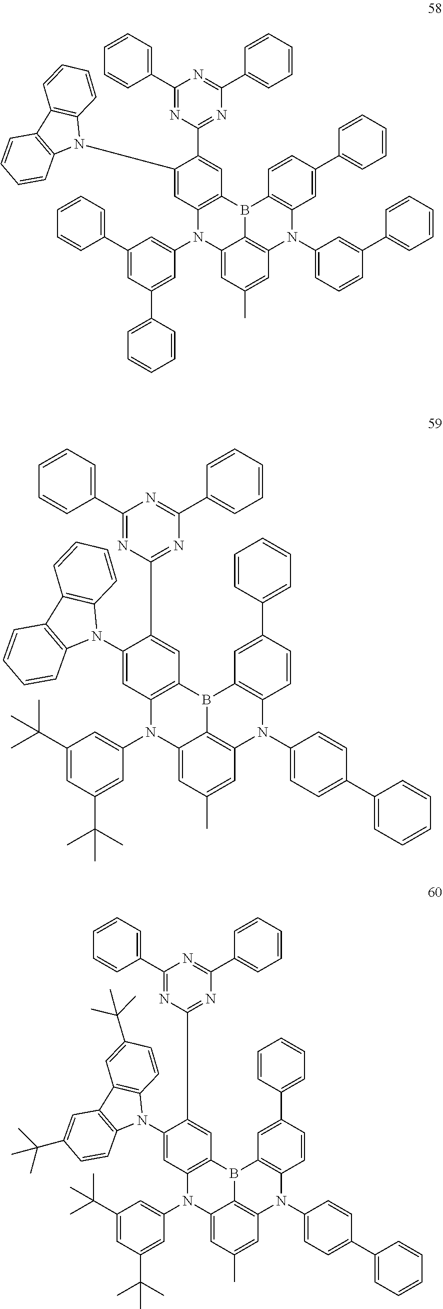 [SMILES: Cc1cc2c3c(c1)N(c1cc(-c4ccccc4)cc(-c4ccccc4)c1)c1cc(-n4c5ccccc5c5ccccc54)c(-c4nc(-c5ccccc5)nc(-c5ccccc5)n4)cc1B3c1ccc(-c3ccccc3)cc1N2c1cccc(-c2ccccc2)c1 ; Cc1cc2c3c(c1)N(c1cc(C(C)(C)C)cc(C(C)(C)C)c1)c1cc(-n4c5ccccc5c5ccccc54)c(-c4nc(-c5ccccc5)nc(-c5ccccc5)n4)cc1B3c1cc(-c3ccccc3)ccc1N2c1ccc(-c2ccccc2)cc1 ; Cc1cc2c3c(c1)N(c1cc(C(C)(C)C)cc(C(C)(C)C)c1)c1cc(-n4c5ccc(C(C)(C)C)cc5c5cc(C(C)(C)C)ccc54)c(-c4nc(-c5ccccc5)nc(-c5ccccc5)n4)cc1B3c1cc(-c3ccccc3)ccc1N2c1ccc(-c2ccccc2)cc1]

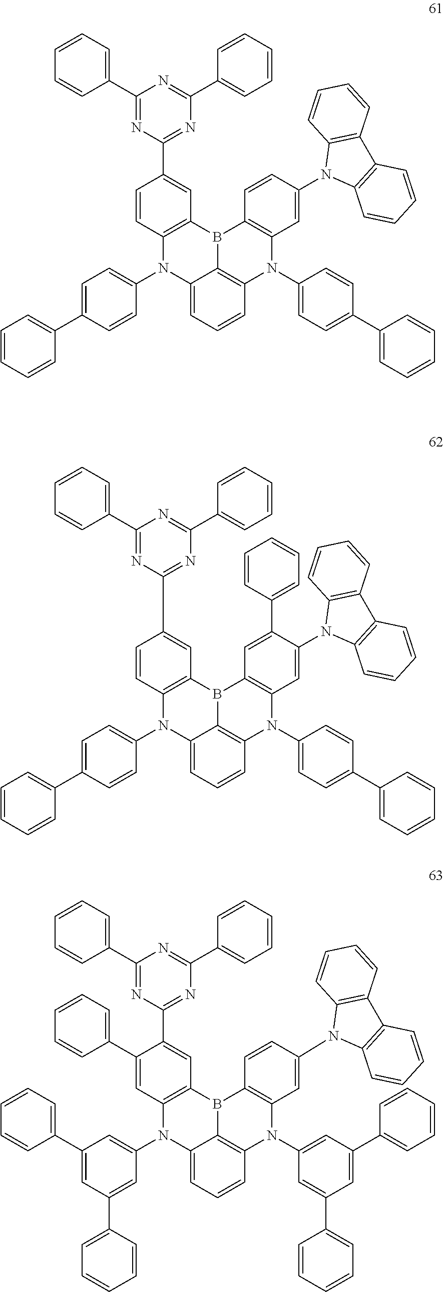 [SMILES: c1ccc(-c2ccc(N3c4ccc(-c5nc(-c6ccccc6)nc(-c6ccccc6)n5)cc4B4c5ccc(-n6c7ccccc7c7ccccc76)cc5N(c5ccc(-c6ccccc6)cc5)c5cccc3c54)cc2)cc1 ; c1ccc(-c2ccc(N3c4ccc(-c5nc(-c6ccccc6)nc(-c6ccccc6)n5)cc4B4c5cc(-c6ccccc6)c(-n6c7ccccc7c7ccccc76)cc5N(c5ccc(-c6ccccc6)cc5)c5cccc3c54)cc2)cc1 ; c1ccc(-c2cc(-c3ccccc3)cc(N3c4cc(-n5c6ccccc6c6ccccc65)ccc4B4c5cc(-c6nc(-c7ccccc7)nc(-c7ccccc7)n6)c(-c6ccccc6)cc5N(c5cc(-c6ccccc6)cc(-c6ccccc6)c5)c5cccc3c54)c2)cc1]

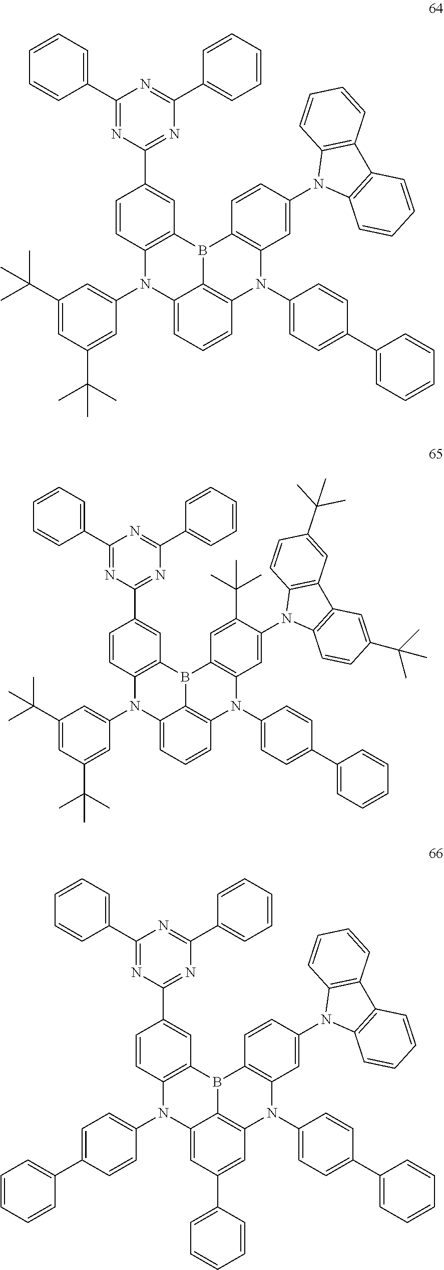 [SMILES: CC(C)(C)c1cc(N2c3ccc(-c4nc(-c5ccccc5)nc(-c5ccccc5)n4)cc3B3c4ccc(-n5c6ccccc6c6ccccc65)cc4N(c4ccc(-c5ccccc5)cc4)c4cccc2c43)cc(C(C)(C)C)c1 ; CC(C)(C)c1cc(N2c3ccc(-c4nc(-c5ccccc5)nc(-c5ccccc5)n4)cc3B3c4cc(C(C)(C)C)c(-n5c6ccc(C(C)(C)C)cc6c6cc(C(C)(C)C)ccc65)cc4N(c4ccc(-c5ccccc5)cc4)c4cccc2c43)cc(C(C)(C)C)c1 ; c1ccc(-c2ccc(N3c4ccc(-c5nc(-c6ccccc6)nc(-c6ccccc6)n5)cc4B4c5ccc(-n6c7ccccc7c7ccccc76)cc5N(c5ccc(-c6ccccc6)cc5)c5cc(-c6ccccc6)cc3c54)cc2)cc1]

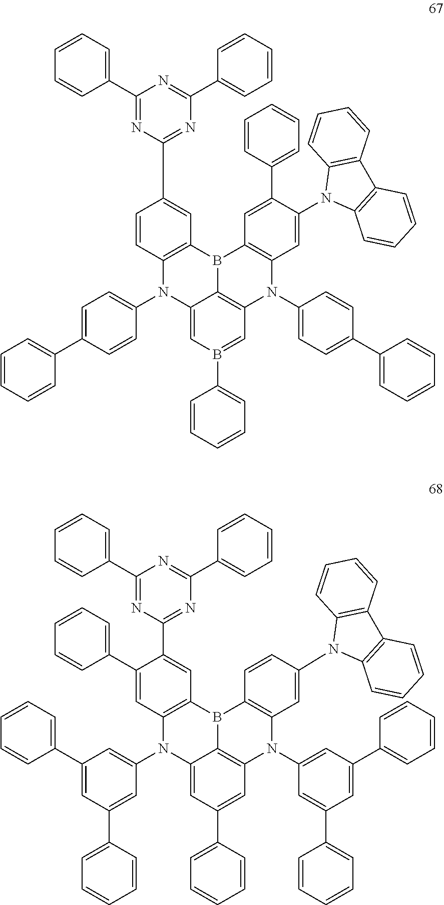

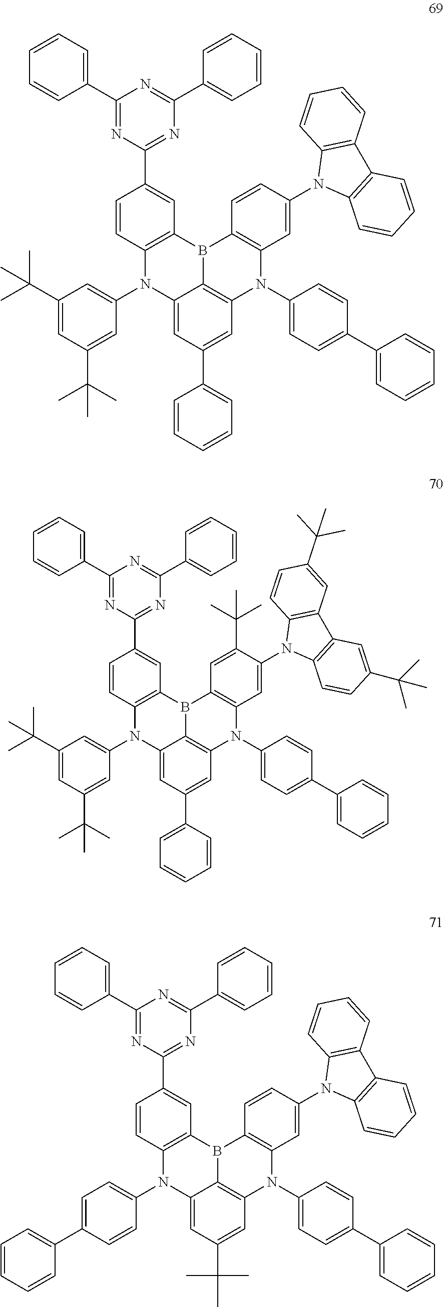 [SMILES: CC(C)(C)c1cc(N2c3ccc(-c4nc(-c5ccccc5)nc(-c5ccccc5)n4)cc3B3c4ccc(-n5c6ccccc6c6ccccc65)cc4N(c4ccc(-c5ccccc5)cc4)c4cc(-c5ccccc5)cc2c43)cc(C(C)(C)C)c1 ; CC(C)(C)c1cc(N2c3ccc(-c4nc(-c5ccccc5)nc(-c5ccccc5)n4)cc3B3c4cc(C(C)(C)C)c(-n5c6ccc(C(C)(C)C)cc6c6cc(C(C)(C)C)ccc65)cc4N(c4ccc(-c5ccccc5)cc4)c4cc(-c5ccccc5)cc2c43)cc(C(C)(C)C)c1 ; CC(C)(C)c1cc2c3c(c1)N(c1ccc(-c4ccccc4)cc1)c1cc(-n4c5ccccc5c5ccccc54)ccc1B3c1cc(-c3nc(-c4ccccc4)nc(-c4ccccc4)n3)ccc1N2c1ccc(-c2ccccc2)cc1]

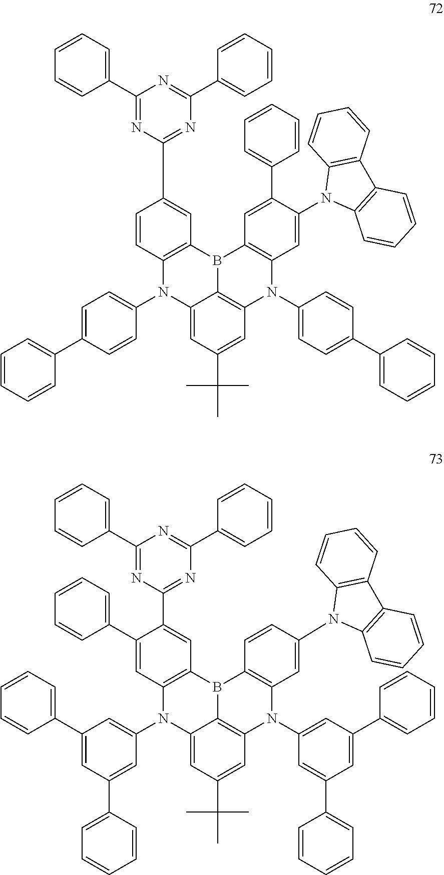 [SMILES: CC(C)(C)c1cc2c3c(c1)N(c1ccc(-c4ccccc4)cc1)c1cc(-n4c5ccccc5c5ccccc54)c(-c4ccccc4)cc1B3c1cc(-c3nc(-c4ccccc4)nc(-c4ccccc4)n3)ccc1N2c1ccc(-c2ccccc2)cc1 ; CC(C)(C)c1cc2c3c(c1)N(c1cc(-c4ccccc4)cc(-c4ccccc4)c1)c1cc(-c4ccccc4)c(-c4nc(-c5ccccc5)nc(-c5ccccc5)n4)cc1B3c1ccc(-n3c4ccccc4c4ccccc43)cc1N2c1cc(-c2ccccc2)cc(-c2ccccc2)c1]

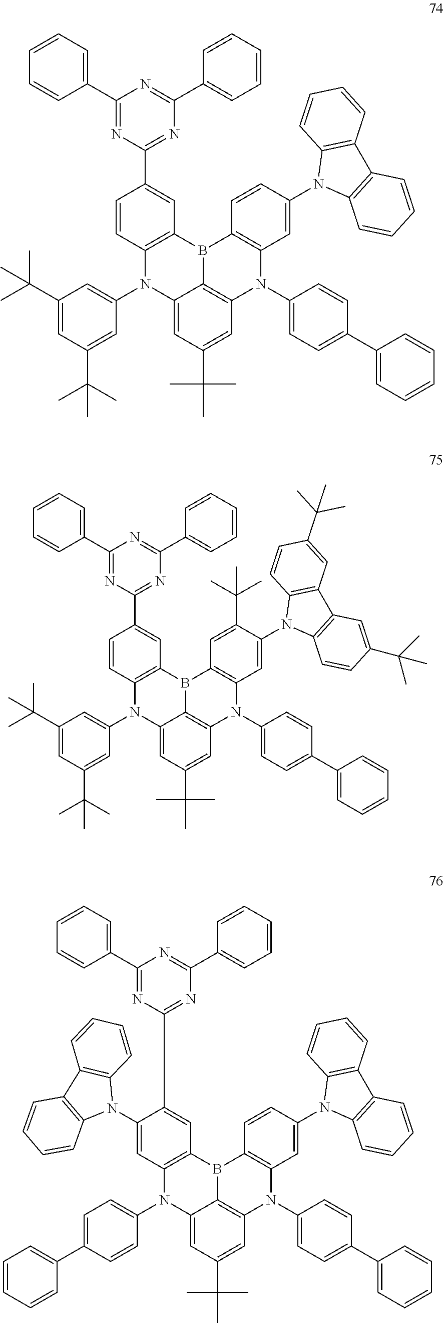 [SMILES: CC(C)(C)c1cc(N2c3ccc(-c4nc(-c5ccccc5)nc(-c5ccccc5)n4)cc3B3c4ccc(-n5c6ccccc6c6ccccc65)cc4N(c4ccc(-c5ccccc5)cc4)c4cc(C(C)(C)C)cc2c43)cc(C(C)(C)C)c1 ; CC(C)(C)c1cc(N2c3ccc(-c4nc(-c5ccccc5)nc(-c5ccccc5)n4)cc3B3c4cc(C(C)(C)C)c(-n5c6ccc(C(C)(C)C)cc6c6cc(C(C)(C)C)ccc65)cc4N(c4ccc(-c5ccccc5)cc4)c4cc(C(C)(C)C)cc2c43)cc(C(C)(C)C)c1 ; CC(C)(C)c1cc2c3c(c1)N(c1ccc(-c4ccccc4)cc1)c1cc(-n4c5ccccc5c5ccccc54)c(-c4nc(-c5ccccc5)nc(-c5ccccc5)n4)cc1B3c1ccc(-n3c4ccccc4c4ccccc43)cc1N2c1ccc(-c2ccccc2)cc1]

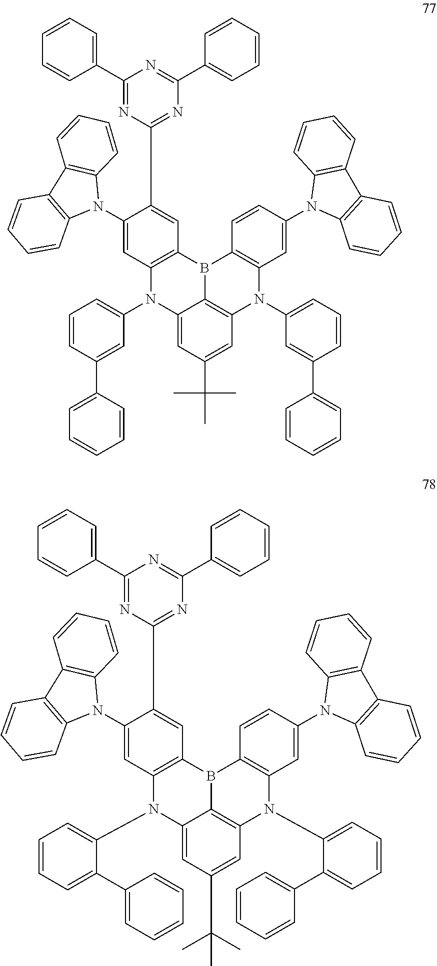 [SMILES: CC(C)(C)c1cc2c3c(c1)N(c1cccc(-c4ccccc4)c1)c1cc(-n4c5ccccc5c5ccccc54)c(-c4nc(-c5ccccc5)nc(-c5ccccc5)n4)cc1B3c1ccc(-n3c4ccccc4c4ccccc43)cc1N2c1cccc(-c2ccccc2)c1 ; CC(C)(C)c1cc2c3c(c1)N(c1ccccc1-c1ccccc1)c1cc(-n4c5ccccc5c5ccccc54)c(-c4nc(-c5ccccc5)nc(-c5ccccc5)n4)cc1B3c1ccc(-n3c4ccccc4c4ccccc43)cc1N2c1ccccc1-c1ccccc1]

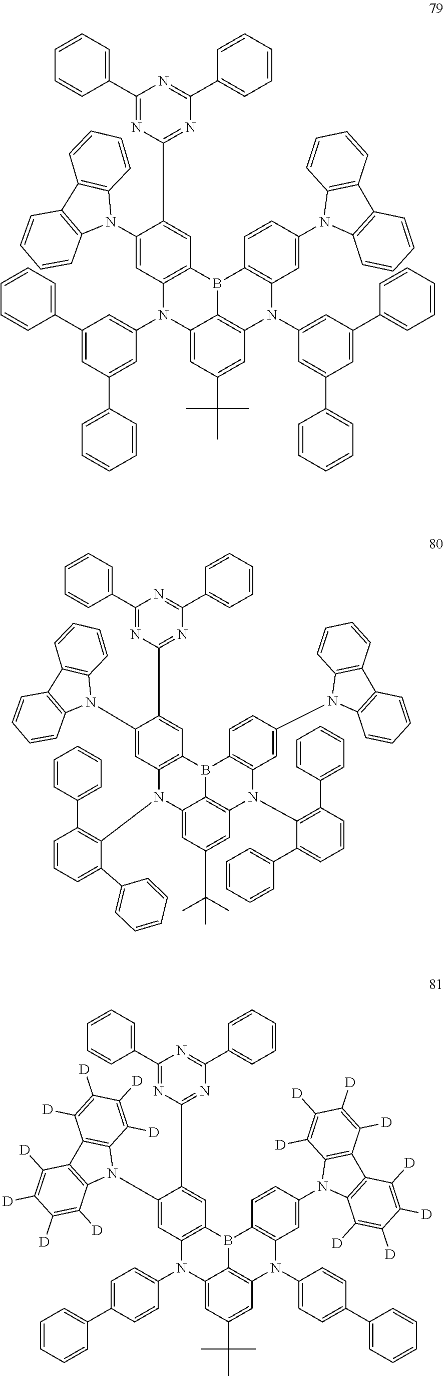

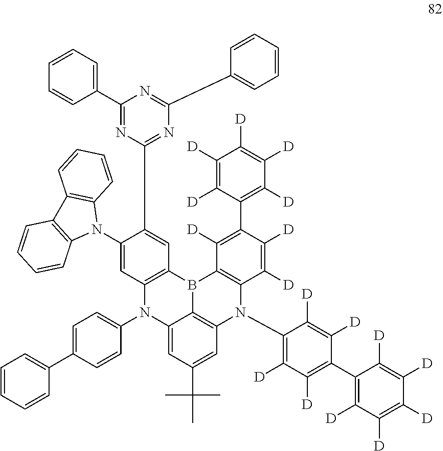 [SMILES: [2H]c1c([2H])c([2H])c(-c2c([2H])c([2H])c(N3c4cc(C(C)(C)C)cc5c4B(c4cc(-c6nc(-c7ccccc7)nc(-c7ccccc7)n6)c(-n6c7ccccc7c7ccccc76)cc4N5c4ccc(-c5ccccc5)cc4)c4c([2H])c(-c5c([2H])c([2H])c([2H])c([2H])c5[2H])c([2H])c([2H])c43)c([2H])c2[2H])c([2H])c1[2H]]

The polycyclic compound according to an embodiment includes a pentacyclic boron-containing fused ring core, a first substituent that is a triazine moiety directly bonded to the fused ring core, and a second substituent that is a carbazole moiety directly bonded to the fused ring core, and the polycyclic compound may be used as a delayed fluorescence material. For example, the polycyclic compound may be used as a thermally activated delayed fluorescence (TADF) material. The polycyclic compound may exhibit a high fluorescence quantum yield. For example, the polycyclic compound may exhibit a high fluorescence quantum yield in a blue wavelength region having a maximum wavelength equal to or less than about 470 nm.

The polycyclic compound according to an embodiment has a structure in which the first substituent and the second substituent are bonded to the fused ring core such that they are adjacent to each other, and thus the first and second substituents prevent rotational movement against each other, thereby exhibiting excellent material stability. The polycyclic compound according to an embodiment may include a boron-containing fused ring core, at least one triazine moiety directly bonded to the fused ring core, and at least one carbazole moiety directly bonded to the fused ring core such that it is bonded to a same benzene ring as the triazine group or bonded to a neighboring benzene ring, and the polycyclic compound may be used as a luminescent material that emits light in a blue light wavelength region. The polycyclic compound may exhibit high luminous efficiency and excellent service life characteristics in a blue light wavelength region.

The light emitting element according to an embodiment including the polycyclic compound according to an embodiment may exhibit high efficiency and long service life characteristics. The light emitting element including the polycyclic compound according to an embodiment, having excellent luminous efficiency and improved material stability, in the emission layer may exhibit high light efficiency and excellent service life characteristics.

In the light emitting element according to an embodiment, the emission layer EML may be a delayed fluorescence emission layer that includes a host and a dopant. For example, the emission layer EML may emit thermally activated delayed fluorescence (TADF). The polycyclic compound according to an embodiment may be a thermally activated delayed fluorescence dopant.

The emission layer EML may include the polycyclic compound according to an embodiment as a dopant. The polycyclic compound may emit blue light. For example, the polycyclic compound may be a luminescent material having a maximum emission wavelength in a range of about 430 nm to about 490 nm. For example, the polycyclic compound may be a luminescent material having a maximum emission wavelength in a range of about 440 nm to about 470 nm.

In an embodiment, the emission layer EML may include the polycyclic compound according to an embodiment and may further include at least one of a second compound, a third compound, and a fourth compound.

In an embodiment, the emission layer EML may further include a second compound represented by Formula HT-1. In an embodiment, the second compound may be used as a hole transporting host material in the emission layer EML:

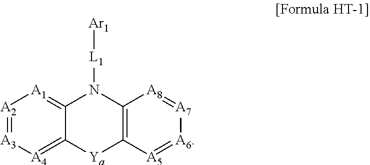

In Formula HT-1, A₁ to A₈ may each independently be N or C(R₅₁). For example, A₁ to A₈ may each independently be C(R₅₁). As another example, one of A₁ to A₈ may be N, and the remainder of A₁ to A₈ may each independently be C(R₅₁).

In Formula HT-1, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, L₁ may be a direct linkage, a substituted or unsubstituted phenylene group, a substituted or unsubstituted divalent biphenyl group, or a substituted or unsubstituted divalent carbazole group, etc., but embodiments are not limited thereto.

In Formula HT-1, Yₐ may be a direct linkage, C(R₅₂)(R₅₃), or Si(R₅₄)(R₅₅). For example, the two benzene rings that are linked to the nitrogen atom in Formula HT-1 may be linked to each other via a direct linkage,

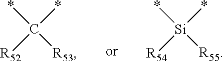

In Formula HT-1, when Yₐ is a direct linkage, the second compound represented by Formula HT-1 may include a carbazole moiety.

In Formula HT-1, Ar₁ may be a substituted or unsubstituted aryl group having 6 to 30 ring-forming carbon atoms or a substituted or unsubstituted heteroaryl group having 2 to 30 ring-forming carbon atoms. For example, Ar₁ may be a substituted or unsubstituted carbazole group, a substituted or unsubstituted dibenzofuran group, a substituted or unsubstituted dibenzothiophene group, a substituted or unsubstituted biphenyl group, etc., but embodiments are not limited thereto.

In Formula HT-1, R₅₁ to R₅₅ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₅₁ to R₅₅ may each independently be a hydrogen atom or a deuterium atom. For example, R₅₁ to R₅₅ may each independently be an unsubstituted methyl group or an unsubstituted phenyl group.

In an embodiment, the second compound represented by Formula HT-1 may be selected from Compound Group 2 below. In an embodiment, in light emitting element ED, the second compound may include at least one compound selected from Compound Group 2:

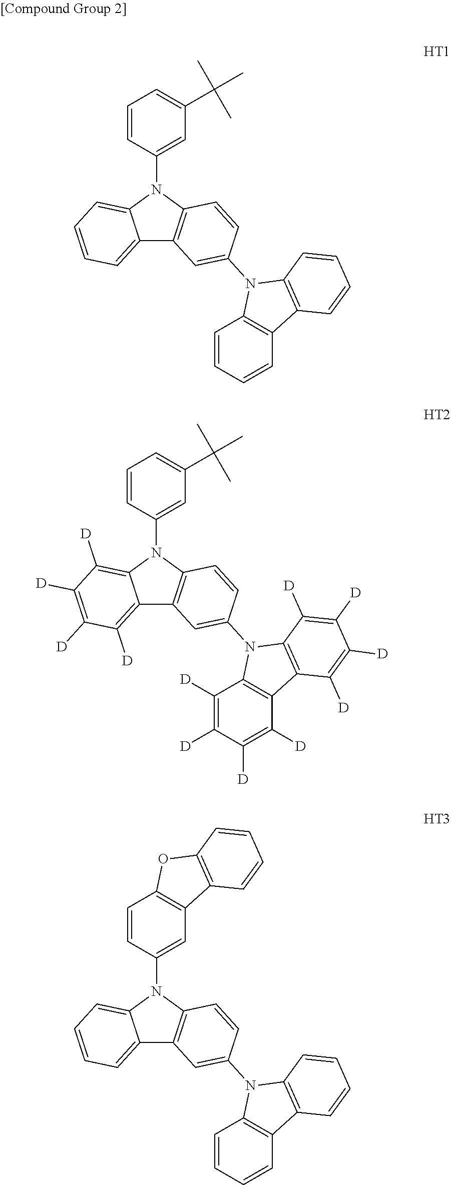 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

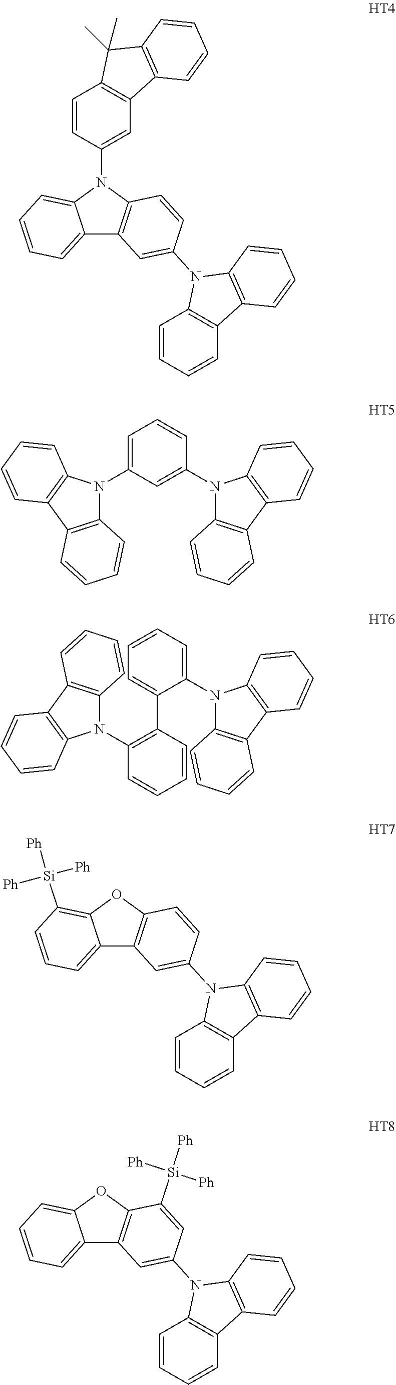

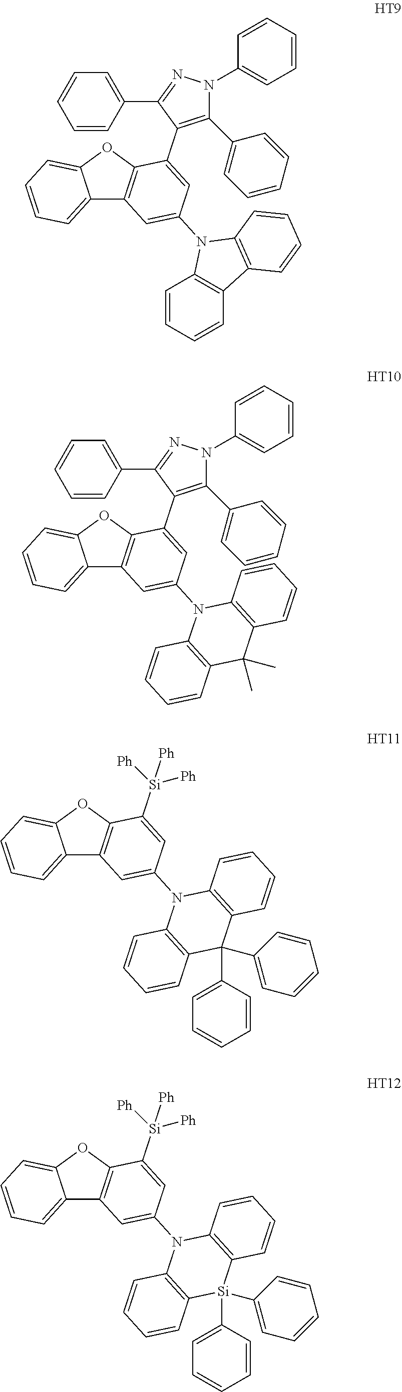 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

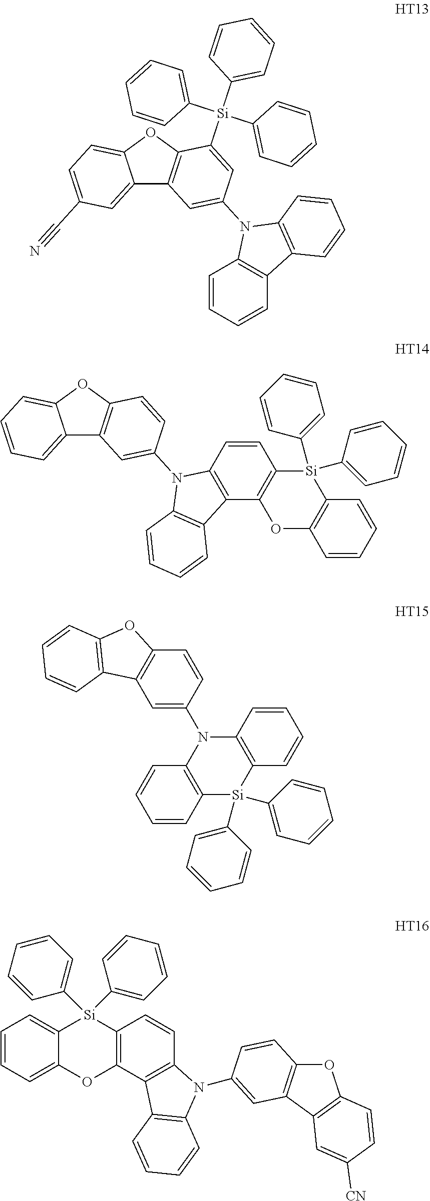 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

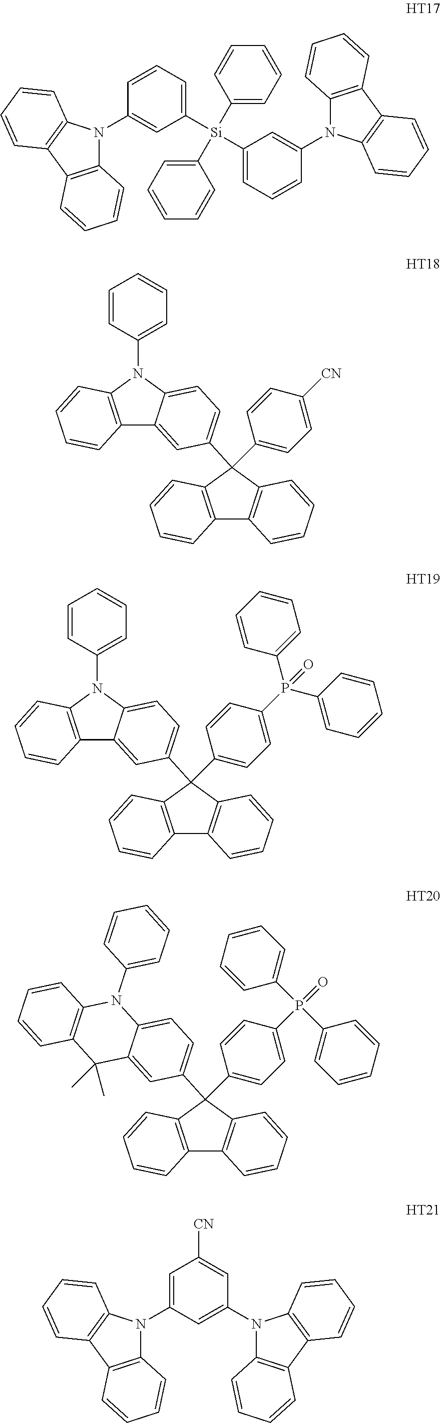 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21 ; N#Cc1cc(-n2c3ccccc3c3ccccc32)cc(-n2c3ccccc3c3ccccc32)c1]

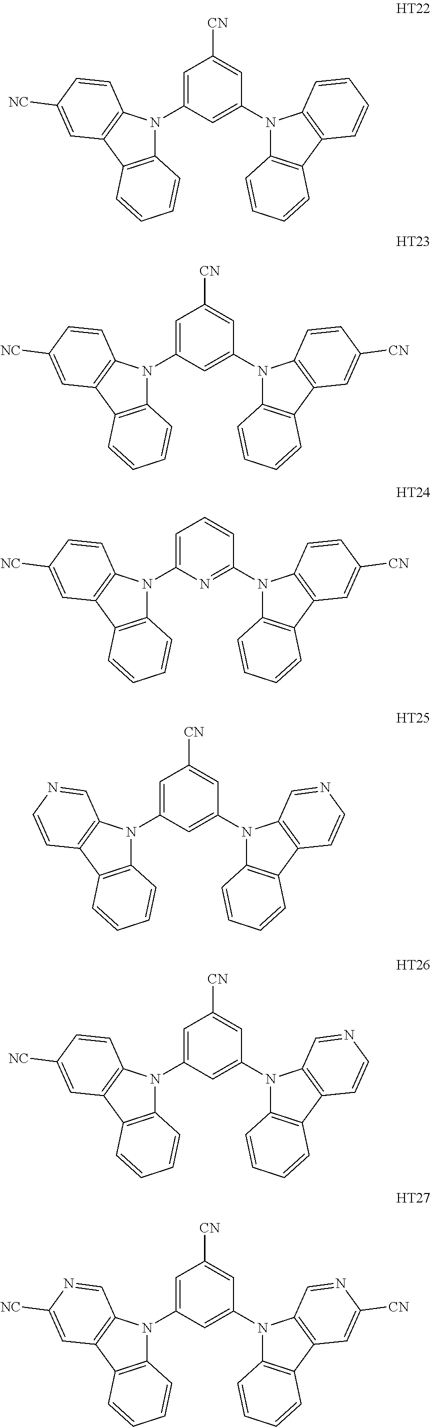 [SMILES: N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1]

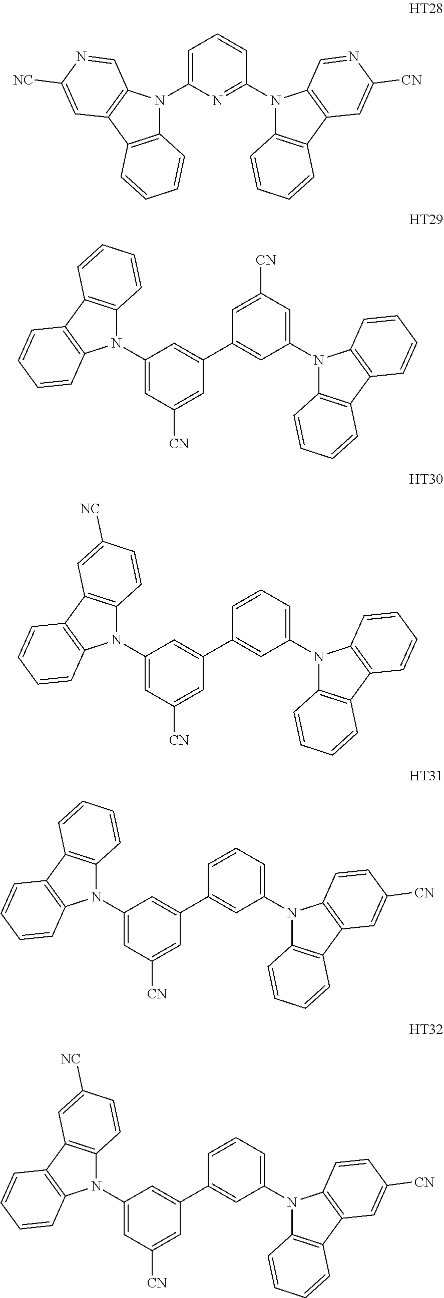 [SMILES: N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

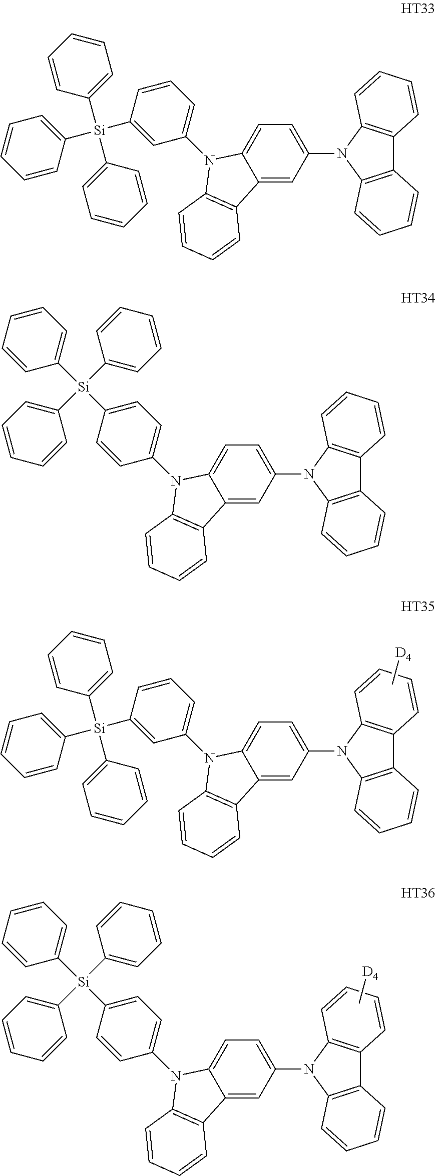

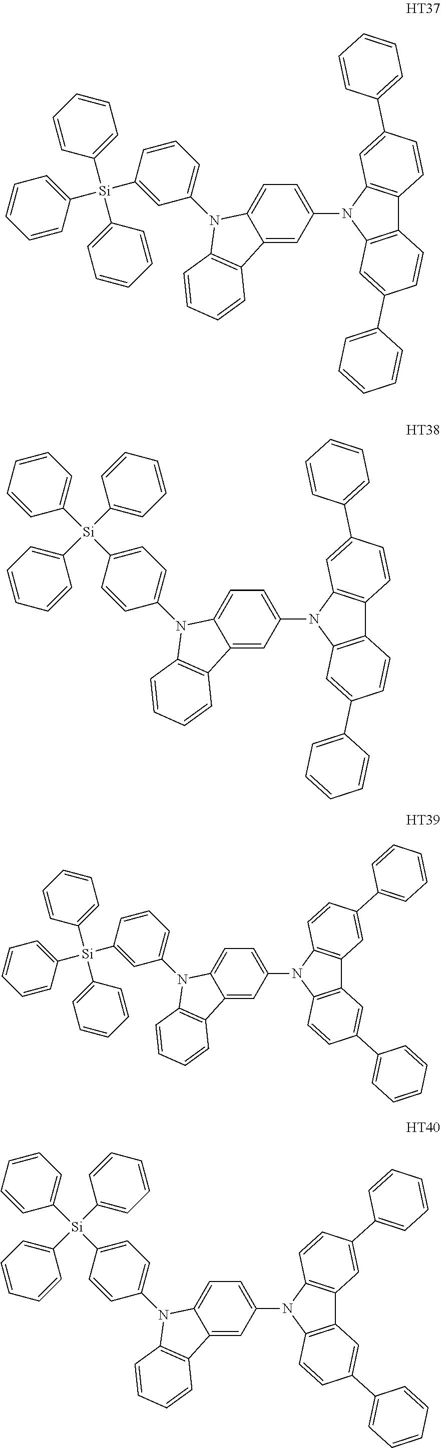 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

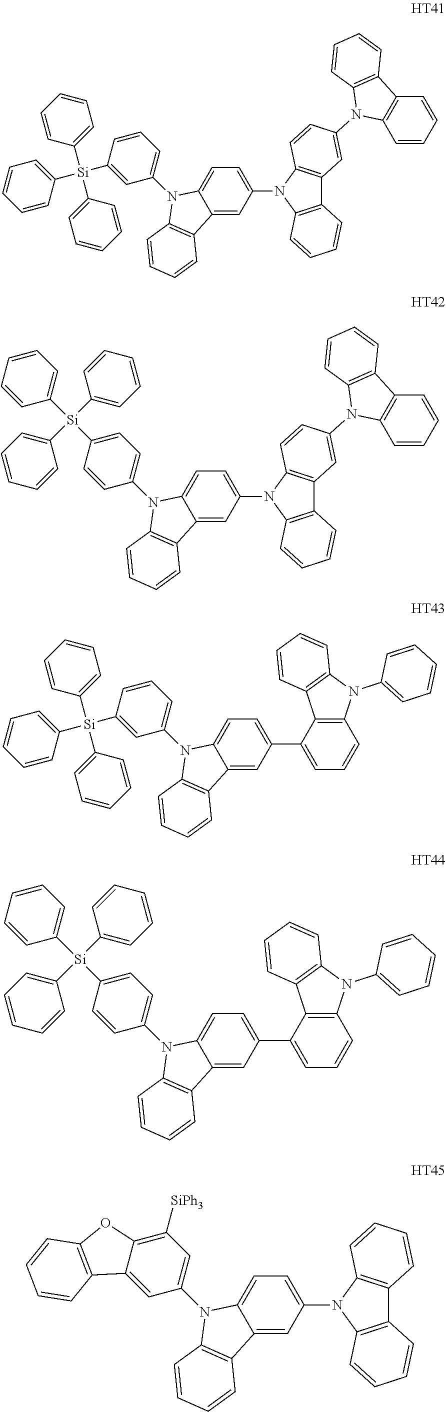

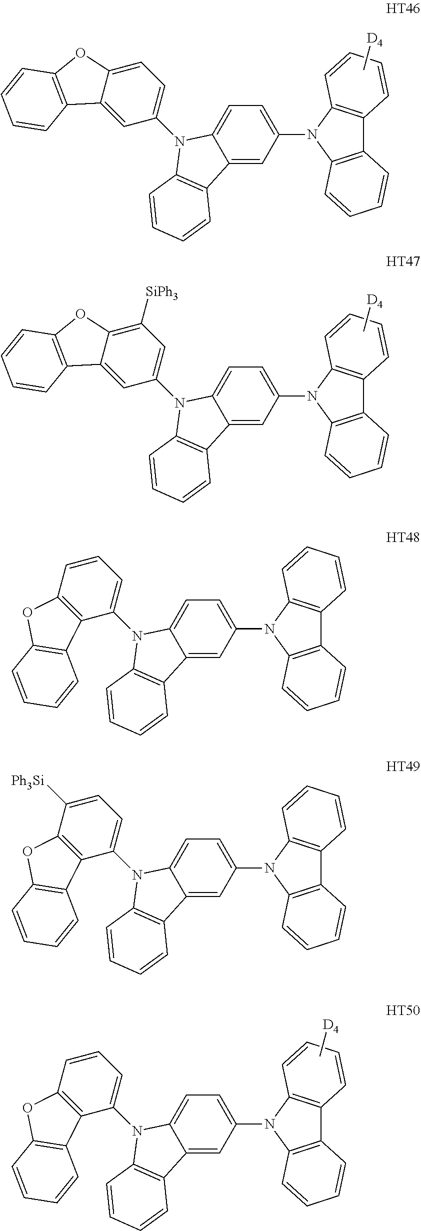

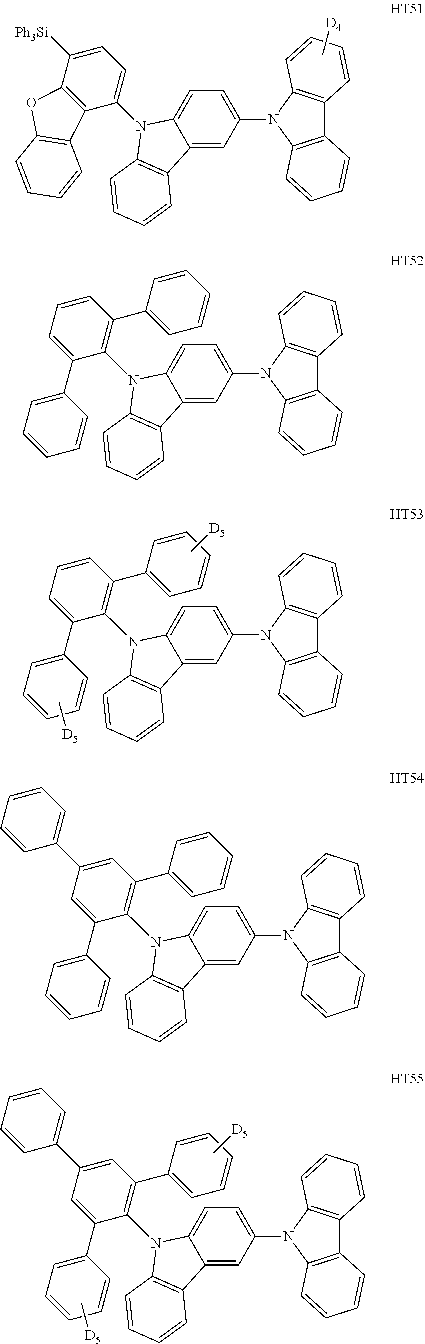

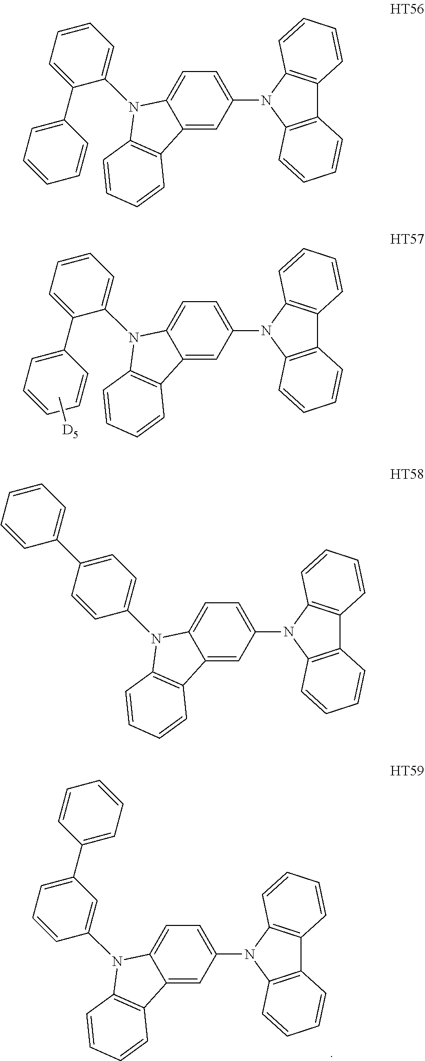

In Compound Group 2, D represents a deuterium atom, and Ph represents a substituted or unsubstituted phenyl group. For example, in Compound Group 2, Ph may represent an unsubstituted phenyl group.

In an embodiment, the emission layer EML may further include a third compound represented by Formula ET-1. In an embodiment, the third compound may be used as an electron transport host material in the emission layer EML:

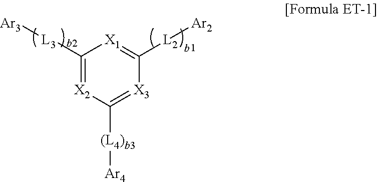

In Formula ET-1, at least one of X₁ to X₃ may each be N, and the remainder of X₁ to X₃ may each independently be C(R₅₆). For example, one of X₁ to X₃ may be N, and the remainder of X₁ to X₃ may each independently be C(R₅₆). Thus, the third compound represented by Formula ET-1 may include a pyridine moiety. As another example, two of X₁ to X₃ may each be N, and the remainder of X₁ to X₃ may be C(R₅₆). Thus, the third compound represented by Formula ET-1 may include a pyrimidine moiety. As yet another example, X₁ to X₃ may each be N. Thus, the third compound represented by Formula ET-1 may include a triazine moiety.

In Formula ET-1, R₅₆ may be a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms.

In Formula ET-1, b1 to b3 may each independently be an integer from 0 to 10.

In Formula ET-1, Ar₂ to Ar₄ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. For example, Ar₂ to Ar₄ may each independently be a substituted or unsubstituted phenyl group or a substituted or unsubstituted carbazole group.

In Formula ET-1, L₂ to L₄ may each independently be a direct linkage, a substituted or unsubstituted arylene group having 6 to 30 ring-forming carbon atoms, or a substituted or unsubstituted heteroarylene group having 2 to 30 ring-forming carbon atoms. When b1 to b3 are each 2 or greater, multiple groups of each of L₂ to L₄ may each independently be a substituted or unsubstituted arylene group having 6 to 30 ring-forming carbon atoms or a substituted or unsubstituted heteroarylene group having 2 to 30 ring-forming carbon atoms.

In an embodiment, the third compound represented by Formula ET-1 may be selected from Compound Group 3. In an embodiment, in the light emitting element ED, the third compound may include at least one compound selected from Compound Group 3:

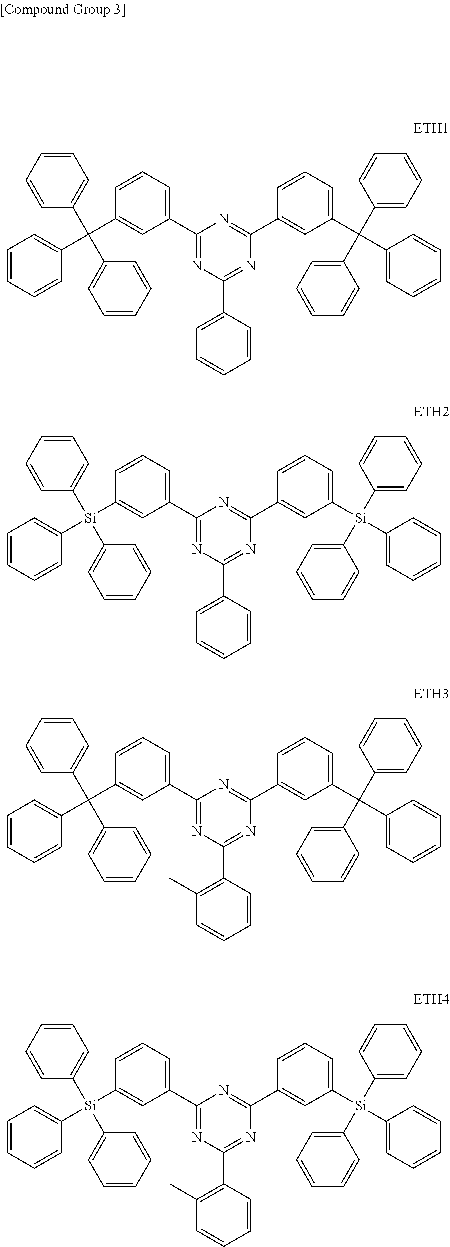 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

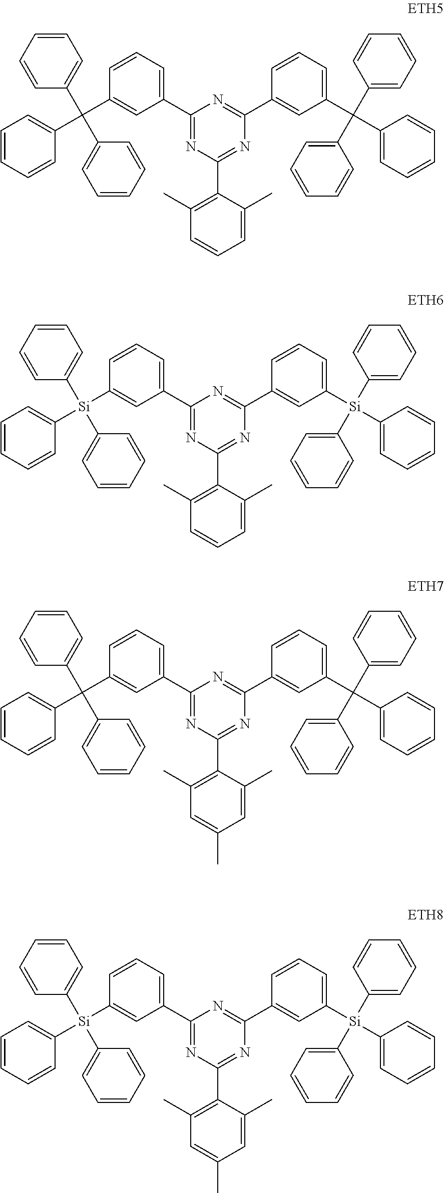 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

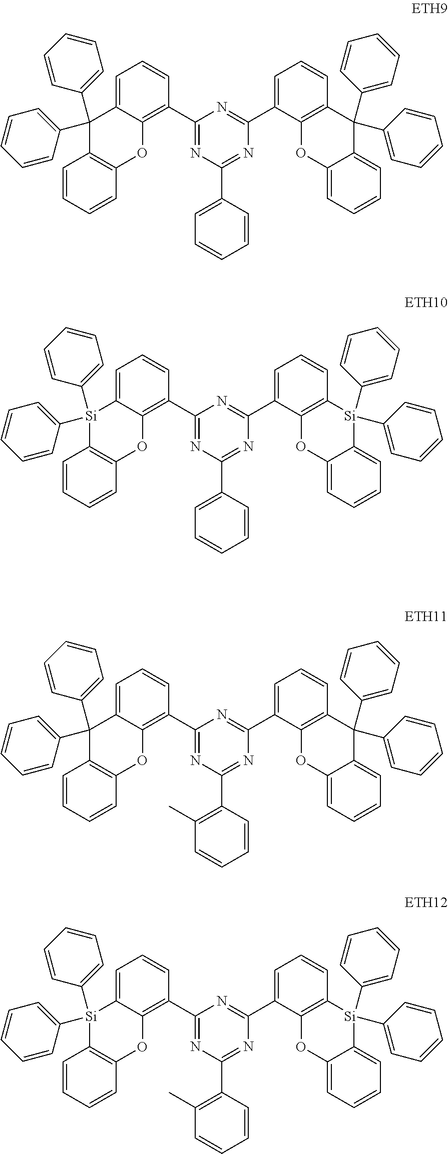 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

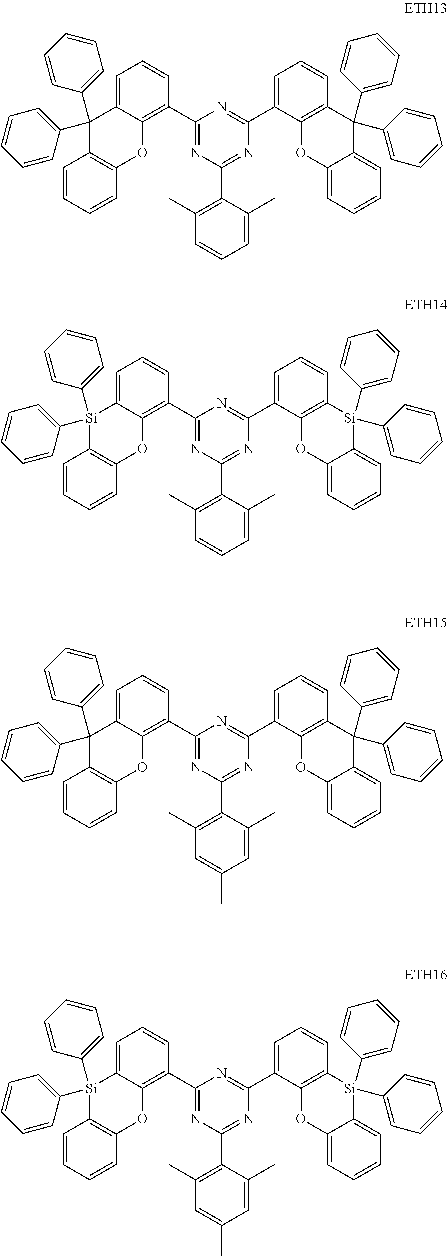 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

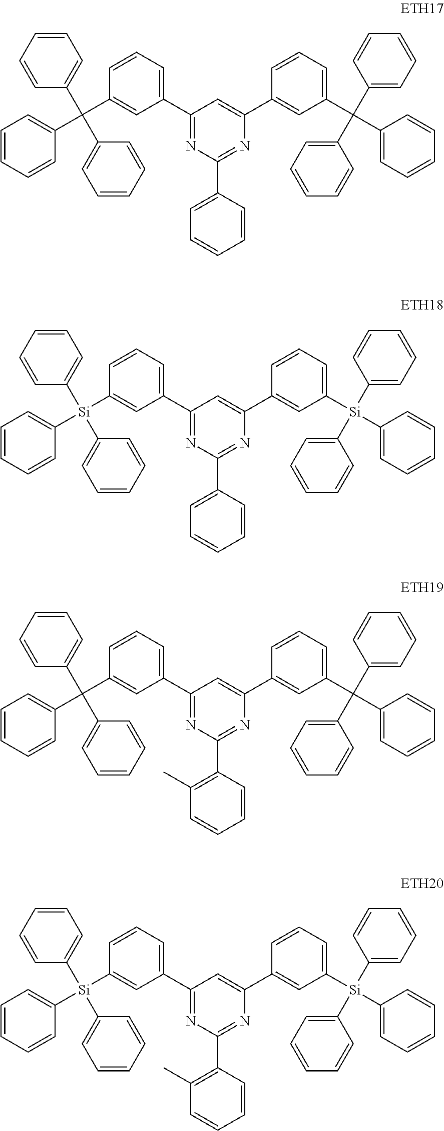 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

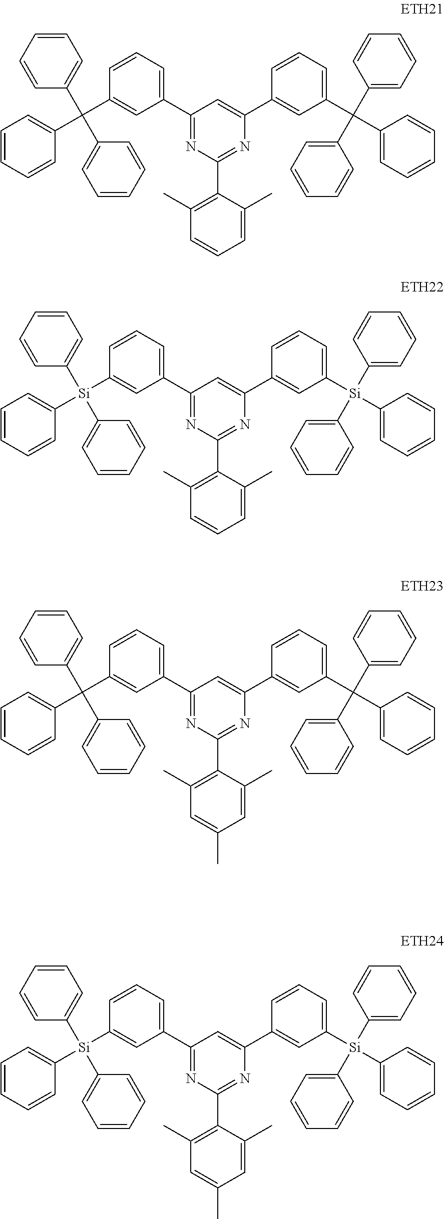 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

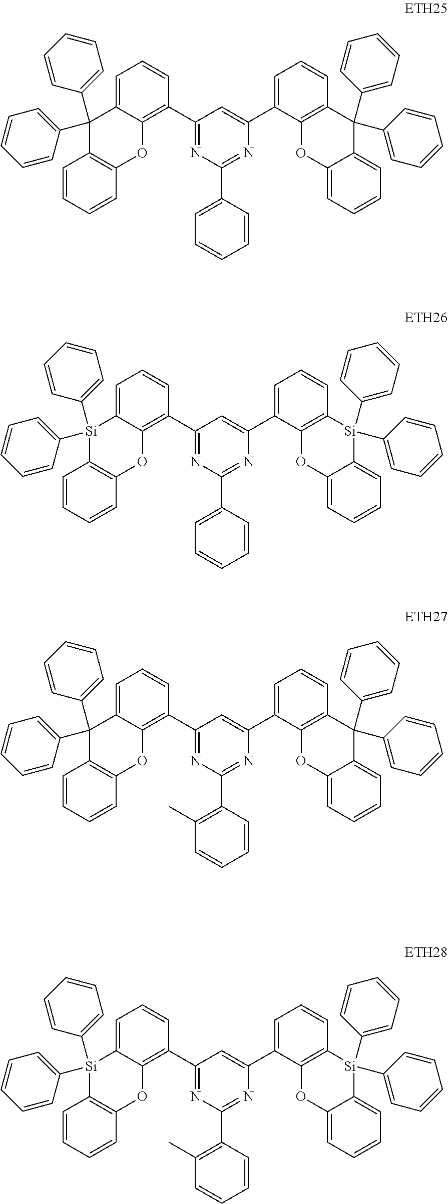 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

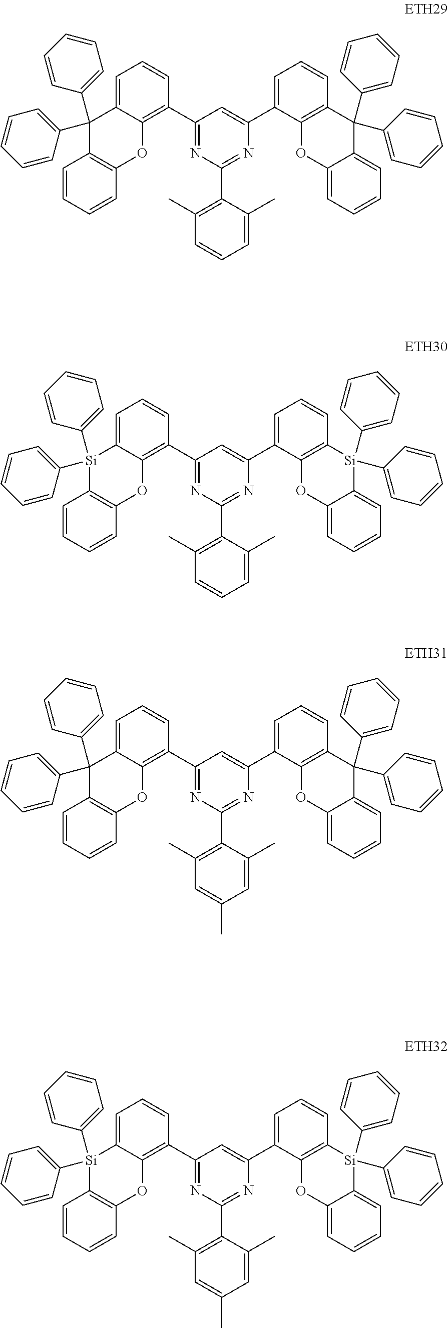 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

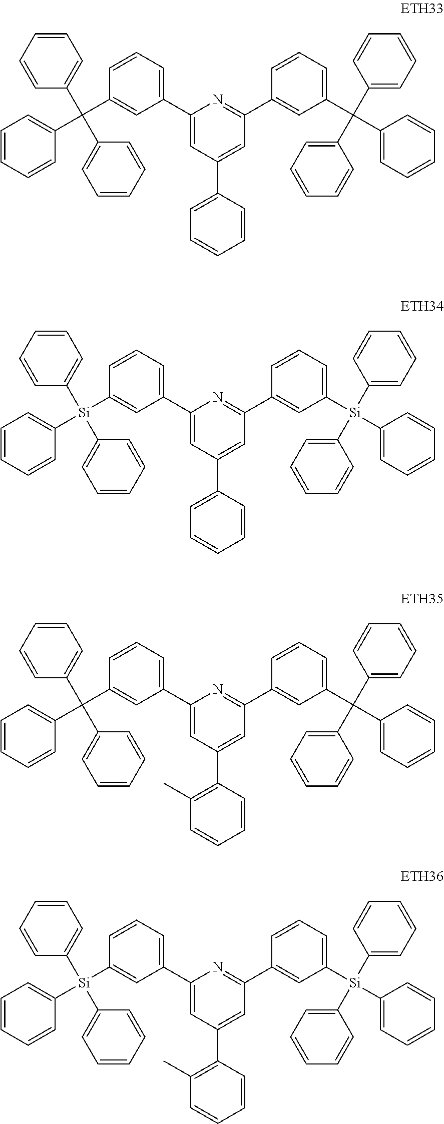 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

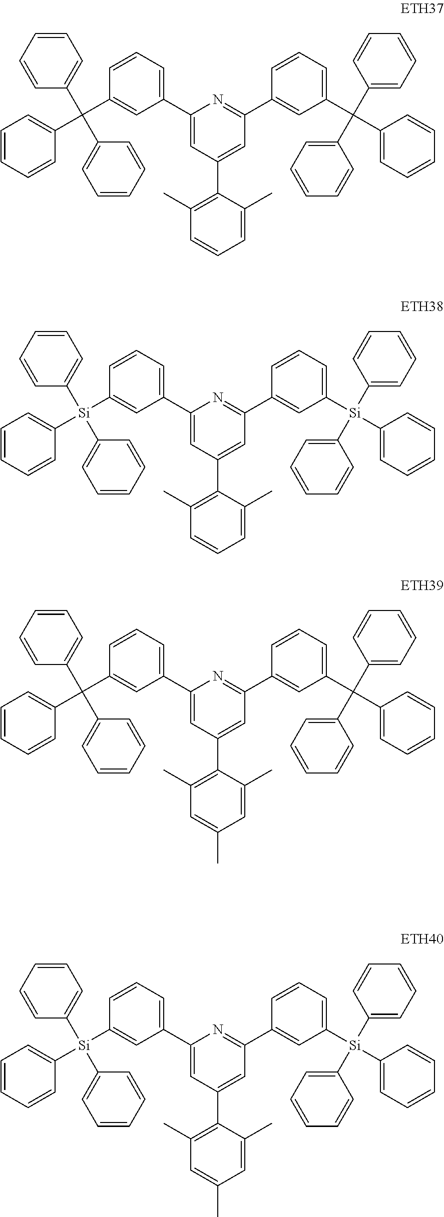 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

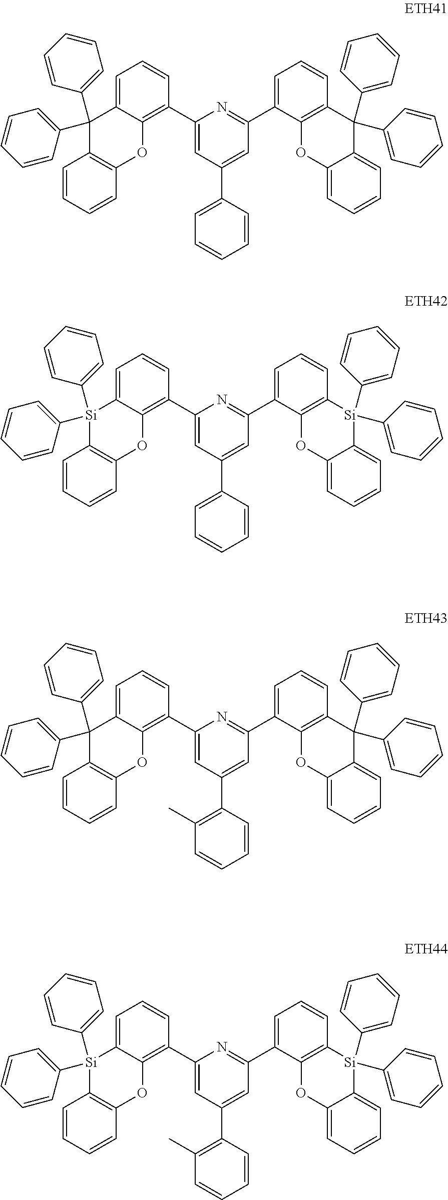 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

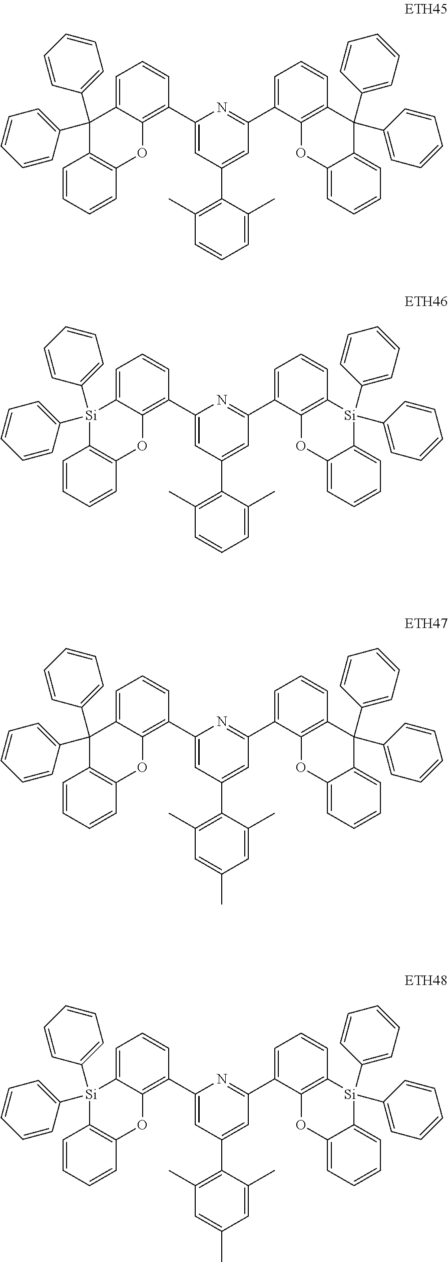 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

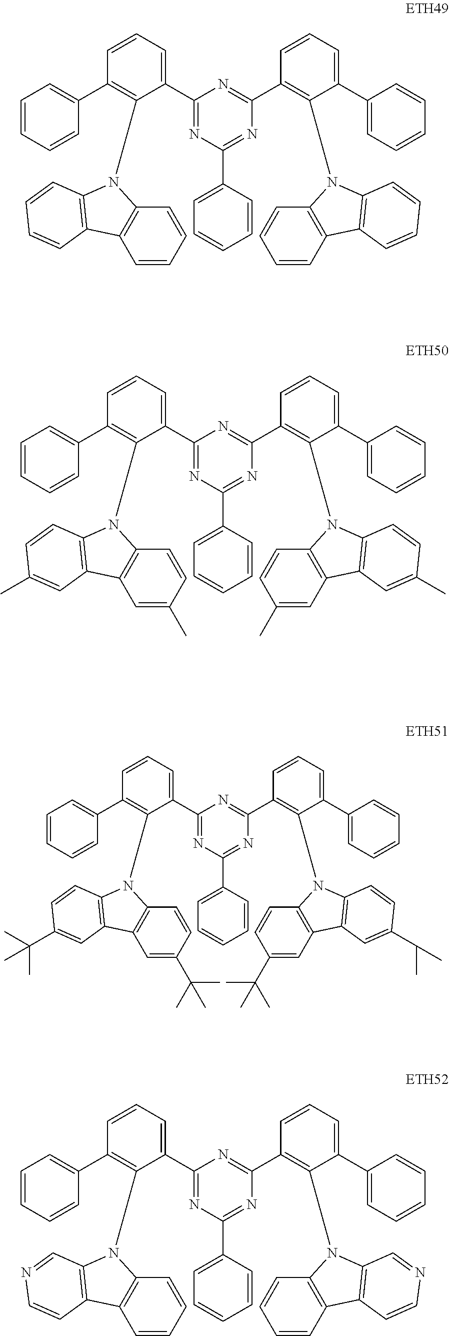

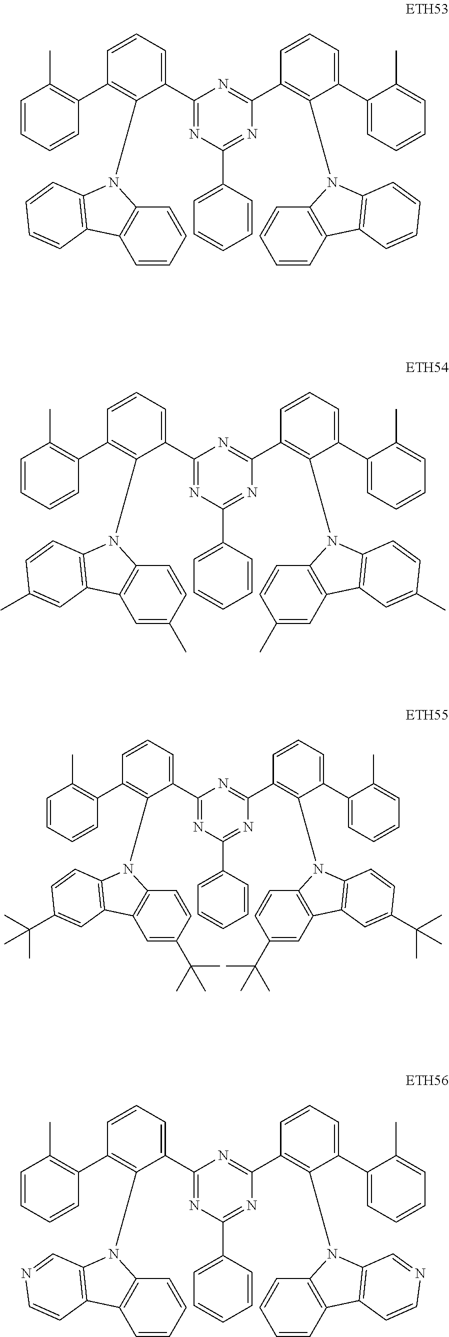

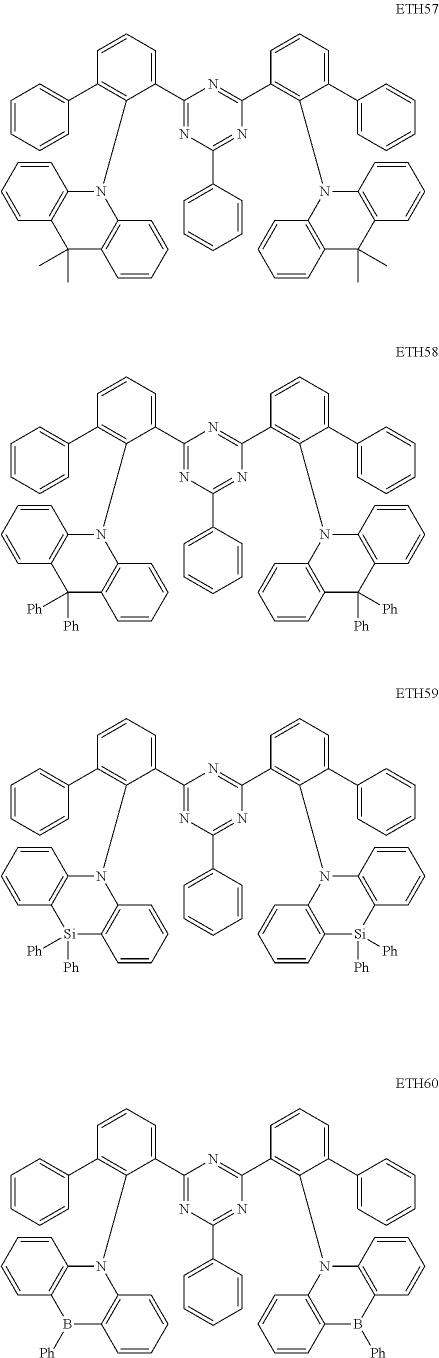

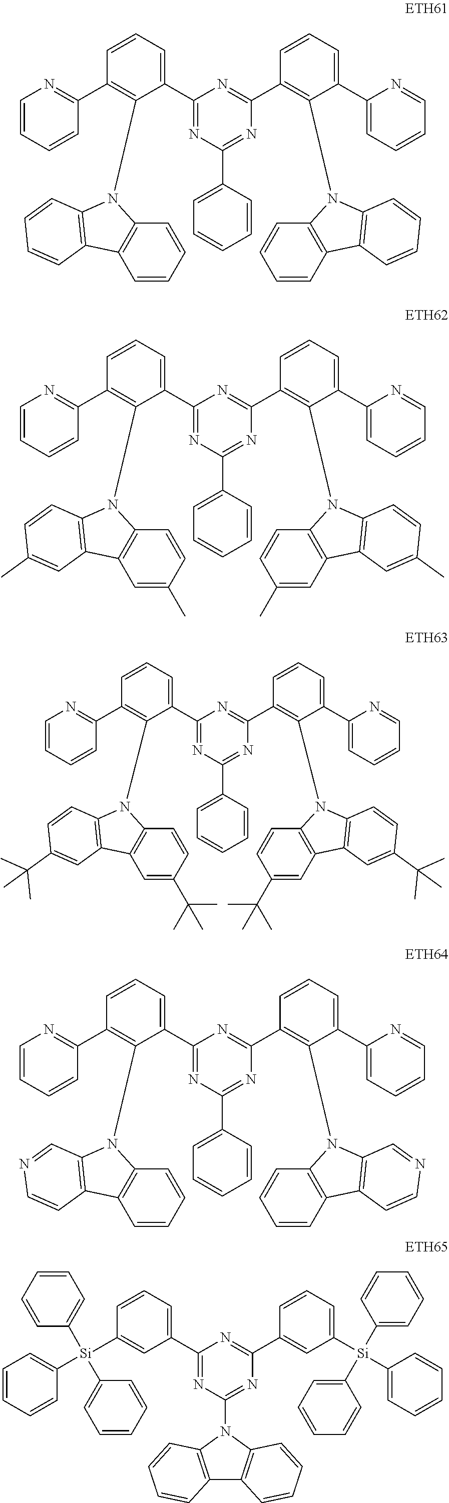

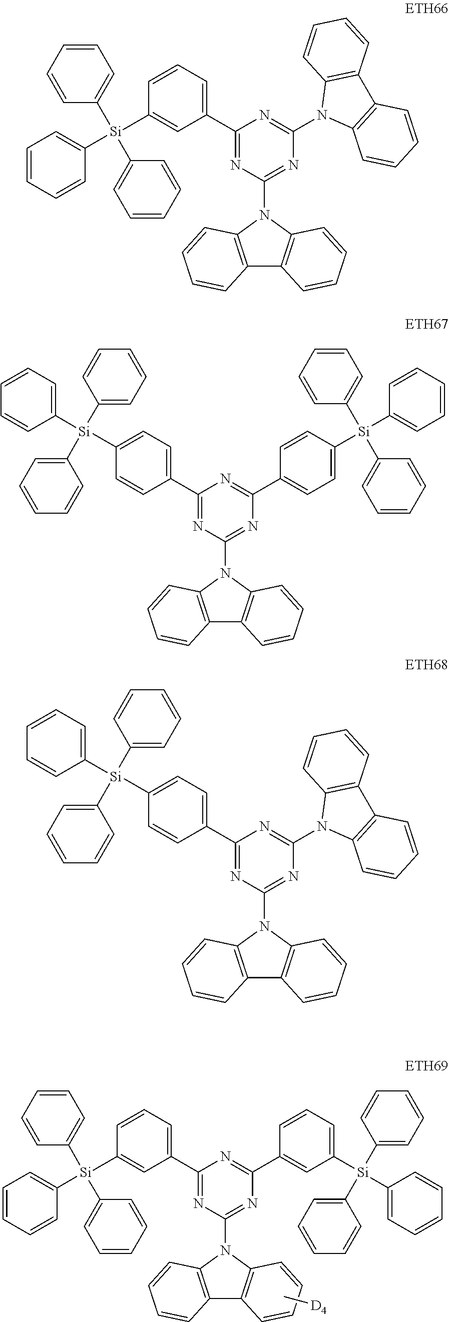

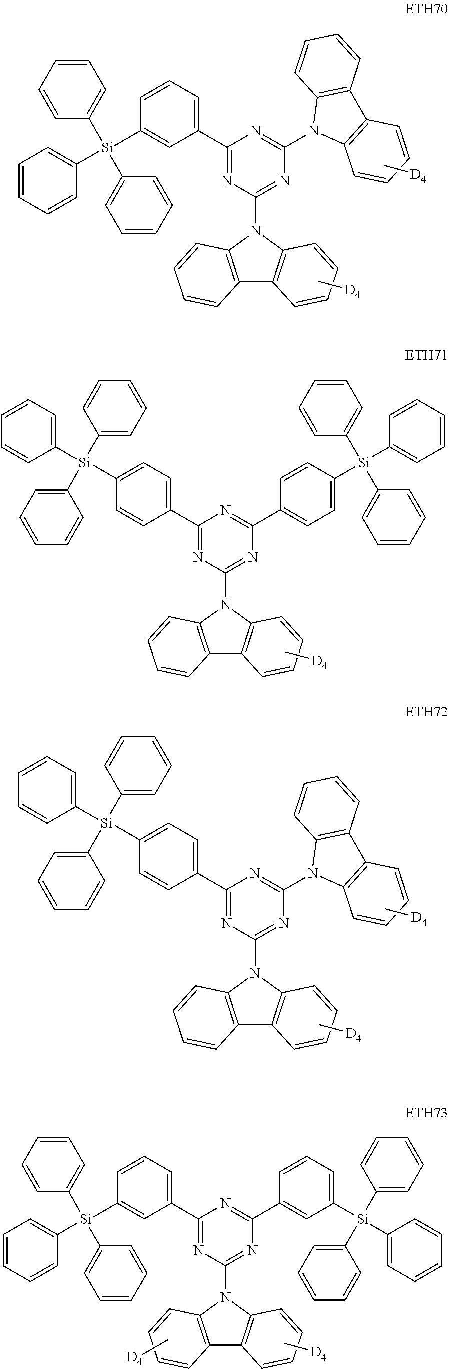

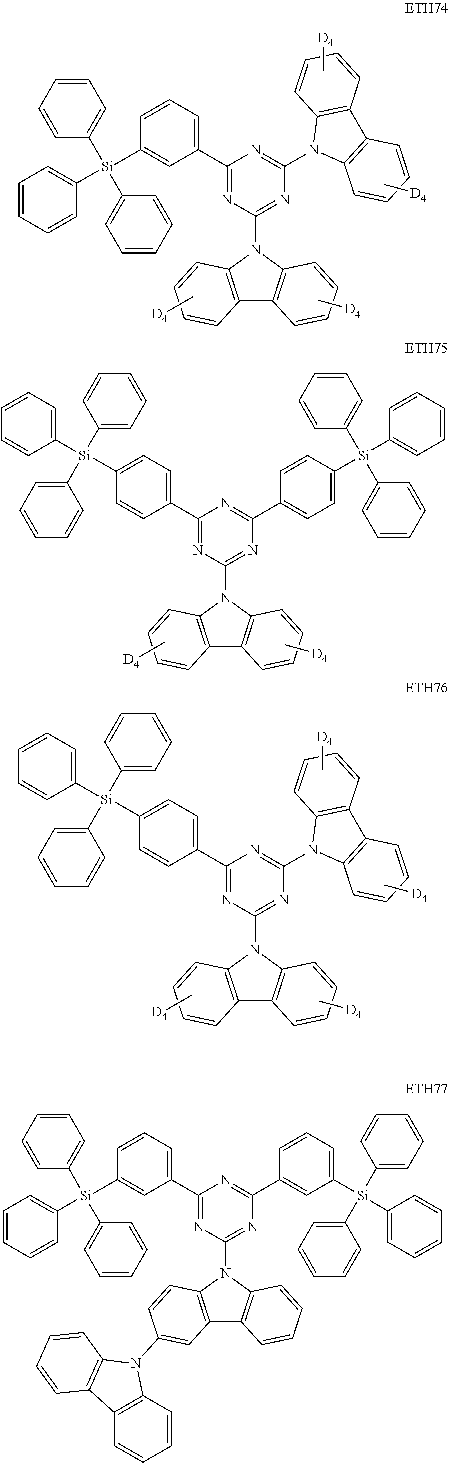

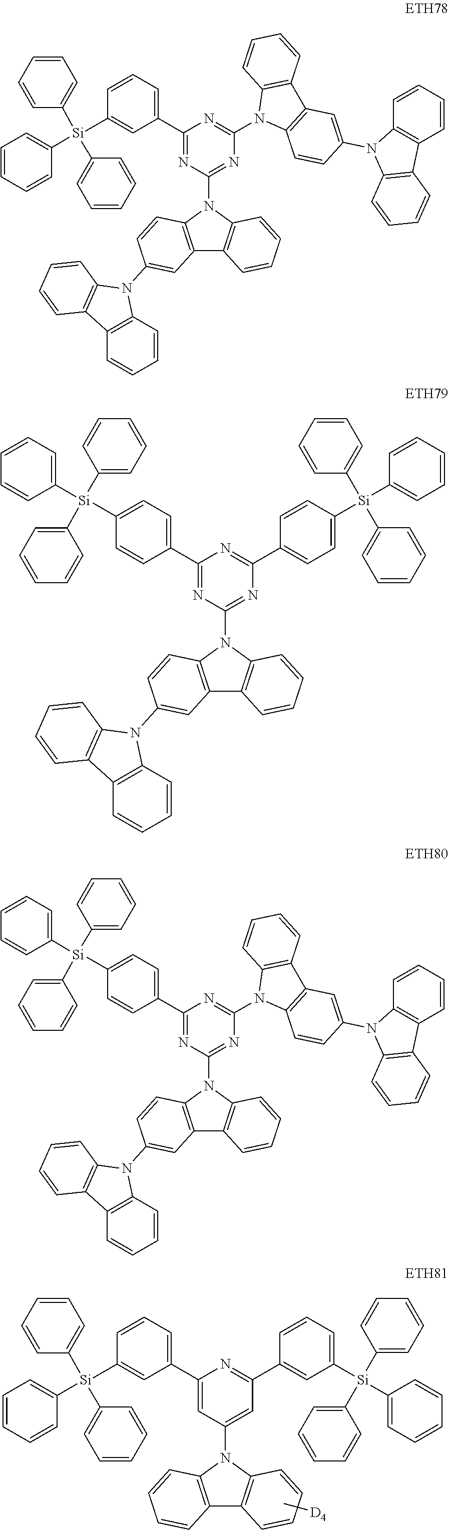

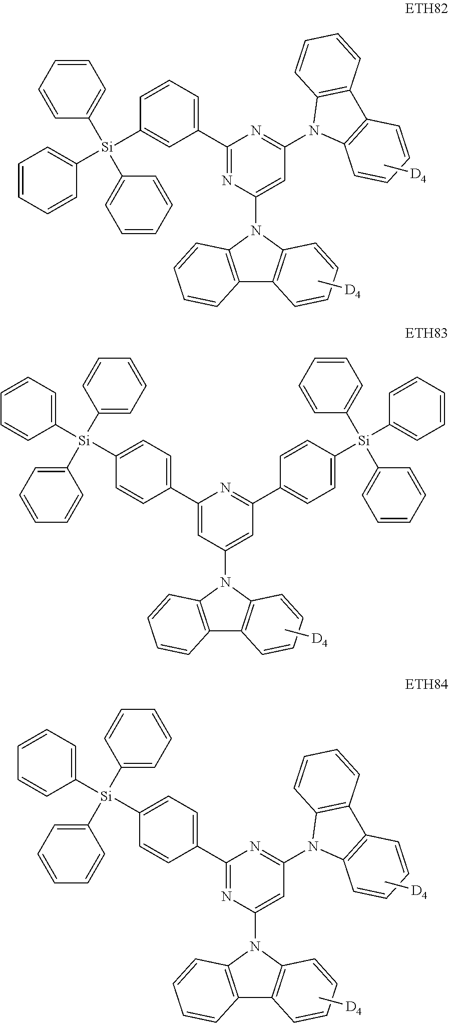

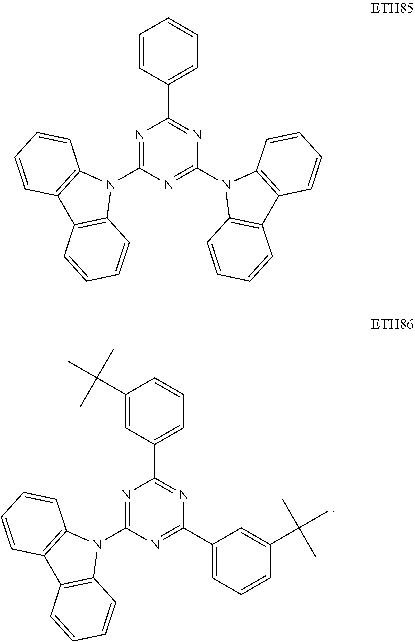 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In Compound Group 3, D represents a deuterium atom, and Ph represents an unsubstituted phenyl group.

In an embodiment, the emission layer EML may include the second compound and the third compound, and the second compound and the third compound may form an exciplex. In the emission layer EML, an exciplex may be formed by a hole transporting host and an electron transporting host. A triplet energy of the exciplex formed by a hole transporting host and an electron transporting host may correspond to a difference between a lowest unoccupied molecular orbital (LUMO) energy level of the electron transporting host and a highest occupied molecular orbital (HOMO) energy level of the hole transporting host.

For example, an absolute value of a triplet (T1) energy level of the exciplex formed by the hole transporting host and the electron transporting host may be in a range of about 2.4 eV to about 3.0 eV. The triplet energy level of the exciplex may be a value that is smaller than an energy gap of each host material. The exciplex may have a triplet energy level equal to or less than about 3.0 eV, which is an energy gap between the hole transporting host and the electron transporting host.

In an embodiment, the emission layer EML may further include a fourth compound, in addition to the first compound, the second compound, and the third compound as described above. The fourth compound may be used as a phosphorescent sensitizer in the emission layer EML. Energy may be transferred from the fourth compound to the first compound, thereby effecting light emission.

In an embodiment, the emission layer EML may further include, as a fourth compound, an organometallic complex that includes platinum (Pt) as a central metal atom and ligands linked to the central metal atom. In an embodiment, the emission layer EML may further include a fourth compound represented by Formula D-1:

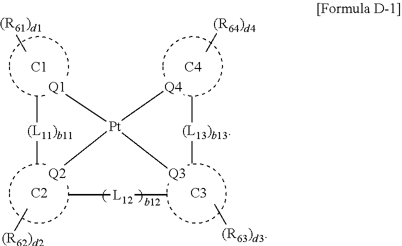

In Formula D-1, Q₁ to Q₄ may each independently be C or N. In Formula D-1, C1 to C4 may each independently be a substituted or unsubstituted hydrocarbon ring having 5 to 30 ring-forming carbon atoms or a substituted or unsubstituted heterocycle having 2 to 30 ring-forming carbon atoms.

In Formula D-1, L₁₁ to L₁₃ may each independently be a direct linkage,

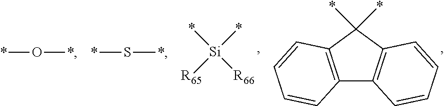

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms. In L₁₁ to L₁₃, [symbol] represents a bond to one of C1 to C4.

In Formula D-1, b11 to b13 may each independently be 0 or 1. If b11 is 0, C1 and C2 may not be directly linked to each other. If b12 is 0, C2 and C3 may not be directly linked to each other. If b13 is 0, C3 and C4 may not be directly linked to each other.

In Formula D-1, R₆₁ to R₆₆ may each independently be a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring. For example, R₆₁ to R₆₆ may each independently be a substituted or unsubstituted methyl group or a substituted or unsubstituted t-butyl group.

In Formula D-1, d1 to d4 may each independently be an integer from 0 to 4. If d1 to d4 are each 0, the fourth compound may not be substituted with R₆₁ to R₆₄, respectively. A case where d1 to d4 are each 4 and four groups of each of R₆₁ to R₆₄ are all hydrogen atoms may be the same as a case where d1 to d4 are each 0. When d1 to d4 are each 2 or more, multiple groups of each of R₆₁ to R₆₄ may all be the same or at least one thereof may be different from the remainder.

In an embodiment, in Formula D-1, C1 to C4 may each independently be a substituted or unsubstituted hydrocarbon ring or a substituted or unsubstituted heterocycle that is represented by one of Formula C-1 to Formula C-4:

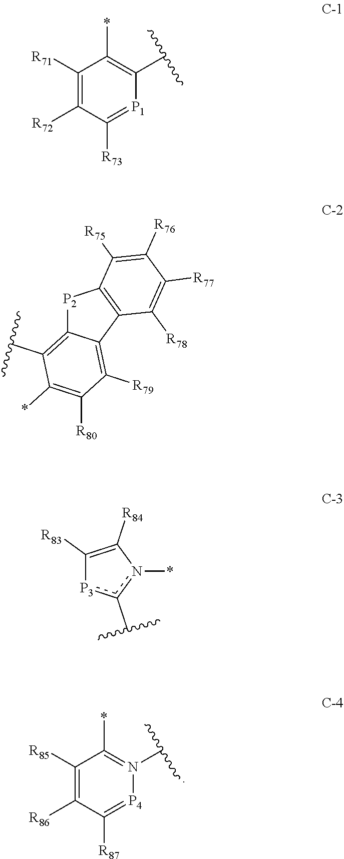

In Formula C-1 to Formula C-4, P₁ may be [symbol] or C(R₇₄), P₂ may be [symbol] or N(R₈₁), P₃ may be [symbol] or N(R₈₂), and P₄ may be [symbol] or C(R₈₈).

In Formula C-1 to Formula C-4, R₇₁ to R₈₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula C-1 to Formula C-4, [symbol] represents a part bond to Pt, which is a central metal atom, and [symbol] represents a bond to a neighboring cyclic group (C1 to C4) or to a linking moiety (L₁ to L₁₃).

In an embodiment, the emission layer EML may include the first compound represented by Formula 1, and at least one of the second compound, the third compound, and the fourth compound. In an embodiment, the emission layer EML may include the first compound, the second compound, and the third compound. In the emission layer EML, the second compound and the third compound may form an exciplex, and energy may be transferred from the exciplex to the first compound, thereby effecting light emission.

In another embodiment, the emission layer EML may include the first compound, the second compound, the third compound, and the fourth compound. In the emission layer EML, the second compound and the third compound may form an exciplex, and energy may be transferred from the exciplex to the fourth compound and to the first compound, thereby effecting light emission. In an embodiment, the fourth compound may be a sensitizer. In the light emitting element ED, the fourth compound included in the emission layer EML may serve as a sensitizer that transfers energy from a host (for example, an exciplex host) to the first compound, which is a light emitting dopant. For example, the fourth compound, which serves as an auxiliary dopant, may accelerate energy transfer to the first compound, which serves as a light emitting dopant, thereby increasing an emission ratio of the first compound. Therefore, the emission layer EML may exhibit improved luminous efficiency. When energy transfer to the first compound increases, excitons formed in the emission layer EML may not accumulate and may rapidly emit light, so that deterioration of the light emitting element ED may be reduced. Accordingly, the service life of the light emitting element ED may be improved.

The light emitting element ED may include the first compound, the second compound, the third compound, and the fourth compound, and the emission layer EML may include a combination of two host materials and two dopant materials. In the light emitting element ED, the emission layer EML may include the second compound and the third compound, which are two different hosts, the first compound that emits delayed fluorescence, and the fourth compound that includes an organometallic complex, so that the light emitting element ED may exhibit excellent luminous efficiency characteristics.

In an embodiment, the fourth compound represented by Formula D-1 may be selected from Compound Group 4. In an embodiment, in the light emitting element ED, the fourth compound may include at least one compound selected from Compound Group 4:

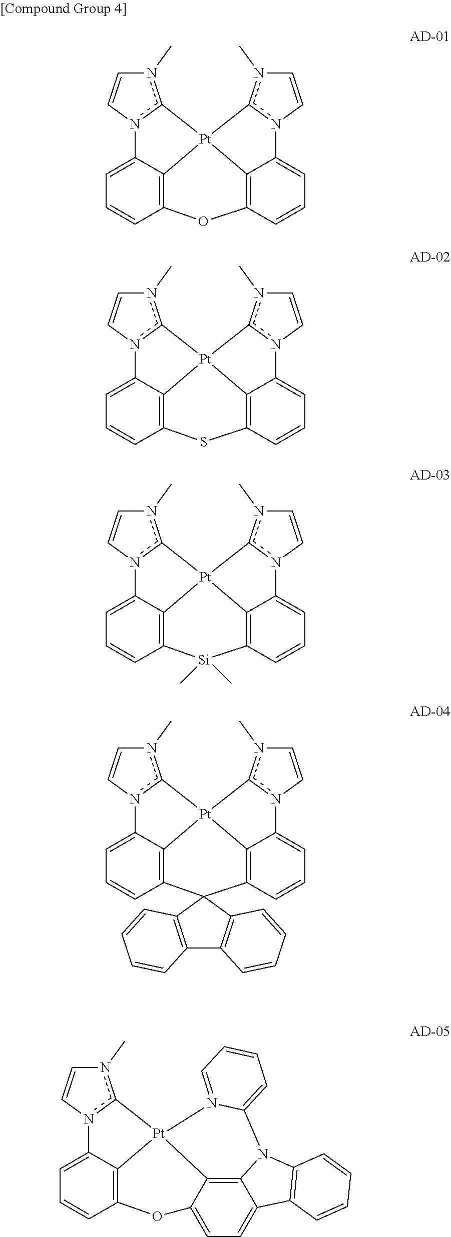

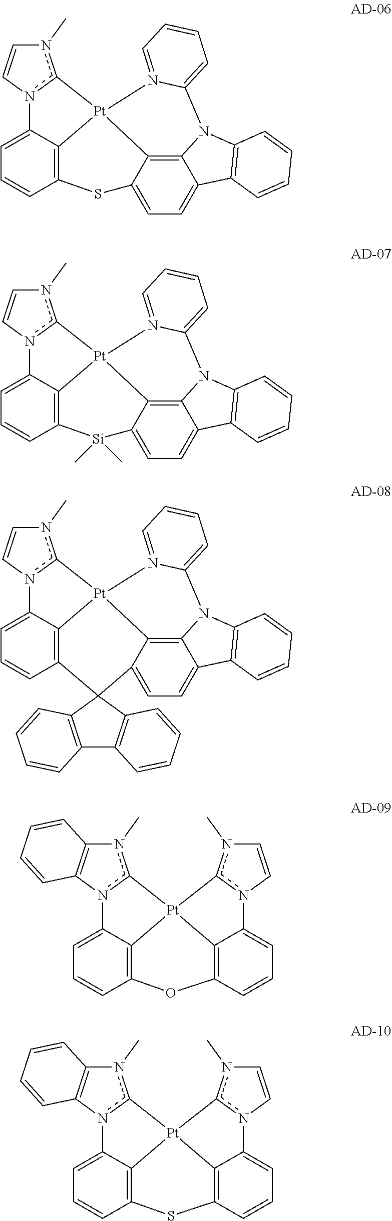

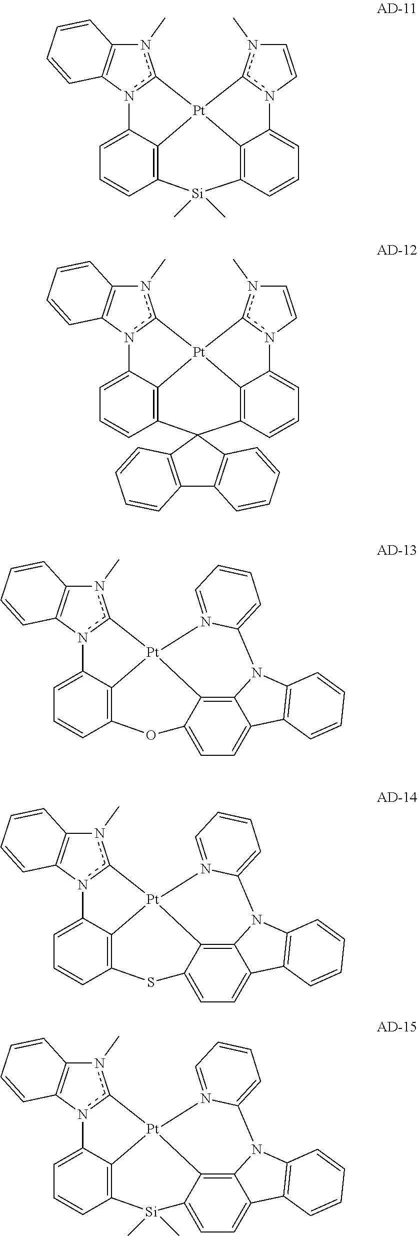

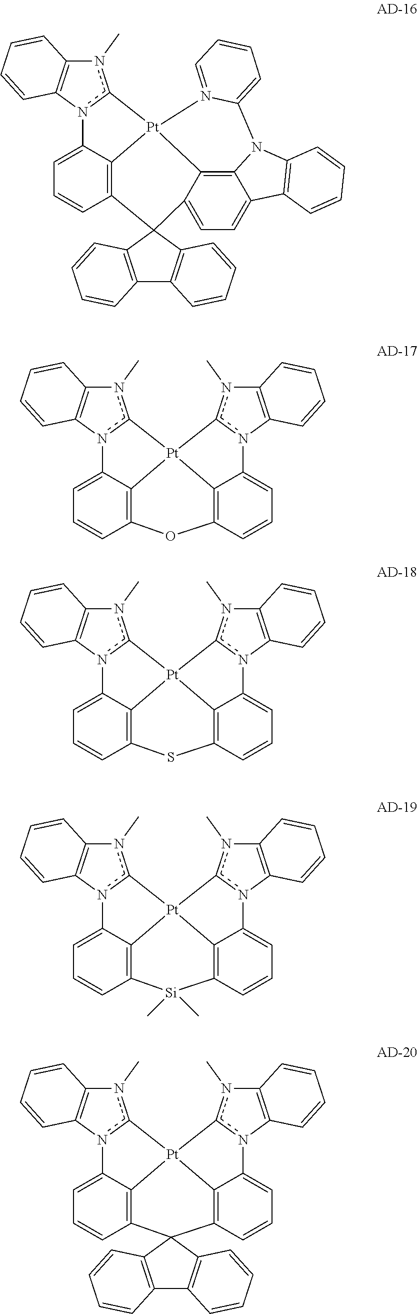

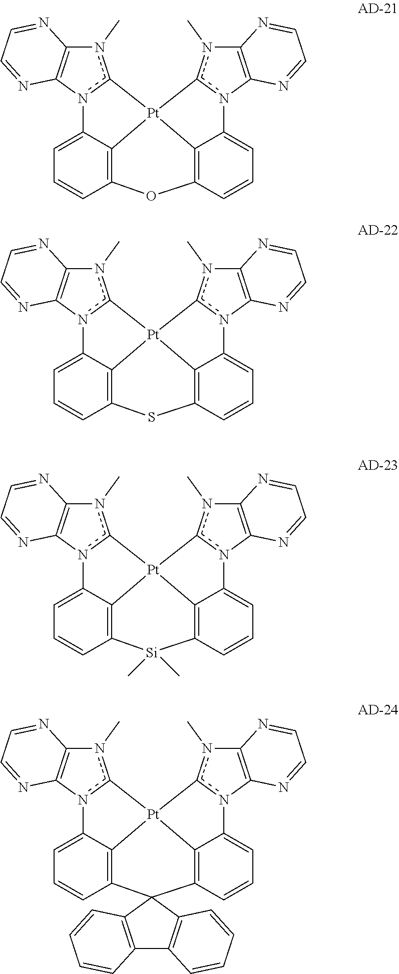

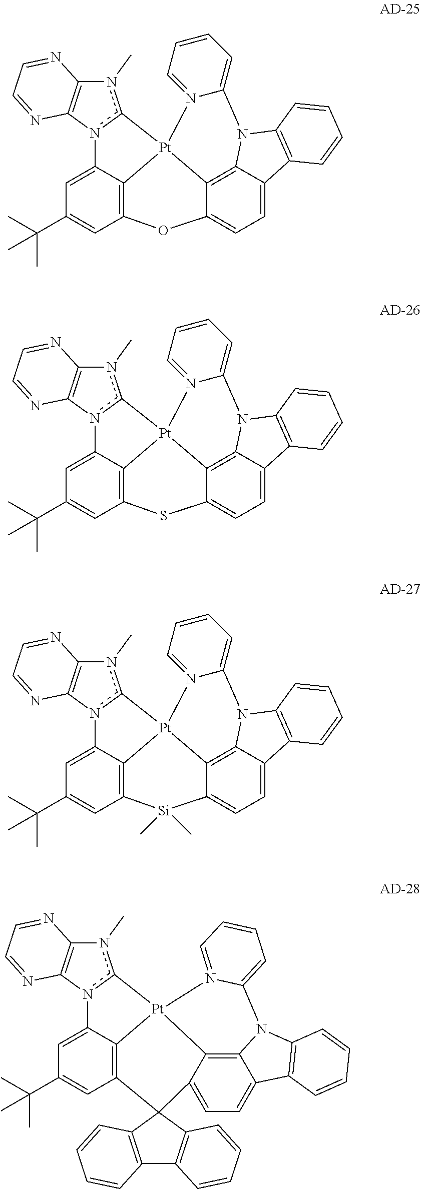

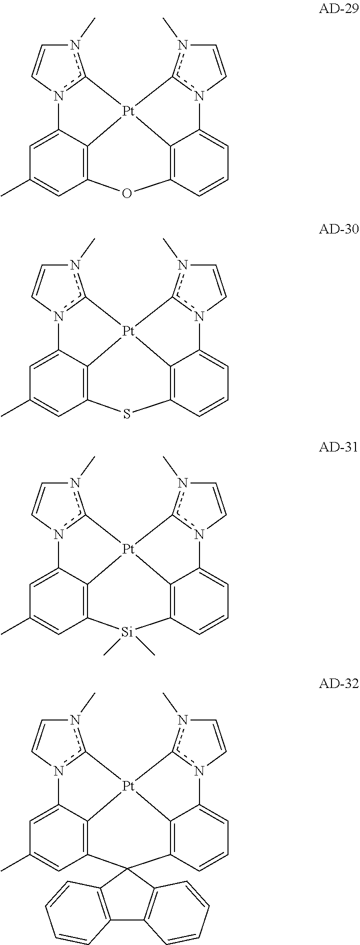

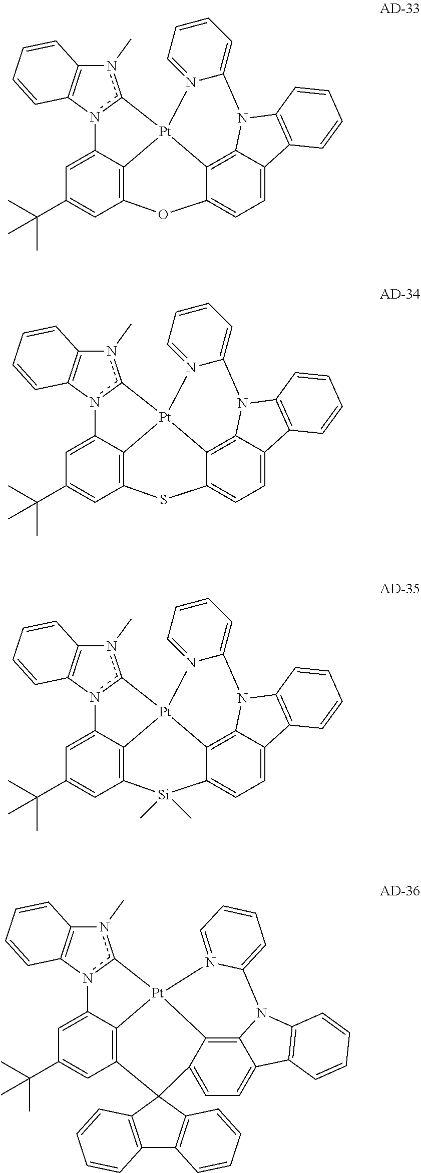

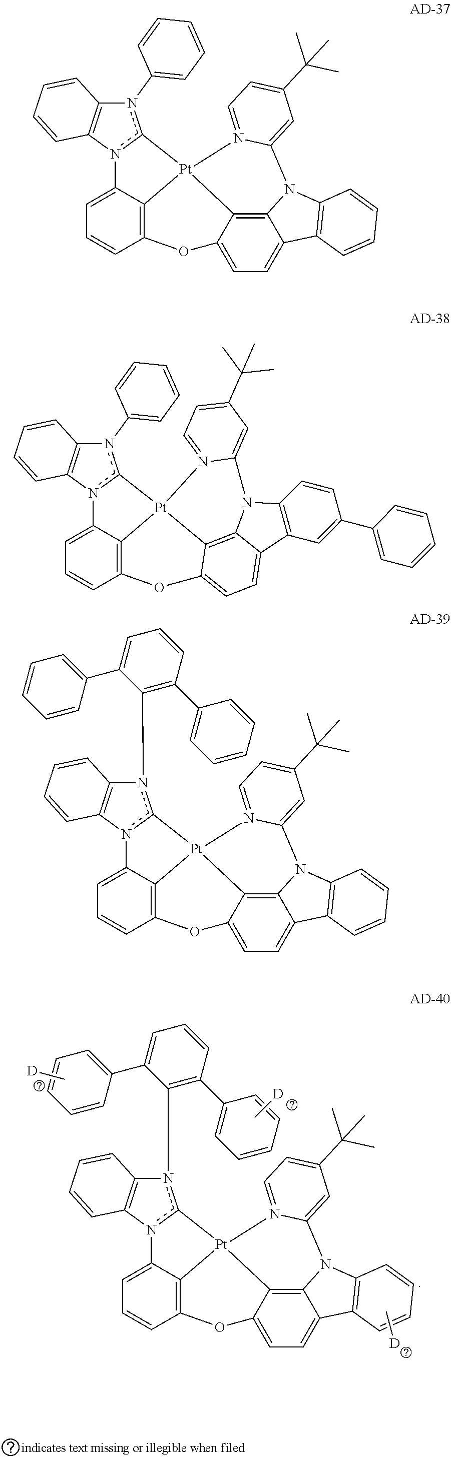

In Compound Group 4, D represents a deuterium atom.

In the light emitting element ED, when the emission layer EML includes the first compound, the second compound, and the third compound, an amount of the first compound may be in a range of about 0.1 wt % to about 5 wt %, with respect to a total weight of the first compound, the second compound, and the third compound. However, embodiments are not limited thereto. When an amount of the first compound satisfies the range described above, energy transfer from the second compound and the third compound to the first compound may increase, and thus luminous efficiency and element service life may increase.

In the emission layer EML, a total amount of the second compound and the third compound may be the remainder of the total weight of the first compound, the second compound, and the third compound, excluding the amount of the first compound. For example, a combined amount of the second compound and the third compound in the emission layer EML may be in a range of about 65 wt % to about 95 wt %, with respect to a total weight of the first compound, the second compound, and the third compound.

Within the combined amount of the second compound and the third compound in the emission layer EML, a weight ratio of the second compound to the third compound may be in a range of about 3:7 to about 7:3.

When the amounts of the second compound and the third compound satisfy the above-described ranges and ratios, charge balance characteristics in the emission layer EML may be improved, and thus luminous efficiency and element service life may increase. When the amounts of the second compound and the third compound deviate from the above-described ranges and ratios, charge balance in the emission layer EML may not be achieved, so that luminous efficiency may be reduced and the element may readily deteriorate.

When the emission layer EML includes the fourth compound, an amount of the fourth compound in the emission layer EML may be in a range of about 10 wt % to about 30 wt %, with respect to a total weight of the first compound, the second compound, the third compound, and the fourth compound. However, embodiments are not limited thereto. When an amount of the fourth compound satisfies the above-described range, energy transfer from a host (for example, an exciplex host) to the first compound, which is a light emitting dopant, may increase, so that an emission ratio may improve. Accordingly, luminous efficiency of the emission layer EML may improve. When the amounts of first compound, the second compound, the third compound, and the fourth compound included in the emission layer EML satisfy the above-described ranges and ratios, excellent luminous efficiency and long service life may be achieved.

The emission layer EML may have a thickness in a range of about 100 Å to about 1,000 Å. For example, the emission layer EML may have a thickness in a range of about 100 Å to about 300 Å. The emission layer EML may have a structure consisting of a layer consisting of a single material, a structure consisting of a layer including different materials, or a structure including multiple layers including different materials.

In the light emitting elements ED according to embodiments as shown in each of FIGS. 3 to 7, the emission layer EML may include the polycyclic compound according to an embodiment as a dopant. In embodiments, in each of the light emitting elements ED illustrated in FIGS. 3 to 7, the emission layer EML may include the first compound, which is the polycyclic compound according to an embodiment, and at least one of the second compound represented by Formula HT-1 and the third compound represented by Formula ET-1. In other embodiments, in each of the light emitting elements ED illustrated in FIGS. 3 to 7, the emission layer EML may include the first compound, which is the polycyclic compound according to an embodiment, the second compound represented by Formula HT-1, the third compound represented by Formula ET-1, and the fourth compound represented by Formula D-1.

In the light emitting element ED, the emission layer EML may further include an anthracene derivative, a pyrene derivative, a fluoranthene derivative, a chrysene derivative, a dihydrobenzanthracene derivative, or a triphenylene derivative. For example, the emission layer EML may further include an anthracene derivative or a pyrene derivative.

In the light emitting elements ED according to embodiments as shown in each of FIGS. 3 to 7, the emission layer EML may include a host and a dopant.

In an embodiment, the emission layer EML may include a compound represented by Formula E-1. The compound represented by Formula E-1 may be used as a fluorescent host material.

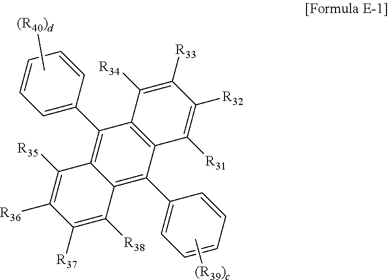

In Formula E-1, R₃₁ to R₄₀ may each independently be a hydrogen atom, a deuterium atom, a halogen atom, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer from 0 to 5.

In an embodiment, the compound represented by Formula E-1 may be any compound selected from Compound E1 to Compound E19:

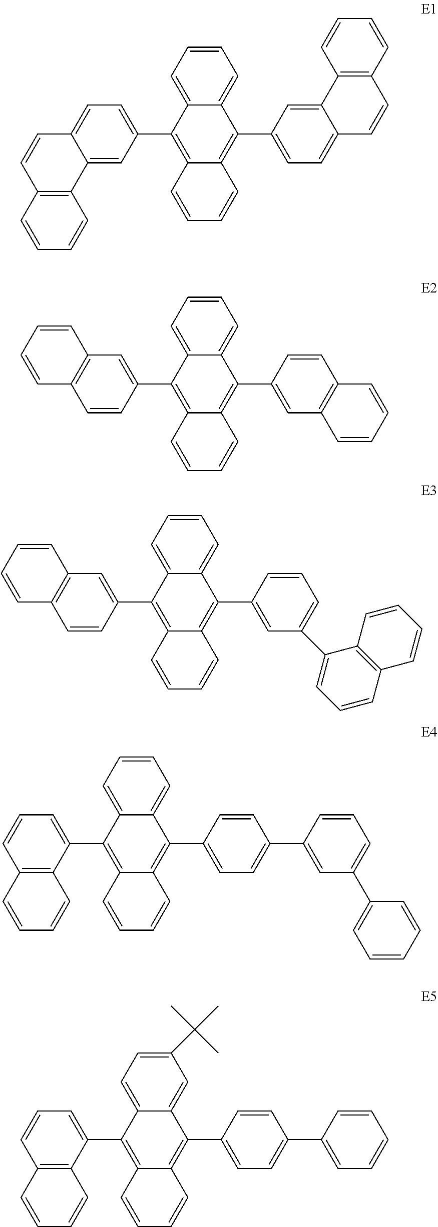

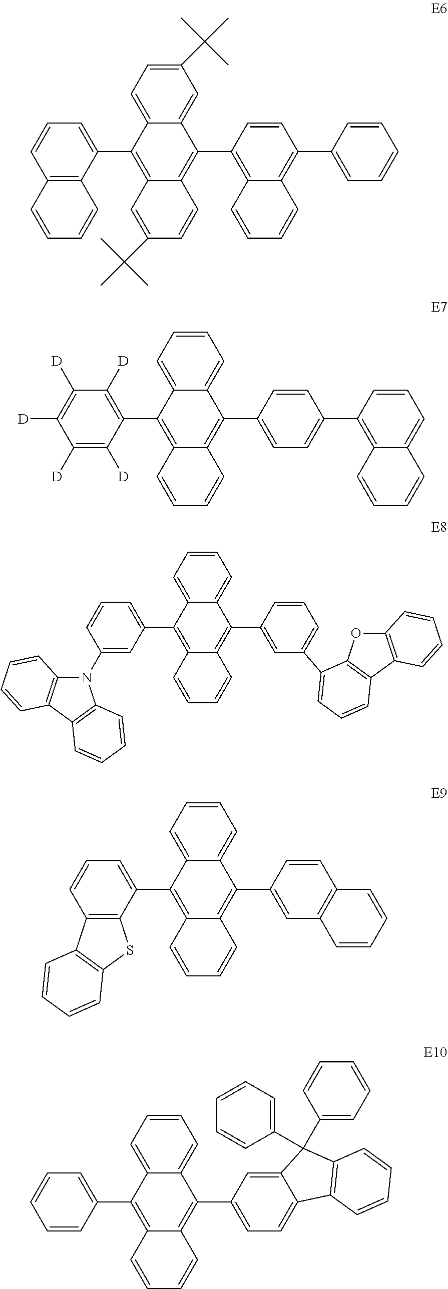

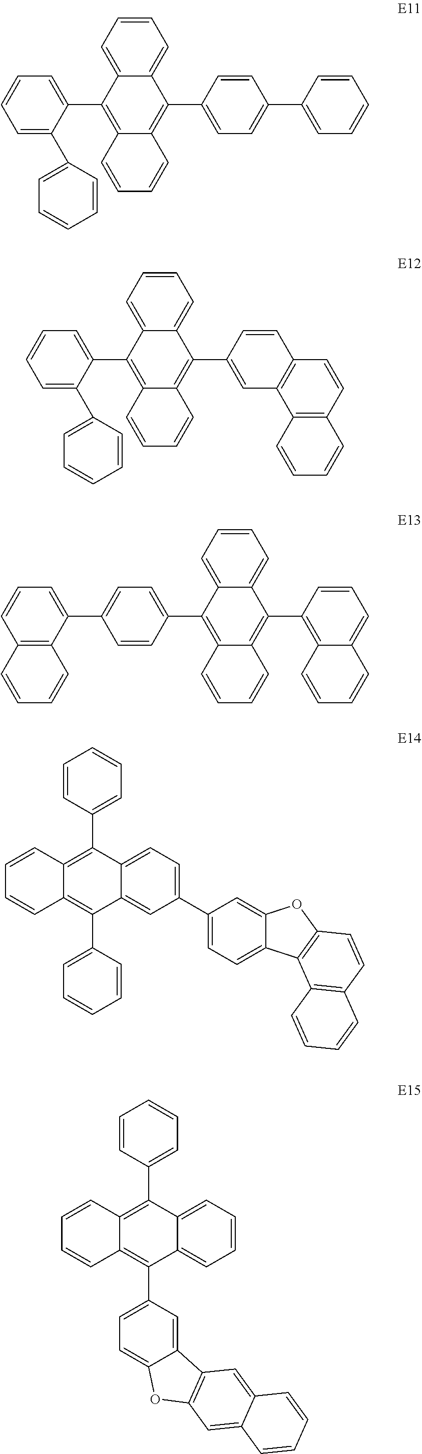

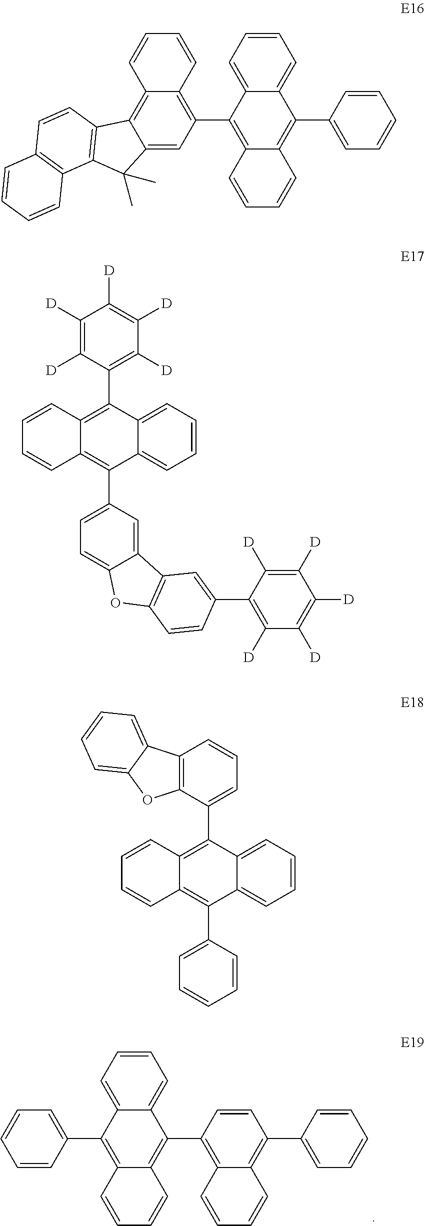

In an embodiment, the emission layer EML may further include a compound represented by Formula E-2a or Formula E-2b. The compound represented by Formula E-2a or Formula E-2b may be used as a phosphorescent host material.

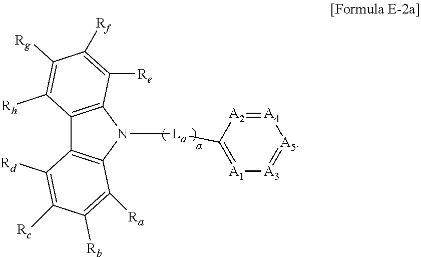

In Formula E-2a, a may be an integer from 0 to 10; and La may be a direct linkage, a substituted or unsubstituted arylene group having 6 to 30 ring-forming carbon atoms, or a substituted or unsubstituted heteroarylene group having 2 to 30 ring-forming carbon atoms. When a is 2 or greater, multiple La groups may each independently be a substituted or unsubstituted arylene group having 6 to 30 ring-forming carbon atoms or a substituted or unsubstituted heteroarylene group having 2 to 30 ring-forming carbon atoms.

In Formula E-2a, A₁ to A₅ may each independently be N or C(Rᵢ). In Formula E-2a, Rₐ to Rᵢ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. For example, Rₐ to Rᵢ may be bonded to an adjacent group to form a hydrocarbon ring or a heterocycle containing N, O, S, etc., as a ring-forming atom.

In Formula E-2a, two or three of A₁ to A₅ may each be N, and the remainder of A₁ to A₅ may each independently be C(Rᵢ).

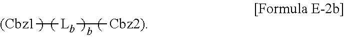

In Formula E-2b, Cbz1 and Cbz2 may each independently be an unsubstituted carbazole group, or a carbazole group substituted with an aryl group having 6 to 30 ring-forming carbon atoms. In Formula E-2b, L_{b} may be a direct linkage, a substituted or unsubstituted arylene group having 6 to 30 ring-forming carbon atoms, or a substituted or unsubstituted heteroarylene group having 2 to 30 ring-forming carbon atoms. In Formula E-2b, b may be an integer from 0 to 10. When b is 2 or greater, multiple L_{b} groups may each independently be a substituted or unsubstituted arylene group having 6 to 30 ring-forming carbon atoms or a substituted or unsubstituted heteroarylene group having 2 to 30 ring-forming carbon atoms.

In an embodiment, the compound represented by Formula E-2a or Formula E-2b may be any compound selected from Compound Group E-2. However, the compounds listed in Compound Group E-2 are only examples, and the compound represented by Formula E-2a or Formula E-2b is not limited to Compound Group E-2:

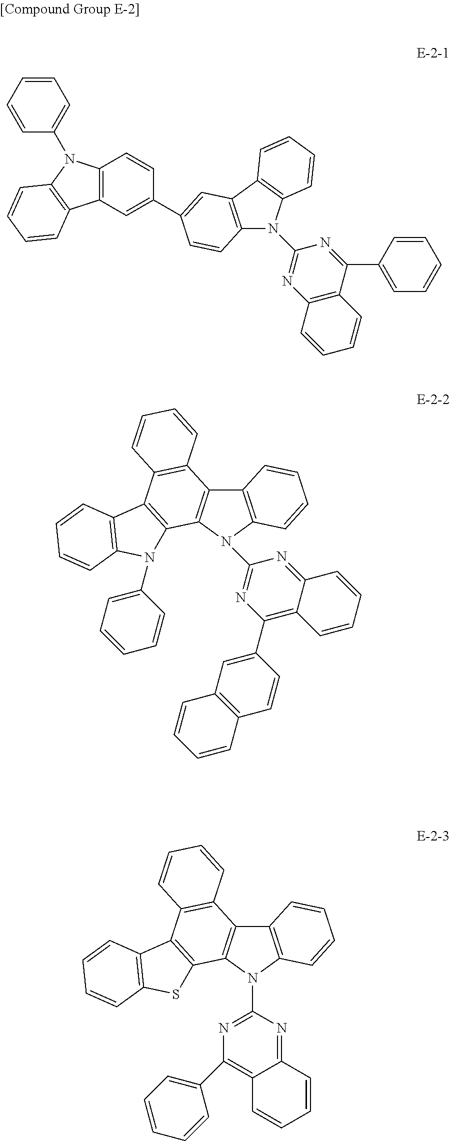 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-n2c3ccccc3c3c4ccccc4c4c5ccccc5n(-c5nc(-c6ccc7ccccc7c6)c6ccccc6n5)c4c32)cc1 ; c1ccc(-c2nc(-n3c4ccccc4c4c5ccccc5c5c6ccccc6sc5c43)nc3ccccc23)cc1]

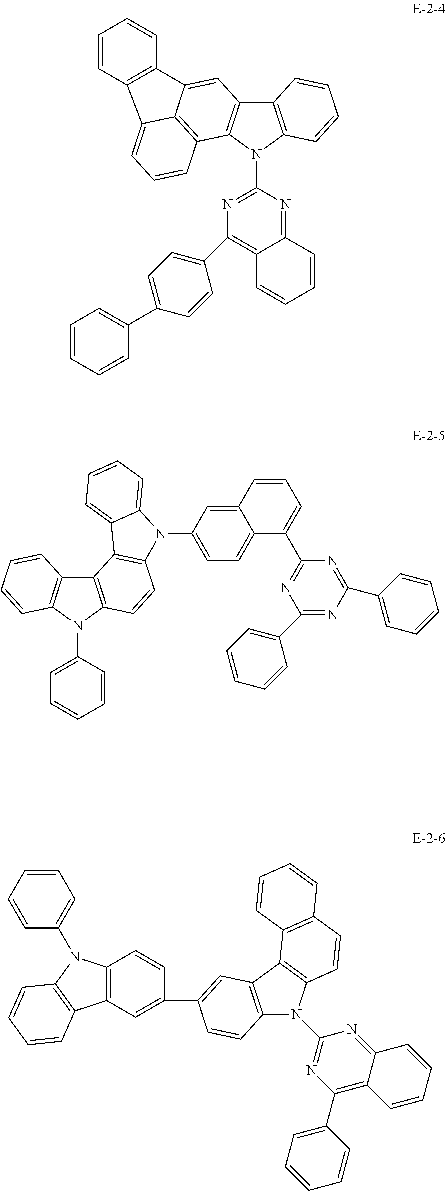 [SMILES: c1ccc(-c2ccc(-c3nc(-n4c5ccccc5c5cc6c7c(cccc7c54)-c4ccccc4-6)nc4ccccc34)cc2)cc1 ; c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1]

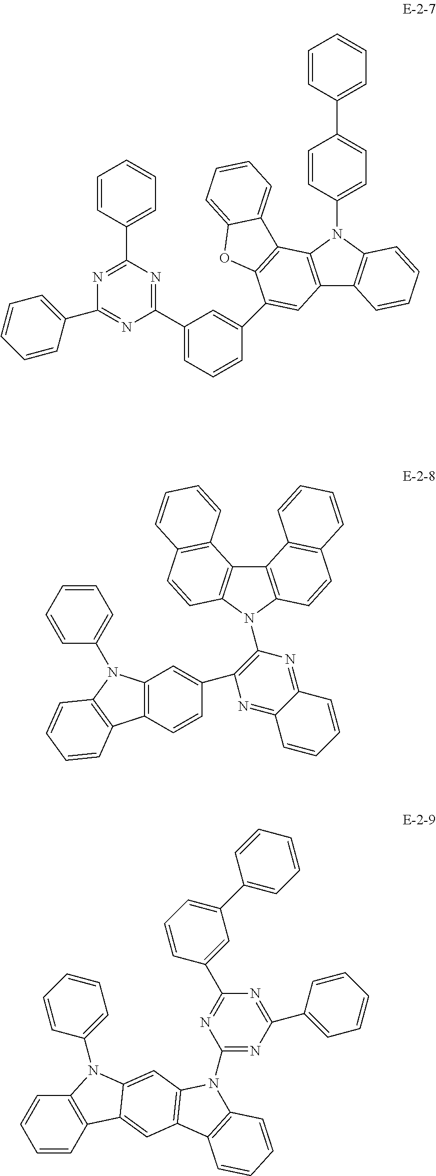 [SMILES: c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1 ; c1ccc(-c2cccc(-c3nc(-c4ccccc4)nc(-n4c5ccccc5c5cc6c7ccccc7n(-c7ccccc7)c6cc54)n3)c2)cc1]

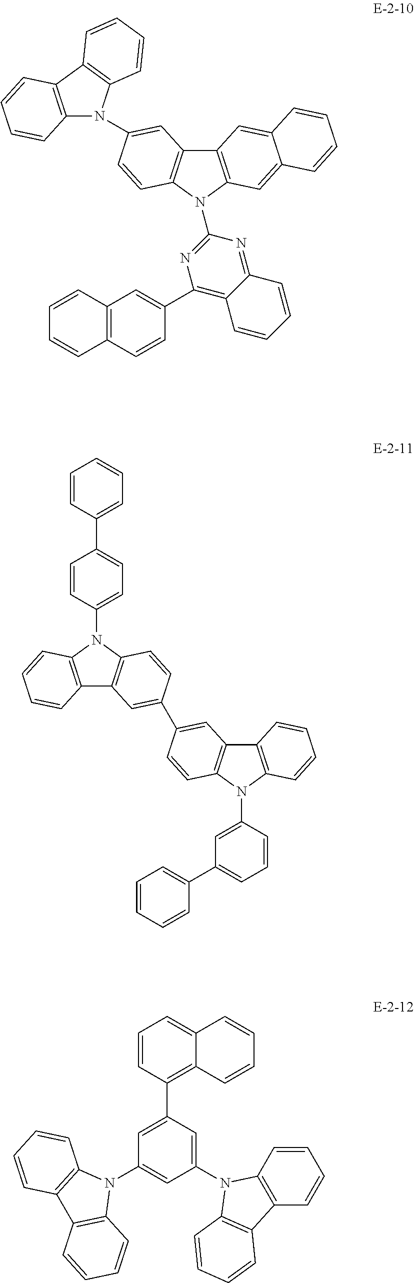 [SMILES: c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1 ; c1ccc2c(-c3cc(-n4c5ccccc5c5ccccc54)cc(-n4c5ccccc5c5ccccc54)c3)cccc2c1]

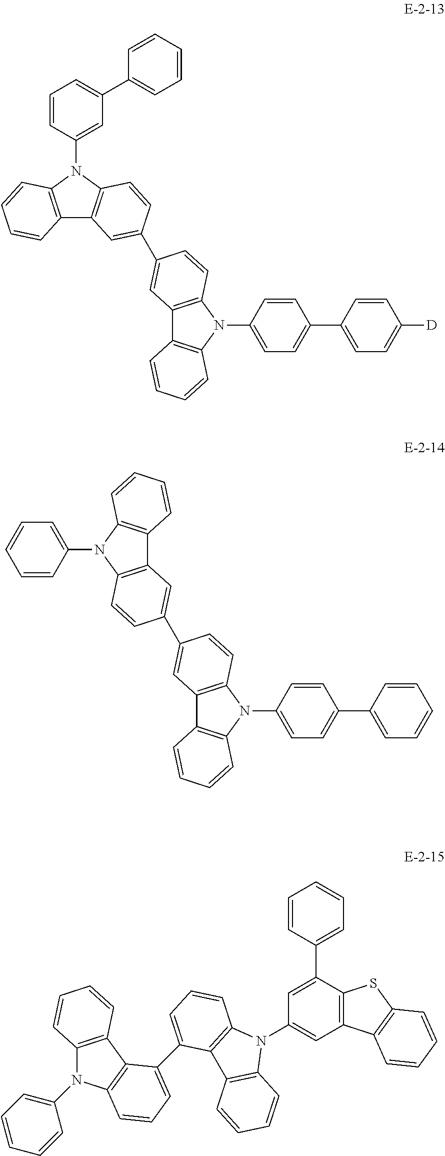 [SMILES: [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

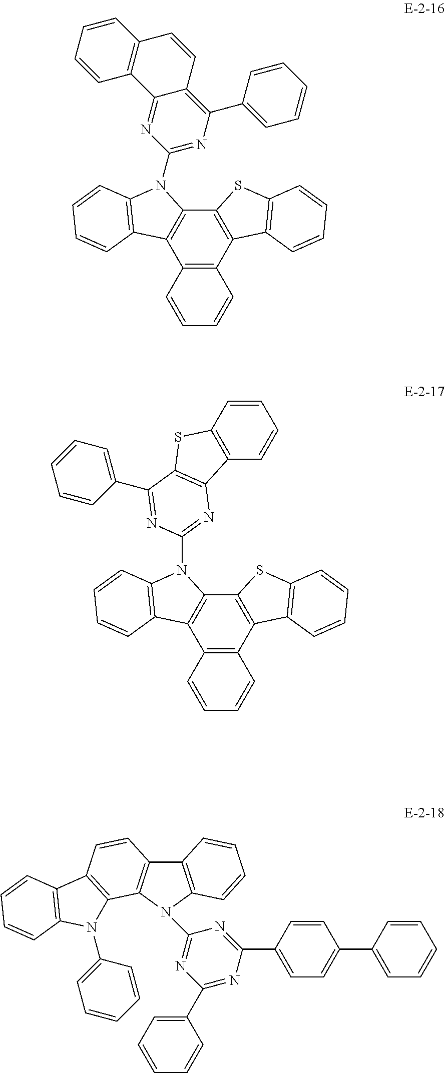 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1]

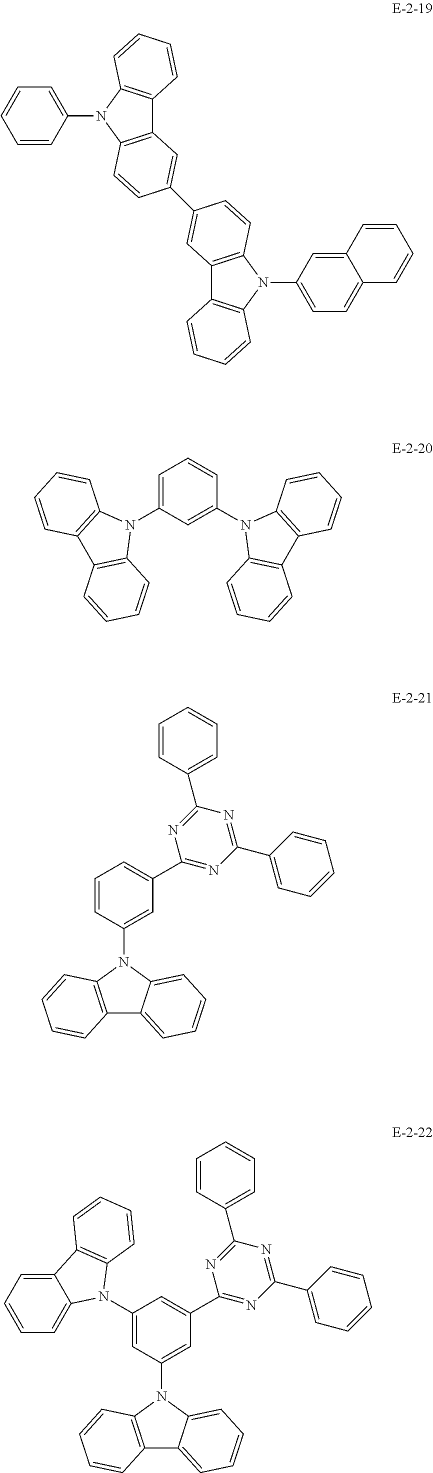 [SMILES: c1ccc(-n2c3ccccc3c3cc(-c4ccc5c(c4)c4ccccc4n5-c4ccc5ccccc5c4)ccc32)cc1 ; c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1]

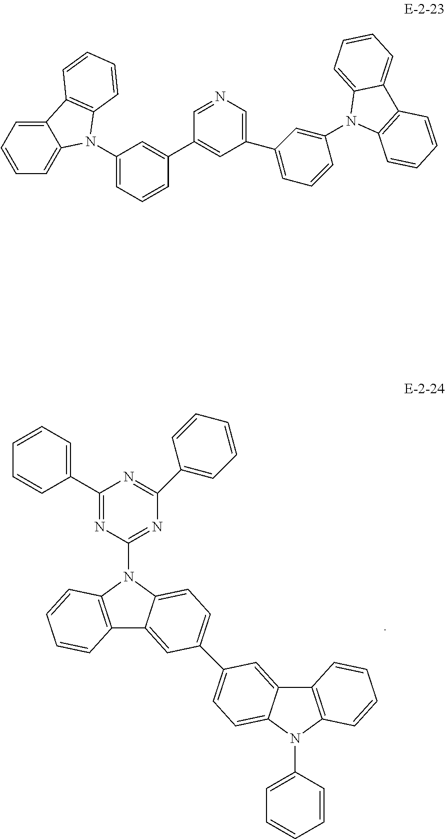 [SMILES: c1cc(-c2cncc(-c3cccc(-n4c5ccccc5c5ccccc54)c3)c2)cc(-n2c3ccccc3c3ccccc32)c1 ; c1ccc(-c2nc(-c3ccccc3)nc(-n3c4ccccc4c4cc(-c5ccc6c(c5)c5ccccc5n6-c5ccccc5)ccc43)n2)cc1]

In an embodiment, the emission layer EML may further include a compound represented by Formula M-a. The compound represented by Formula M-a below may be used as a phosphorescent dopant material.

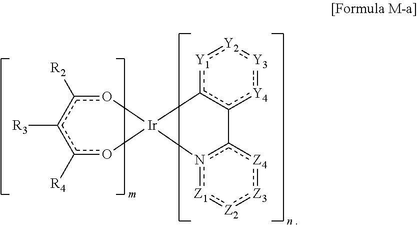

In Formula M-a, Y₁ to Y₄ and Z₁ to Z₄ may each independently be C(R₁) or N; and R₁ to R₄ may each independently be a hydrogen atom, a deuterium atom, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula M-a, m may be 0 or 1, and n may be 2 or 3. In Formula M-a, when m is 0, n may be 3, and when m is 1, n may be 2.

In an embodiment, the compound represented by Formula M-a may be any compound selected from Compound M-a1 to Compound M-a25. However, Compounds M-a1 to M-a25 are only examples, and the compound represented by Formula M-a is not limited to Compounds M-a1 to M-a25:

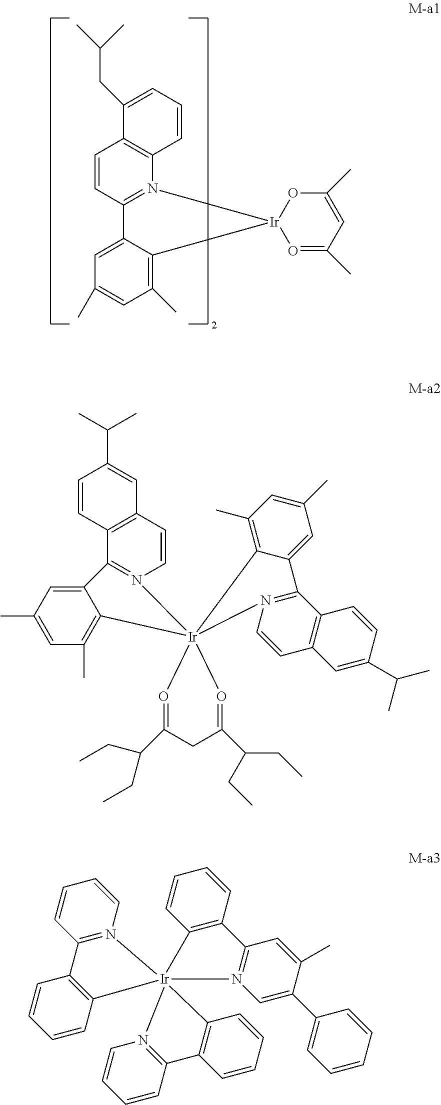

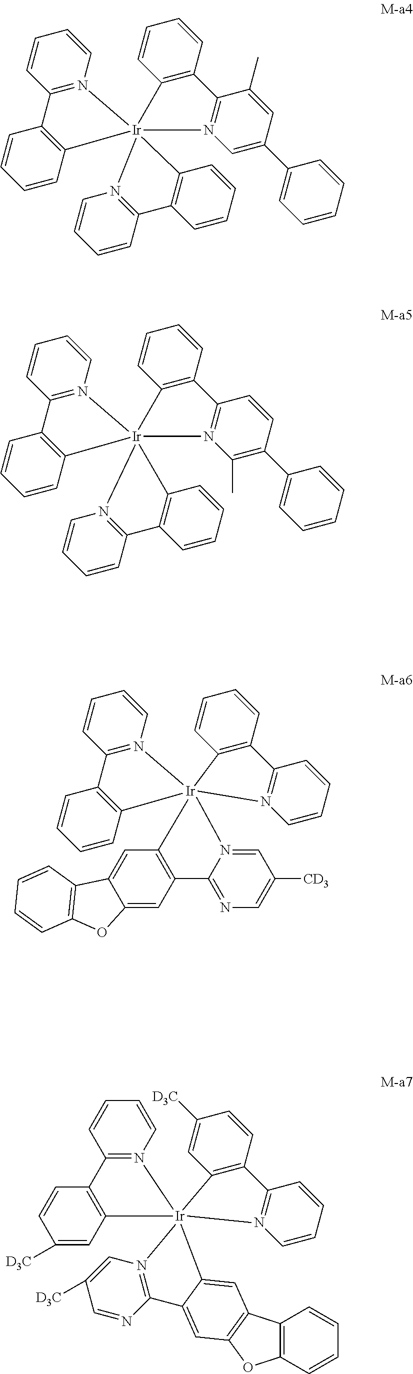

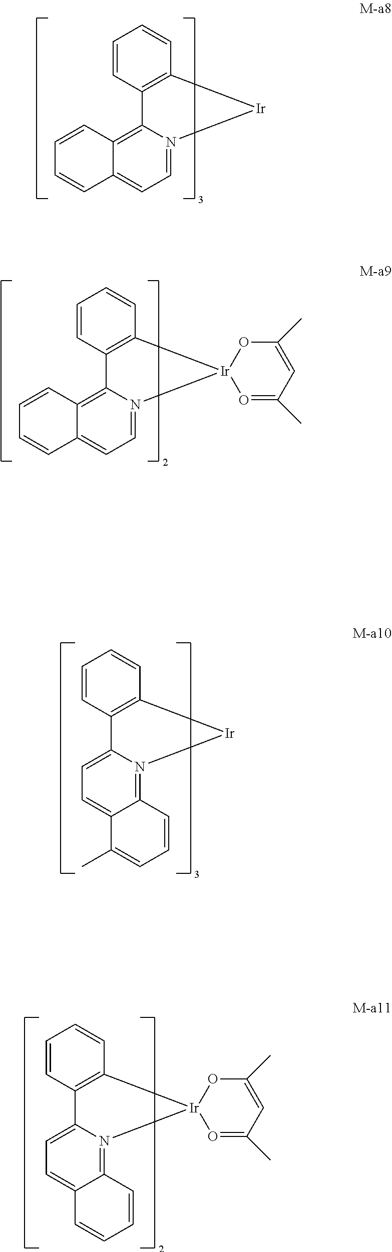

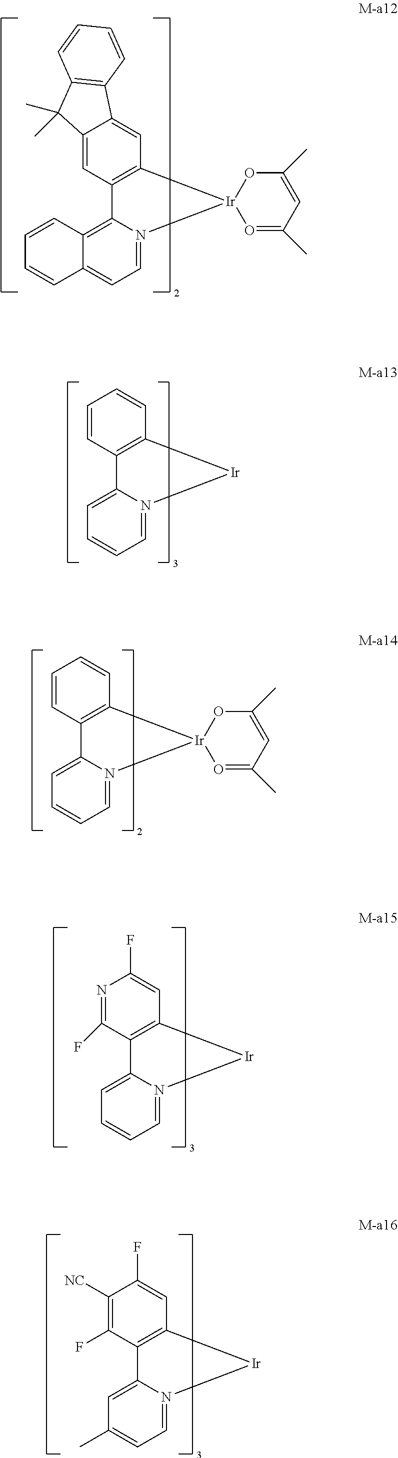

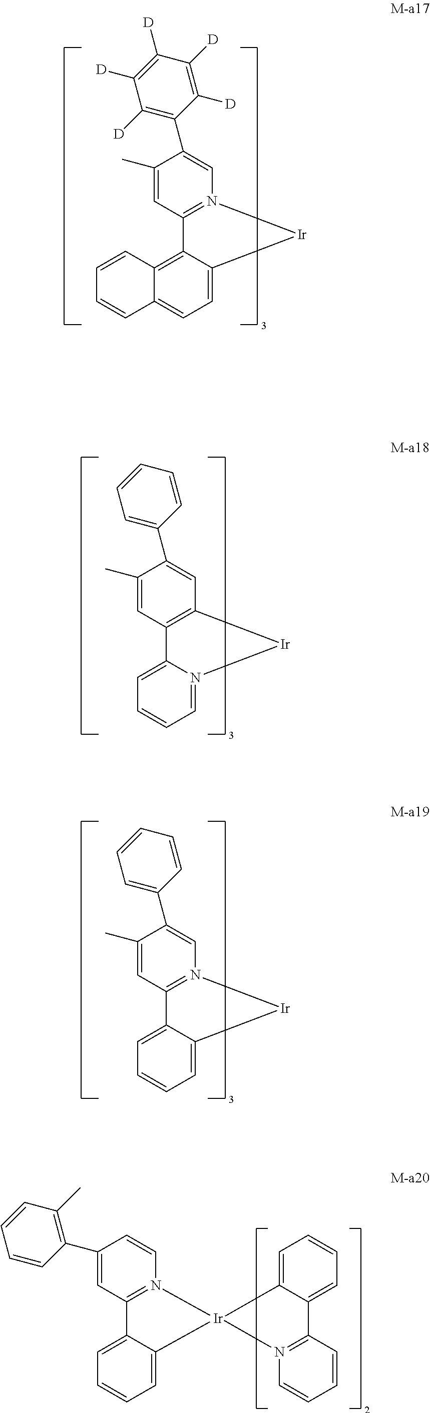

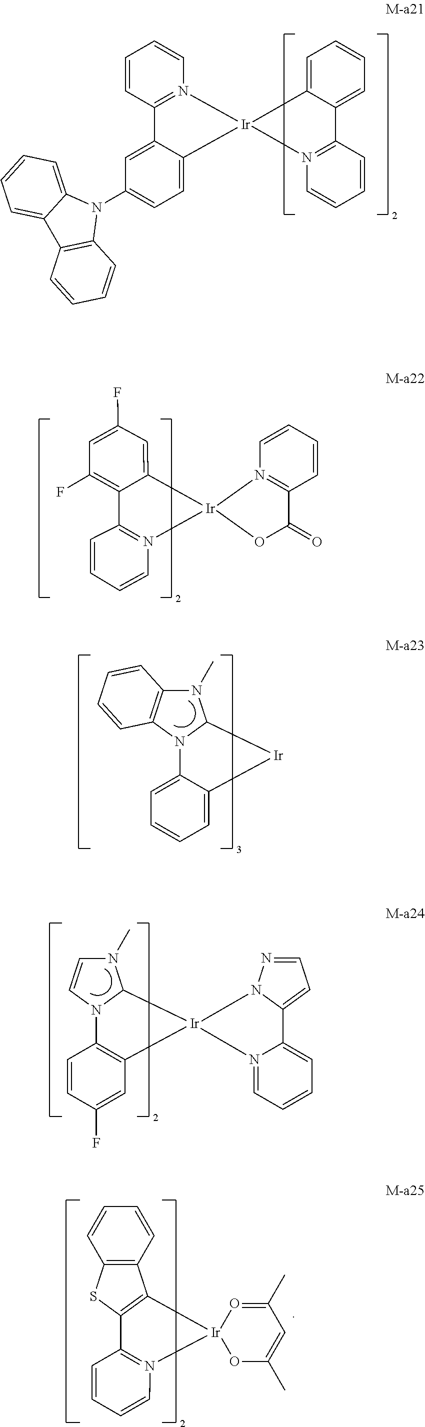

In an embodiment, the emission layer EML may further include a compound represented by one of Formula F-a to Formula F-c. The compounds represented by one of Formula F-a to Formula F-c may be used as a fluorescent dopant material.

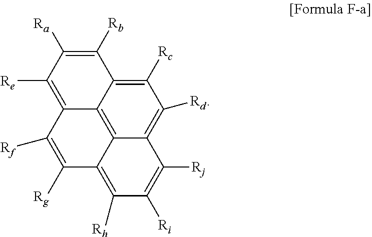

In Formula F-a, two of Rₐ to Rⱼ may each independently be substituted with a group represented by

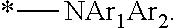

The remainder of Rₐ to Rⱼ that are not substituted with the group represented by

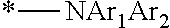

may each independently be a hydrogen atom, a deuterium atom, a halogen atom, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In the group represented by

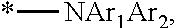

Ar₁ and Ar₂ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ and Ar₂ may each independently be a heteroaryl group containing O or S as a ring-forming atom.

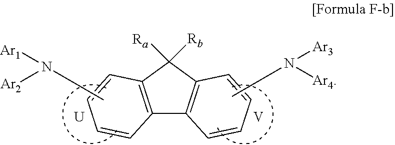

In Formula F-b, Rₐ and R_{b} may each independently be a hydrogen atom, a deuterium atom, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring. In Formula F-b, Ar₁ to Ar₄ may each independently be a substituted or unsubstituted aryl group having 6 to 30 ring-forming carbon atoms or a substituted or unsubstituted heteroaryl group having 2 to 30 ring-forming carbon atoms. For example, at least one of Ar₁ to Ar₄ may each independently be a heteroaryl group containing O or S as a ring-forming atom.

In Formula F-b, U and V may each independently be a substituted or unsubstituted hydrocarbon ring having 5 to 30 ring-forming carbon atoms or a substituted or unsubstituted heterocycle having 2 to 30 ring-forming carbon atoms.

In Formula F-b, the number of rings represented by U and V may each independently be 0 or 1. When the number of U or V is 1, a fused ring may be present at a portion respectively indicated by U or V, and when the number of U or V is 0, a fused ring may not be present at the portion respectively indicated by U or V. When the number of U is 0 and the number of V is 1, or when the number of U is 1 and the number of V is 0, a fused ring having a fluorene core of Formula F-b may be a cyclic compound having four rings. When the number of U and V is each 0, a fused ring having a fluorene core of Formula F-b may be a cyclic compound having three rings. When the number of U and V is each 1, a fused ring having a fluorene core of Formula F-b may be a cyclic compound having five rings.

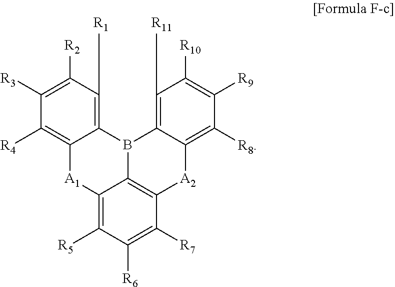

In Formula F-c, A₁ and A₂ may each independently be O, S, Se, or N(Rₘ); and Rₘ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula F-c, R₁ to R₁₁ may each independently be a hydrogen atom, a deuterium atom, a halogen atom, a cyano group, a substituted or unsubstituted amine group, a substituted or unsubstituted boron group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, or bonded to an adjacent group to form a ring.

In Formula F-c, A₁ and A₂ may each independently be bonded to a substituent of an adjacent ring to form a fused ring. For example, when A₁ and A₂ are each independently N(Rₘ), A₁ may be bonded to R₄ or R₅ to form a fused ring, and/or A₂ may be bonded to R₇ or R₈ to form a fused ring.

In an embodiment, the emission layer EML may further include, as a dopant material of the related art, a styryl derivative (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino) styryl) naphthalen-2-yl)vinyl)phenyl)-N-phenylbenzenamine (N-BDAVBi), and 4,4′-bis[2-(4-(N,N-diphenylamino)phenyl)vinyl]biphenyl (DPAVBi)), perylene or a derivative thereof (e.g., 2,5,8,11-tetra-t-butylperylene (TBP)), pyrene or a derivative thereof (e.g., 1,1-dipyrene, 1,4-dipyrenylbenzene, 1,4-bis(N,N-diphenylamino)pyrene), etc.

The emission layer EML may further include a phosphorescence dopant material of the related art. For example, a metal complex containing iridium (Ir), platinum (Pt), osmium (Os), gold (Au), titanium (Ti), zirconium (Zr), hafnium (Hf), europium (Eu), terbium (Tb), or thulium (Tm) may be used as a phosphorescent dopant. For example, iridium(III) bis(4,6-difluorophenylpyridinato-N,C2′) picolinate (FIrpic), bis(2,4-difluorophenylpyridinato)-tetrakis(1-pyrazolyl)borate iridium(III) (Fir6), or platinum octaethyl porphyrin (PtOEP) may be used as a phosphorescent dopant. However, embodiments are not limited thereto.

In an embodiment, the emission layer EML may include a quantum dot. The quantum dot may be include a Group II-VI compound, a Group I-II-VI compound, a Group II-IV-VI compound, a Group I-II-IV-VI compound, a Group II-IV-V compound, a Group III-VI compound, a Group I-III-VI compound, a Group III-V compound, a Group III-II-V compound, a Group IV-VI compound, a Group IV element, a Group IV compound, or a combination thereof.

Examples of a Group II-VI compound may be include: a binary compound such as CdSe, CdTe, CdS, ZnS, ZnSe, ZnTe, ZnO, HgS, HgSe, HgTe, MgSe, MgS, and a mixture thereof; a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; a quaternary compound such as HgZnTeS, CdZnSeS, CdZnSeTe, CdZnSTe, CdHgSeS, CdHgSeTe, CdHgSTe, HgZnSeS, HgZnSeTe, and a mixture thereof; and any combination thereof.

Examples of a Group III-VI compound may include: a binary compound such as In₂S₃ or In₂Se₃; a ternary compound such as InGaS₃ or InGaSe₃; and any combination thereof.

Examples of a Group I-III-VI compound may include: a ternary compound such as AgInS, AgInS₂, CuInS, CuInS₂, AgGaS₂, CuGaS₂, CuGaO₂, AgGaO₂, AgAlO₂, and a mixture thereof; a quaternary compound such as AgInGaS₂ or CuInGaS₂; and any combination thereof.

Examples of a Group III-V compound may include: a binary compound such as GaN, GaP, GaAs, GaSb, AlN, AlP, AlAs, AlSb, InN, InP, InAs, InSb, and a mixture thereof; a ternary compound such as GaNP, GaNAs, GaNSb, GaPAs, GaPSb, AlNP, AlNAs, AlNSb, AlPAS, AlPSb, InGaP, InAlP, InNP, InNAs, InNSb, InPAs, InPSb, and a mixture thereof; a quaternary compound such as GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof; and any combination thereof. In an embodiment, a Group III-V compound may further include a Group II element. Examples of a Group III-II-V compound may include InZnP, etc.

Examples of a Group IV-VI compound may include: a binary compound such as SnS, SnSe, SnTe, PbS, PbSe, PbTe, and a mixture thereof; a ternary compound such as SnSeS, SnSeTe, SnSTe, PbSeS, PbSeTe, PbSTe, SnPbS, SnPbSe, SnPbTe, and a mixture thereof; a quaternary compound such as SnPbSSe, SnPbSeTe, SnPbSTe, and a mixture thereof; and any combination thereof. Examples of a Group IV element may include Si, Ge, and a mixture thereof. Examples of a Group IV compound may include a binary compound such as SiC, SiGe, and a mixture thereof.

Each element included in a compound such as a binary compound, a ternary compound, or a quaternary compound, may be present in a particle at a uniform concentration distribution or at a non-uniform concentration distribution. For example, a formula may indicate the elements that are included in a compound, but an elemental ratio of the compound may vary. For example, AgInGaS₂ may indicate AgInₓGa₁₋ₓS₂ (where x may be a real number between 0 to 1).

In an embodiment, a quantum dot may have a single structure in which the concentration of each element included in the quantum dot is uniform. In another embodiment, a quantum dot may have a core-shell structure in which a quantum dot material surrounds another quantum dot. For example, a material included in the core may be different from a material included in the shell.

The shell of a quantum dot may serve as a protection layer that prevents chemical deformation of the core to maintain semiconductor properties, and/or may serve as a charging layer that imparts electrophoretic properties to the quantum dot. The shell may have a single-layered structure or a multilayered structure. An interface between the core and the shell may have a concentration gradient in which the concentration of an element that is present in the shell decreases towards the core.

Examples of a shell of a quantum dot may include a metal oxide, a non-metal oxide, a semiconductor compound, or a combination thereof. Examples of a metal oxide or a non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; or a ternary compound such as MgAl₂O₄, CoFe₂O₄, NiFC₂O₄, or CoMn₂O₄, but embodiments are not limited thereto.

Examples of a semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments are not limited thereto.

The quantum dot may have a full width at half maximum (FWHM) of an emission spectrum equal to or less than about 45 nm. For example, the quantum dot may have a FWHM of an emission spectrum equal to or less than about 40 nm. For example, the quantum dot may have a FWHM of an emission spectrum equal to or less than about 30 nm. Color purity or color reproducibility may be improved in any of the above ranges. Light emitted through a quantum dot may be emitted in all directions, so that a wide viewing angle may be improved.

The form of a quantum dot is not particularly limited and may be any form used in the related art. For example, a quantum dot may have a spherical shape, a pyramidal shape, a multi-arm shape, or a cubic shape, or a quantum dot may be the form of nanoparticles, nanotubes, nanowires, nanofibers, nanoplate particles, etc.

As a size of a quantum dot is adjusted or an elemental ratio in the quantum dot compound is adjusted, an energy band gap may be changed accordingly, so that light in various wavelength ranges may be emitted by a quantum dot emission layer. Therefore, by utilizing a quantum dot as described above (for example, using different sizes of quantum dots or having different elemental ratios in a quantum dot compound), a light emitting element that emits light of various wavelengths may be implemented. For example, the size of the quantum dot or the elemental ratio of the quantum dot compound may be adjusted to emit red light, green light, and/or blue light. For example, quantum dots may be configured to emit white light by combining various colors of light.

In the light emitting elements ED according to embodiments as shown in each of FIGS. 3 to 7, the electron transport region ETR may be provided on the emission layer EML. The electron transport region ETR may include at least one of a hole blocking layer HBL, an electron transport layer ETL, and an electron injection layer EIL, but embodiments are not limited thereto.

The electron transport region ETR may have a structure consisting of a layer consisting of a single material, a structure consisting of a layer including different materials, or a structure including multiple layers including different materials.

For example, the electron transport region ETR may have a single layer structure of an electron injection layer EIL or an electron transport layer ETL, or may have a single layer structure formed of an electron injection material and an electron transport material. In an embodiment, the electron transport region ETR may have a single layer structure formed of different materials, or may have a structure in which an electron transport layer ETL/electron injection layer EIL, or a hole blocking layer HBL/electron transport layer ETL/electron injection layer EIL are stacked in its respective stated order from the emission layer EML, but embodiments are not limited thereto. The electron transport region ETR may have a thickness, for example, in a range of about 1,000 Å to about 1,500 Å.

The electron transport region ETR may be formed using various methods such as a vacuum deposition method, a spin coating method, a cast method, a Langmuir-Blodgett (LB) method, an inkjet printing method, a laser printing method, and a laser induced thermal imaging (LITI) method.

In the light emitting element ED according to an embodiment, the electron transport region ETR may include a compound represented by Formula ET-2:

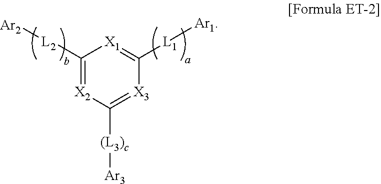

In Formula ET-2, at least one of X₁ to X₃ may each be N, and the remainder of X₁ to X₃ may each independently be C(Rₐ). In Formula ET-2, Rₐ may be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In Formula ET-2, Ar₁ to Ar₃ may each independently be a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-2, a to c may each independently be an integer from 0 to 10. In Formula ET-2, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. When a to c are each 2 or more, multiple groups of each of L₁ to L₃ may each independently be a substituted or unsubstituted arylene group having 6 to 30 ring-forming carbon atoms or a substituted or unsubstituted heteroarylene group having 2 to 30 ring-forming carbon atoms.

The electron transport region ETR may include an anthracene-based compound. However, embodiments are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri (1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), beryllium bis(benzoquinolin-10-olate) (Bebq₂), 9,10-di(naphthalene-2-yl)anthracene (ADN), 1,3-bis[3,5-di(pyridin-3-yl)phenyl]benzene (BmPyPhB), or a mixture thereof.

In an embodiment, the electron transport region ETR may include at least one compound selected from Compound ET1 to Compound ET36:

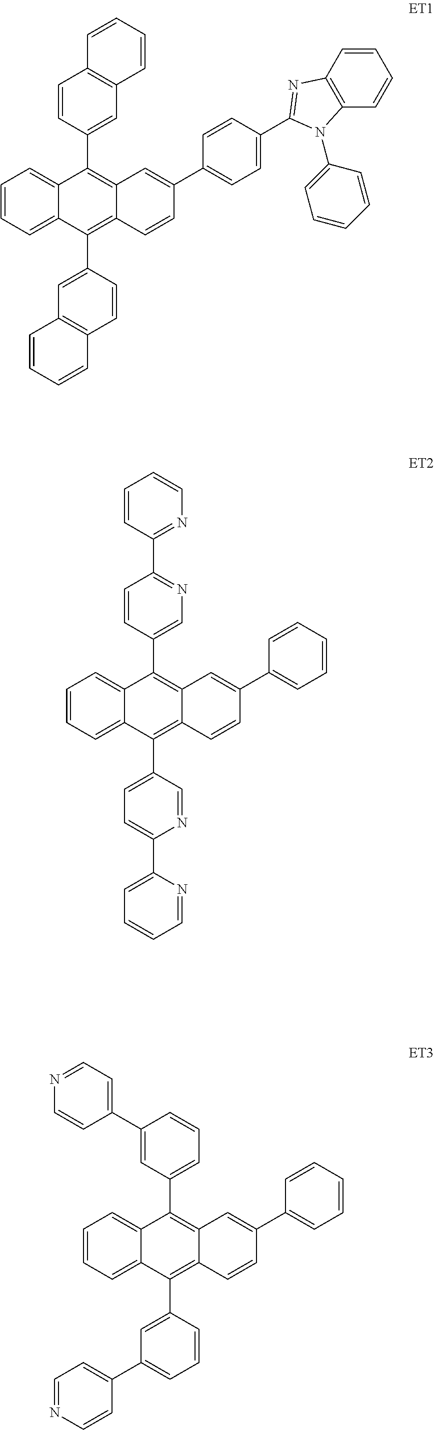 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

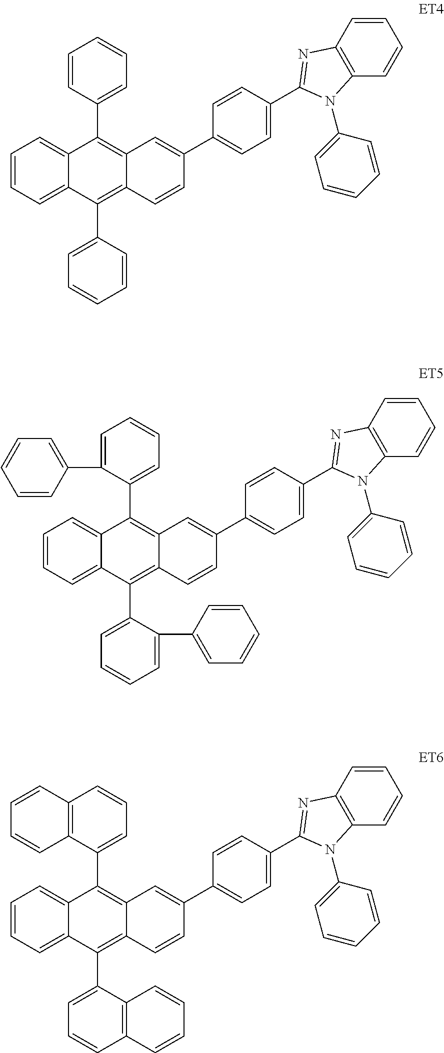 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

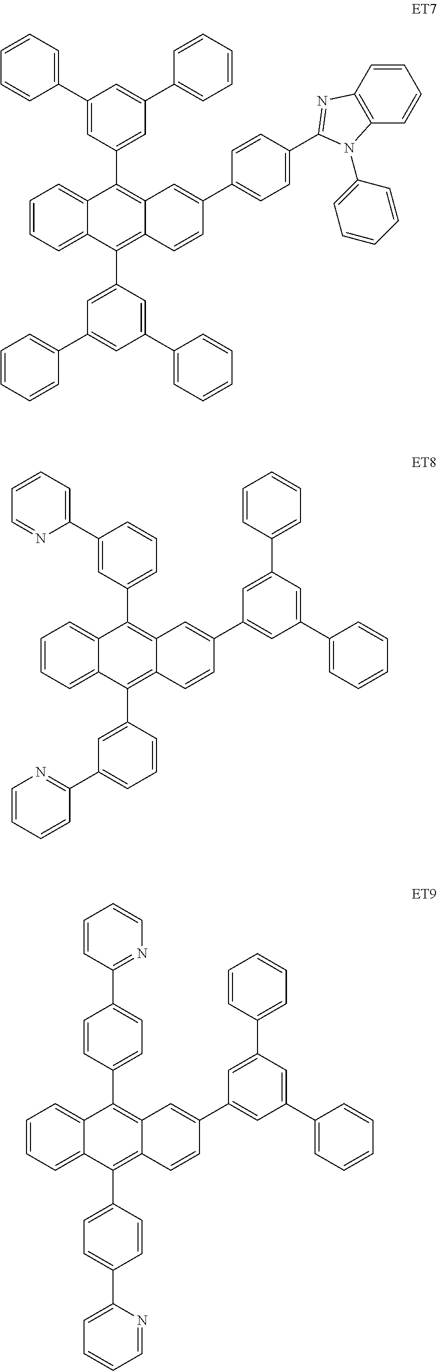 [SMILES: c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1]

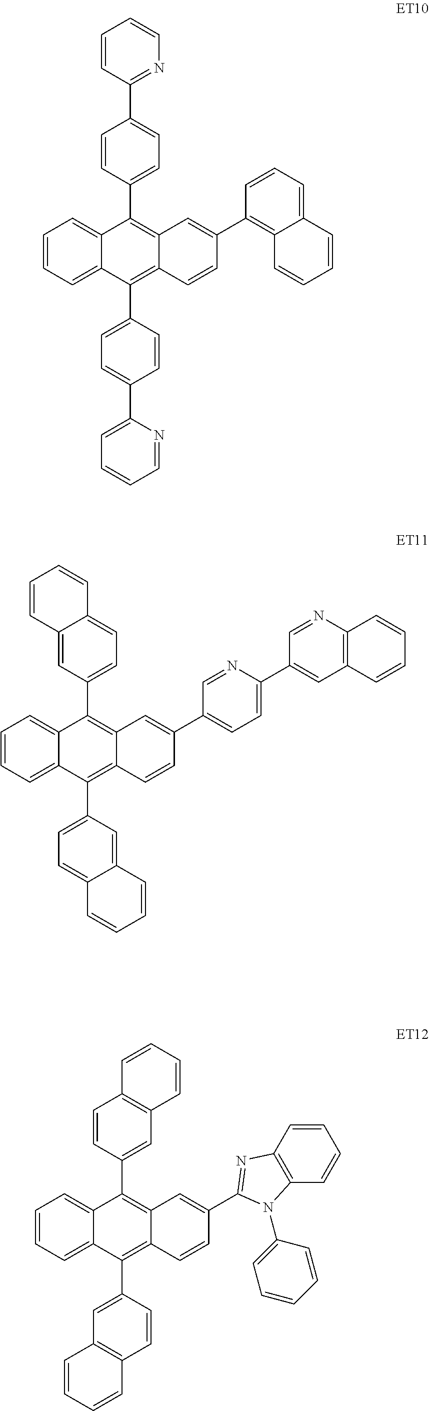 [SMILES: c1ccc(-c2ccc(-c3c4ccccc4c(-c4ccc(-c5ccccn5)cc4)c4cc(-c5cccc6ccccc56)ccc34)cc2)nc1 ; c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1]

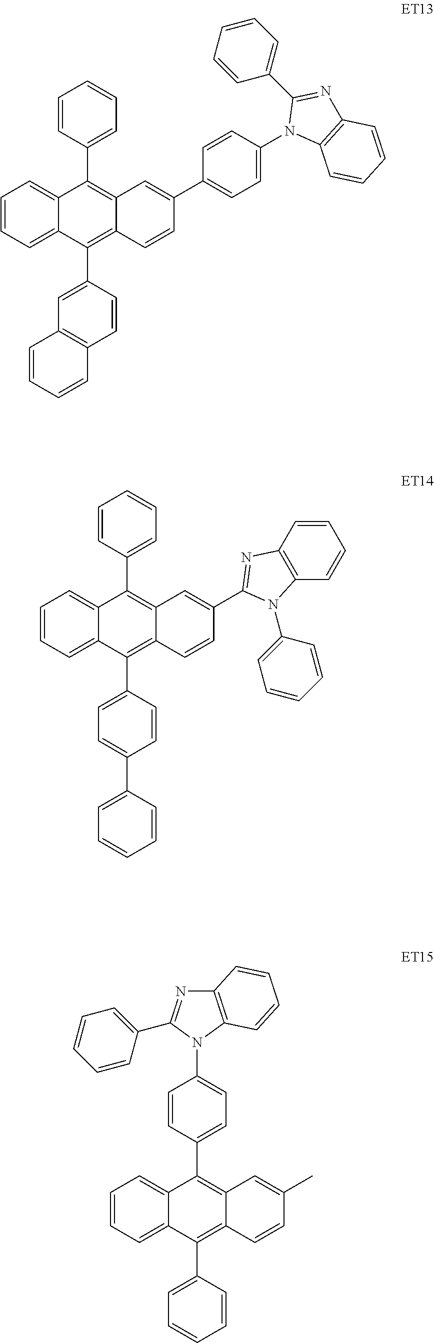 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

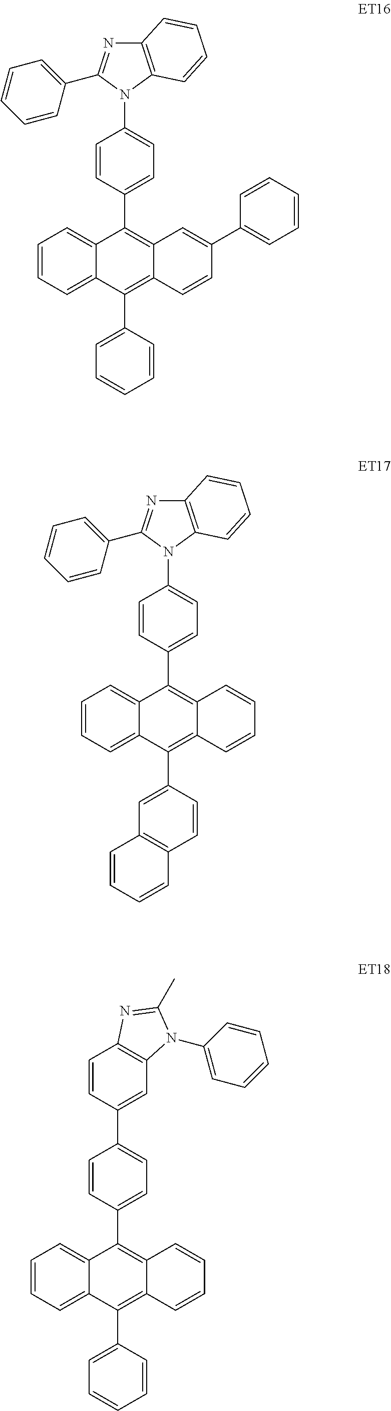 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

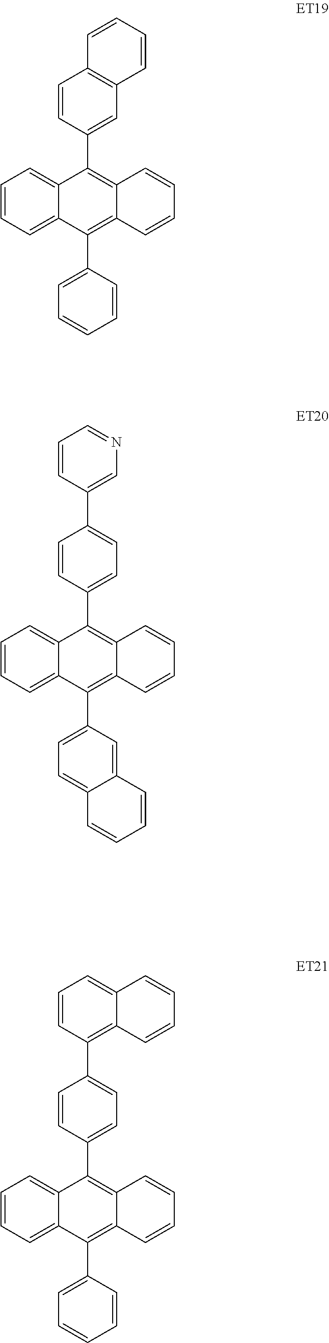

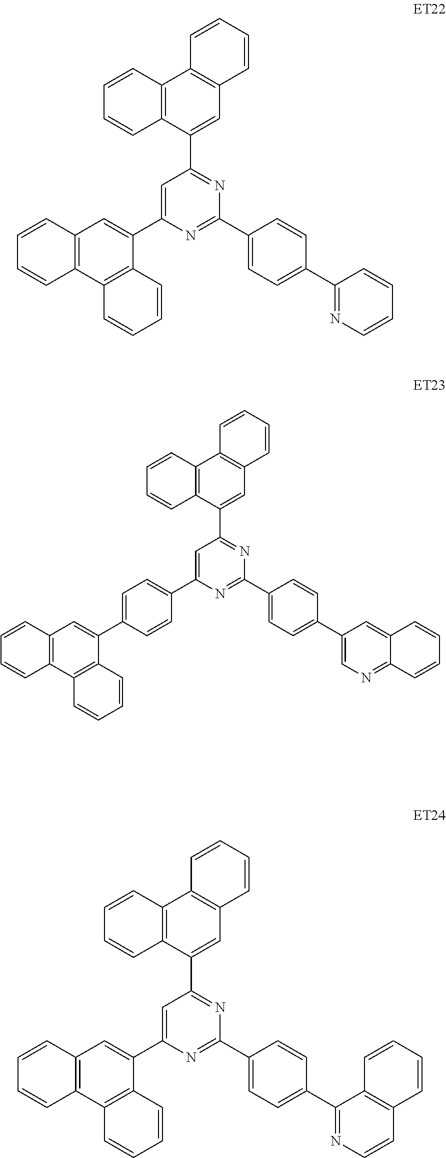 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

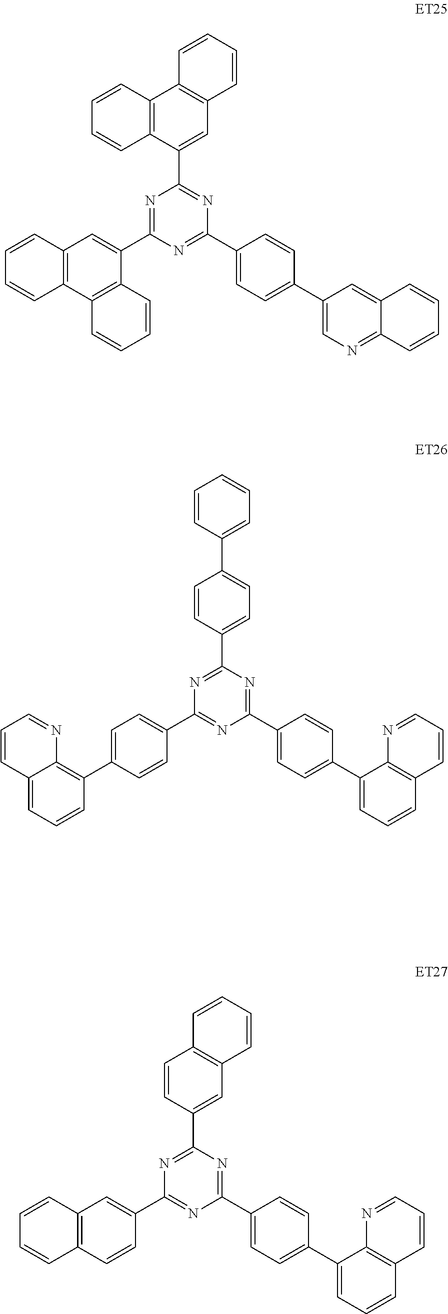 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

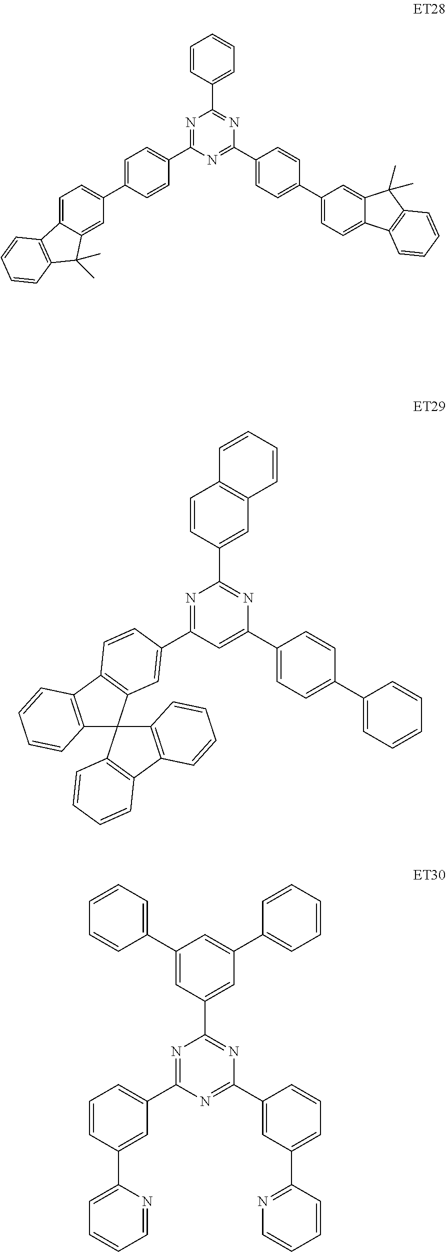 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

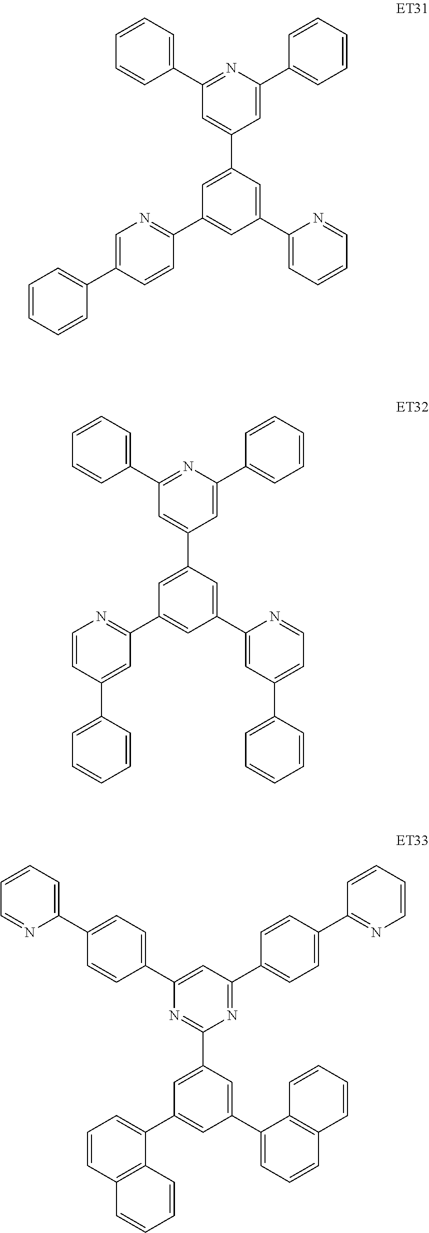 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

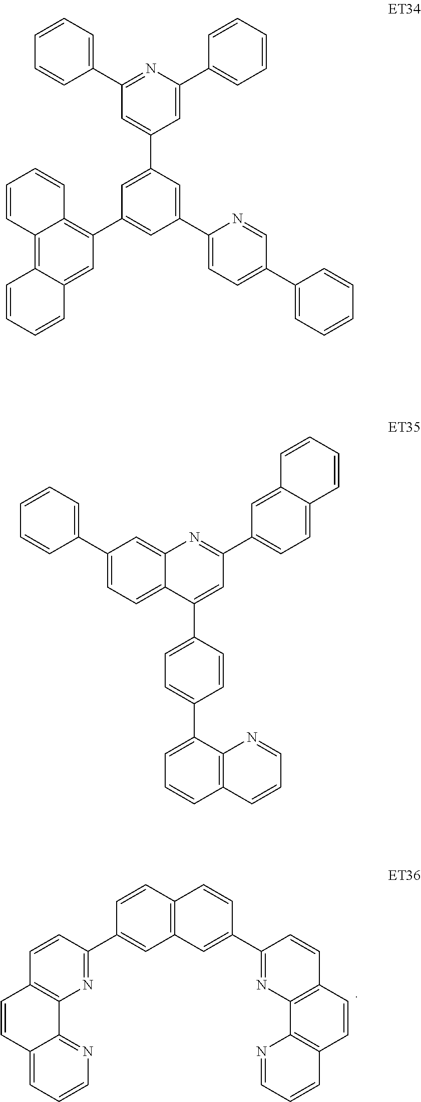 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

In an embodiment, the electron transport region ETR may include: a metal halide such as LiF, NaCl, CsF, RbCl, RbI, CuI, and KI; a lanthanide such as Yb; or a co-deposited material of the metal halide and the lanthanide. For example, the electron transport region ETR may include KI:Yb, RbI:Yb, LiF:Yb, etc., as a co-deposited material. The electron transport region ETR may include a metal oxide such as Li₂O or BaO, or 8-hydroxyl-lithium quinolate (Liq), etc., but embodiments are not limited thereto. The electron transport region ETR may also be formed of a mixture of an electron transport material and an insulating organometallic salt. The organometallic salt may be a material having an energy band gap equal to or greater than about 4 eV. For example, the organometallic salt may include a metal acetate, a metal benzoate, a metal acetoacetate, a metal acetylacetonate, or a metal stearate.

The electron transport region ETR may further include at least one of 2,9-dimethyl-4,7-diphenyl-1,10-phenanthroline (BCP), diphenyl (4-(triphenylsilyl)phenyl)phosphine oxide (TSPO1), and 4,7-diphenyl-1,10-phenanthroline (Bphen) in addition to the above-described materials, but embodiments are not limited thereto.

The electron transport region ETR may include the above-described compounds of the electron transport region in at least one of an electron injection layer EIL, an electron transport layer ETL, and a hole blocking layer HBL.

When the electron transport region ETR includes an electron transport layer ETL, the electron transport layer ETL may have a thickness in a range of about 100 Å to about 1,000 Å. For example, the electron transport layer ETL may have a thickness in a range of about 150 Å to about 500 Å. If the thickness of the electron transport layer ETL satisfies the aforementioned range, satisfactory electron transport characteristics may be obtained without a substantial increase in driving voltage. When the electron transport region ETR includes an electron injection layer EIL, the electron injection layer EIL may have a thickness in a range of about 1 Å to about 100 Å. For example, the electron injection layer EIL may have a thickness in a range of about 3 Å to about 90 Å. If the thickness of the electron injection layer EIL satisfies the above-described range, satisfactory electron injection characteristics may be obtained without a substantial increase in driving voltage.

The second electrode EL2 may be provided on the electron transport region ETR. The second electrode EL2 may be a common electrode. The second electrode EL2 may be a cathode or an anode, but embodiments are not limited thereto. For example, when the first electrode EL1 is an anode, the second electrode EL2 may be a cathode, and when the first electrode EL1 is a cathode, the second electrode EL2 may be an anode.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, a compound thereof, or a mixture thereof (e.g., AgMg, AgYb, or MgAg). In an embodiment, the second electrode EL2 may have a multilayer structure including a reflective film or a transflective film formed of the above-described materials, and a transparent conductive film formed of ITO, IZO, ZnO, ITZO, etc. For example, the second electrode EL2 may include the above-described metal materials, combinations of at least two of the above-described metal materials, oxides of the above-described metal materials, or the like.

Although not shown in the drawings, the second electrode EL2 may be electrically connected to an auxiliary electrode. If the second electrode EL2 is electrically connected to an auxiliary electrode, resistance of the second electrode EL2 may decrease.

In an embodiment, the light emitting element ED may further include a capping layer CPL disposed on the second electrode EL2. The capping layer CPL may have a multilayered structure or a single-layered structure.

In an embodiment, the capping layer CPL may include an organic layer or an inorganic layer. For example, when the capping layer CPL contains an inorganic material, the inorganic material may include an alkaline metal compound (e.g., LiF), an alkaline earth metal compound (e.g., MgF₂), SiON, SiNₓ, SiOy, etc.

For example, when the capping layer CPL includes an organic material, the organic material may include α-NPD, NPB, TPD, m-MTDATA, Alq₃, CuPc, N4,N4,N4′,N4′-tetra(biphenyl-4-yl)biphenyl-4,4′-diamine (TPD15), 4,4′,4″-tris(carbazol-9-yl)triphenylamine (TCTA), etc., or may include an epoxy resin, or an acrylate such as methacrylate. However, embodiments are not limited thereto, and the capping layer CPL may include at least one of Compounds P1 to P5:

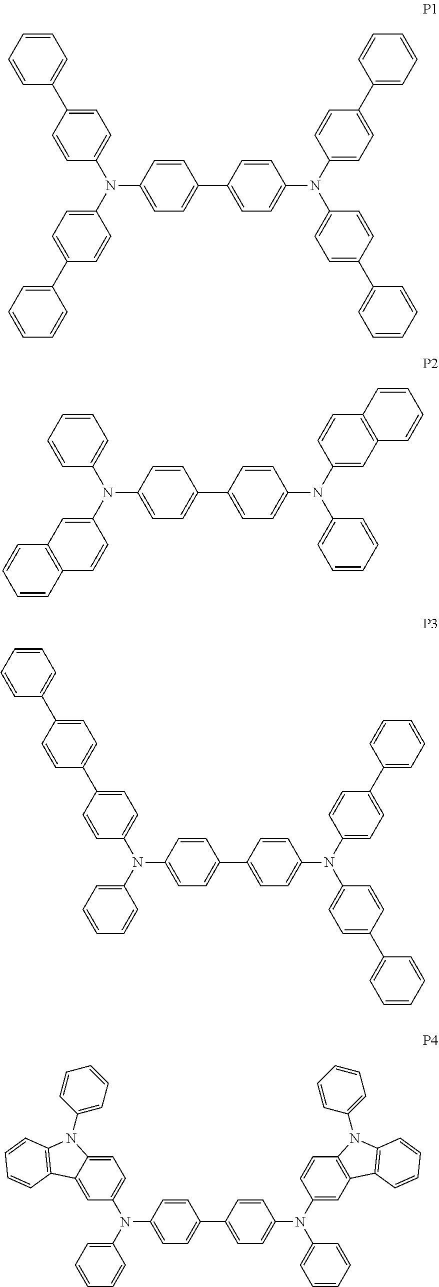 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

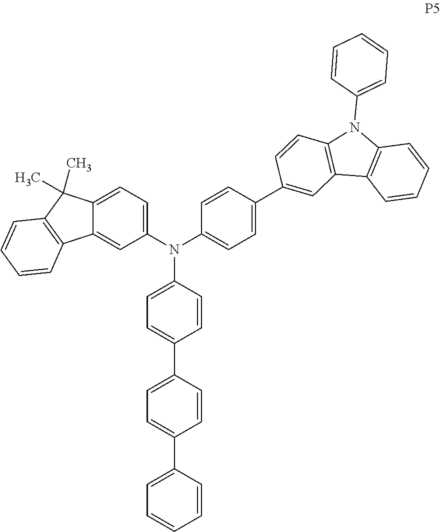 [SMILES: CC1(C)c2ccccc2-c2cc(N(c3ccc(-c4ccc(-c5ccccc5)cc4)cc3)c3ccc(-c4ccc5c(c4)c4ccccc4n5-c4ccccc4)cc3)ccc21]

A refractive index of the capping layer CPL may be equal to or greater than about 1.6. For example, the refractive index of the capping layer CPL may be equal to or greater than about 1.6, with respect to light in a wavelength range of about 550 nm to about 660 nm.

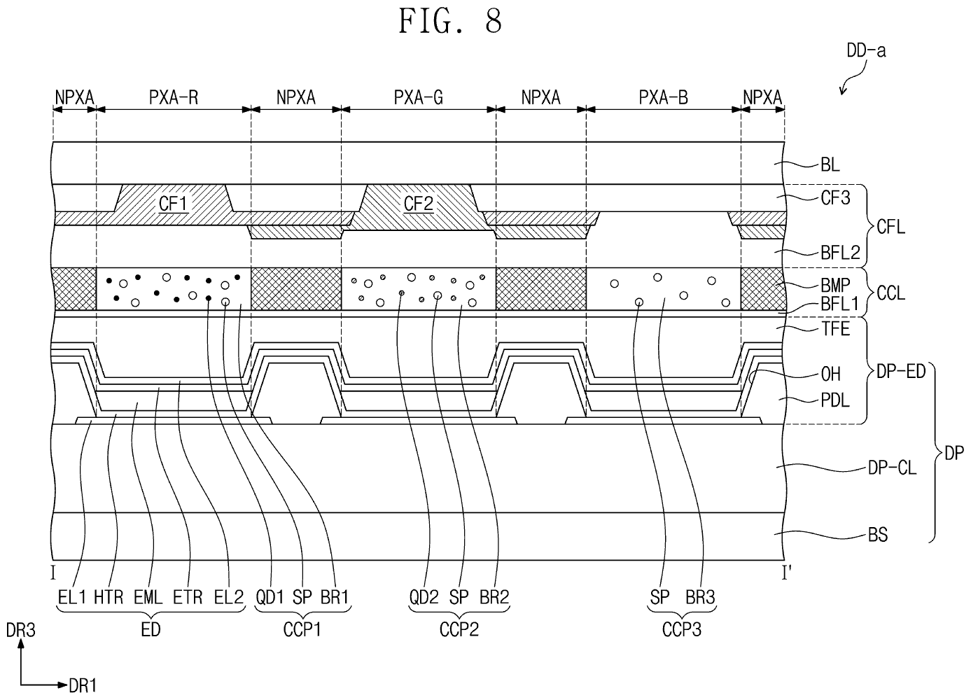

FIGS. 8 to 11 are each a schematic cross-sectional view of a display device according to an embodiment. In the descriptions of the display devices according to embodiments as shown in FIGS. 8 to 11, the features which have been described above with respect to FIGS. 1 to 7 will not be described again, and the differing features will be described.

Referring to FIG. 8, the display device DD-a according to an embodiment may include a display panel DP including a display element layer DP-ED, a light control layer CCL disposed on the display panel DP, and a color filter layer CFL. In an embodiment shown in FIG. 8, the display panel DP may include a base layer BS, a circuit layer DP-CL provided on the base layer BS, and the display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, and a second electrode EL2 disposed on the electron transport region ETR. In embodiments, a structure of the light emitting element ED shown in FIG. 8 may be same as a structure of a light emitting element according to one of FIG. 3 to FIG. 7 as described above.

The light emitting element ED according to an embodiment shown in FIG. 8 may include the polycyclic compound according to an embodiment. Accordingly, the light emitting element ED may exhibit high efficiency and long service life characteristics. For example, the light emitting element ED may exhibit high light efficiency and long service life characteristics in a blue light emitting region.

Referring to FIG. 8, the emission layer EML may be disposed in an opening OH defined in a pixel defining layer PDL. For example, the emission layer EML, which is separated by the pixel defining layer PDL and correspondingly provided to each of the light emitting regions PXA-R, PXA-G, and PXA-B, may emit light in a same wavelength range. In the display device DD-a, the emission layer EML may emit blue light. Although not shown in the drawings, in an embodiment, the emission layer EML may be provided as a common layer for all of the light emitting regions PXA-R, PXA-G, and PXA-B.

The light control layer CCL may be disposed on the display panel DP. Although the light control layer CCL is shown as being disposed above the display element layer DP-ED, embodiments are not limited thereto, and the light control layer CCL may be disposed below the display element layer DP-ED. The light control layer CCL may include a light conversion body. The light conversion body may be a quantum dot, a phosphor, or the like. The light conversion body may convert the wavelength of a provided light and emit the resulting light. For example, the light control layer CCL may be a layer that includes a quantum dot or a layer that includes a phosphor.

The light control layer CCL may include light control parts CCP1, CCP2, and CCP3. The light control parts CCP1, CCP2, and CCP3 may be spaced apart from each other.

Referring to FIG. 8, divided patterns BMP may be disposed between the light control parts CCP1, CCP2, and CCP3, which are spaced apart from each other, but embodiments are not limited thereto. In FIG. 8, it is shown that the divided patterns BMP do not overlap the light control parts CCP1, CCP2, and CCP3, but the edges of the light control parts CCP1, CCP2, and CCP3 may overlap at least a portion of the divided patterns BMP.

The light control layer CCL may include a first light control part CCP1 containing a first quantum dot QD1 that converts first color light provided from the light emitting element ED into second color light, a second light control part CCP2 containing a second quantum dot QD2 that converts the first color light into third color light, and a third light control part CCP3 that transmits the first color light.

In an embodiment, the first light control part CCP1 may provide red light, which is the second color light, and the second light control part CCP2 may provide green light, which is the third color light. The third light control part CCP3 may provide blue light by transmitting the blue light that is the first color light provided from the light emitting element ED. For example, the first quantum dot QD1 may be a red quantum dot, and the second quantum dot QD2 may be a green quantum dot. The quantum dots QD1 and QD2 may each be a quantum dot as described above.

The light control layer CCL may further include a scatterer SP. The first light control part CCP1 may include the first quantum dot QD1 and the scatterer SP, the second light control part CCP2 may include the second quantum dot QD2 and the scatterer SP, and the third light control part CCP3 may not include any quantum dot but may include the scatterer SP.

The scatterer SP may be inorganic particles. For example, the scatterer SP may include at least one of TiO₂, ZnO, Al₂O₃, SiO₂, and hollow silica. The scatterer SP may include one of TiO₂, ZnO, Al₂O₃, SiO₂, and hollow silica, or may be a mixture of at least two materials selected from TiO₂, ZnO, Al₂O₃, SiO₂, and hollow silica.

The first light control part CCP1, the second light control part CCP2, and the third light control part CCP3 may include base resins BR1, BR2, and BR3, in which the quantum dots QD1 and QD2 and the scatterer SP are dispersed. In an embodiment, the first light control part CCP1 may include the first quantum dot QD1 and the scatterer SP dispersed in a first base resin BR1, the second light control part CCP2 may include the second quantum dot QD2 and the scatterer SP dispersed in a second base resin BR2, and the third light control part CCP3 may include the scatterer SP dispersed in a third base resin BR3.

The base resins BR1, BR2, and BR3 are media in which the quantum dots QD1 and QD2 and the scatterer SP are dispersed, and may include various resin compositions, which may be referred to as a binder. For example, the base resins BR1, BR2, and BR3 may be acrylic-based resins, urethane-based resins, silicone-based resins, epoxy-based resins, etc. The base resins BR1, BR2, and BR3 may each be a transparent resin. In an embodiment, the first base resin BR1, the second base resin BR2, and the third base resin BR3 may be the same as or different from each other.

The light control layer CCL may include a barrier layer BFL1. The barrier layer BFL1 may prevent the penetration of moisture and/or oxygen (hereinafter, referred to as ‘moisture/oxygen’). The barrier layer BFL1 may block the light control parts CCP1, CCP2, and CCP3 from exposure to moisture/oxygen. The barrier layer BFL1 may cover the light control parts CCP1, CCP2, and CCP3. In an embodiment, the barrier layer BFL2 may be provided between the light control parts CCP1, CCP2, and CCP3, and the color filter layer CFL.

The barrier layers BFL1 and BFL2 may each independently include at least one inorganic layer. For example, the barrier layers BFL1 and BFL2 may each independently include an inorganic material. For example, the barrier layers BFL1 and BFL2 may each independently include a silicon nitride, an aluminum nitride, a zirconium nitride, a titanium nitride, a hafnium nitride, a tantalum nitride, a silicon oxide, an aluminum oxide, a titanium oxide, a tin oxide, a cerium oxide, a silicon oxynitride, a metal thin film that secures light transmittance, etc. The barrier layers BFL1 and BFL2 may each independently further include an organic material. The barrier layers BFL1 and BFL2 may be formed of a single layer or of multiple layers.

In the display device DD-a, the color filter layer CFL may be disposed on the light control layer CCL. In an embodiment, the color filter layer CFL may be directly disposed on the light control layer CCL. For example, the barrier layer BFL2 may be omitted.

The color filter layer CFL may include filters CF1, CF2, and CF3. The color filter layer CFL may include a first filter CF1 that transmits second color light, a second filter CF2 that transmits third color light, and a third filter CF3 that transmits first color light. For example, the first filter CF1 may be a red filter, the second filter CF2 may be a green filter, and the third filter CF3 may be a blue filter. The filters CF1, CF2, and CF3 may each include a polymeric photosensitive resin and a pigment or dye. The first filter CF1 may include a red pigment or dye, the second filter CF2 may include a green pigment or dye, and the third filter CF3 may include a blue pigment or dye.

However, embodiments are not limited thereto, and the third filter CF3 may not include a pigment or dye. The third filter CF3 may include a polymeric photosensitive resin and may not include a pigment or dye. The third filter CF3 may be transparent. The third filter CF3 may be formed of a transparent photosensitive resin.

In an embodiment, the first filter CF1 and the second filter CF2 may each be a yellow filter. The first filter CF1 and the second filter CF2 may not be provided as separate filters and may be provided as a unitary filter.

Although not shown in the drawings, in an embodiment, the color filter layer CFL may further include a light shielding part (not shown). The light shielding part (not shown) may be a black matrix. The light shielding part (not shown) may include an organic light shielding material or an inorganic light shielding material, each including a black pigment or a black dye. The light shielding part (not shown) may prevent light leakage, and may separate boundaries between adjacent filters CF1, CF2, and CF3. In an embodiment, the light shielding part (not shown) may be formed of a blue filter.

The first filter CF1, the second filter CF2, and the third filter CF3 may be disposed to respectively correspond to the red light emitting region PXA-R, the green light emitting region PXA-G, and the blue light emitting region PXA-B.

A base substrate BL may be disposed on the color filter layer CFL. The base substrate BL may provide a base surface on which the color filter layer CFL, the light control layer CCL, and the like are disposed. The base substrate BL may be a glass substrate, a metal substrate, a plastic substrate, etc. However, embodiments are not limited thereto, and the base substrate BL may include an inorganic layer, an organic layer, or a composite material layer. Although not shown in the drawings, in an embodiment, the base substrate BL may be omitted.

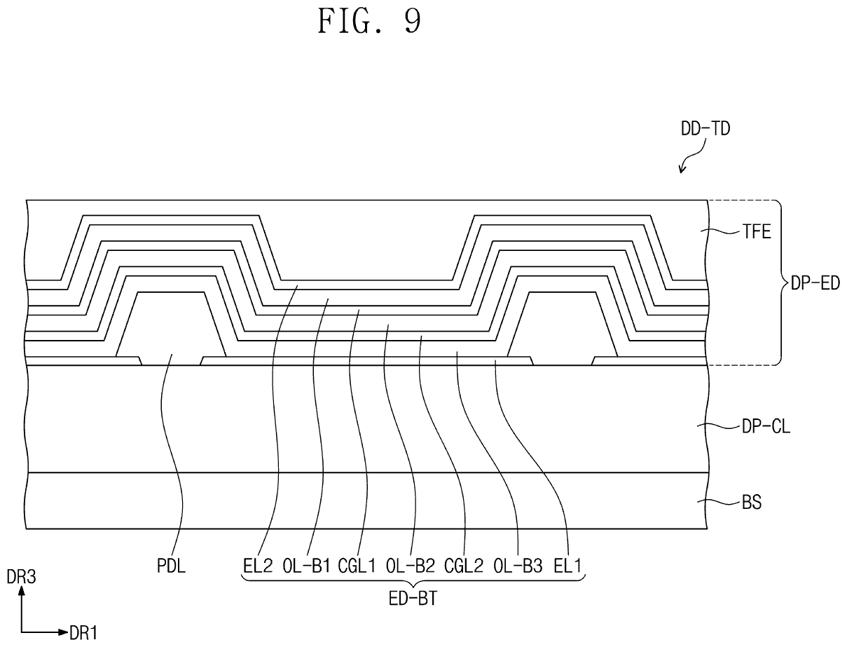

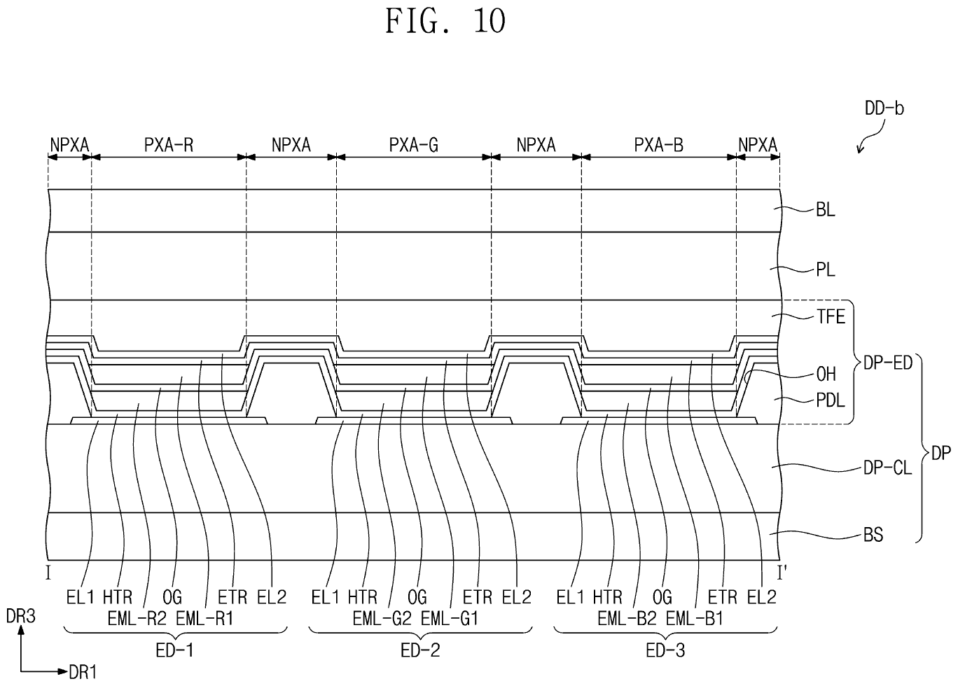

FIG. 9 is a schematic cross-sectional view of a portion of a display device according to an embodiment. In a display device DD-TD according to an embodiment, a light-emitting element ED-BT may include light-emitting structures OL-B1, OL-B2, and OL-B3. At least one of the light emitting structures OL-B1, OL-B2, and OL-B3 may include the polycyclic compound according to an embodiment. Accordingly, the light emitting element ED-BT may exhibit high efficiency and long service life characteristics. For example, the light emitting element ED-BT may exhibit high light efficiency and long service life characteristics in a blue light emitting region.

The light emitting element ED-BT may include a first electrode EL1 and a second electrode EL2 that face each other, and light emitting structures OL-B1, OL-B2, and OL-B3 stacked in a thickness direction between the first electrode EL1 and the second electrode EL2. The light emitting structures OL-B1, OL-B2, and OL-B3 may each include a hole transport region HTR, an emission layer EML (FIG. 8), and an electron transport region ETR, which may be disposed in that order between the first electrode EL1 and the second electrode EL2. For example, the light emitting element ED-BT included in the display device DD-TD may be a light emitting element having a tandem structure that includes multiple emission layers.

In an embodiment illustrated in FIG. 9, light emitted from the light emitting structures OL-B1, OL-B2, and OL-B3 may each be blue light. However, embodiments are not limited thereto, and the light emitted from each of the light emitting structures OL-B1, OL-B2, and OL-B3 may have wavelength ranges that are different from each other. For example, the light emitting element ED-BT that includes the light emitting structures OL-B1, OL-B2, and OL-B3, which emit light having wavelength ranges that are different from each other, may emit white light.

Charge generating layers CGL1 and CGL2 may each be disposed between two adjacent light emitting structures among the light-emitting structures OL-B1, OL-B2, and OL-B3. In an embodiment as shown in FIG. 9, a first charge generating layer CGL1 may be disposed between a first light-emitting structure OL-B1 and a second light-emitting structure OL-B2, and a second charge generating layer CGL2 may be disposed between the second light-emitting structure OL-B2 and a third light-emitting structure OL-B3. Charge generating layers CGL1 and CGL2 may each independently include a p-type charge generating layer and/or an n-type charge generating layer.

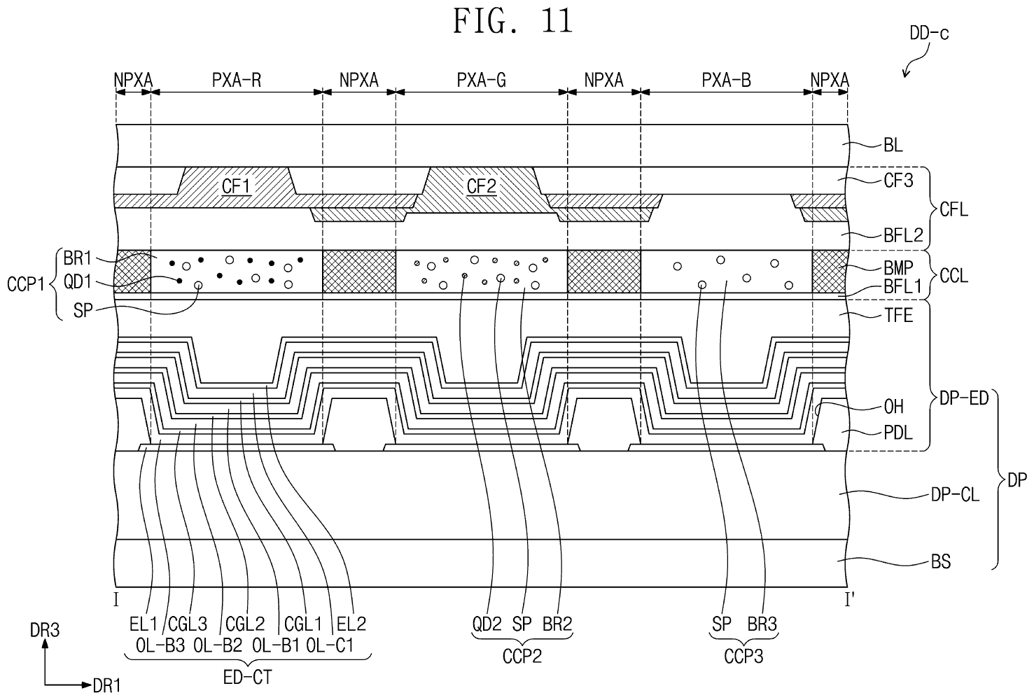

FIG. 10 is a schematic cross-sectional view of a display device DD-b according to an embodiment. FIG. 11 is a schematic cross-sectional view of a display device DD-c according to an embodiment.

Referring to FIG. 10, a display device DD-b according to an embodiment may include light emitting elements ED-1, ED-2, and ED-3 in which two emission layers are stacked. At least one of the light emitting elements ED-1, ED-2, and ED-3 may each independently include a polycyclic compound according to an embodiment, thereby exhibiting high efficiency and long service life characteristics. For example, the light emitting element ED-3 may include a polycyclic compound according to an embodiment, thereby exhibiting high light efficiency and long service life characteristics in a blue light emitting region.

In comparison to the display device DD shown in FIG. 2, the embodiment shown in FIG. 10 is different at least in that the first to third light emitting elements ED-1, ED-2, and ED-3 each include two emission layers that are stacked in a thickness direction. In each of the first to third light emitting elements ED-1, ED-2, and ED-3, the two emission layers may emit light in a same wavelength region.

The first light emitting element ED-1 may include a first red emission layer EML-R1 and a second red emission layer EML-R2. The second light emitting element ED-2 may include a first green emission layer EML-G1 and a second green emission layer EML-G2. The third light emitting element ED-3 may include a first blue emission layer EML-B1 and a second blue emission layer EML-B2. An emission auxiliary part OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The emission auxiliary part OG may have a single-layered structure or a multilayered structure. The emission auxiliary part OG may include a charge generation layer. For example, the emission auxiliary part OG may include an electron transport region, a charge generation layer, and a hole transport region, which may be stacked in that order. The emission auxiliary part OG may be provided as a common layer for the first to third light emitting elements ED-1, ED-2, and ED-3. However, embodiments are not limited thereto, and the emission auxiliary part OG may be provided by being patterned within the openings OH defined in the pixel defining layer PDL.

The first red emission layer EML-R1, the first green emission layer EML-G1, and the first blue emission layer EML-B1 may each be disposed between the electron transport region ETR and the emission auxiliary part OG. The second red emission layer EML-R2, the second green emission layer EML-G2, and the second blue emission layer EML-B2 may each be disposed between the emission auxiliary part OG and the hole transport region HTR.

For example, the first light emitting element ED-1 may include a first electrode EL1, a hole transport region HTR, a second red emission layer EML-R2, an emission auxiliary part OG, a first red emission layer EML-R1, an electron transport region ETR, and a second electrode EL2, which are stacked in that order. The second light emitting element ED-2 may include a first electrode EL1, a hole transport region HTR, a second green emission layer EML-G2, an emission auxiliary part OG, a first green emission layer EML-G1, an electron transport region ETR, and a second electrode EL2, which are stacked in that order. The third light emitting element ED-3 may include a first electrode EL1, a hole transport region HTR, a second blue emission layer EML-B2, an emission auxiliary part OG, a first blue emission layer EML-B1, an electron transport region ETR, and a second electrode EL2, which are stacked in that order.

An optical auxiliary layer PL may be disposed on the display element layer DP-ED. The optical auxiliary layer PL may include a polarizing layer. The optical auxiliary layer PL may be disposed on the display panel DP and may control light that is reflected at the display panel DP from an external light. Although not shown in the drawings, in an embodiment, the optical auxiliary layer PL may be omitted from the display device DD-b.

In contrast to FIGS. 9 and 10, FIG. 11 shows a display device DD-c that is different at least in that it includes four light emitting structures OL-B1, OL-B2, OL-B3, and OL-C1. A light emitting element ED-CT may include a first electrode EL1 and a second electrode EL2 that face each other, and first to fourth light emitting structures OL-B1, OL-B2, OL-B3, and OL-C1 that are stacked in a thickness direction between the first electrode EL1 and the second electrode EL2. At least one of the light emitting structures OL-B1, OL-B2, OL-B3, and OL-C1 may each independently include a polycyclic compound according to an embodiment, thereby exhibiting high efficiency and long service life characteristics. For example, the light emitting element ED-CT may include a polycyclic compound according to an embodiment, thereby exhibiting high light efficiency and long service life characteristics in a blue light emitting region.

Charge generation layers CGL1, CGL2, and CGL3 may each be disposed between two adjacent light emitting structures among the first to fourth light emitting structures OL-B1, OL-B2, OL-B3, and OL-C1. Charge generation layers CGL1, CGL2, and CGL3 may each independently include a p-type charge generation layer and/or an n-type charge generation layer.

Among the four light emitting structures, the first to third light emitting structures OL-B1, OL-B2, and OL-B3 may each emit blue light, and the fourth light emitting structure OL-C1 may emit green light. However, embodiments are not limited thereto, and the first to fourth light emitting structures OL-B1, OL-B2, OL-B3, and OL-C1 may emit light having wavelength regions that are different from each other.

In an embodiment, an electronic apparatus may include a display device that includes multiple light emitting elements, and a control part that controls the display device. The electronic apparatus may be a device that is activated by an electrical signal. The electronic apparatus may include display devices according to various embodiments. Examples of an electronic apparatus may include large, medium-sized, and small apparatuses, such as a television set, a monitor, a billboard, a personal computer, a laptop computer, a personal digital terminal, a display apparatus for a vehicle, a game console, a portable electronic device, or a camera.

The display device according to an embodiment may include a light emitting element that includes a polycyclic compound according to an embodiment in an emission layer, thereby exhibiting high efficiency and long service life characteristics. The display device according to an embodiment may have improved display efficiency and display service life, and may exhibit excellent display quality.

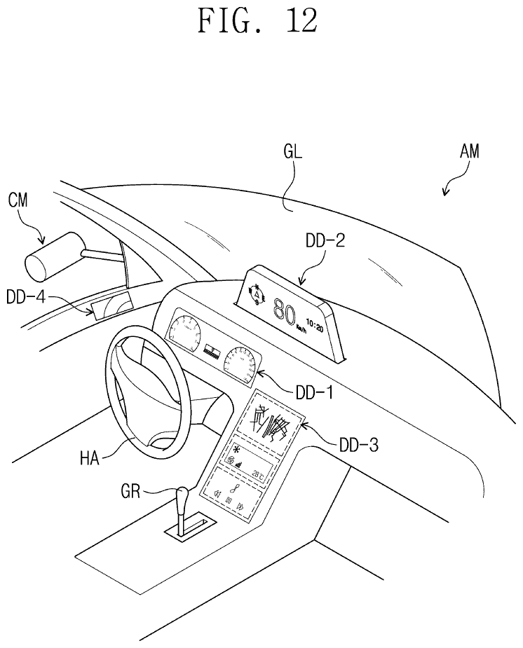

FIG. 12 is a schematic perspective view of a vehicle AM that includes first to fourth display devices DD-1, DD-2, DD-3, and DD-4. At least one of the first to fourth display devices DD-1, DD-2, DD-3, and DD-4 may have a structure according to one of display devices DD, DD-TD, DD-a, DD-b, and DD-c, as described with reference to FIGS. 1, 2, and 8 to 11.

FIG. 12 illustrates a vehicle AM, but this is only an example, and the first to fourth display devices DD-1, DD-2, DD-3, and DD-4 may be disposed in various transportation means such as a bicycle, a motorcycle, a train, a ship, or an airplane. In an embodiment, at least one of the first to fourth display devices DD-1, DD-2, DD-3, and DD-4 each having a structure according to one of display devices DD, DD-TD, DD-a, DD-b, and DD-c, may be included in a personal computer, a laptop computer, a personal digital terminal, a game console, a portable electronic device, a television, a monitor, a billboard, or the like. However, these are merely provided as examples, and the display device may be included in other electronic apparatuses.

At least one of the first to fourth display devices DD-1, DD-2, DD-3, and DD-4 may each independently include a light emitting element ED according to an embodiment as described with reference to any of FIGS. 3 to 7. At least one of the first to fourth display devices DD-1, DD-2, DD-3, and DD-4 may each independently include a polycyclic compound according to an embodiment. Accordingly, the first to fourth display devices DD-1, DD-2, DD-3, and DD-4 that include a polycyclic compound according to an embodiment may have improved display efficiency and display service life, and may exhibit excellent display quality.

Referring to FIG. 12, the vehicle AM may include a steering wheel HA and a gearshift GR for operating the vehicle AM. The vehicle AM may include a front window GL that is disposed so as to face the driver.

The first display device DD-1 may be disposed in a first region that overlaps the steering wheel HA. For example, the first display device DD-1 may be a digital cluster that displays first information of the vehicle AM. The first information may include a first scale that indicates a driving speed of the vehicle AM, a second scale that indicates an engine speed (for example, as revolutions per minute (RPM)), an image that represents a fuel gauge, etc. The first scale and the second scale may each be represented by a digital image.

The second display device DD-2 may be disposed in a second region facing the driver's seat that overlaps the front window GL. The driver's seat may be a seat where the steering wheel HA is disposed. For example, the second display device DD-2 may be a head up display (HUD) that shows second information of the vehicle AM. The second display device DD-2 may be optically transparent. The second information may include digital numbers that indicate a driving speed and may further include information such as the current time. Although not shown in the drawings, in an embodiment, the second information of the second display device DD-2 may be displayed by being projected onto the front window GL.

The third display device DD-3 may be disposed in a third region that is adjacent to the gearshift GR. For example, the third display device DD-3 may be disposed between the driver's seat and the passenger seat and may be a center information display (CID) for the vehicle AM that displays third information. The passenger seat may be a seat that is spaced apart from the driver's seat, and the gearshift GR may be disposed between the driver's seat and the passenger seat. The third information may include information about traffic (e.g., navigation information), about music or radio that is playing, about a video (or an image) that is displayed, about temperatures inside the vehicle AM, etc.

The fourth display device DD-4 may be disposed in a fourth region that is spaced apart from the steering wheel HA and the gearshift GR and adjacent to a side of the vehicle AM. For example, the fourth display device DD-4 may be a digital side-view mirror that displays fourth information. The fourth display device DD-4 may display an image that is external to the vehicle AM, which may be taken by a camera module CM that is disposed on the exterior of the vehicle AM. The fourth information may include an exterior image of the vehicle AM.

The first to fourth information as described above are only provided as examples, and the first to fourth display device DD-1, DD-2, DD-3, and DD-4 may further display information about the interior and exterior of the vehicle AM. The first to fourth information may include information that is different from each other. However, embodiments are not limited thereto, and a portion of the first to fourth information may include a same information.

Hereinafter, a polycyclic compound according to an embodiment and a light emitting element according to an embodiment will be described in detail with reference to the Examples and the Comparative Examples. The Examples described below are only provided to assist in understanding the disclosure and the scope thereof is not limited thereto.

### EXAMPLE

### 1. Synthesis of Polycyclic Compound of Example

A synthesis method for the polycyclic compound according to embodiments will be described in detail by illustrating synthesis methods for Compounds 47, 60, 61, and 76. In the following descriptions, the synthesis methods for the polycyclic compounds are provided as examples, and the synthesis method for the compound according to an embodiment is not limited to the Examples below.

### (1) Synthesis of Compound 47

Compound 47 according to an embodiment may be synthesized by, for example, the steps shown in Reaction Scheme 1-1 to 1-4 below.

### Synthesis of Intermediate M1

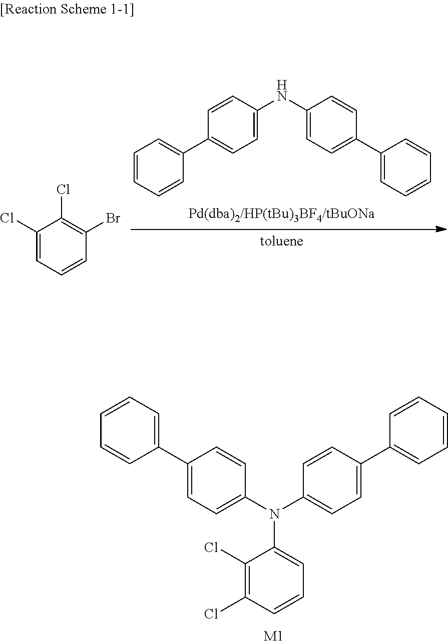

To a 500-mL two-necked flask, 1-bromo-2,3-dichlorobenzene (15 g), di([1,1′-biphenyl]-4-yl)amine (26 g), bis(dibenzylideneacetone)palladium (0) (1.8 g), HP(tBu)₃BF₄ (1.9 g), sodium t-butoxide (8.3 g), and toluene (330 mL) were added, and heated and stirred at about 120° C. for about 3 hours. The resulting reaction solution was filtered through Celite, concentrated, and purified by column chromatography (eluent: toluene/hexane=1:1) to obtain a white solid (26 g, yield: 83%). FAB-MS of the obtained product was determined as m/z=466, and thus the target product was identified as Intermediate M1.

### Synthesis of Intermediate M2

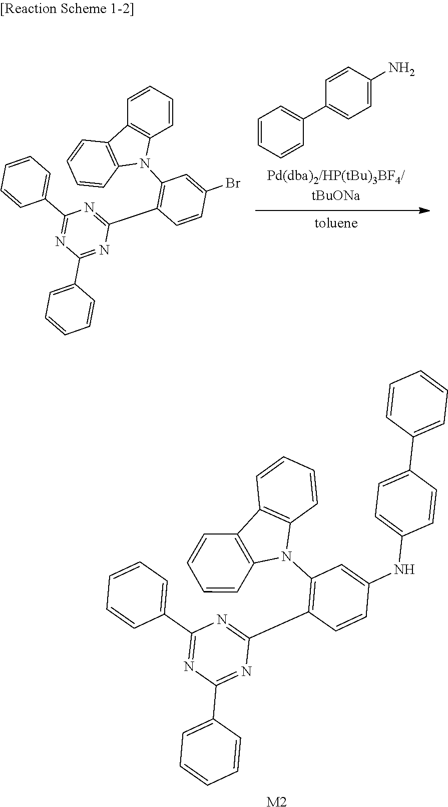 [SMILES: Brc1ccc(-c2nc(-c3ccccc3)nc(-c3ccccc3)n2)c(-n2c3ccccc3c3ccccc32)c1 ; Nc1ccc(-c2ccccc2)cc1 ; c1ccc(-c2ccc(Nc3ccc(-c4nc(-c5ccccc5)nc(-c5ccccc5)n4)c(-n4c5ccccc5c5ccccc54)c3)cc2)cc1 ; "M2"]

To a 300-mL two-necked flask, Intermediate 9-(5-bromo-2-(4,6-diphenyl-1,3,5-triazin-2-yl)phenyl)-9H-carbazole (10 g), [1,1′-biphenyl]-4-amine (3.7 g), bis(dibenzylideneacetone)palladium (0) (0.5 g), HP(tBu)₃BF₄ (0.5 g), sodium t-butoxide (8.3 g), and toluene (330 mL) were added, and heated and stirred at about 120° C. for about 3 hours. The resulting reaction solution was filtered through Celite, concentrated, and purified by column chromatography (eluent: dichloromethane) to obtain a pale yellow solid (7.2 g, yield: 62%). FAB-MS of the obtained product was determined as m/z=642, and thus the target product was identified as Intermediate M2.

### Synthesis of Intermediate M3

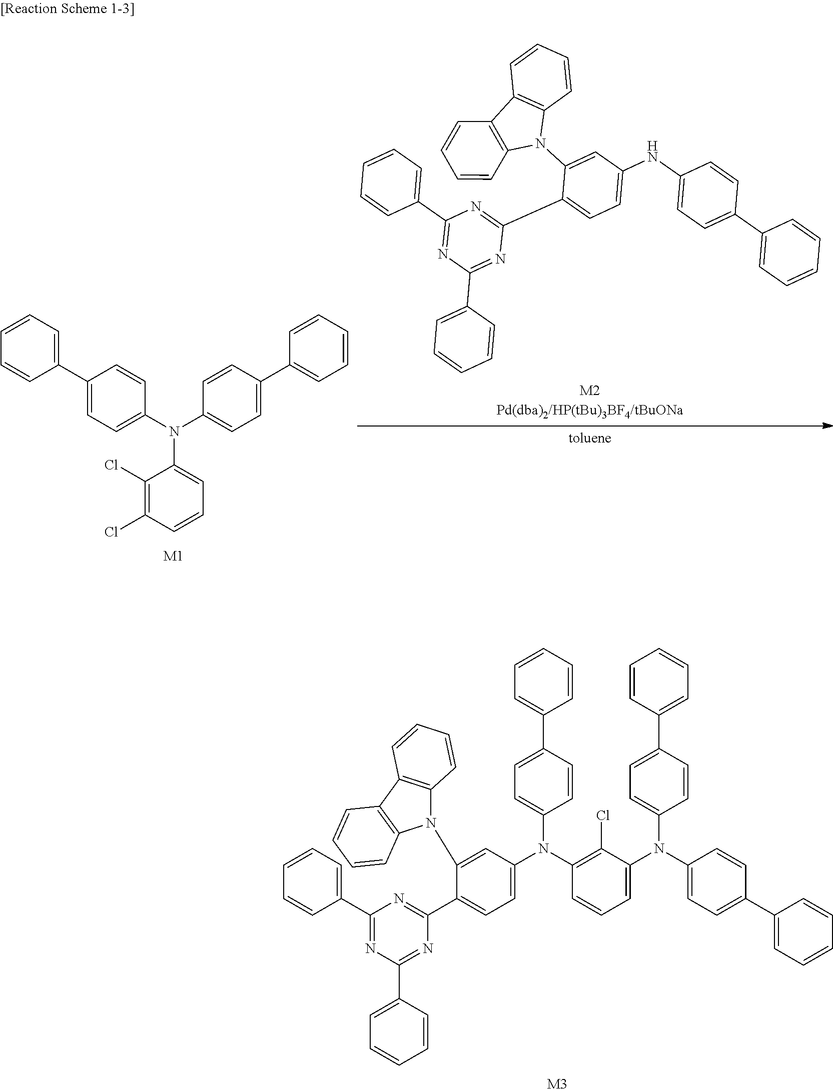

To a 500-mL two-necked flask, Intermediate M1 (5.0 g) intermediate M2 (6.9 g), bis(dibenzylideneacetone)palladium (0) (0.25 g), HP(tBu)₃BF₄ (0.25 g), sodium t-butoxide (1.3 g), and toluene (50 mL) were added, and heated and stirred at about 120° C. for about 3 hours. The resulting reaction solution was filtered through Celite, concentrated, and purified by column chromatography (eluent: dichloromethane) to obtain a pale yellow solid (5.2 g, yield: 45%). FAB-MS of the obtained product was determined as m/z=1071, and thus the target product was identified as Intermediate M3.

### Synthesis of Compound 47

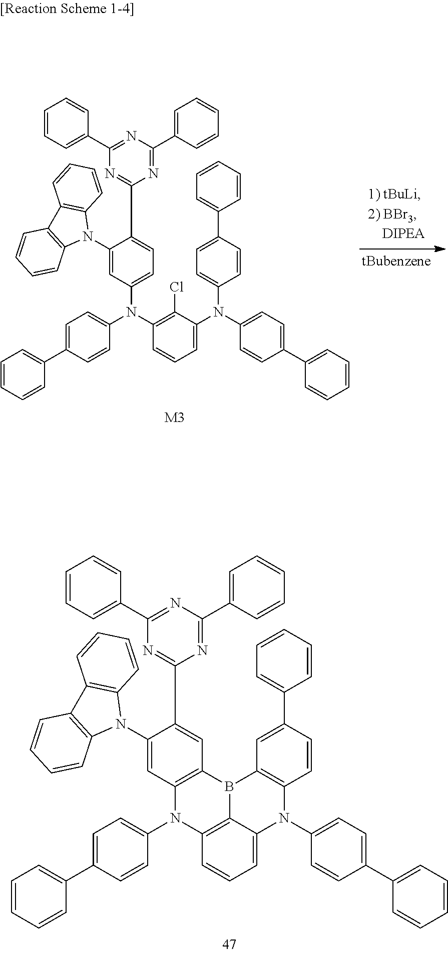 [SMILES: Clc1c(N(c2ccc(-c3ccccc3)cc2)c2ccc(-c3ccccc3)cc2)cccc1N(c1ccc(-c2ccccc2)cc1)c1ccc(-c2nc(-c3ccccc3)nc(-c3ccccc3)n2)c(-n2c3ccccc3c3ccccc32)c1 ; "M3" ; c1ccc(-c2ccc(N3c4ccc(-c5ccccc5)cc4B4c5cc(-c6nc(-c7ccccc7)nc(-c7ccccc7)n6)c(-n6c7ccccc7c7ccccc76)cc5N(c5ccc(-c6ccccc6)cc5)c5cccc3c54)cc2)cc1]

To a 200-mL three-necked flask in which Intermediate M3 (5.00 g) was added and dried, tBu-benzene (50 mL) was added in an argon (Ar) atmosphere, and cooled to about −78° C., and the resultant mixture was heated and stirred at about 60° C. for about 3 hours while slowly adding a tBuLi solution (1.60 M in pentane, 6 mL) thereto. The mixture was cooled to about-78° C., and BBr₃ (0.89 mL) was added thereto, followed by stirring at room temperature for about 30 minutes. While cooling the obtained reaction solution with ice, N,N-diisopropylethylamine (DIPEA, 2.4 mL) was added thereto, and the resultant mixture was heated and stirred at about 120° C. for about 3 hours. The reaction solution was cooled at room temperature, and MeOH was added thereto to precipitate a solid. The precipitated solid was cleansed by ultrasonic waves to recover the precipitate. The precipitated reaction product was purified by column chromatography (eluent: dichloromethane/hexane=1/1), and the molecular weight of the purified product was determined by FAB-MS. A yellow solid (0.78 g, yield: 16%) was obtained. The measurement of FAB-MS was m/z=1045, and thus the obtained solid was identified as Compound 47.

### (2) Synthesis of Compound 60

Compound 60 according to an embodiment may be synthesized by, for example, the steps shown in Reaction Scheme 2-1 to 2-4 below.

### Synthesis of Intermediate M4

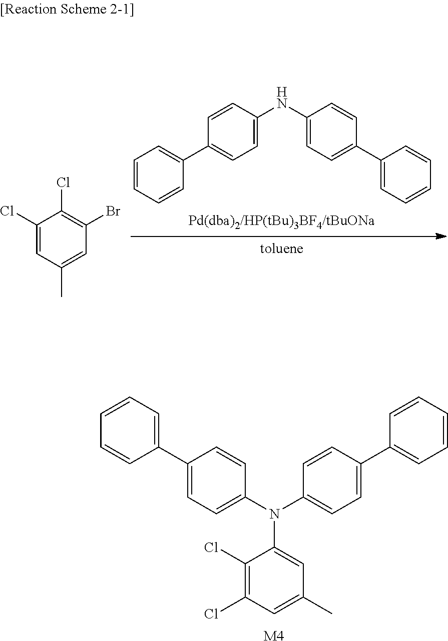

The reaction was performed in the same synthesis process as the synthesis process of Intermediate M1, except that 1-bromo-2,3-dichloro-5-methylbenzene was added instead of 1-bromo-2,3-dichlorobenzene in the synthesis of Intermediate M1. The reaction product was purified by column chromatography (eluent: toluene/hexane=1:1) to obtain a white solid (24 g, yield: 80%). FAB-MS of the obtained product was determined as m/z=480, and thus the target product was identified as Intermediate M4.

### Synthesis of Intermediate M5

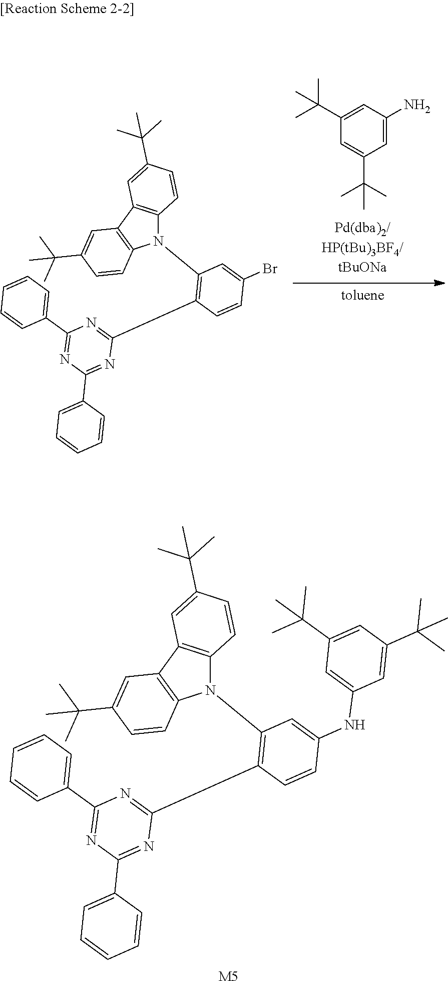 [SMILES: CC(C)(C)c1ccc2c(c1)c1cc(C(C)(C)C)ccc1n2-c1cc(Br)ccc1-c1nc(-c2ccccc2)nc(-c2ccccc2)n1 ; CC(C)(C)c1cc(N)cc(C(C)(C)C)c1 ; CC(C)(C)c1cc(Nc2ccc(-c3nc(-c4ccccc4)nc(-c4ccccc4)n3)c(-n3c4ccc(C(C)(C)C)cc4c4cc(C(C)(C)C)ccc43)c2)cc(C(C)(C)C)c1 ; "M5"]

The reaction was performed in the same synthesis process as the synthesis process of Intermediate M2, except that 9-(5-bromo-2-(4,6-diphenyl-1,3,5-triazin-2-yl)phenyl)-3,6-di-tert-butyl-9H-carbazole was added instead of 9-(5-bromo-2-(4,6-diphenyl-1,3,5-triazin-2-yl)phenyl)-9H-carbazole and 3,5-di-tert-butylanilinen was added instead of [1,1′-biphenyl]-4-amine in the synthesis of Intermediate M5. The reaction product was purified by column chromatography (eluent: dichloromethane) to obtain a pale yellow solid (7.4 g, yield: 62%). FAB-MS of the obtained product was determined as m/z=790, and thus the target product was identified as Intermediate M5.

### Synthesis of Intermediate M6

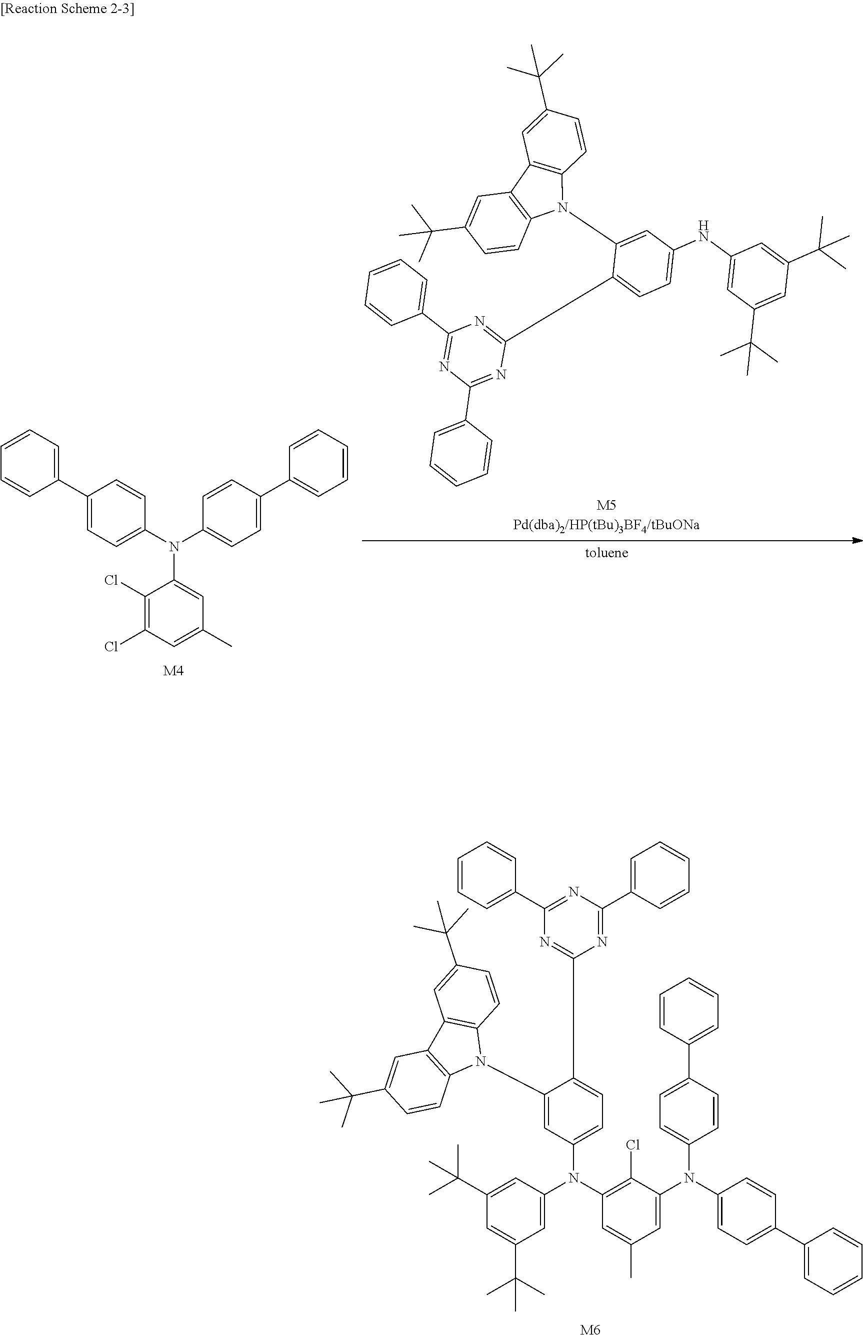

The reaction was performed in the same synthesis process as the synthesis process of Intermediate M3, except that Intermediate M4 was used instead of Intermediate M1, and Intermediate M5 was used instead of Intermediate M2 in the synthesis of Intermediate M6. The reaction product was purified by column chromatography (eluent: dichloromethane) to obtain a pale yellow solid (4.8 g, yield: 53%). FAB-MS of the obtained product was determined as m/z=1234, and thus the target product was identified as Intermediate M6.

### Synthesis of Compound 60

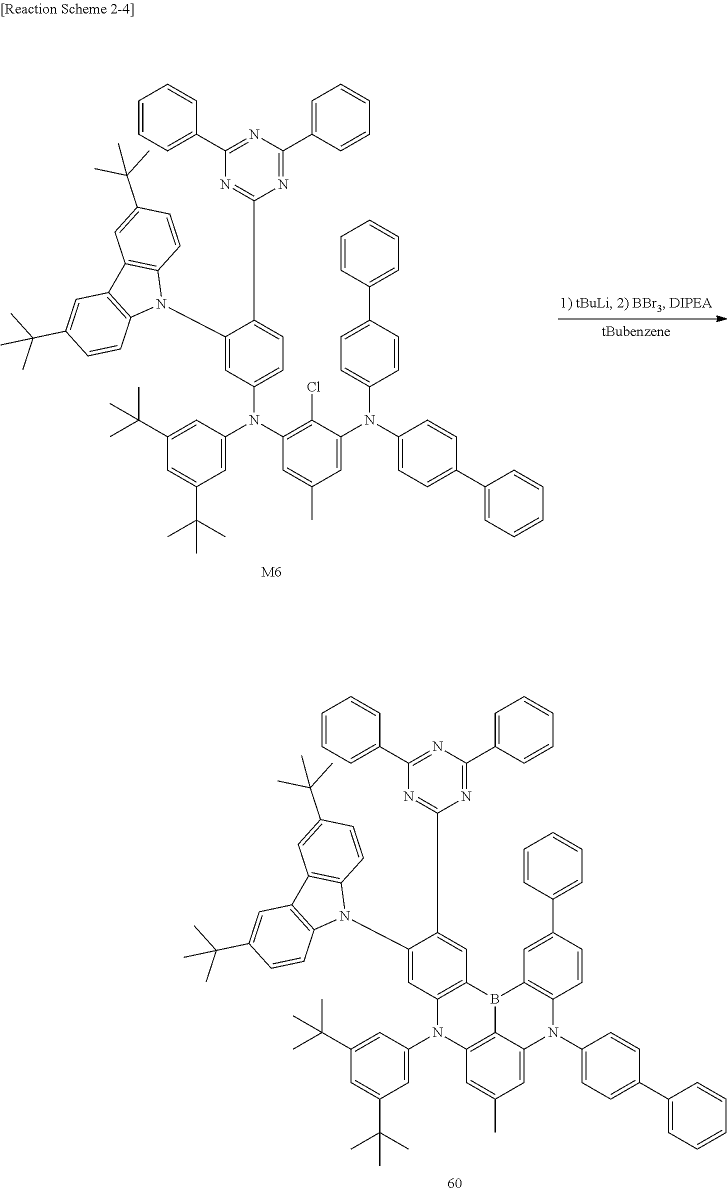 [SMILES: Cc1cc(N(c2ccc(-c3ccccc3)cc2)c2ccc(-c3ccccc3)cc2)c(Cl)c(N(c2cc(C(C)(C)C)cc(C(C)(C)C)c2)c2ccc(-c3nc(-c4ccccc4)nc(-c4ccccc4)n3)c(-n3c4ccc(C(C)(C)C)cc4c4cc(C(C)(C)C)ccc43)c2)c1 ; "M6" ; Cc1cc2c3c(c1)N(c1cc(C(C)(C)C)cc(C(C)(C)C)c1)c1cc(-n4c5ccc(C(C)(C)C)cc5c5cc(C(C)(C)C)ccc54)c(-c4nc(-c5ccccc5)nc(-c5ccccc5)n4)cc1B3c1cc(-c3ccccc3)ccc1N2c1ccc(-c2ccccc2)cc1 ; "60"]

The reaction was performed in the same synthesis process as the synthesis process of Compound 47, except that Intermediate M6 was added instead of Intermediate M3 in the synthesis of Compound 60. The reaction product was purified by column chromatography (eluent: dichloromethane/Hexane=1/1) to obtain a yellow solid (1.0 g, yield: 23%). FAB-MS of the obtained product was determined as m/z=1207, and thus the target product was identified as Compound 60.

### (3) Synthesis of Compound 61

Compound 61 according to an embodiment may be synthesized by, for example, the steps shown in Reaction Scheme 3-1 to 3-4 below.

### Synthesis of Intermediate M7

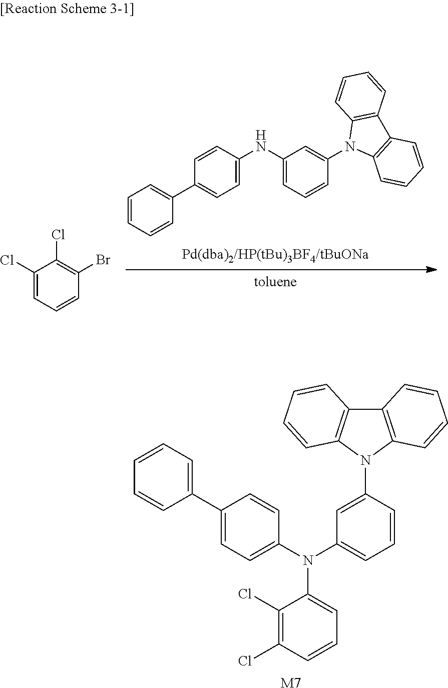

The reaction was performed in the same manner as in the synthesis of Intermediate M1, except that N-(3-(9H-carbazol-9-yl)phenyl)-[1,1′-biphenyl]-4-amine was added instead of di([1,1′-biphenyl]-4-yl)amine in the synthesis of Intermediate M1. The reaction product was purified by column chromatography (eluent: toluene/hexane=1:1) to obtain a white solid (32 g, yield: 87%). FAB-MS of the obtained product was determined as m/z=556, and thus the target product was identified as Intermediate M7.

### Synthesis of Intermediate M8

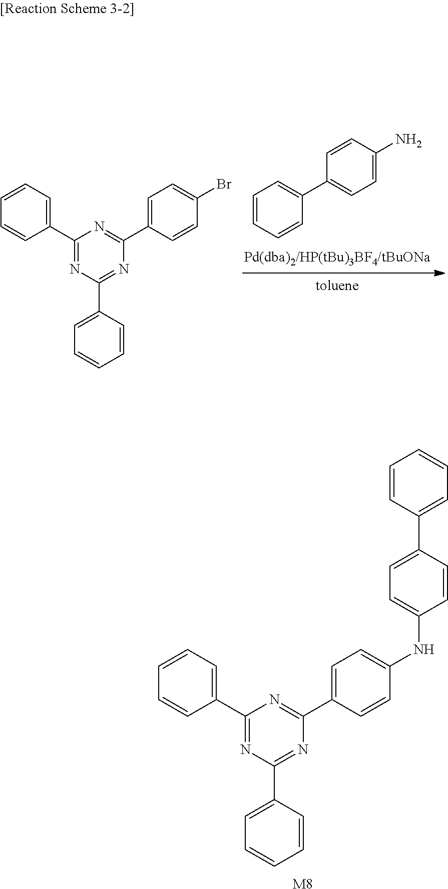

The reaction was performed in the same synthesis process as the synthesis process of Intermediate M2, except that 2-(4-bromophenyl)-4,6-diphenyl-1,3,5-triazine was added instead of 9-(5-bromo-2-(4,6-diphenyl-1,3,5-triazin-2-yl)phenyl)-9H-carbazole in the synthesis of Intermediate M8. The reaction product was purified by column chromatography (eluent: dichloromethane) to obtain a pale yellow solid (6.6 g, yield: 54%). FAB-MS of the obtained product was determined as m/z=477, and thus the target product was identified as Intermediate M8.

### Synthesis of Intermediate M9

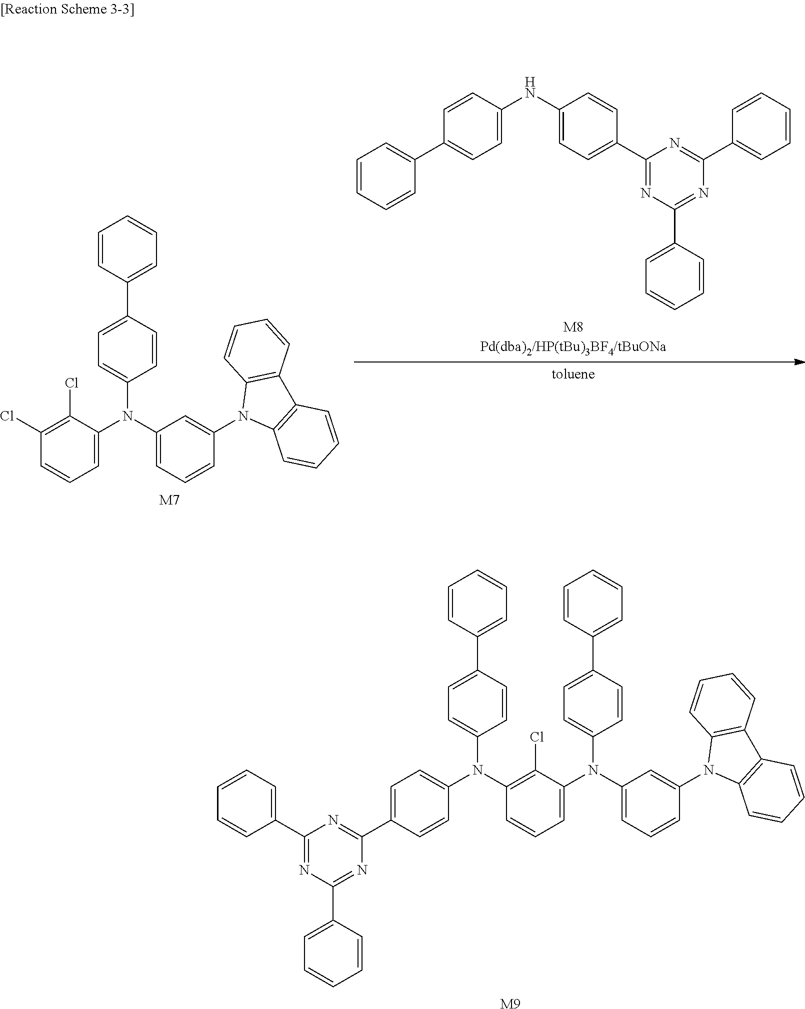

The reaction was performed in the same synthesis process as the synthesis process of Intermediate M3, except that Intermediate M7 was used instead of Intermediate M1, and Intermediate M8 was used instead of Intermediate M2 in the synthesis of Intermediate M9. The reaction product was purified by column chromatography (eluent: dichloromethane) to obtain a pale yellow solid (3.5 g, yield: 56%). FAB-MS of the obtained product was determined as m/z=996, and thus the target product was identified as Intermediate M9.

### Synthesis of Compound 61

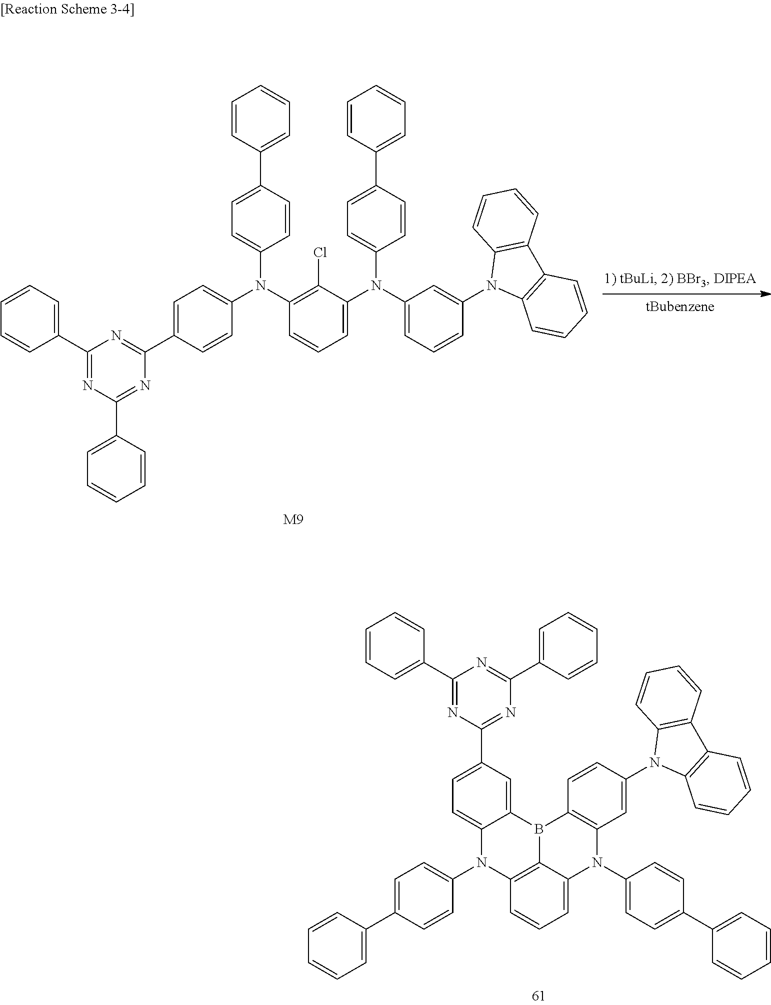 [SMILES: Clc1c(N(c2ccc(-c3ccccc3)cc2)c2ccc(-c3nc(-c4ccccc4)nc(-c4ccccc4)n3)cc2)cccc1N(c1ccc(-c2ccccc2)cc1)c1cccc(-n2c3ccccc3c3ccccc32)c1 ; "M9" ; c1ccc(-c2ccc(N3c4ccc(-c5nc(-c6ccccc6)nc(-c6ccccc6)n5)cc4B4c5ccc(-n6c7ccccc7c7ccccc76)cc5N(c5ccc(-c6ccccc6)cc5)c5cccc3c54)cc2)cc1]

The reaction was performed in the same synthesis process as the synthesis process of Compound 47, except that Intermediate M9 was used instead of Intermediate M3 in the synthesis of Compound 61. The reaction product was purified by column chromatography (eluent: dichloromethane/Hexane=1/1) to obtain a yellow solid (0.3 g, yield: 10%). FAB-MS of the obtained product was determined as m/z=969, and thus the target product was identified as Compound 61.

### (4) Synthesis of Compound 76

Compound 76 according to an embodiment may be synthesized by, for example, the steps shown in Reaction Scheme 4-1 to 4-3 below.

### Synthesis of Intermediate M10

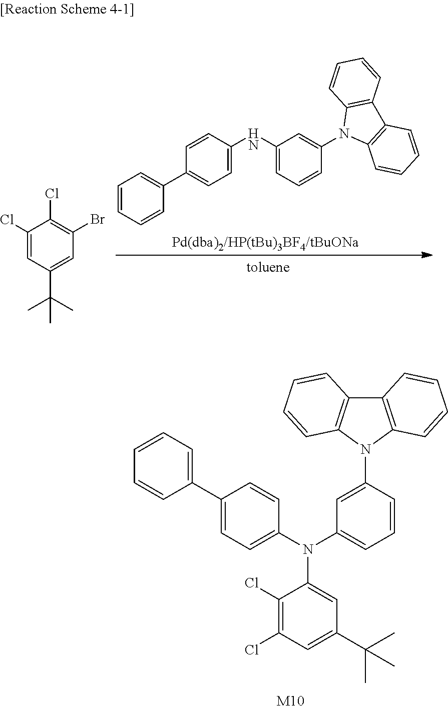

The reaction was performed in the same manner as in the synthesis of Intermediate M10, except that 1-bromo-5-(tert-butyl)-2,3-dichlorobenzene was used instead of 1-bromo-2,3-dichlorobenzene, and N-(3-(9H-carbazol-9-yl)phenyl)-[1,1′-biphenyl]-4-amine was used instead of di([1,1′-biphenyl]-4-yl)amine in the synthesis of Intermediate M1. The reaction product was purified by column chromatography (eluent: toluene/hexane=1:1) to obtain a white solid (30 g, yield: 92%). FAB-MS of the obtained product was determined as m/z=612, and thus the target product was identified as Intermediate M10.

### Synthesis of Intermediate M11

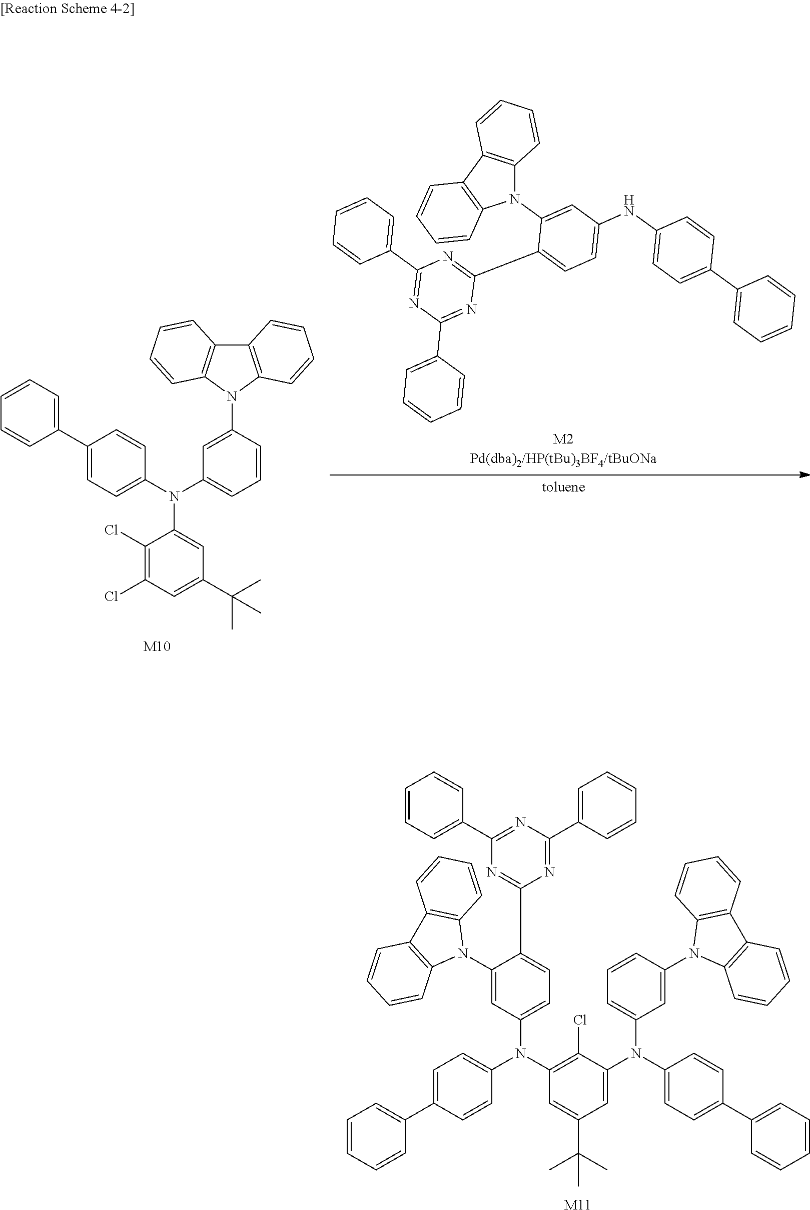

The reaction was performed in the same synthesis process as the synthesis process of Intermediate M3, except that Intermediate M10 was used instead of Intermediate M1 in the synthesis of Intermediate M11. The reaction product was purified by column chromatography (eluent: dichloromethane) to obtain a pale yellow solid (6.4 g, yield: 64%). FAB-MS of the obtained product was determined as m/z=1217, and thus the target product was identified as Intermediate M11.

### Synthesis of Compound 76

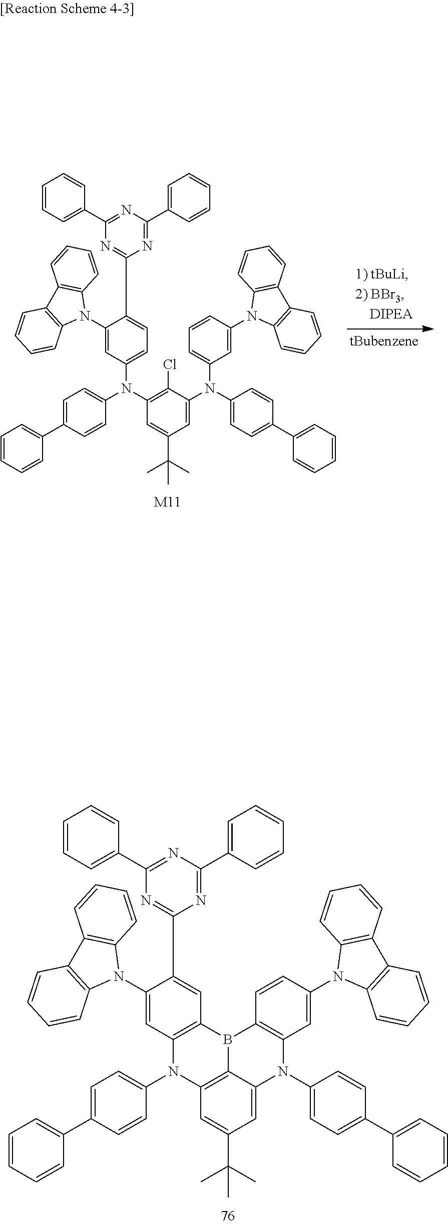

The reaction was performed in the same synthesis process as the synthesis process of Compound 47, except that Intermediate M11 was used instead of Intermediate M3 in the synthesis of Compound 76. The reaction product was purified by column chromatography (eluent: dichloromethane/Hexane=1/1) to obtain a yellow solid (0.9 g, yield: 18%). FAB-MS of the obtained product was determined as m/z=1190, and thus the target product was identified as Compound 76.

### 2. Evaluation of Polycyclic Compounds

The polycyclic compounds used in the Examples and the Comparative Examples are listed in Table 1:

TABLE 1

| Division | Compound |
|---|---|
| Example 1 | 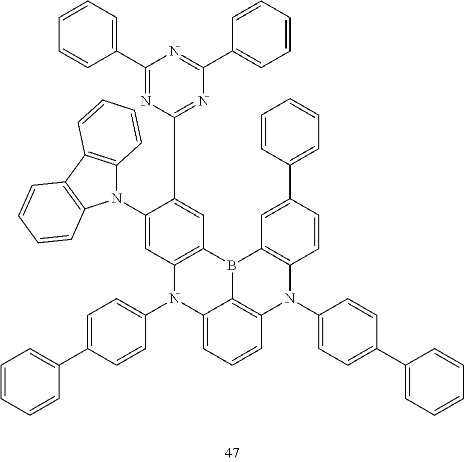 [SMILES: c1ccc(-c2ccc(N3c4ccc(-c5ccccc5)cc4B4c5cc(-c6nc(-c7ccccc7)nc(-c7ccccc7)n6)c(-n6c7ccccc7c7ccccc76)cc5N(c5ccc(-c6ccccc6)cc5)c5cccc3c54)cc2)cc1] |
| Example 2 | 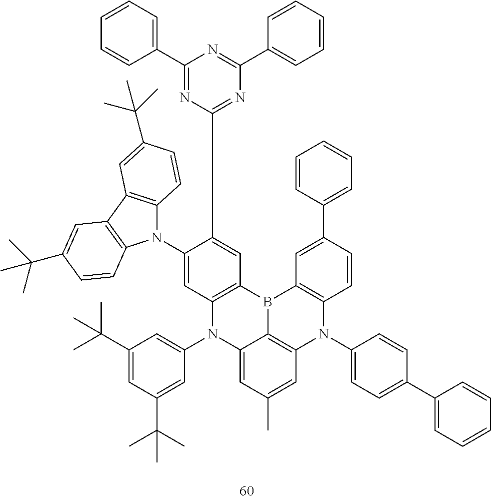 [SMILES: Cc1cc2c3c(c1)N(c1cc(C(C)(C)C)cc(C(C)(C)C)c1)c1cc(-n4c5ccc(C(C)(C)C)cc5c5cc(C(C)(C)C)ccc54)c(-c4nc(-c5ccccc5)nc(-c5ccccc5)n4)cc1B3c1cc(-c3ccccc3)ccc1N2c1ccc(-c2ccccc2)cc1] |
| Example 3 | 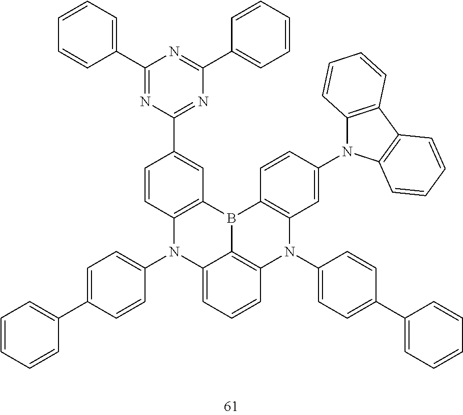 [SMILES: c1ccc(-c2ccc(N3c4ccc(-c5nc(-c6ccccc6)nc(-c6ccccc6)n5)cc4B4c5ccc(-n6c7ccccc7c7ccccc76)cc5N(c5ccc(-c6ccccc6)cc5)c5cccc3c54)cc2)cc1] |
| Example 4 | 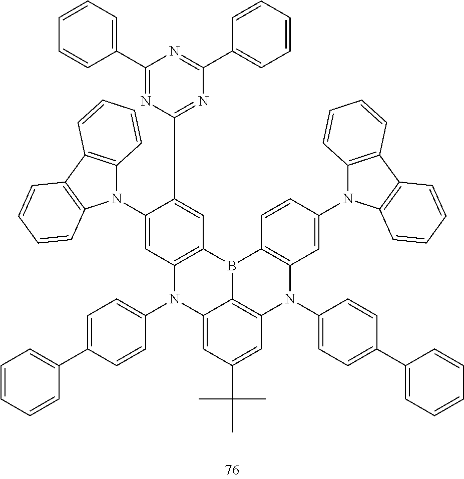 [SMILES: CC(C)(C)c1cc2c3c(c1)N(c1ccc(-c4ccccc4)cc1)c1cc(-n4c5ccccc5c5ccccc54)c(-c4nc(-c5ccccc5)nc(-c5ccccc5)n4)cc1B3c1ccc(-n3c4ccccc4c4ccccc43)cc1N2c1ccc(-c2ccccc2)cc1] |
| Comparative Example 1 | 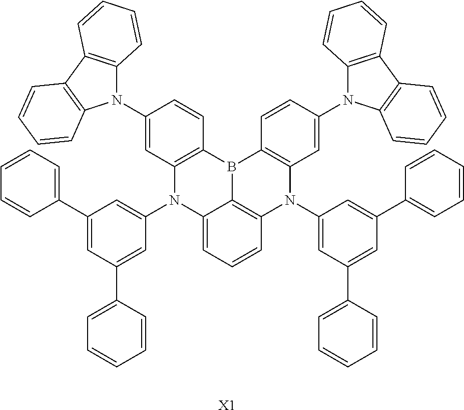 [SMILES: c1ccc(-c2cc(-c3ccccc3)cc(N3c4cc(-n5c6ccccc6c6ccccc65)ccc4B4c5ccc(-n6c7ccccc7c7ccccc76)cc5N(c5cc(-c6ccccc6)cc(-c6ccccc6)c5)c5cccc3c54)c2)cc1 ; "X1"] |
| Comparative Example 2 | 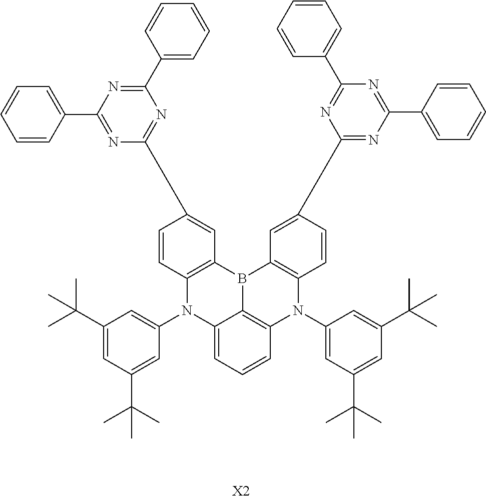 [SMILES: CC(C)(C)c1cc(N2c3ccc(-c4nc(-c5ccccc5)nc(-c5ccccc5)n4)cc3B3c4cc(-c5nc(-c6ccccc6)nc(-c6ccccc6)n5)ccc4N(c4cc(C(C)(C)C)cc(C(C)(C)C)c4)c4cccc2c43)cc(C(C)(C)C)c1 ; "X2"] |
| Comparative Example 3 | 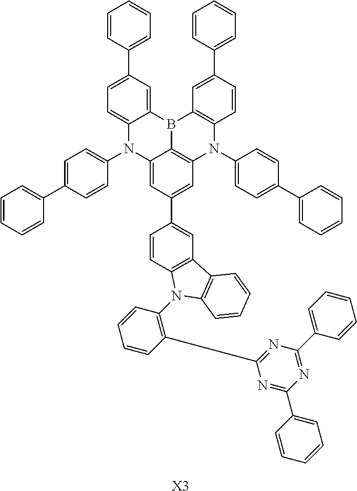 [SMILES: c1ccc(-c2ccc(N3c4ccc(-c5ccccc5)cc4B4c5cc(-c6ccccc6)ccc5N(c5ccc(-c6ccccc6)cc5)c5cc(-c6ccc7c(c6)c6ccccc6n7-c6ccccc6-c6nc(-c7ccccc7)nc(-c7ccccc7)n6)cc3c54)cc2)cc1 ; "X3"] |
| Comparative Example 4 | 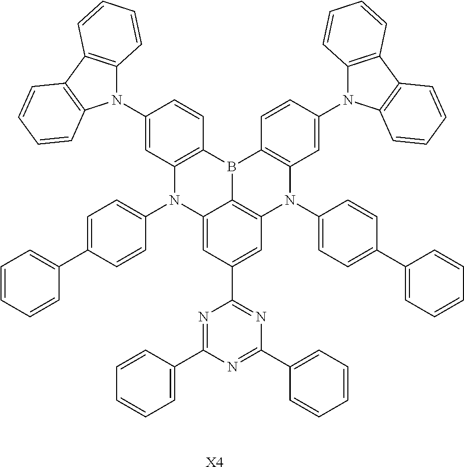 [SMILES: c1ccc(-c2ccc(N3c4cc(-n5c6ccccc6c6ccccc65)ccc4B4c5ccc(-n6c7ccccc7c7ccccc76)cc5N(c5ccc(-c6ccccc6)cc5)c5cc(-c6nc(-c7ccccc7)nc(-c7ccccc7)n6)cc3c54)cc2)cc1 ; "X4"] |

The results of characterization of the luminescence of the polycyclic compounds used in the Examples and the Comparative Examples are listed in Table 2. The maximum emission wavelength (PL/max), fluorescence quantum yield (PLQY), and delayed fluorescence decay time (Tau) of each compound were evaluated and the results are shown in Table 2. The maximum emission wavelengths of the compounds of the Examples and the Comparative Examples were measured under an inert gas atmosphere using the Fluorescence Spectrophotometer F-7000 from Hitachi High-Tech Corporation. The fluorescence quantum yield was measured using Quantaurus QY from Hamamatsu Photonics. The delayed fluorescence decay time was measured using Quantaurus Tau from Hamamatsu Photonics. The characterization of the luminescence of the compounds shown in Table 2 was performed in a toluene solution state of the compounds of the Examples and the Comparative Examples.

TABLE 2

| Division | Compound | PLλₘₐₓ (nm) | PLQY (%) | Tau/μsec |
|---|---|---|---|---|
| Example 1 | 47 | 462 | 93 | 18 |
| Example 2 | 60 | 461 | 94 | 14 |
| Example 3 | 61 | 463 | 96 | 15 |
| Example 4 | 76 | 461 | 92 | 14 |
| Comparative | X1 | 459 | 89 | 132 |
| Example 1 | | | | |
| Comparative | X2 | 462 | 91 | 23 |
| Example 2 | | | | |
| Comparative | X3 | 474 | 65 | 53 |
| Example 3 | | | | |
| Comparative | X4 | 509 | 83 | 46 |
| Example 4 | | | | |

Referring to Table 2, it may be confirmed that the polycyclic compounds of the Examples emit blue light having a maximum emission wavelength equal to or less than about 470 nm. The compounds of the Examples exhibited high fluorescence quantum yield characteristics and short delayed fluorescence decay time characteristics, as compared to the compounds of the Comparative Examples. In consideration of the results of the characterization of the luminescence of the compounds, it may be seen that the compounds of the Examples, which include the boron-containing fused ring core, at least one triazine group directly bonded to the fused ring core, and at least one carbazole group directly bonded to the fused ring core, exhibit high luminous efficiency and short delayed fluorescence decay time characteristics, as compared to the compounds of the Comparative Examples, which do not have such a structure.

### 3. Manufacture and Evaluation of Light Emitting Elements

### (1) Manufacture of Light Emitting Elements

Light emitting elements including a polycyclic compound of an Example or including a Comparative Example Compound in the emission layer were manufactured as follows. The polycyclic compounds of the Examples were used as a dopant material for an emission layer to manufacture the light emitting elements of Examples 1 to 4. Comparative Example Compounds X1 to X4 were respectively used as a dopant material for the emission layer to manufacture the light emitting elements of Comparative Examples 1 to Comparative Example 4.

A glass substrate on which ITO had been patterned as a first electrode was ultrasonically washed by using isopropyl alcohol and pure water for about 5 minutes each. After ultrasonic washing, the glass substrate was irradiated with UV rays for about 30 minutes and treated with ozone. HAT-CN was deposited at a thickness of about 10 nm, TrisPCz was deposited at a thickness of about 30 nm, and mCBP was deposited at a thickness of about 5 nm in this order to form a hole transport region.

An Example Compound or a Comparative Example Compound and mCBP were co-deposited to form a 30 nm-thick emission layer. The Example Compound or Comparative Example Compound and mCBP were co-deposited at a weight ratio of about 3:97. In the manufacture of the light emitting element, the Example Compound or the Comparative Example Compound was used as a dopant material.

SF3-TRZ was deposited at a thickness of about 10 nm, SF3-TRZ:Liq were deposited at a weight ratio of about 50:50 at a thickness of about 20 nm, and Liq was deposited at a thickness of about 2 nm in this order to form an electron transport region.

Al was deposited to form a 100 nm-thick second electrode.

In the Examples and the Comparative Examples, the hole transport region, the emission layer, the electron transport region, and the second electrode were each formed using a vacuum deposition apparatus.

The compounds used to manufacture the light emitting element are as follows.

### (Materials Used to Manufacture Light Emitting Element)

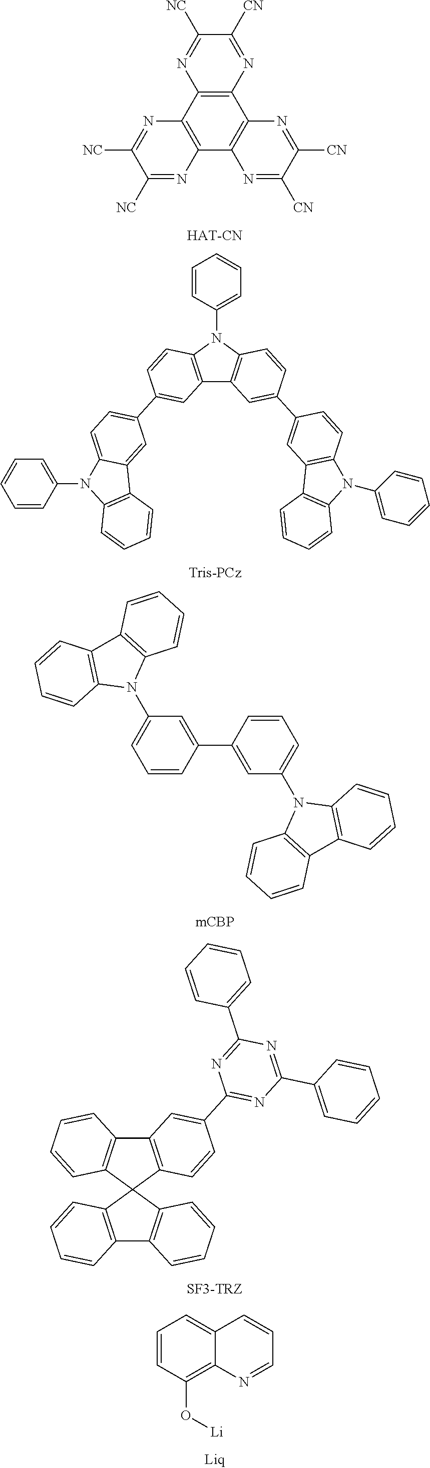

### (2) Evaluation of Light Emitting Elements

The light emitting elements of the Examples and the Comparative Examples were evaluated and the results are shown in Table 3. Table 3 shows the maximum emission wavelength (λmax), maximum external quantum efficiency (EQEmax), and relative element service life for the light emitting elements of Examples and Comparative Examples. For the relative element service life, a time taken to deteriorate the brightness to 50% of an initial brightness during the continuous driving of the element at 0.75 mA is relatively indicated based on 100% of the value of Comparative Example 1.

TABLE 3

| Element | | | | |
|---|---|---|---|---|
| Manufacture | Dopant | λmax | EQEmax | Relative element |
| Examples | compound | (nm) | (%) | service life (%) |
| Example 1 | 47 | 462 | 22 | 142 |
| Example 2 | 60 | 461 | 19 | 156 |
| Example 3 | 61 | 463 | 20 | 153 |
| Example 4 | 76 | 461 | 21 | 148 |
| Comparative | X1 | 460 | 16 | 100 |
| Example 1 | | | | |
| Comparative | X2 | 463 | 14 | 82 |
| Example 2 | | | | |
| Comparative | X3 | 478 | 17 | 138 |
| Example 3 | | | | |
| Comparative | X4 | 512 | 18 | 133 |
| Example 4 | | | | |

Referring to the results of Table 3, it may be confirmed that the light emitting element of the Examples emit blue light having a maximum emission wavelength equal to or less than about 470 nm. In terms of the maximum external quantum efficiency (EQEmax) characteristics and the relative element service life characteristics, the Examples showed superior results to the Comparative Examples.

Thus, the polycyclic compounds of the Examples that were used in the light emitting elements according to embodiments have a specific substituent configuration and a bonding structure of a pentacyclic boron-containing fused ring core-triazine group-carbazole group that is different from those of the Comparative Examples, and thus may have characteristics such as excellent maximum external quantum efficiency and material stability, as compared to the compounds of the Comparative Examples. It may be said that the elements including the polycyclic compounds of the Examples also exhibit excellent efficiency and service life characteristics.

Comparative Example Compound X1 used in Comparative Example 1 does not include a triazine group, which is the first substituent, as compared to a polycyclic compound according to an embodiment. In the evaluation of the physical properties of the polycyclic compounds in Table 2 as described above, Comparative Example Compound X1 of Comparative Example 1 exhibited the longest delayed fluorescence decay time, and accordingly, Comparative Example 1 exhibited low external quantum efficiency and short element service life characteristics as compared to the Examples.

Comparative Example Compound X2 used in Comparative Example 2 does not include a carbazole group, which is the second substituent, as compared to the polycyclic compound according to an embodiment. In the evaluation of the physical properties of the polycyclic compounds in Table 2 as described above, Comparative Example Compound X2 of Comparative Example 2 exhibited a delayed fluorescence decay time that is shorter than other Comparative Examples, but exhibited a delayed fluorescence decay time longer than the Examples. Thus, it may be seen that in the Example Compounds, which include a carbazole group in addition to a triazine group, RISC may be more readily generated as compared to Comparative Example Compound X2. Referring to the results of Table 3, Comparative Example 2 exhibited element service life characteristics that were significantly lower than the Examples. This is believed that in the case of Comparative Example Compound X2, which does not include a carbazole group as a substituent, a deterioration reaction is likely to occur when the element is driven, and thus service life characteristics are deteriorated.

Comparative Example Compound X3 used in Comparative Example 3 has a difference in the bonding positions of the first and second substituents, as compared to the polycyclic compound according to an embodiment. Comparative Example Compound X3 differs from the structure of the polycyclic compound of an Example in which the triazine group, which is an electron withdrawing group, and the carbazole group, which is an electron donating group, are each bonded to the boron-containing fused ring core at the light emitting center. However, the triazine group is not directly bonded to the fused ring core, and is instead bonded to the fused ring core via the carbazole group as a linking moiety. Furthermore, neither the triazine group and the carbazole group are bonded, directly or indirectly, to Ar1 or Ar2 in Formula A as described above. According to the difference in the positions of the substituents, in the case of Comparative Example Compound X3, effective RISC at the light emitting center does not occur, and the delayed fluorescence decay time increases. In the case of Comparative Example Compound X3, the emission wavelength is red-shifted due to the expansion of conjugation structure by the triazine group and the carbazole group, and the steric protection around the boron-containing fused ring core becomes insufficient. Accordingly, Comparative Example 3 including Comparative Example Compound X3 showed inferior results in both external quantum efficiency and relative service life, as compared to Examples.

Comparative Example Compound X4 used in Comparative Example 4 differs in the substitution position of the triazine group, which is the first substituent, as compared to the polycyclic compound according to an embodiment. In the case of Comparative Example Compound X4, the triazine group is substituted at a position that is sterically distant from the carbazole group, and thus the emission wavelength is red-shifted. Comparative Example 4 emits light having a maximum center wavelength of about 512 nm, which corresponds to a green wavelength region. Thus, Comparative Example 4 differs in emission wavelength, as compared to the Examples, which each emit light in a blue wavelength region, and Comparative Example 4 also showed a deteriorated characteristic in the relative element service life, as compared to the Examples.

The polycyclic compound according to an embodiment includes a pentacyclic boron-containing fused ring core, at least one electron withdrawing group directly bonded to the fused ring core, and at least one electron donating group directly bonded to the fused ring core, and has a structure in which the electron withdrawing group and the electron donating group are each bonded at a position that are sterically adjacent to each other. The polycyclic compound according to an embodiment may exhibit excellent luminous efficiency and excellent material stability characteristics. The polycyclic compound according to an embodiment may be used as a thermally activated delayed fluorescence material. The light emitting element according to an embodiment including the polycyclic compound according to an embodiment in the emission layer may exhibit excellent luminous efficiency characteristics in the blue light emission region and may exhibit long service life characteristics.

The light emitting element according to an embodiment may include the polycyclic compound according to an embodiment, thereby exhibiting high efficiency and long service life characteristics.

The polycyclic compound according to an embodiment may contribute to the improvement in light efficiency and a long service life of the light emitting element.

The display device of an embodiment may exhibit excellent display quality.

Embodiments have been disclosed herein, and although terms are employed, they are used and are to be interpreted in a generic and descriptive sense only and not for the purposes of limitation. In some instances, as would be apparent to one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light emitting element comprising:
a first electrode;
a second electrode disposed on the first electrode; and
an emission layer disposed between the first electrode and the second electrode, wherein
the emission layer comprises a first compound represented by Formula 1: 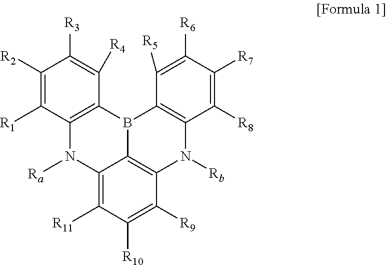
wherein in Formula 1,
at least one of R₁ to R₈ is each independently a first substituent represented by Formula 2,
at least one of the remainder of R₁ to R₈ that is not the first substituent is each independently a second substituent represented by Formula 3, and
the remainder of R₁ to R₈ that are not the first substituent or the second substituent, R₉ to R₁₁, Rₐ, and R_{b} are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; 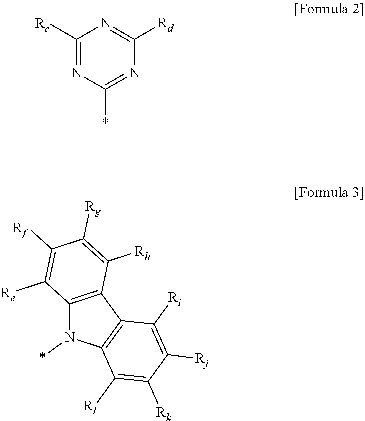
wherein in Formula 2 and Formula 3,
R_{c} to Rₗ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and [symbol]
represents a position linked to Formula 1.

2. The light emitting element of claim 1, wherein the emission layer further comprises at least one of a second compound represented by Formula HT-1 and a third compound represented by Formula ET-1: 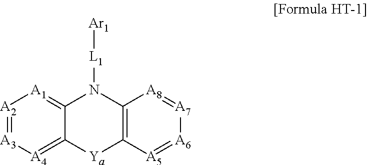
wherein in Formula HT-1,
A₁ to A₈ are each independently N or C(R₅₁),
L₁ is a direct linkage, a substituted or unsubstituted arylene group having 6 to 30 ring-forming carbon atoms, or a substituted or unsubstituted heteroarylene group having 2 to 30 ring-forming carbon atoms,
Yₐ is a direct linkage, C(R₅₂)(R₅₃), or Si(R₅₄)(R₅₅),
Ar₁ is a substituted or unsubstituted aryl group having 6 to 30 ring-forming carbon atoms or a substituted or unsubstituted heteroaryl group having 2 to 30 ring-forming carbon atoms, and
R₅₁ to R₅₅ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, or bonded to an adjacent group to form a ring; 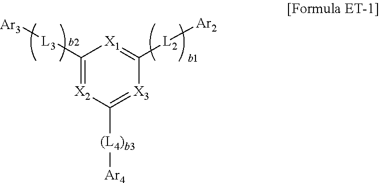
wherein in Formula ET-1,
at least one of X₁ to X₃ is each N,
the remainder of X₁ to X₃ are each independently C(R₅₆),
R₅₆ is a hydrogen atom, a deuterium atom, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms,
b1 to b3 are each independently an integer from 0 to 10,
Ar₂ to Ar₄ are each independently a hydrogen atom, a deuterium atom, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and
L₂ to L₄ are each independently a direct linkage, a substituted or unsubstituted arylene group having 6 to 30 ring-forming carbon atoms, or a substituted or unsubstituted heteroarylene group having 2 to 30 ring-forming carbon atoms.

3. The light emitting element of claim 2, wherein the emission layer further comprises a fourth compound represented by Formula D-1: 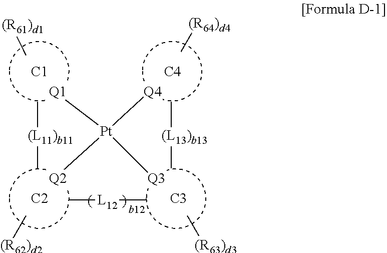
wherein in Formula D-1,
Q₁ to Q₄ are each independently C or N,
C1 to C4 are each independently a substituted or unsubstituted hydrocarbon ring having 5 to 30 ring-forming carbon atoms or a substituted or unsubstituted heterocycle having 2 to 30 ring-forming carbon atoms,
L₁₁ to L₁₃ are each independently a direct linkage, 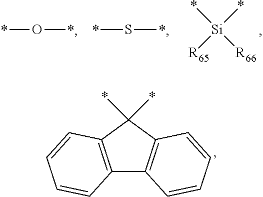
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms,
b11 to b13 are each independently 0 or 1,
R₆₁ to R₆₆ are each independently a hydrogen atom, a deuterium atom, a halogen atom, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted alkenyl group having 2 to 20 carbon atoms, a substituted or unsubstituted aryl group having 6 to 60 ring-forming carbon atoms, or a substituted or unsubstituted heteroaryl group having 2 to 60 ring-forming carbon atoms, and
d1 to d4 are each independently an integer from 0 to 4.

4. The light emitting element of claim 3, wherein the emission layer comprises the first compound, the second compound, the third compound, and the fourth compound.

5. The light emitting element of claim 1, wherein the emission layer emits delayed fluorescence.

6. The light emitting element of claim 1, wherein the emission layer emits blue light.

7. The light emitting element of claim 1, wherein the first compound is represented by Formula 1-1 or Formula 1-2: 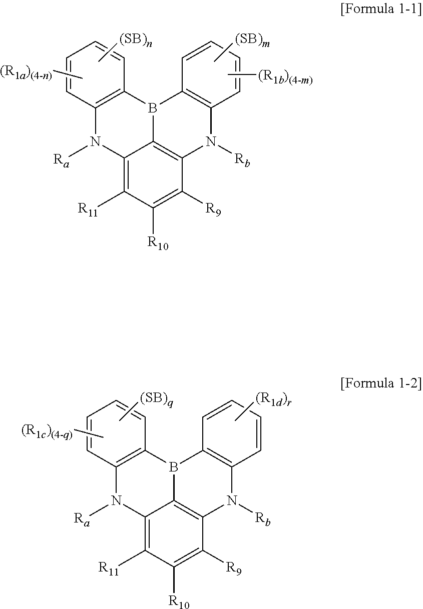
wherein in Formula 1-1 and Formula 1-2,
SB is each independently the first substituent or the second substituent, provided that at least one SB is the first substituent and at least one SB is the second substituent,
R₁ₐ to R_{1d} are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, provided that R₁ₐ to R₁ₐ are not a triazine group or a carbazole group,
n and m are each independently an integer from 1 to 3,
q is an integer from 2 to 4,
r is an integer from 1 to 4, and
R₉ to R₁₁, Rₐ, and R_{b} are each the same as defined in Formula 1.

8. The light emitting element of claim 1, wherein in the first compound, at least one hydrogen atom is substituted with a deuterium atom.

9. The light emitting element of claim 1, wherein the first compound is selected from Compound Group 1: 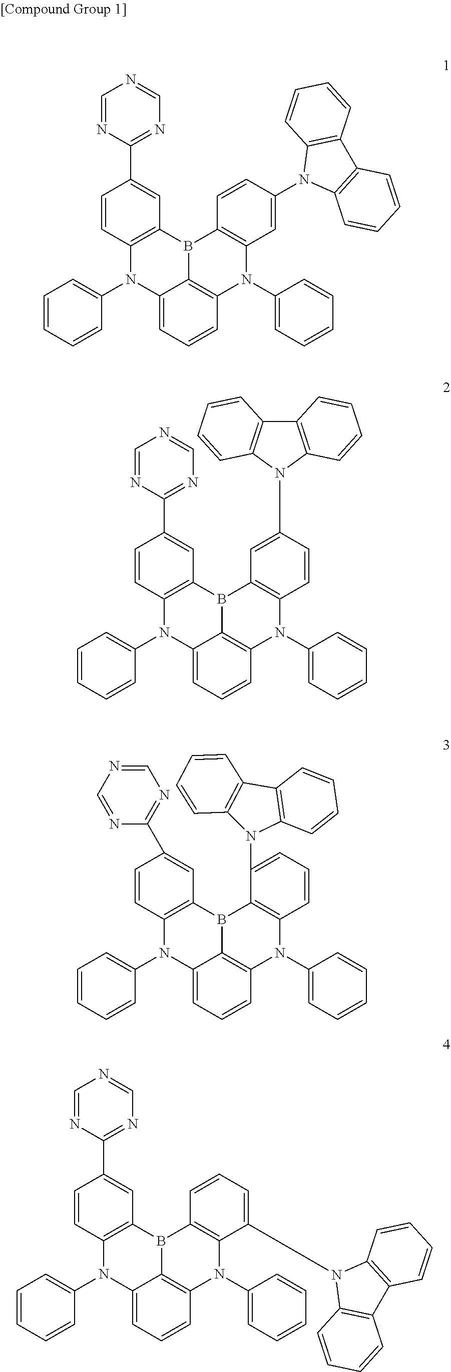 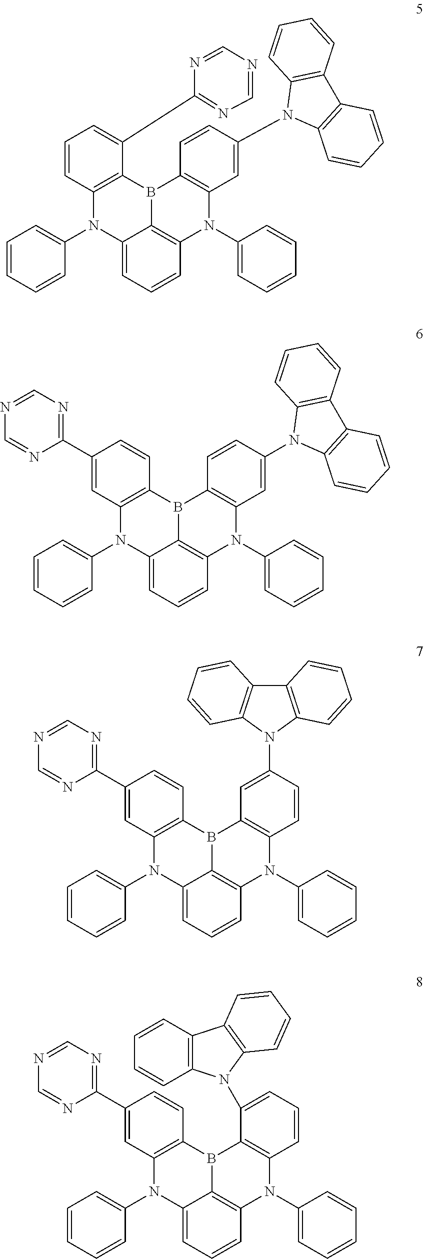 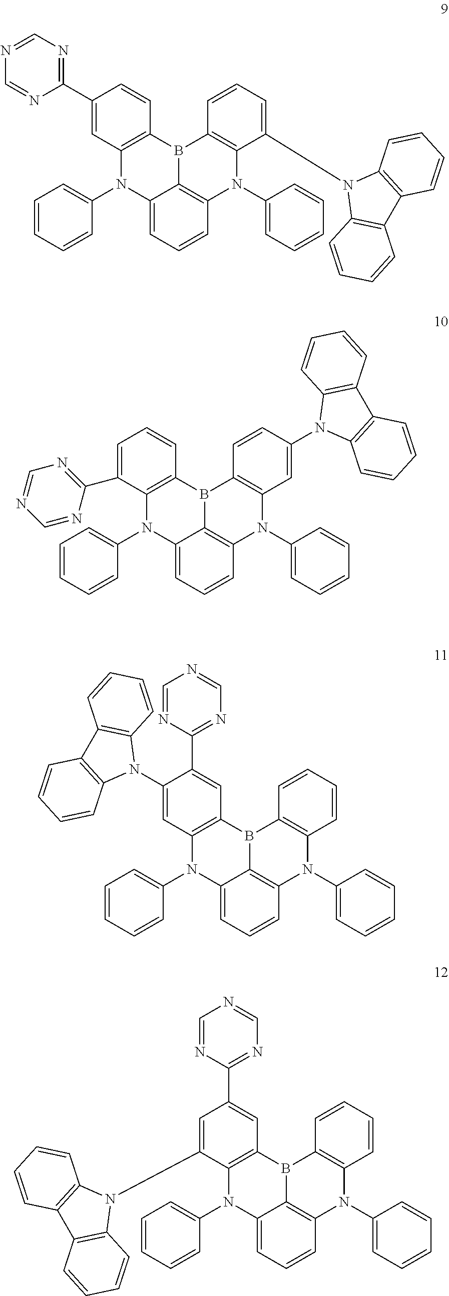 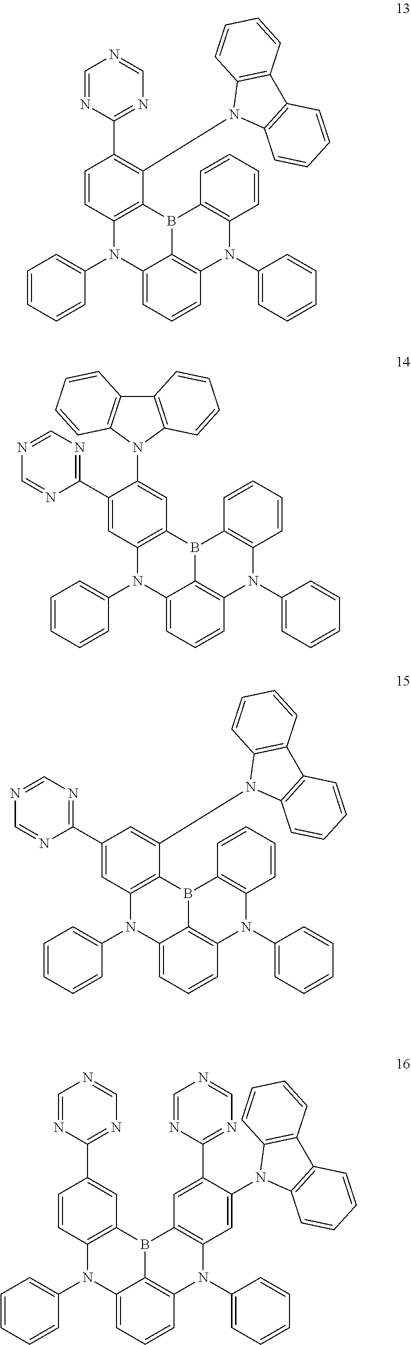 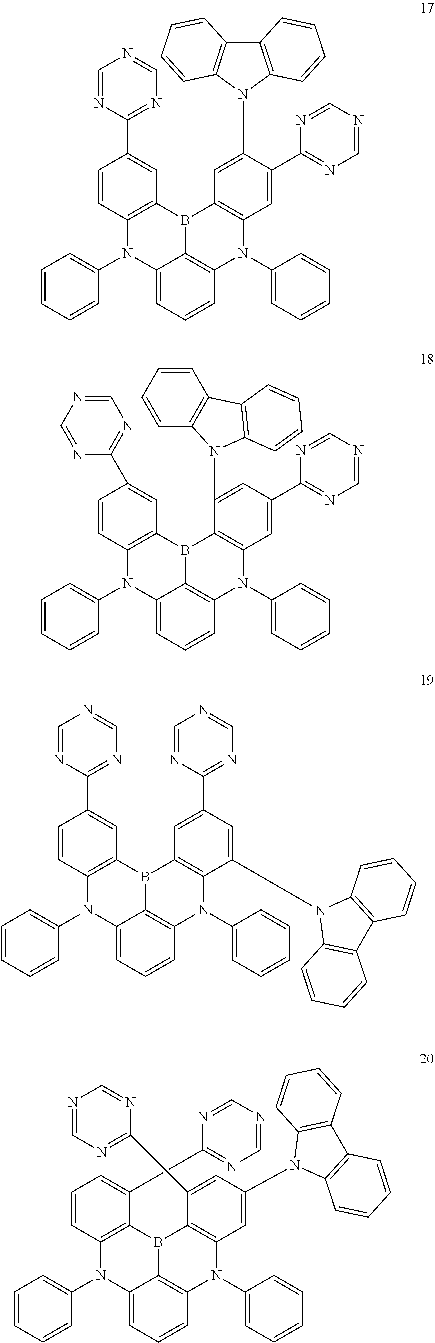 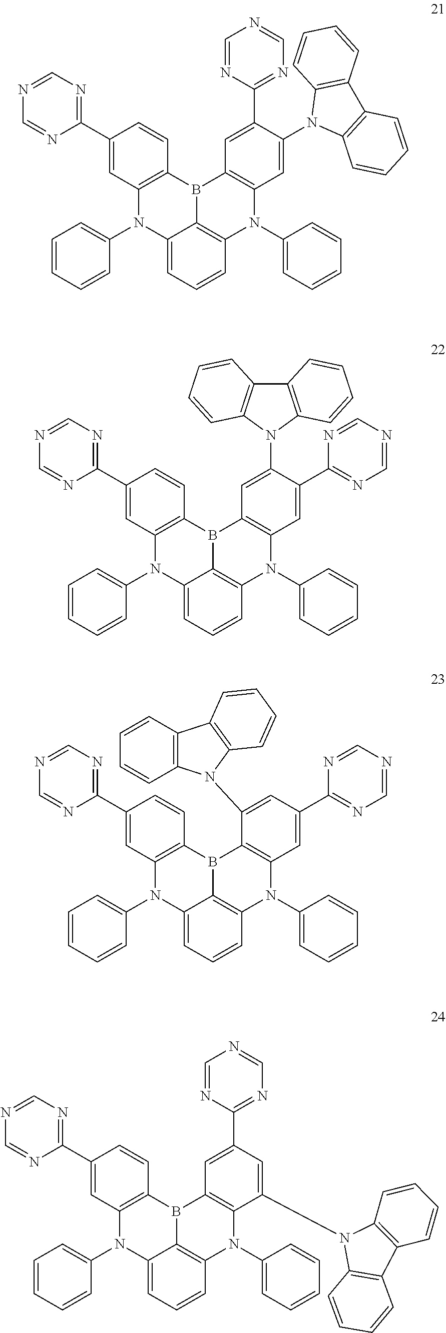 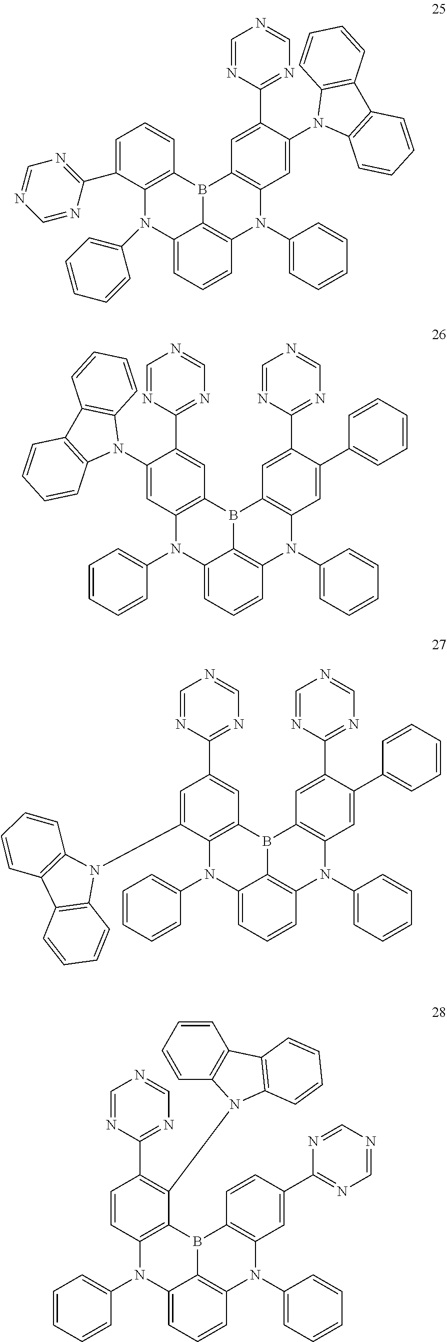 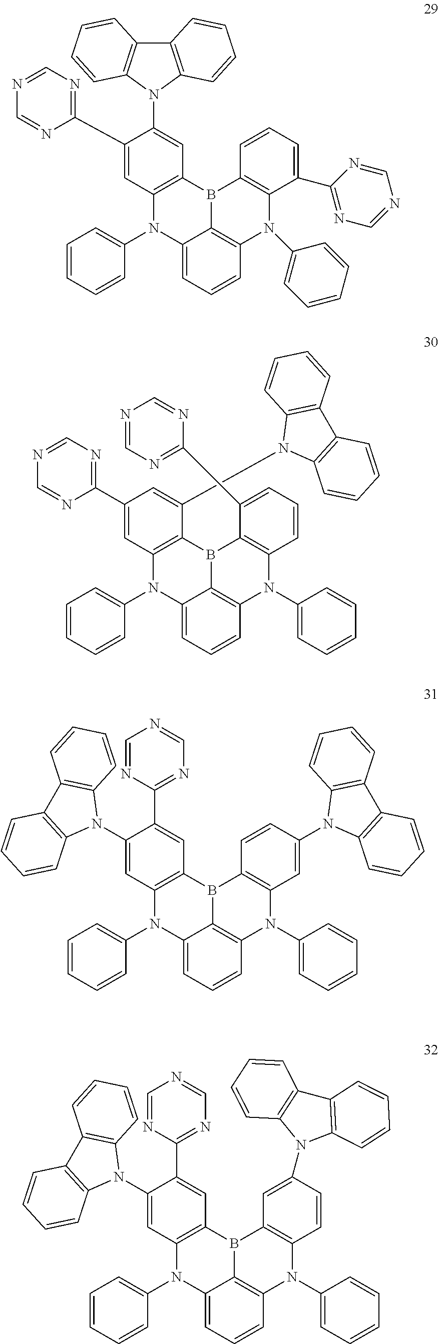 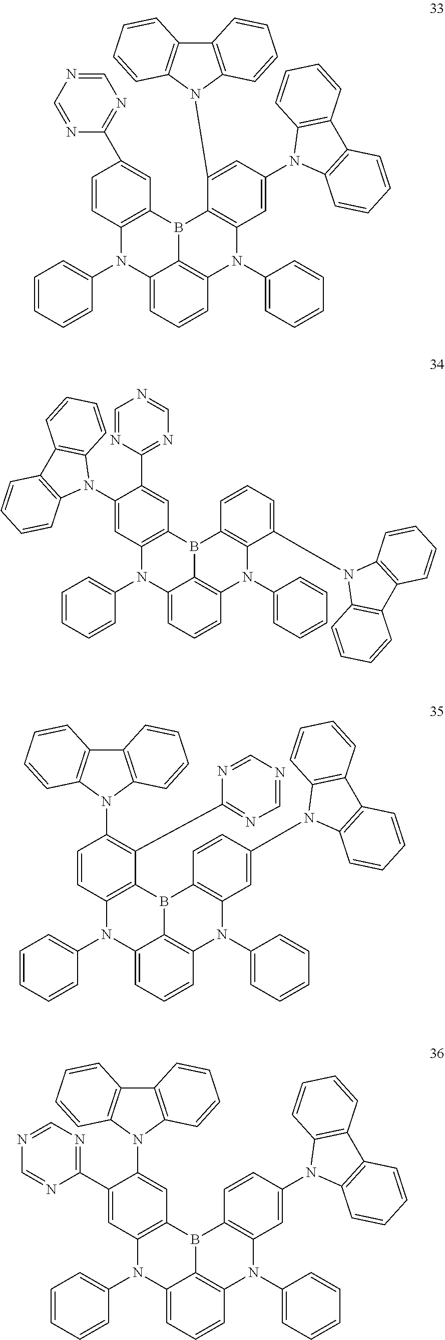 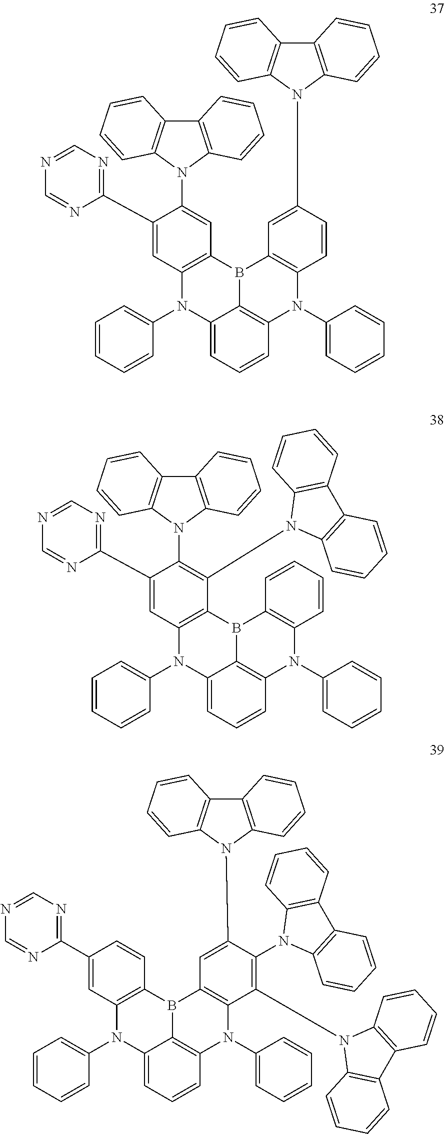 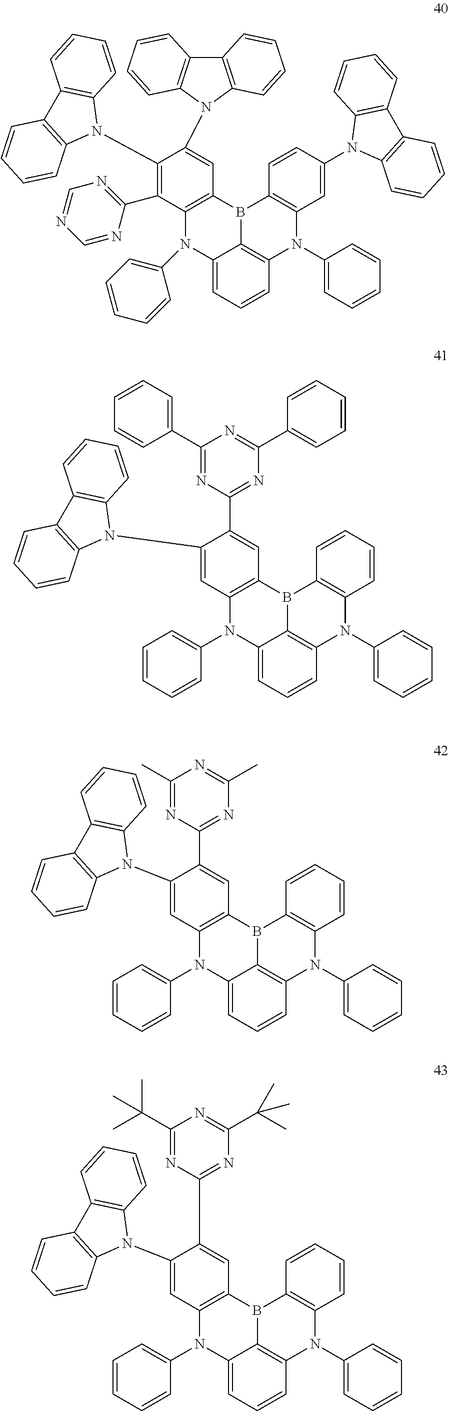 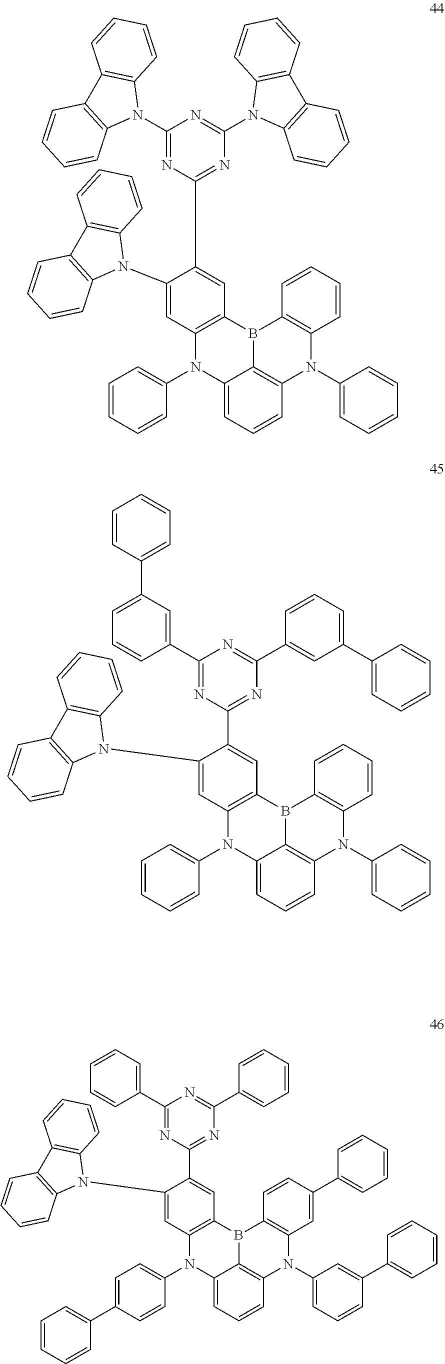 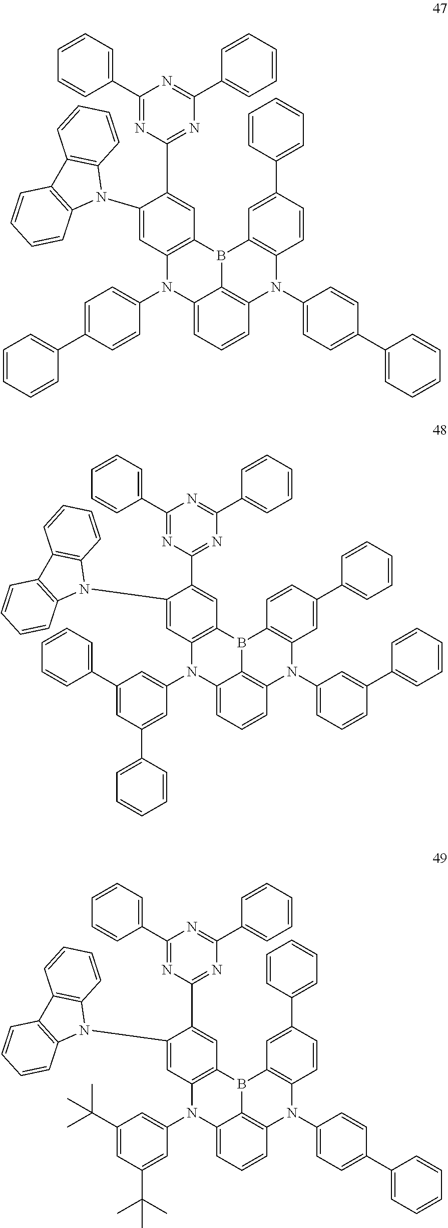 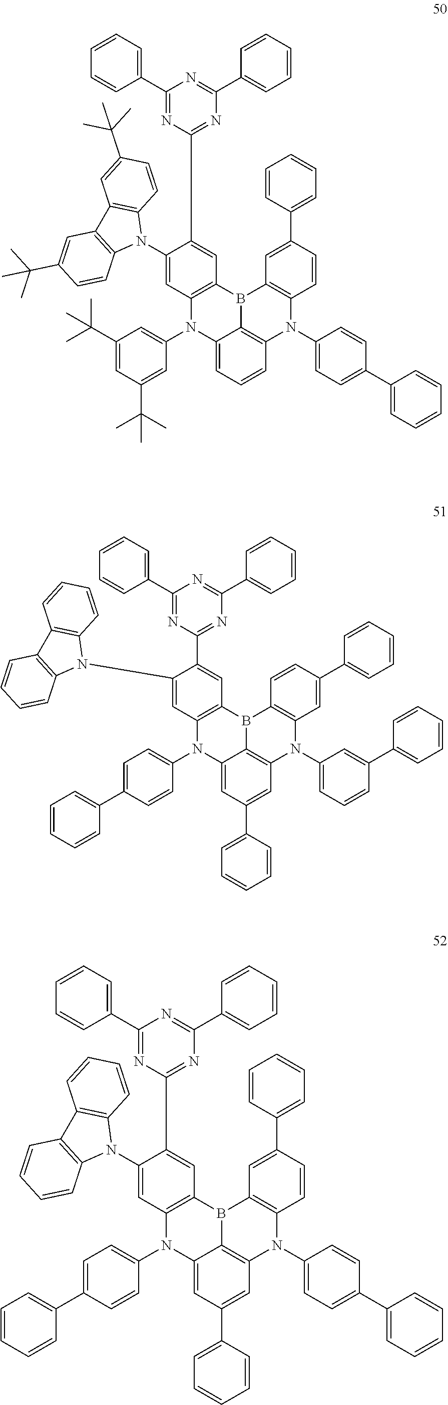 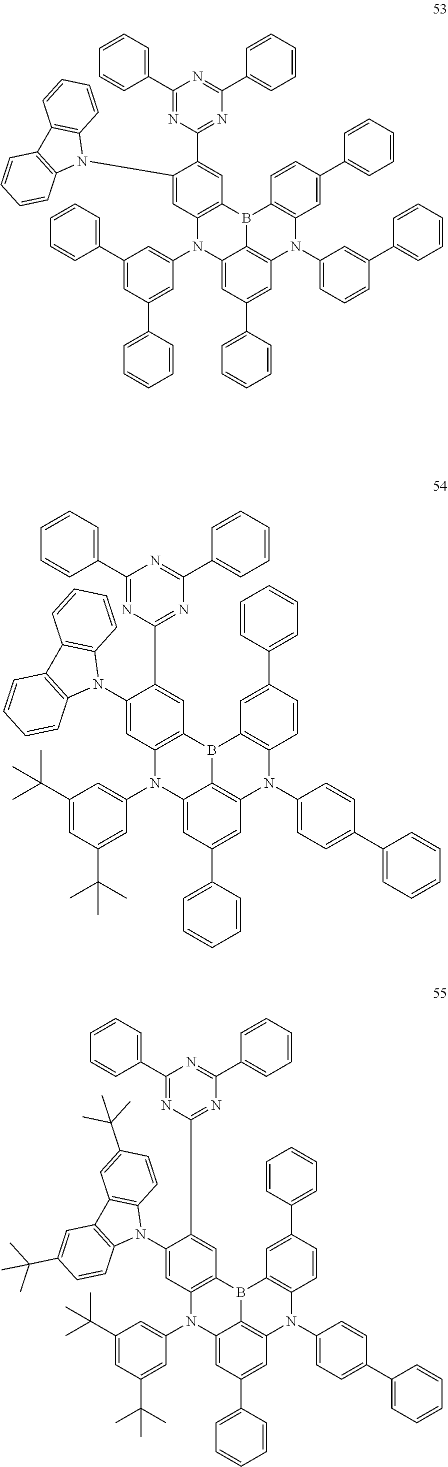 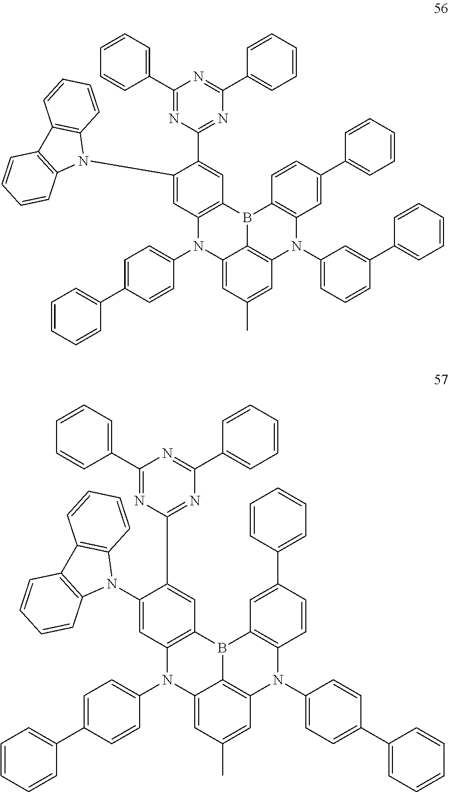 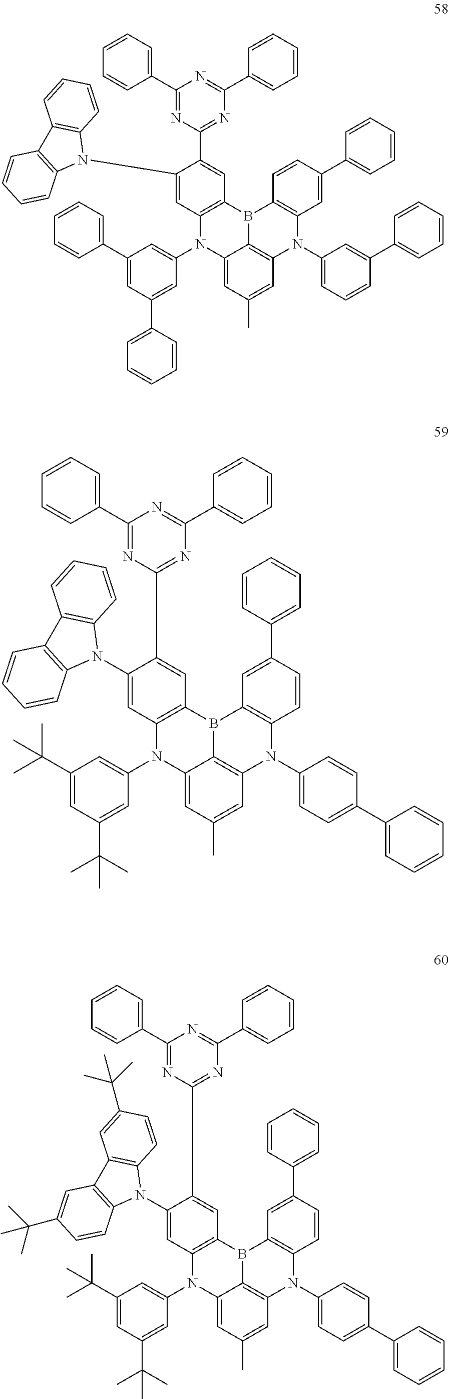 [SMILES: Cc1cc2c3c(c1)N(c1cc(-c4ccccc4)cc(-c4ccccc4)c1)c1cc(-n4c5ccccc5c5ccccc54)c(-c4nc(-c5ccccc5)nc(-c5ccccc5)n4)cc1B3c1ccc(-c3ccccc3)cc1N2c1cccc(-c2ccccc2)c1 ; Cc1cc2c3c(c1)N(c1cc(C(C)(C)C)cc(C(C)(C)C)c1)c1cc(-n4c5ccccc5c5ccccc54)c(-c4nc(-c5ccccc5)nc(-c5ccccc5)n4)cc1B3c1cc(-c3ccccc3)ccc1N2c1ccc(-c2ccccc2)cc1 ; Cc1cc2c3c(c1)N(c1cc(C(C)(C)C)cc(C(C)(C)C)c1)c1cc(-n4c5ccc(C(C)(C)C)cc5c5cc(C(C)(C)C)ccc54)c(-c4nc(-c5ccccc5)nc(-c5ccccc5)n4)cc1B3c1cc(-c3ccccc3)ccc1N2c1ccc(-c2ccccc2)cc1] 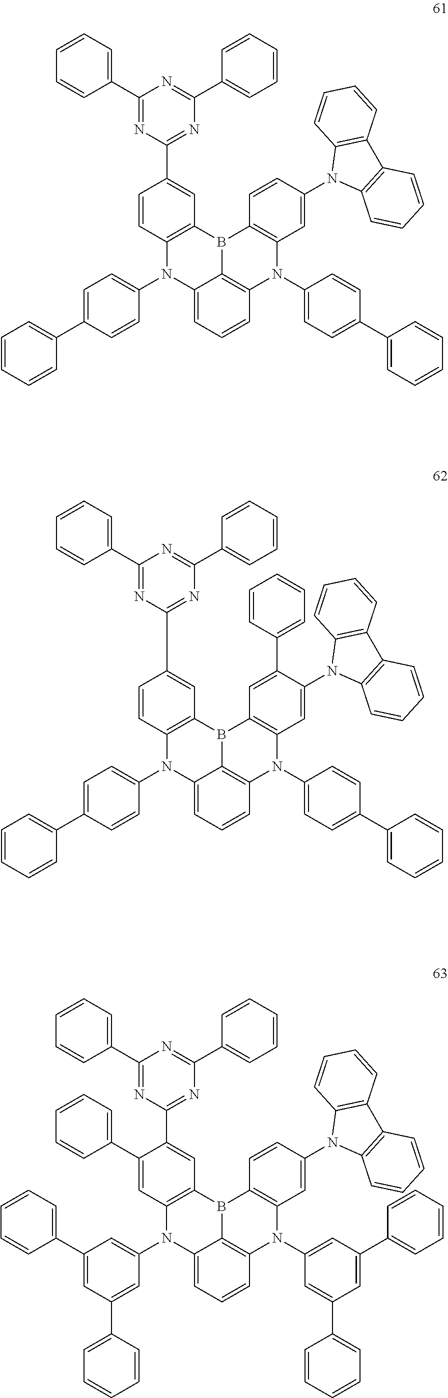 [SMILES: c1ccc(-c2ccc(N3c4ccc(-c5nc(-c6ccccc6)nc(-c6ccccc6)n5)cc4B4c5ccc(-n6c7ccccc7c7ccccc76)cc5N(c5ccc(-c6ccccc6)cc5)c5cccc3c54)cc2)cc1 ; c1ccc(-c2ccc(N3c4ccc(-c5nc(-c6ccccc6)nc(-c6ccccc6)n5)cc4B4c5cc(-c6ccccc6)c(-n6c7ccccc7c7ccccc76)cc5N(c5ccc(-c6ccccc6)cc5)c5cccc3c54)cc2)cc1 ; c1ccc(-c2cc(-c3ccccc3)cc(N3c4cc(-n5c6ccccc6c6ccccc65)ccc4B4c5cc(-c6nc(-c7ccccc7)nc(-c7ccccc7)n6)c(-c6ccccc6)cc5N(c5cc(-c6ccccc6)cc(-c6ccccc6)c5)c5cccc3c54)c2)cc1] 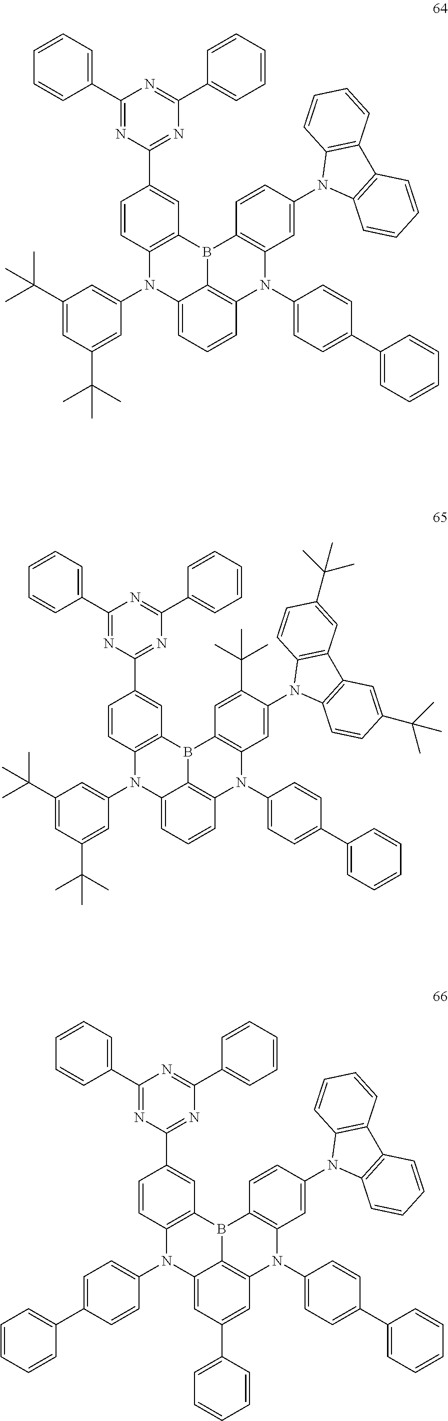 [SMILES: CC(C)(C)c1cc(N2c3ccc(-c4nc(-c5ccccc5)nc(-c5ccccc5)n4)cc3B3c4ccc(-n5c6ccccc6c6ccccc65)cc4N(c4ccc(-c5ccccc5)cc4)c4cccc2c43)cc(C(C)(C)C)c1 ; CC(C)(C)c1cc(N2c3ccc(-c4nc(-c5ccccc5)nc(-c5ccccc5)n4)cc3B3c4cc(C(C)(C)C)c(-n5c6ccc(C(C)(C)C)cc6c6cc(C(C)(C)C)ccc65)cc4N(c4ccc(-c5ccccc5)cc4)c4cccc2c43)cc(C(C)(C)C)c1 ; c1ccc(-c2ccc(N3c4ccc(-c5nc(-c6ccccc6)nc(-c6ccccc6)n5)cc4B4c5ccc(-n6c7ccccc7c7ccccc76)cc5N(c5ccc(-c6ccccc6)cc5)c5cc(-c6ccccc6)cc3c54)cc2)cc1] 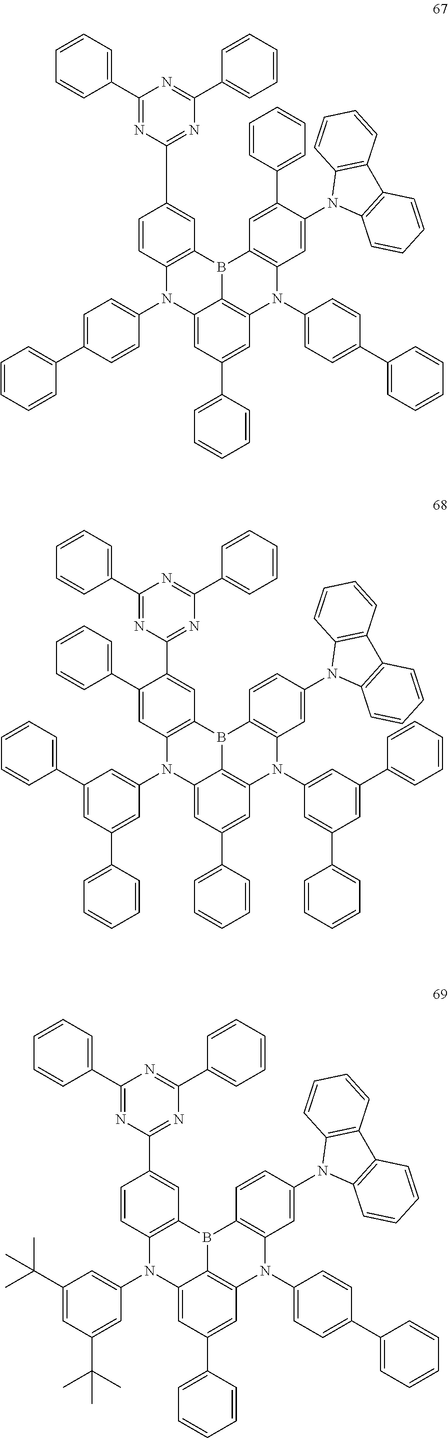 [SMILES: c1ccc(-c2ccc(N3c4ccc(-c5nc(-c6ccccc6)nc(-c6ccccc6)n5)cc4B4c5cc(-c6ccccc6)c(-n6c7ccccc7c7ccccc76)cc5N(c5ccc(-c6ccccc6)cc5)c5cc(-c6ccccc6)cc3c54)cc2)cc1 ; c1ccc(-c2cc(-c3ccccc3)cc(N3c4cc(-n5c6ccccc6c6ccccc65)ccc4B4c5cc(-c6nc(-c7ccccc7)nc(-c7ccccc7)n6)c(-c6ccccc6)cc5N(c5cc(-c6ccccc6)cc(-c6ccccc6)c5)c5cc(-c6ccccc6)cc3c54)c2)cc1 ; CC(C)(C)c1cc(N2c3ccc(-c4nc(-c5ccccc5)nc(-c5ccccc5)n4)cc3B3c4ccc(-n5c6ccccc6c6ccccc65)cc4N(c4ccc(-c5ccccc5)cc4)c4cc(-c5ccccc5)cc2c43)cc(C(C)(C)C)c1] 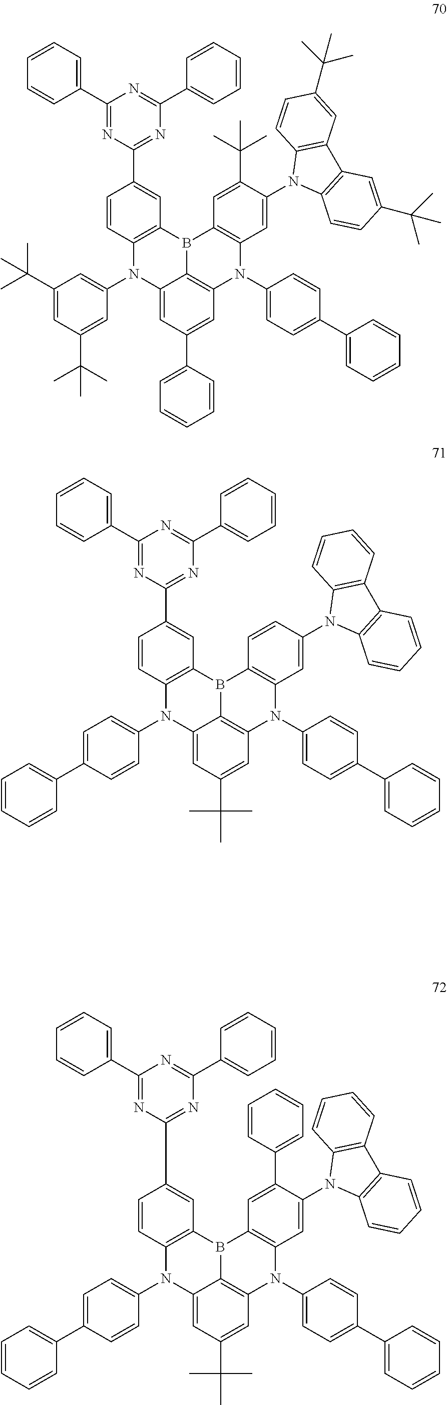 [SMILES: CC(C)(C)c1cc(N2c3ccc(-c4nc(-c5ccccc5)nc(-c5ccccc5)n4)cc3B3c4cc(C(C)(C)C)c(-n5c6ccc(C(C)(C)C)cc6c6cc(C(C)(C)C)ccc65)cc4N(c4ccc(-c5ccccc5)cc4)c4cc(-c5ccccc5)cc2c43)cc(C(C)(C)C)c1 ; CC(C)(C)c1cc2c3c(c1)N(c1ccc(-c4ccccc4)cc1)c1cc(-n4c5ccccc5c5ccccc54)ccc1B3c1cc(-c3nc(-c4ccccc4)nc(-c4ccccc4)n3)ccc1N2c1ccc(-c2ccccc2)cc1 ; CC(C)(C)c1cc2c3c(c1)N(c1ccc(-c4ccccc4)cc1)c1cc(-n4c5ccccc5c5ccccc54)c(-c4ccccc4)cc1B3c1cc(-c3nc(-c4ccccc4)nc(-c4ccccc4)n3)ccc1N2c1ccc(-c2ccccc2)cc1] 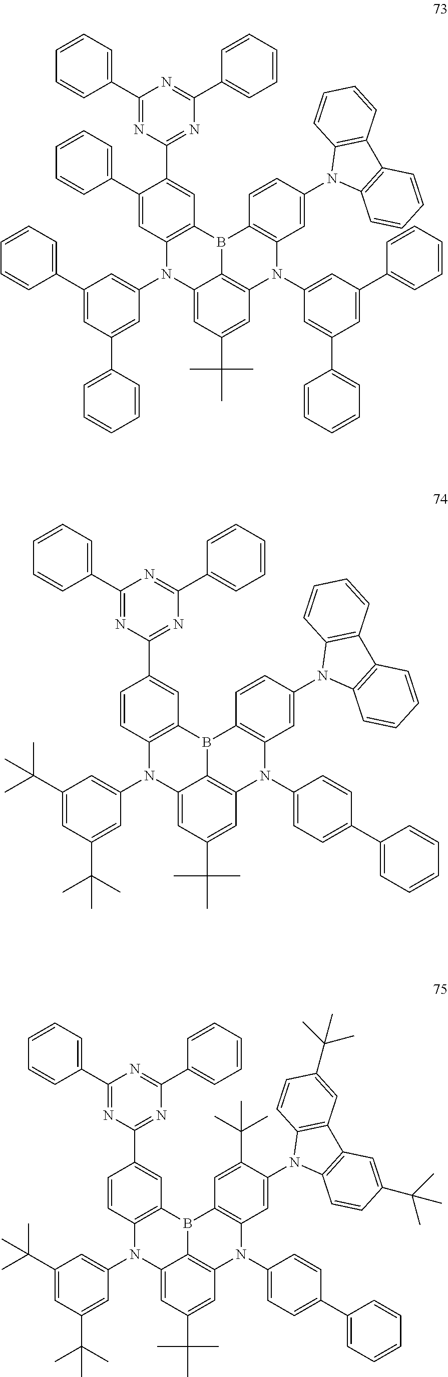 [SMILES: CC(C)(C)c1cc2c3c(c1)N(c1cc(-c4ccccc4)cc(-c4ccccc4)c1)c1cc(-c4ccccc4)c(-c4nc(-c5ccccc5)nc(-c5ccccc5)n4)cc1B3c1ccc(-n3c4ccccc4c4ccccc43)cc1N2c1cc(-c2ccccc2)cc(-c2ccccc2)c1 ; CC(C)(C)c1cc(N2c3ccc(-c4nc(-c5ccccc5)nc(-c5ccccc5)n4)cc3B3c4ccc(-n5c6ccccc6c6ccccc65)cc4N(c4ccc(-c5ccccc5)cc4)c4cc(C(C)(C)C)cc2c43)cc(C(C)(C)C)c1 ; CC(C)(C)c1cc(N2c3ccc(-c4nc(-c5ccccc5)nc(-c5ccccc5)n4)cc3B3c4cc(C(C)(C)C)c(-n5c6ccc(C(C)(C)C)cc6c6cc(C(C)(C)C)ccc65)cc4N(c4ccc(-c5ccccc5)cc4)c4cc(C(C)(C)C)cc2c43)cc(C(C)(C)C)c1] 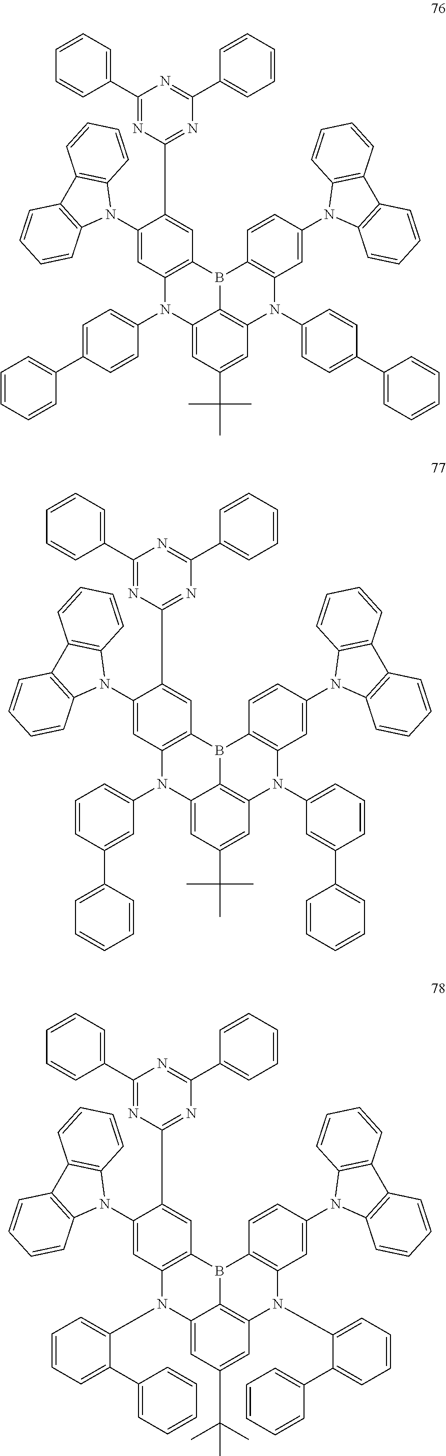 [SMILES: CC(C)(C)c1cc2c3c(c1)N(c1ccc(-c4ccccc4)cc1)c1cc(-n4c5ccccc5c5ccccc54)c(-c4nc(-c5ccccc5)nc(-c5ccccc5)n4)cc1B3c1ccc(-n3c4ccccc4c4ccccc43)cc1N2c1ccc(-c2ccccc2)cc1 ; CC(C)(C)c1cc2c3c(c1)N(c1cccc(-c4ccccc4)c1)c1cc(-n4c5ccccc5c5ccccc54)c(-c4nc(-c5ccccc5)nc(-c5ccccc5)n4)cc1B3c1ccc(-n3c4ccccc4c4ccccc43)cc1N2c1cccc(-c2ccccc2)c1 ; CC(C)(C)c1cc2c3c(c1)N(c1ccccc1-c1ccccc1)c1cc(-n4c5ccccc5c5ccccc54)c(-c4nc(-c5ccccc5)nc(-c5ccccc5)n4)cc1B3c1ccc(-n3c4ccccc4c4ccccc43)cc1N2c1ccccc1-c1ccccc1] 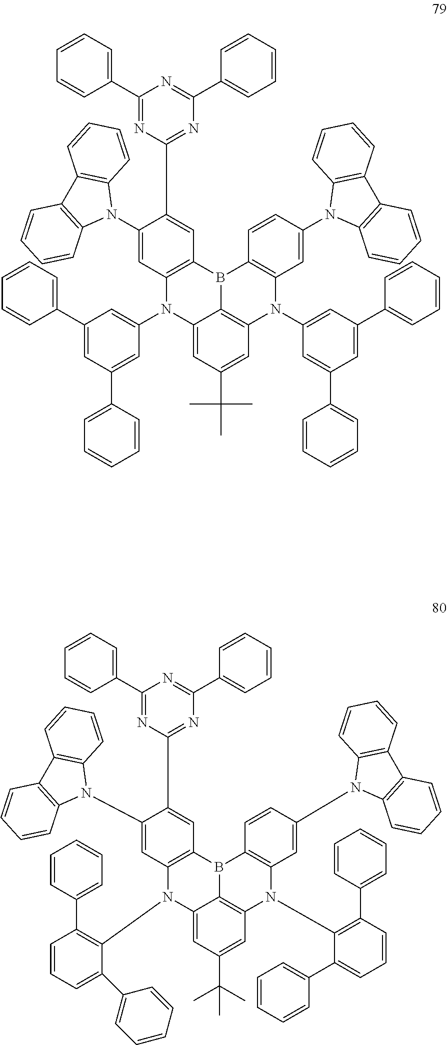 [SMILES: CC(C)(C)c1cc2c3c(c1)N(c1cc(-c4ccccc4)cc(-c4ccccc4)c1)c1cc(-n4c5ccccc5c5ccccc54)c(-c4nc(-c5ccccc5)nc(-c5ccccc5)n4)cc1B3c1ccc(-n3c4ccccc4c4ccccc43)cc1N2c1cc(-c2ccccc2)cc(-c2ccccc2)c1 ; CC(C)(C)c1cc2c3c(c1)N(c1c(-c4ccccc4)cccc1-c1ccccc1)c1cc(-n4c5ccccc5c5ccccc54)c(-c4nc(-c5ccccc5)nc(-c5ccccc5)n4)cc1B3c1ccc(-n3c4ccccc4c4ccccc43)cc1N2c1c(-c2ccccc2)cccc1-c1ccccc1] 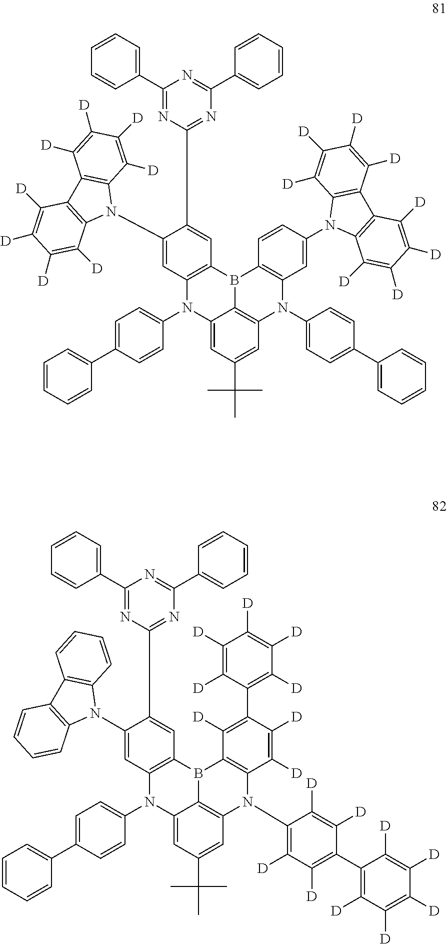 [SMILES: [2H]c1c([2H])c([2H])c2c(c1[2H])c1c([2H])c([2H])c([2H])c([2H])c1n2-c1ccc2c(c1)N(c1ccc(-c3ccccc3)cc1)c1cc(C(C)(C)C)cc3c1B2c1cc(-c2nc(-c4ccccc4)nc(-c4ccccc4)n2)c(-n2c4c([2H])c([2H])c([2H])c([2H])c4c4c([2H])c([2H])c([2H])c([2H])c42)cc1N3c1ccc(-c2ccccc2)cc1 ; [2H]c1c([2H])c([2H])c(-c2c([2H])c([2H])c(N3c4cc(C(C)(C)C)cc5c4B(c4cc(-c6nc(-c7ccccc7)nc(-c7ccccc7)n6)c(-n6c7ccccc7c7ccccc76)cc4N5c4ccc(-c5ccccc5)cc4)c4c([2H])c(-c5c([2H])c([2H])c([2H])c([2H])c5[2H])c([2H])c([2H])c43)c([2H])c2[2H])c([2H])c1[2H]]
wherein in Compound Group 1,
D represents a deuterium atom.

10. A polycyclic compound represented by Formula 1: 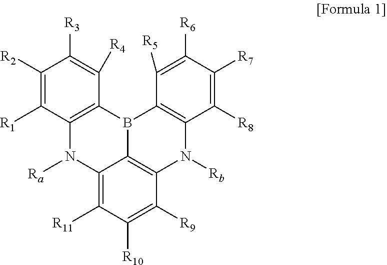
wherein in Formula 1,
at least one of R₁ to R₈ is each independently a first substituent represented by Formula 2,
at least one of the remainder of R₁ to R₈ that is not the first substituent is each independently a second substituent represented by Formula 3, and
the remainder of R₁ to R₈ that are not the first substituent or the second substituent, R₉ to R₁₁, Rₐ, and R_{b} are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; 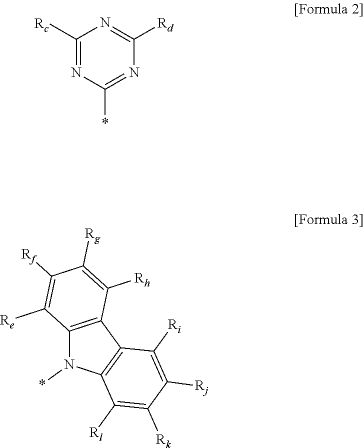
wherein in Formula 2 and Formula 3,
R_{c} to Rₗ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and [symbol]
represents a position linked to Formula 1.

11. The polycyclic compound of claim 10, wherein the polycyclic is represented by Formula 1-1 or Formula 1-2: 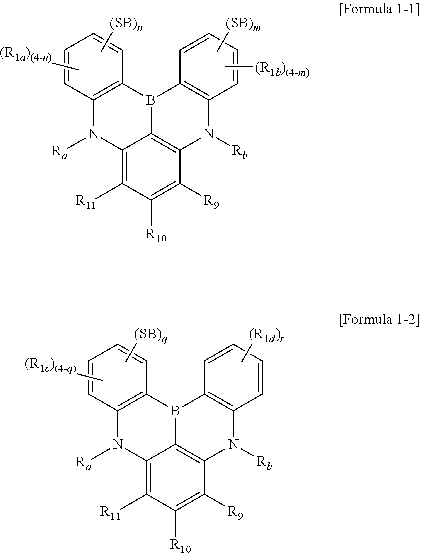
wherein in Formula 1-1 and Formula 1-2,
SB is each independently the first substituent or the second substituent, provided that at least one SB is the first substituent and at least one SB is the second substituent,
R₁ₐ to R_{1d} are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, provided that R₁ₐ to R_{1d} are not a triazine group or a carbazole group,
n and m are each independently an integer from 1 to 3,
q is an integer from 2 to 4,
r is an integer from 1 to 4, and
R₉ to R₁₁, Rₐ, and R_{b} are each the same as defined in Formula 1.

12. The polycyclic compound of claim 10, wherein in Formula 1, R₉ to R₁₁ do not include a triazine group or a carbazole group.

13. The polycyclic compound of claim 10, wherein in Formula 2, R_{c} and R_{d} are each independently a substituted or unsubstituted phenyl group, a substituted or unsubstituted biphenyl group, or a substituted or unsubstituted terphenyl group.

14. The polycyclic compound of claim 10, wherein in Formula 1 to Formula 3, at least one hydrogen atom is substituted with a deuterium atom.

15. The polycyclic compound of claim 10, wherein the polycyclic compound is a blue emission dopant.

16. The polycyclic compound of claim 10, wherein the polycyclic compound is a thermally activated delayed fluorescence material.

17. The polycyclic compound of claim 10, wherein the polycyclic compound is selected from Compound Group 1: 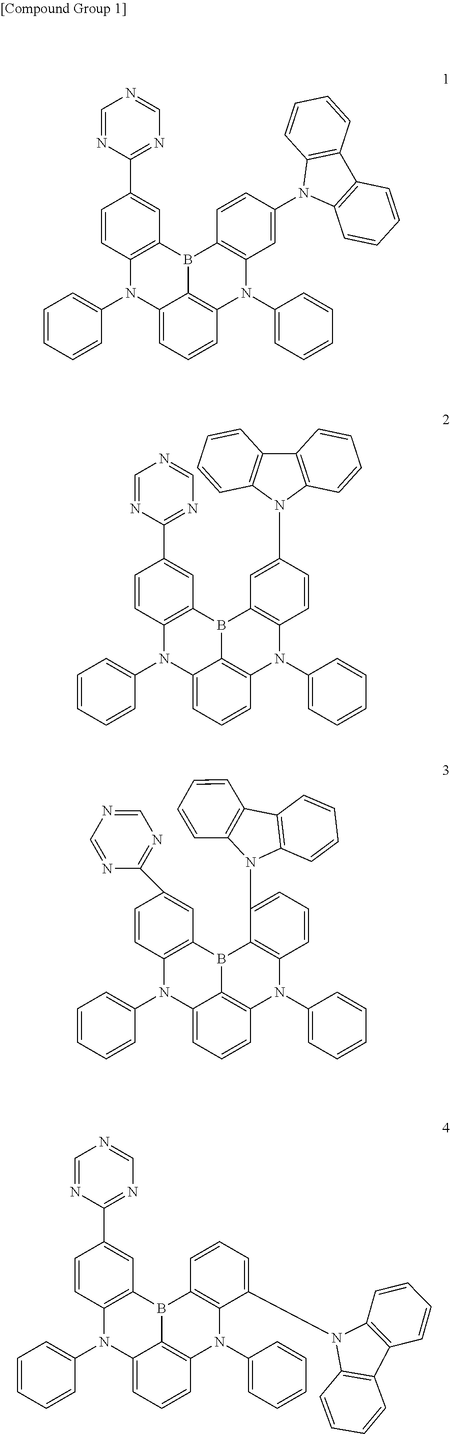 [SMILES: c1ccc(N2c3ccc(-c4ncncn4)cc3B3c4ccc(-n5c6ccccc6c6ccccc65)cc4N(c4ccccc4)c4cccc2c43)cc1 ; c1ccc(N2c3ccc(-c4ncncn4)cc3B3c4cc(-n5c6ccccc6c6ccccc65)ccc4N(c4ccccc4)c4cccc2c43)cc1 ; c1ccc(N2c3ccc(-c4ncncn4)cc3B3c4c2cccc4N(c2ccccc2)c2cccc(-n4c5ccccc5c5ccccc54)c23)cc1 ; c1ccc(N2c3ccc(-c4ncncn4)cc3B3c4cccc(-n5c6ccccc6c6ccccc65)c4N(c4ccccc4)c4cccc2c43)cc1] 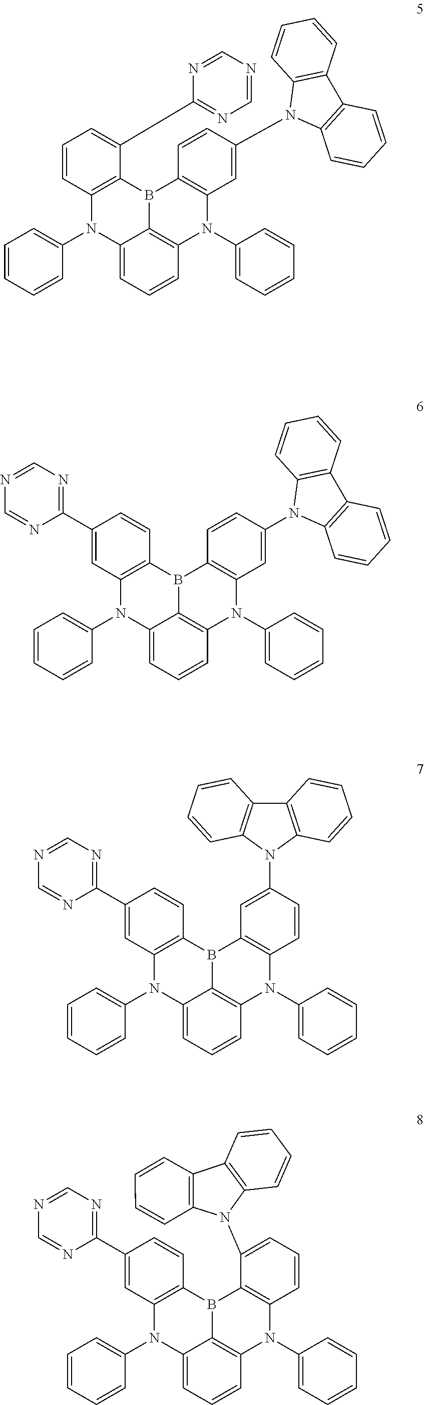 [SMILES: c1ccc(N2c3cc(-n4c5ccccc5c5ccccc54)ccc3B3c4c(-c5ncncn5)cccc4N(c4ccccc4)c4cccc2c43)cc1 ; c1ccc(N2c3cc(-c4ncncn4)ccc3B3c4ccc(-n5c6ccccc6c6ccccc65)cc4N(c4ccccc4)c4cccc2c43)cc1 ; c1ccc(N2c3ccc(-n4c5ccccc5c5ccccc54)cc3B3c4ccc(-c5ncncn5)cc4N(c4ccccc4)c4cccc2c43)cc1 ; c1ccc(N2c3cc(-c4ncncn4)ccc3B3c4c2cccc4N(c2ccccc2)c2cccc(-n4c5ccccc5c5ccccc54)c23)cc1] 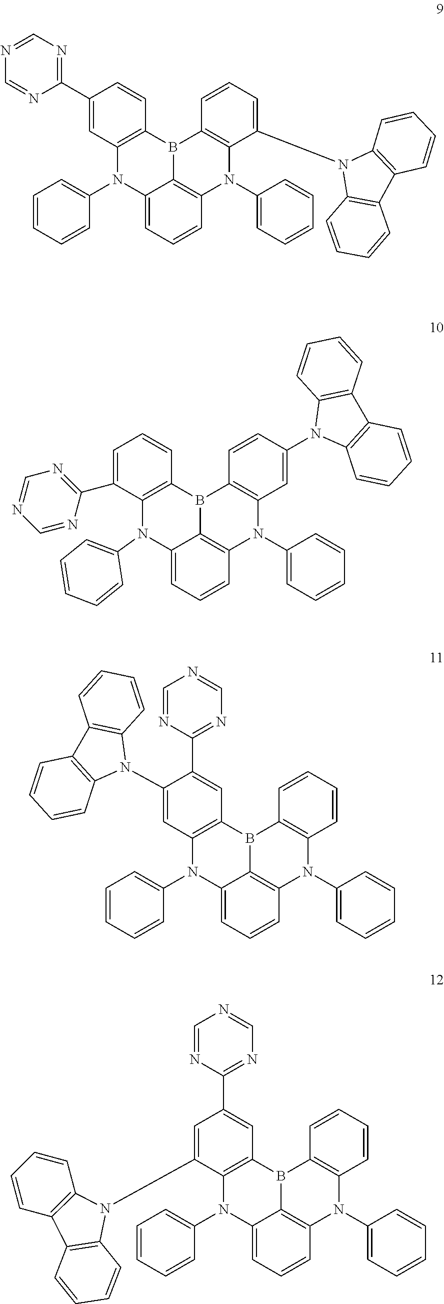 [SMILES: c1ccc(N2c3cc(-c4ncncn4)ccc3B3c4cccc(-n5c6ccccc6c6ccccc65)c4N(c4ccccc4)c4cccc2c43)cc1 ; c1ccc(N2c3cc(-n4c5ccccc5c5ccccc54)ccc3B3c4cccc(-c5ncncn5)c4N(c4ccccc4)c4cccc2c43)cc1 ; c1ccc(N2c3ccccc3B3c4cc(-c5ncncn5)c(-n5c6ccccc6c6ccccc65)cc4N(c4ccccc4)c4cccc2c43)cc1 ; c1ccc(N2c3ccccc3B3c4cc(-c5ncncn5)cc(-n5c6ccccc6c6ccccc65)c4N(c4ccccc4)c4cccc2c43)cc1] 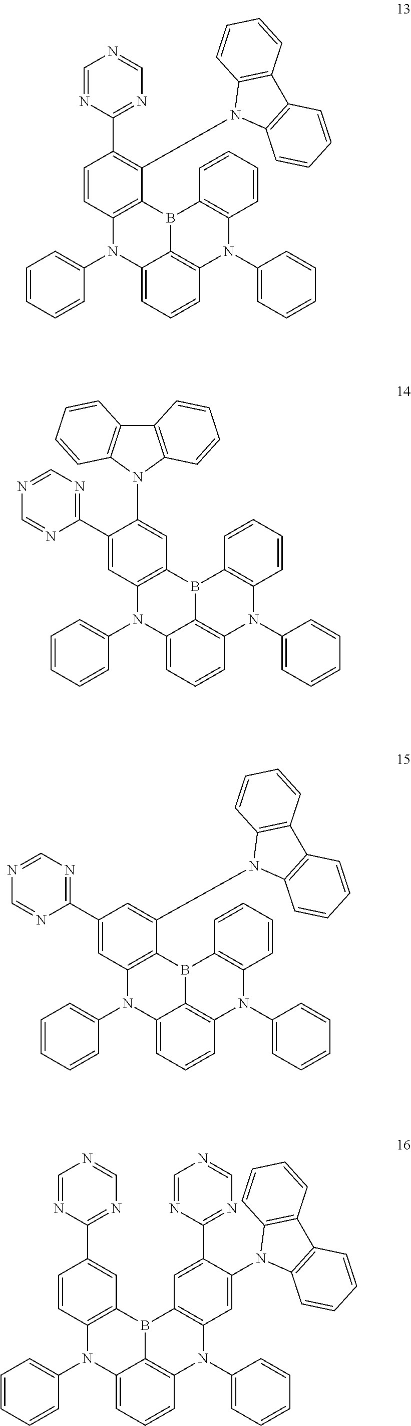 [SMILES: c1ccc(N2c3ccccc3B3c4c2cccc4N(c2ccccc2)c2ccc(-c4ncncn4)c(-n4c5ccccc5c5ccccc54)c23)cc1 ; c1ccc(N2c3ccccc3B3c4cc(-n5c6ccccc6c6ccccc65)c(-c5ncncn5)cc4N(c4ccccc4)c4cccc2c43)cc1 ; c1ccc(N2c3ccccc3B3c4c2cccc4N(c2ccccc2)c2cc(-c4ncncn4)cc(-n4c5ccccc5c5ccccc54)c23)cc1 ; c1ccc(N2c3ccc(-c4ncncn4)cc3B3c4cc(-c5ncncn5)c(-n5c6ccccc6c6ccccc65)cc4N(c4ccccc4)c4cccc2c43)cc1] 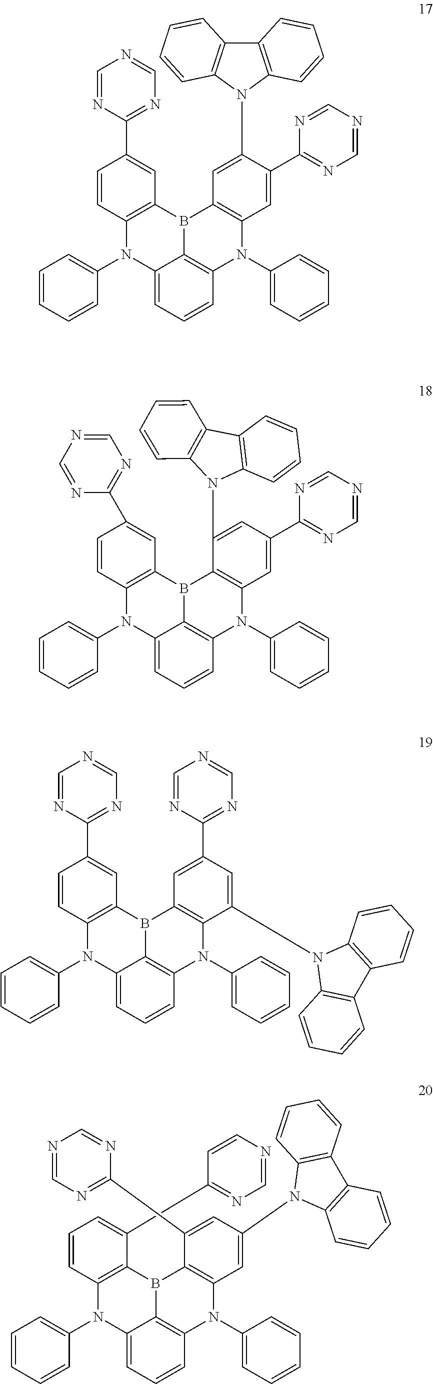 [SMILES: c1ccc(N2c3ccc(-c4ncncn4)cc3B3c4cc(-n5c6ccccc6c6ccccc65)c(-c5ncncn5)cc4N(c4ccccc4)c4cccc2c43)cc1 ; c1ccc(N2c3ccc(-c4ncncn4)cc3B3c4c2cccc4N(c2ccccc2)c2cc(-c4ncncn4)cc(-n4c5ccccc5c5ccccc54)c23)cc1 ; c1ccc(N2c3ccc(-c4ncncn4)cc3B3c4cc(-c5ncncn5)cc(-n5c6ccccc6c6ccccc65)c4N(c4ccccc4)c4cccc2c43)cc1 ; c1ccc(N2c3cccc(-c4ccncn4)c3B3c4c(-c5ncncn5)cc(-n5c6ccccc6c6ccccc65)cc4N(c4ccccc4)c4cccc2c43)cc1] 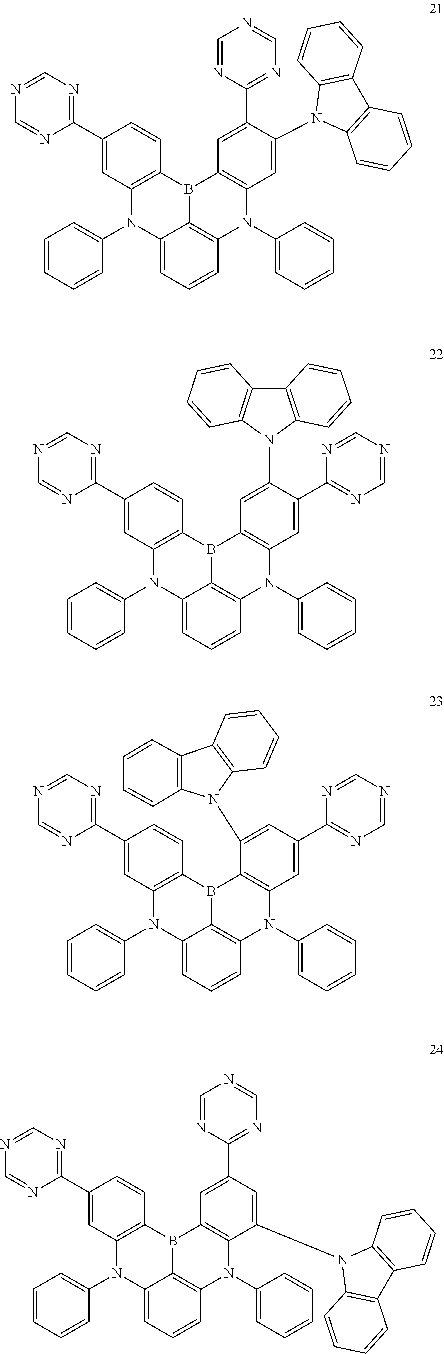 [SMILES: c1ccc(N2c3cc(-c4ncncn4)ccc3B3c4cc(-c5ncncn5)c(-n5c6ccccc6c6ccccc65)cc4N(c4ccccc4)c4cccc2c43)cc1 ; c1ccc(N2c3cc(-c4ncncn4)ccc3B3c4cc(-n5c6ccccc6c6ccccc65)c(-c5ncncn5)cc4N(c4ccccc4)c4cccc2c43)cc1 ; c1ccc(N2c3cc(-c4ncncn4)ccc3B3c4c2cccc4N(c2ccccc2)c2cc(-c4ncncn4)cc(-n4c5ccccc5c5ccccc54)c23)cc1 ; c1ccc(N2c3cc(-c4ncncn4)ccc3B3c4cc(-c5ncncn5)cc(-n5c6ccccc6c6ccccc65)c4N(c4ccccc4)c4cccc2c43)cc1] 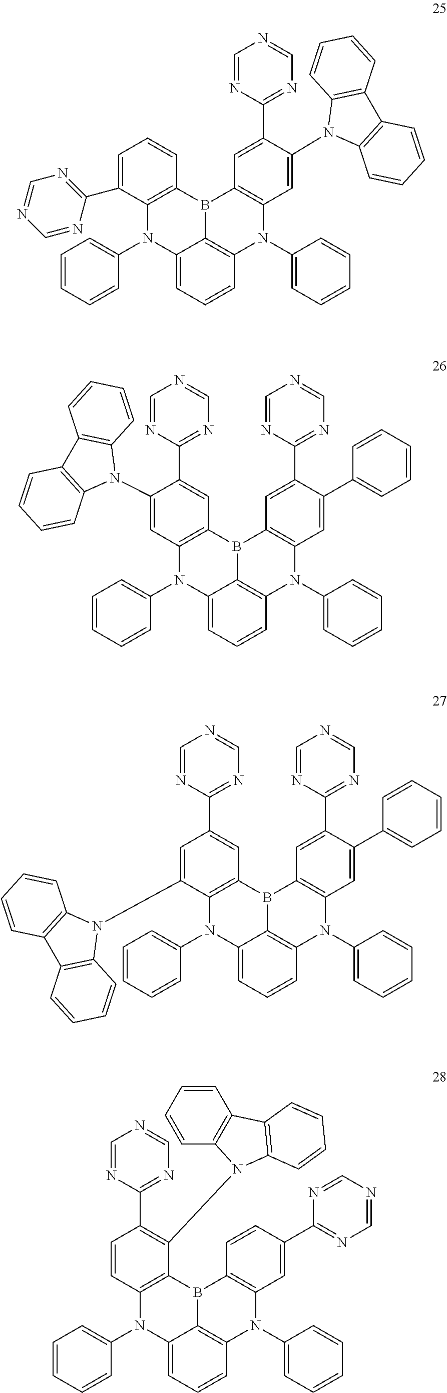 [SMILES: c1ccc(N2c3cc(-n4c5ccccc5c5ccccc54)c(-c4ncncn4)cc3B3c4cccc(-c5ncncn5)c4N(c4ccccc4)c4cccc2c43)cc1 ; c1ccc(-c2cc3c(cc2-c2ncncn2)B2c4cc(-c5ncncn5)c(-n5c6ccccc6c6ccccc65)cc4N(c4ccccc4)c4cccc(c42)N3c2ccccc2)cc1 ; c1ccc(-c2cc3c(cc2-c2ncncn2)B2c4cc(-c5ncncn5)cc(-n5c6ccccc6c6ccccc65)c4N(c4ccccc4)c4cccc(c42)N3c2ccccc2)cc1 ; c1ccc(N2c3cc(-c4ncncn4)ccc3B3c4c2cccc4N(c2ccccc2)c2ccc(-c4ncncn4)c(-n4c5ccccc5c5ccccc54)c23)cc1] 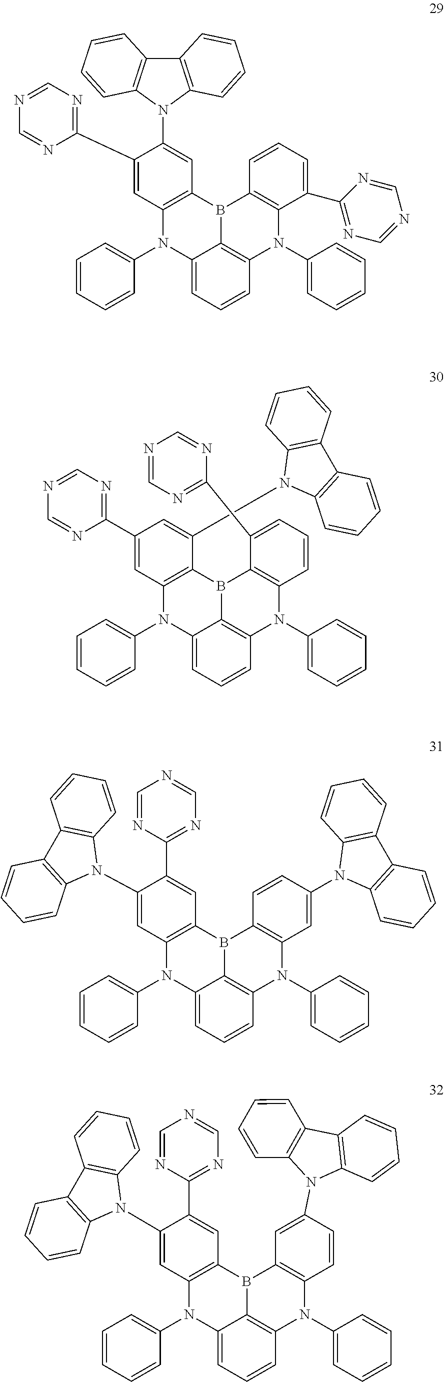 [SMILES: c1ccc(N2c3cc(-c4ncncn4)c(-n4c5ccccc5c5ccccc54)cc3B3c4cccc(-c5ncncn5)c4N(c4ccccc4)c4cccc2c43)cc1 ; c1ccc(N2c3cccc(-c4ncncn4)c3B3c4c2cccc4N(c2ccccc2)c2cc(-c4ncncn4)cc(-n4c5ccccc5c5ccccc54)c23)cc1 ; c1ccc(N2c3cc(-n4c5ccccc5c5ccccc54)ccc3B3c4cc(-c5ncncn5)c(-n5c6ccccc6c6ccccc65)cc4N(c4ccccc4)c4cccc2c43)cc1 ; c1ccc(N2c3ccc(-n4c5ccccc5c5ccccc54)cc3B3c4cc(-c5ncncn5)c(-n5c6ccccc6c6ccccc65)cc4N(c4ccccc4)c4cccc2c43)cc1] 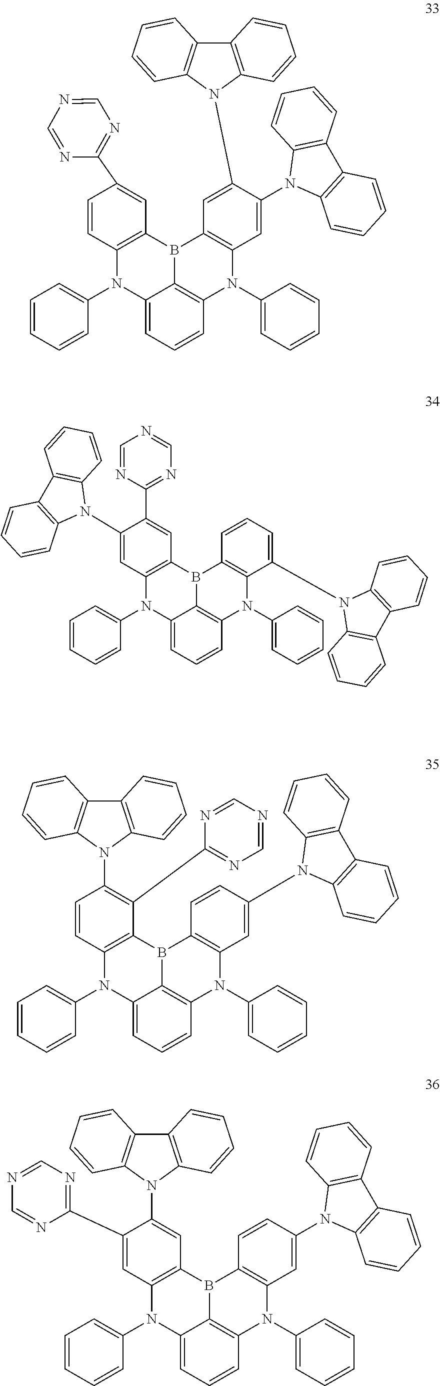 [SMILES: c1ccc(N2c3ccc(-c4ncncn4)cc3B3c4cc(-n5c6ccccc6c6ccccc65)c(-n5c6ccccc6c6ccccc65)cc4N(c4ccccc4)c4cccc2c43)cc1 ; c1ccc(N2c3cc(-n4c5ccccc5c5ccccc54)c(-c4ncncn4)cc3B3c4cccc(-n5c6ccccc6c6ccccc65)c4N(c4ccccc4)c4cccc2c43)cc1 ; c1ccc(N2c3cc(-n4c5ccccc5c5ccccc54)ccc3B3c4c2cccc4N(c2ccccc2)c2ccc(-n4c5ccccc5c5ccccc54)c(-c4ncncn4)c23)cc1 ; c1ccc(N2c3cc(-n4c5ccccc5c5ccccc54)ccc3B3c4cc(-n5c6ccccc6c6ccccc65)c(-c5ncncn5)cc4N(c4ccccc4)c4cccc2c43)cc1] 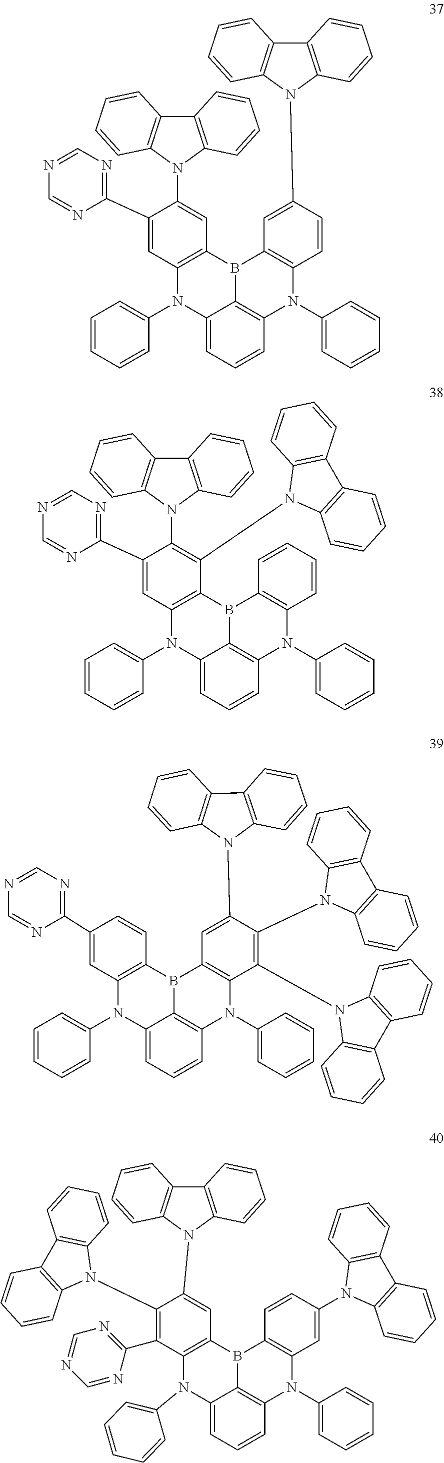 [SMILES: c1ccc(N2c3ccc(-n4c5ccccc5c5ccccc54)cc3B3c4cc(-n5c6ccccc6c6ccccc65)c(-c5ncncn5)cc4N(c4ccccc4)c4cccc2c43)cc1 ; c1ccc(N2c3ccccc3B3c4c2cccc4N(c2ccccc2)c2cc(-c4ncncn4)c(-n4c5ccccc5c5ccccc54)c(-n4c5ccccc5c5ccccc54)c23)cc1 ; c1ccc(N2c3cc(-c4ncncn4)ccc3B3c4cc(-n5c6ccccc6c6ccccc65)c(-n5c6ccccc6c6ccccc65)c(-n5c6ccccc6c6ccccc65)c4N(c4ccccc4)c4cccc2c43)cc1 ; c1ccc(N2c3cc(-n4c5ccccc5c5ccccc54)ccc3B3c4cc(-n5c6ccccc6c6ccccc65)c(-n5c6ccccc6c6ccccc65)c(-c5ncncn5)c4N(c4ccccc4)c4cccc2c43)cc1] 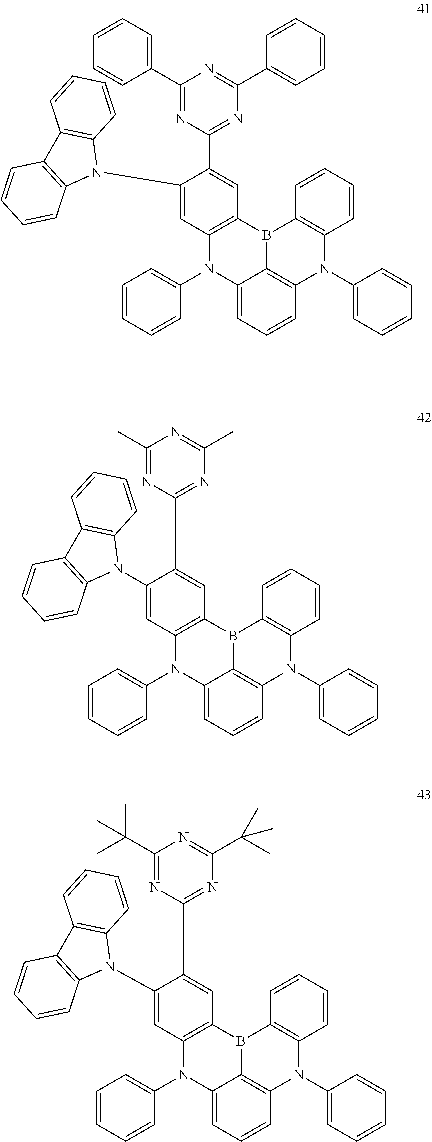 [SMILES: c1ccc(-c2nc(-c3ccccc3)nc(-c3cc4c(cc3-n3c5ccccc5c5ccccc53)N(c3ccccc3)c3cccc5c3B4c3ccccc3N5c3ccccc3)n2)cc1 ; Cc1nc(C)nc(-c2cc3c(cc2-n2c4ccccc4c4ccccc42)N(c2ccccc2)c2cccc4c2B3c2ccccc2N4c2ccccc2)n1 ; CC(C)(C)c1nc(-c2cc3c(cc2-n2c4ccccc4c4ccccc42)N(c2ccccc2)c2cccc4c2B3c2ccccc2N4c2ccccc2)nc(C(C)(C)C)n1] 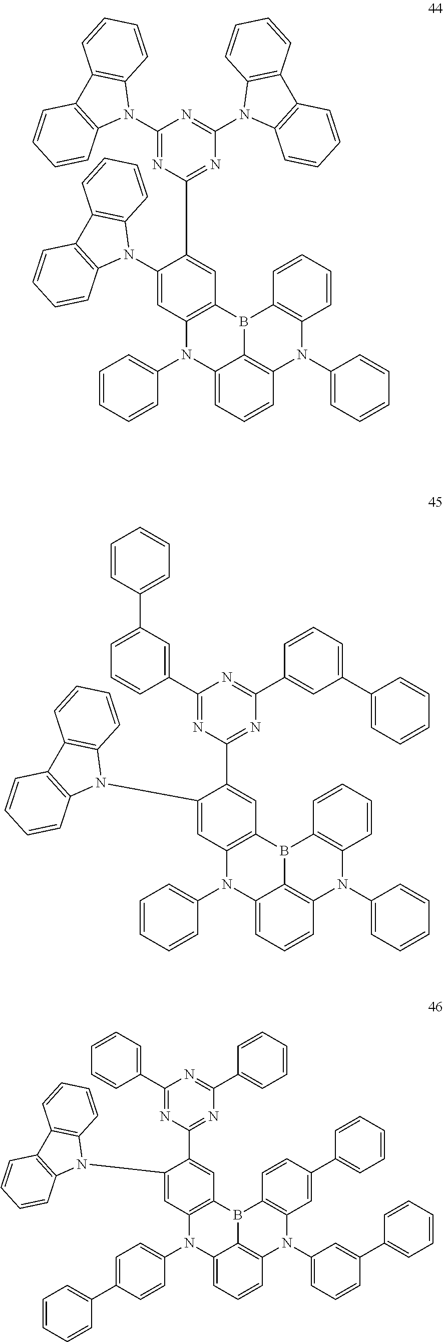 [SMILES: c1ccc(N2c3ccccc3B3c4cc(-c5nc(-n6c7ccccc7c7ccccc76)nc(-n6c7ccccc7c7ccccc76)n5)c(-n5c6ccccc6c6ccccc65)cc4N(c4ccccc4)c4cccc2c43)cc1 ; c1ccc(-c2cccc(-c3nc(-c4cccc(-c5ccccc5)c4)nc(-c4cc5c(cc4-n4c6ccccc6c6ccccc64)N(c4ccccc4)c4cccc6c4B5c4ccccc4N6c4ccccc4)n3)c2)cc1 ; c1ccc(-c2ccc(N3c4cc(-n5c6ccccc6c6ccccc65)c(-c5nc(-c6ccccc6)nc(-c6ccccc6)n5)cc4B4c5ccc(-c6ccccc6)cc5N(c5cccc(-c6ccccc6)c5)c5cccc3c54)cc2)cc1] 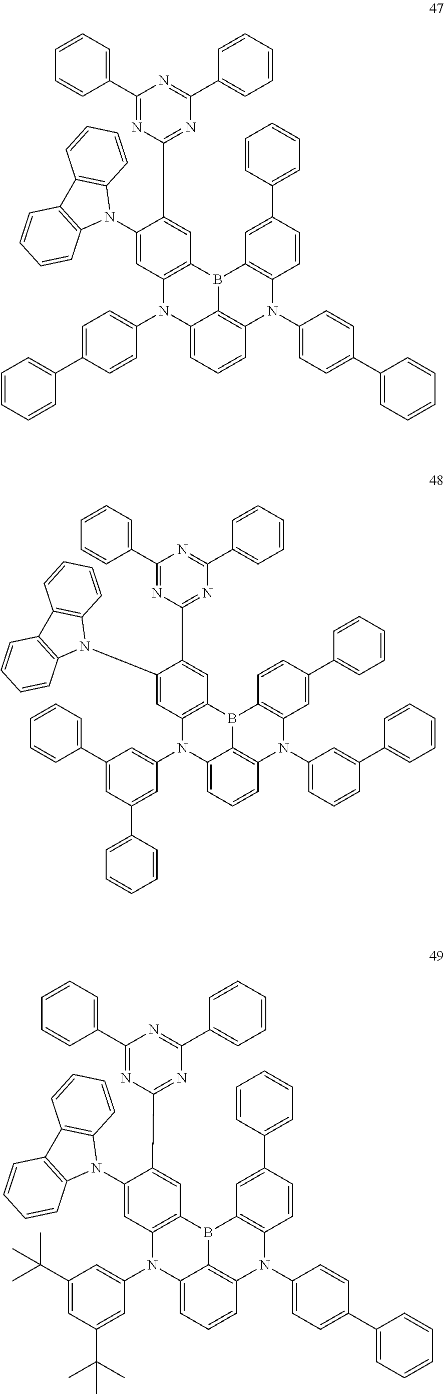 [SMILES: c1ccc(-c2ccc(N3c4ccc(-c5ccccc5)cc4B4c5cc(-c6nc(-c7ccccc7)nc(-c7ccccc7)n6)c(-n6c7ccccc7c7ccccc76)cc5N(c5ccc(-c6ccccc6)cc5)c5cccc3c54)cc2)cc1 ; c1ccc(-c2cccc(N3c4cc(-c5ccccc5)ccc4B4c5cc(-c6nc(-c7ccccc7)nc(-c7ccccc7)n6)c(-n6c7ccccc7c7ccccc76)cc5N(c5cc(-c6ccccc6)cc(-c6ccccc6)c5)c5cccc3c54)c2)cc1 ; CC(C)(C)c1cc(N2c3cc(-n4c5ccccc5c5ccccc54)c(-c4nc(-c5ccccc5)nc(-c5ccccc5)n4)cc3B3c4cc(-c5ccccc5)ccc4N(c4ccc(-c5ccccc5)cc4)c4cccc2c43)cc(C(C)(C)C)c1] 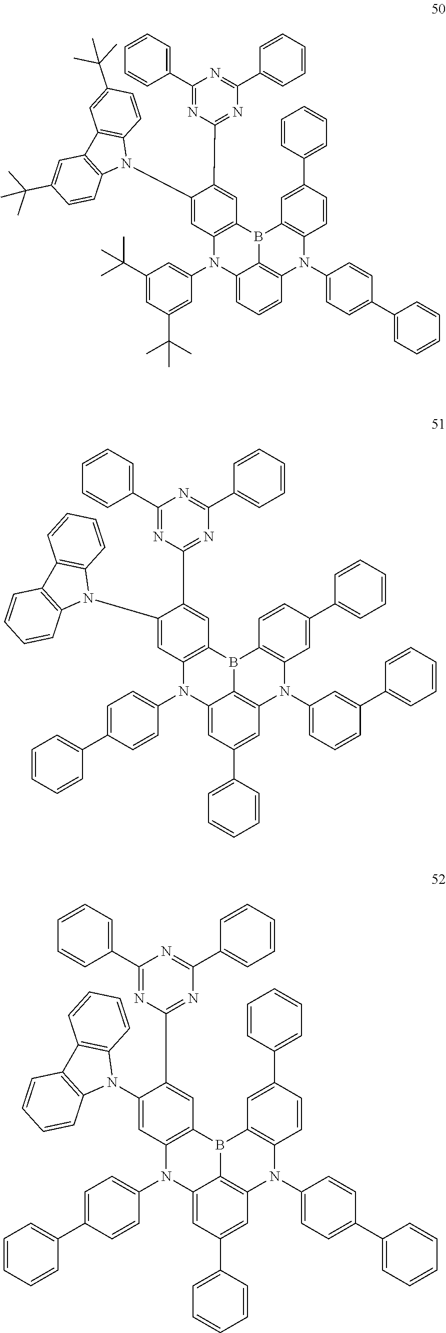 [SMILES: CC(C)(C)c1cc(N2c3cc(-n4c5ccc(C(C)(C)C)cc5c5cc(C(C)(C)C)ccc54)c(-c4nc(-c5ccccc5)nc(-c5ccccc5)n4)cc3B3c4cc(-c5ccccc5)ccc4N(c4ccc(-c5ccccc5)cc4)c4cccc2c43)cc(C(C)(C)C)c1 ; c1ccc(-c2ccc(N3c4cc(-n5c6ccccc6c6ccccc65)c(-c5nc(-c6ccccc6)nc(-c6ccccc6)n5)cc4B4c5ccc(-c6ccccc6)cc5N(c5cccc(-c6ccccc6)c5)c5cc(-c6ccccc6)cc3c54)cc2)cc1 ; c1ccc(-c2ccc(N3c4ccc(-c5ccccc5)cc4B4c5cc(-c6nc(-c7ccccc7)nc(-c7ccccc7)n6)c(-n6c7ccccc7c7ccccc76)cc5N(c5ccc(-c6ccccc6)cc5)c5cc(-c6ccccc6)cc3c54)cc2)cc1] 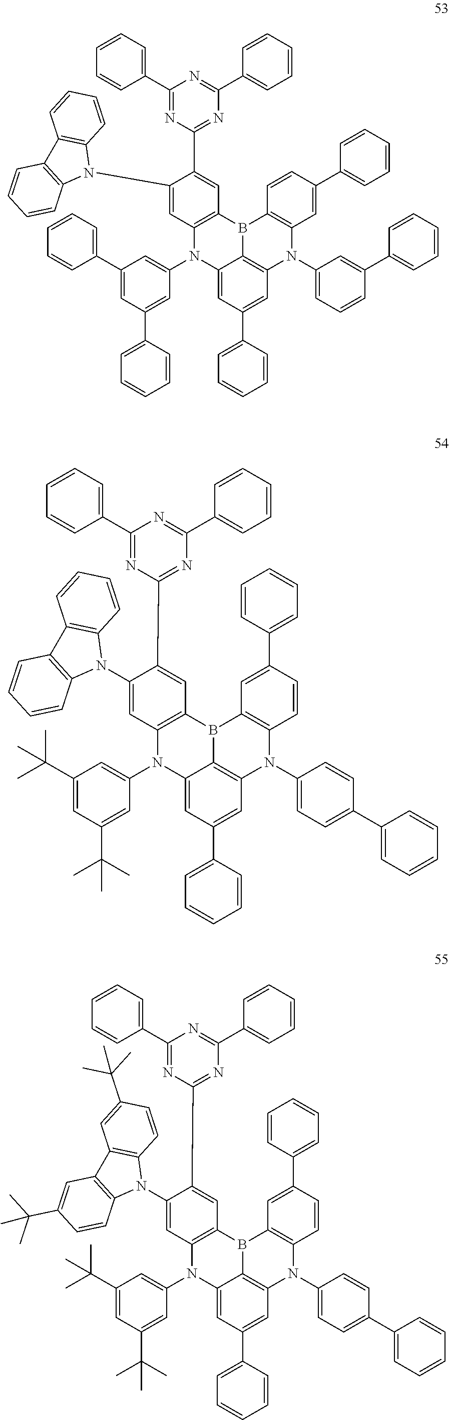 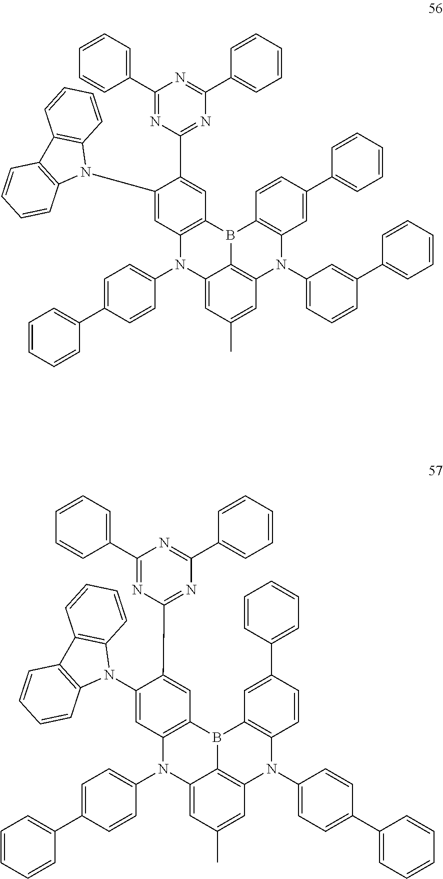 [SMILES: Cc1cc2c3c(c1)N(c1ccc(-c4ccccc4)cc1)c1cc(-n4c5ccccc5c5ccccc54)c(-c4nc(-c5ccccc5)nc(-c5ccccc5)n4)cc1B3c1ccc(-c3ccccc3)cc1N2c1cccc(-c2ccccc2)c1 ; Cc1cc2c3c(c1)N(c1ccc(-c4ccccc4)cc1)c1cc(-n4c5ccccc5c5ccccc54)c(-c4nc(-c5ccccc5)nc(-c5ccccc5)n4)cc1B3c1cc(-c3ccccc3)ccc1N2c1ccc(-c2ccccc2)cc1] 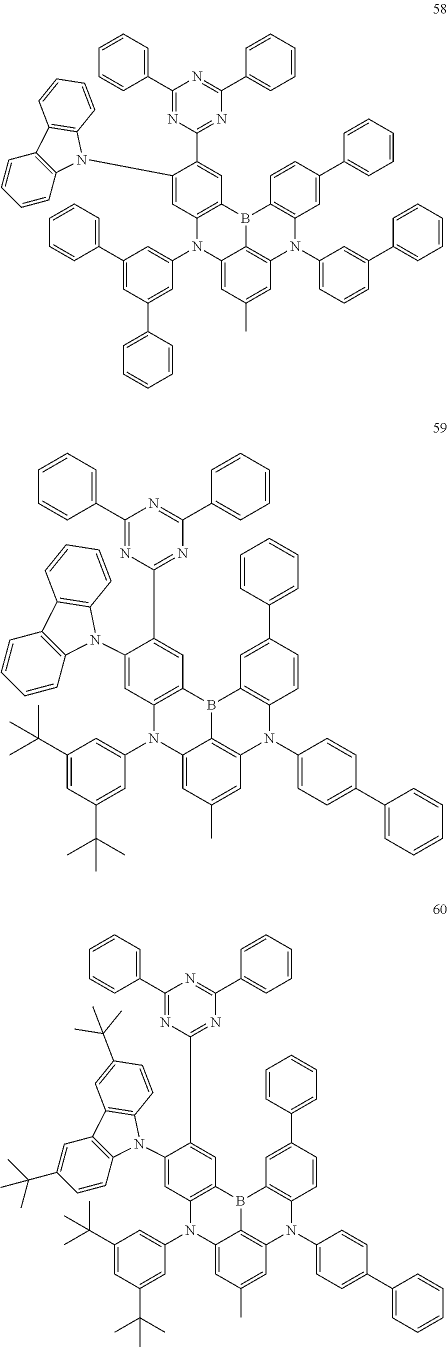 [SMILES: Cc1cc2c3c(c1)N(c1cc(-c4ccccc4)cc(-c4ccccc4)c1)c1cc(-n4c5ccccc5c5ccccc54)c(-c4nc(-c5ccccc5)nc(-c5ccccc5)n4)cc1B3c1ccc(-c3ccccc3)cc1N2c1cccc(-c2ccccc2)c1 ; Cc1cc2c3c(c1)N(c1cc(C(C)(C)C)cc(C(C)(C)C)c1)c1cc(-n4c5ccccc5c5ccccc54)c(-c4nc(-c5ccccc5)nc(-c5ccccc5)n4)cc1B3c1cc(-c3ccccc3)ccc1N2c1ccc(-c2ccccc2)cc1 ; Cc1cc2c3c(c1)N(c1cc(C(C)(C)C)cc(C(C)(C)C)c1)c1cc(-n4c5ccc(C(C)(C)C)cc5c5cc(C(C)(C)C)ccc54)c(-c4nc(-c5ccccc5)nc(-c5ccccc5)n4)cc1B3c1cc(-c3ccccc3)ccc1N2c1ccc(-c2ccccc2)cc1] 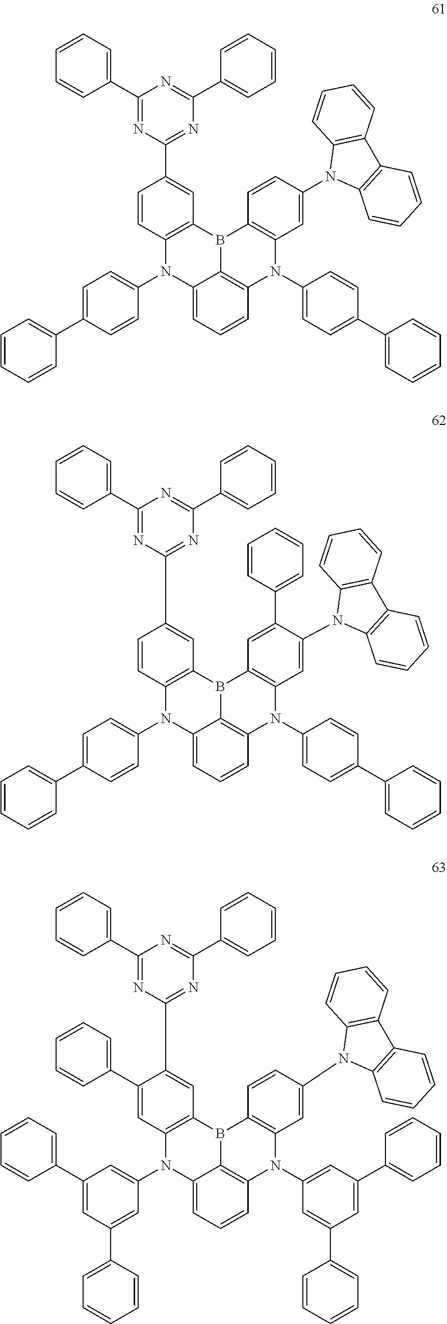 [SMILES: c1ccc(-c2ccc(N3c4ccc(-c5nc(-c6ccccc6)nc(-c6ccccc6)n5)cc4B4c5ccc(-n6c7ccccc7c7ccccc76)cc5N(c5ccc(-c6ccccc6)cc5)c5cccc3c54)cc2)cc1 ; c1ccc(-c2ccc(N3c4ccc(-c5nc(-c6ccccc6)nc(-c6ccccc6)n5)cc4B4c5cc(-c6ccccc6)c(-n6c7ccccc7c7ccccc76)cc5N(c5ccc(-c6ccccc6)cc5)c5cccc3c54)cc2)cc1 ; c1ccc(-c2cc(-c3ccccc3)cc(N3c4cc(-n5c6ccccc6c6ccccc65)ccc4B4c5cc(-c6nc(-c7ccccc7)nc(-c7ccccc7)n6)c(-c6ccccc6)cc5N(c5cc(-c6ccccc6)cc(-c6ccccc6)c5)c5cccc3c54)c2)cc1] 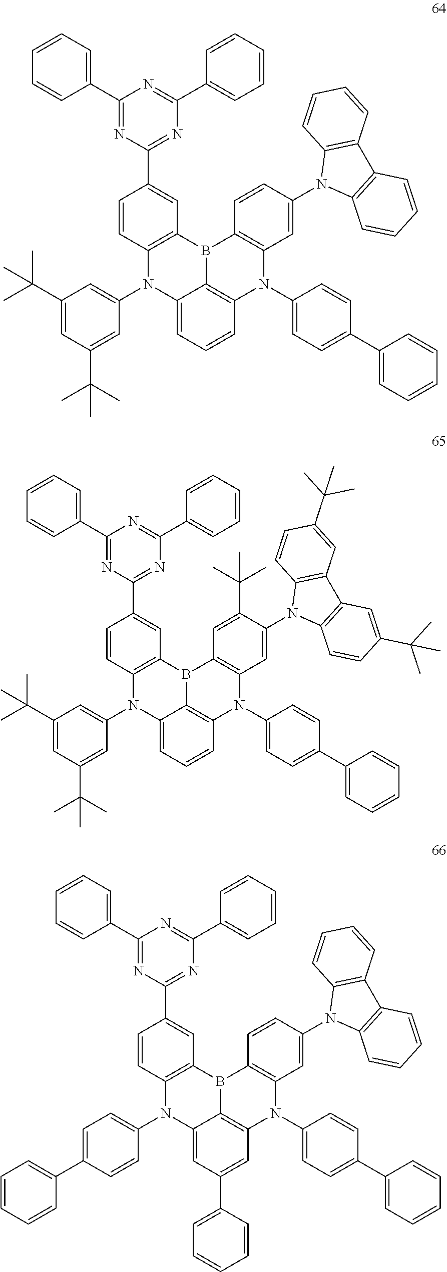 [SMILES: CC(C)(C)c1cc(N2c3ccc(-c4nc(-c5ccccc5)nc(-c5ccccc5)n4)cc3B3c4ccc(-n5c6ccccc6c6ccccc65)cc4N(c4ccc(-c5ccccc5)cc4)c4cccc2c43)cc(C(C)(C)C)c1 ; CC(C)(C)c1cc(N2c3ccc(-c4nc(-c5ccccc5)nc(-c5ccccc5)n4)cc3B3c4cc(C(C)(C)C)c(-n5c6ccc(C(C)(C)C)cc6c6cc(C(C)(C)C)ccc65)cc4N(c4ccc(-c5ccccc5)cc4)c4cccc2c43)cc(C(C)(C)C)c1 ; c1ccc(-c2ccc(N3c4ccc(-c5nc(-c6ccccc6)nc(-c6ccccc6)n5)cc4B4c5ccc(-n6c7ccccc7c7ccccc76)cc5N(c5ccc(-c6ccccc6)cc5)c5cc(-c6ccccc6)cc3c54)cc2)cc1] 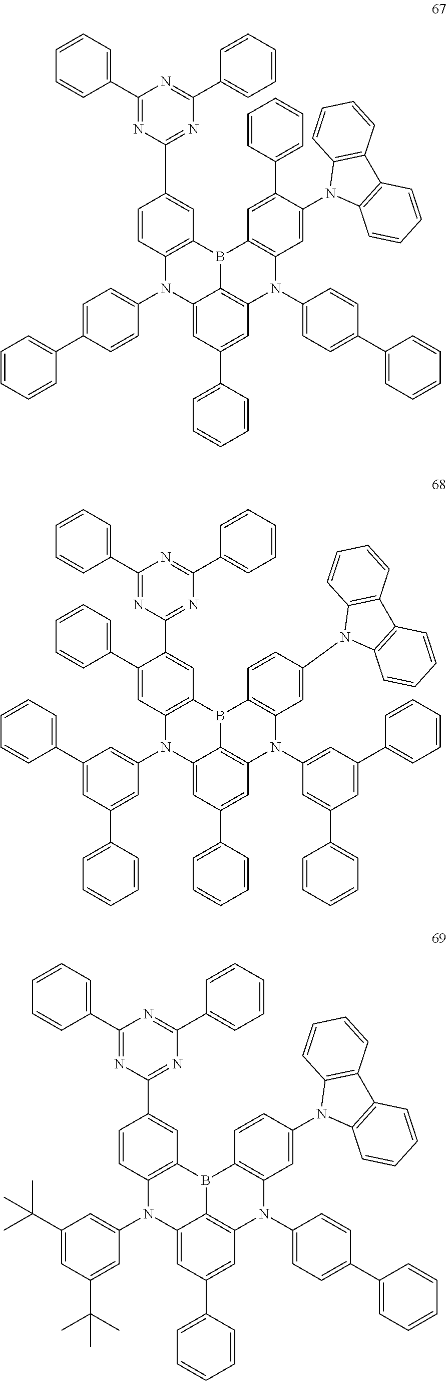 [SMILES: c1ccc(-c2ccc(N3c4ccc(-c5nc(-c6ccccc6)nc(-c6ccccc6)n5)cc4B4c5cc(-c6ccccc6)c(-n6c7ccccc7c7ccccc76)cc5N(c5ccc(-c6ccccc6)cc5)c5cc(-c6ccccc6)cc3c54)cc2)cc1 ; c1ccc(-c2cc(-c3ccccc3)cc(N3c4cc(-n5c6ccccc6c6ccccc65)ccc4B4c5cc(-c6nc(-c7ccccc7)nc(-c7ccccc7)n6)c(-c6ccccc6)cc5N(c5cc(-c6ccccc6)cc(-c6ccccc6)c5)c5cc(-c6ccccc6)cc3c54)c2)cc1 ; CC(C)(C)c1cc(N2c3ccc(-c4nc(-c5ccccc5)nc(-c5ccccc5)n4)cc3B3c4ccc(-n5c6ccccc6c6ccccc65)cc4N(c4ccc(-c5ccccc5)cc4)c4cc(-c5ccccc5)cc2c43)cc(C(C)(C)C)c1] 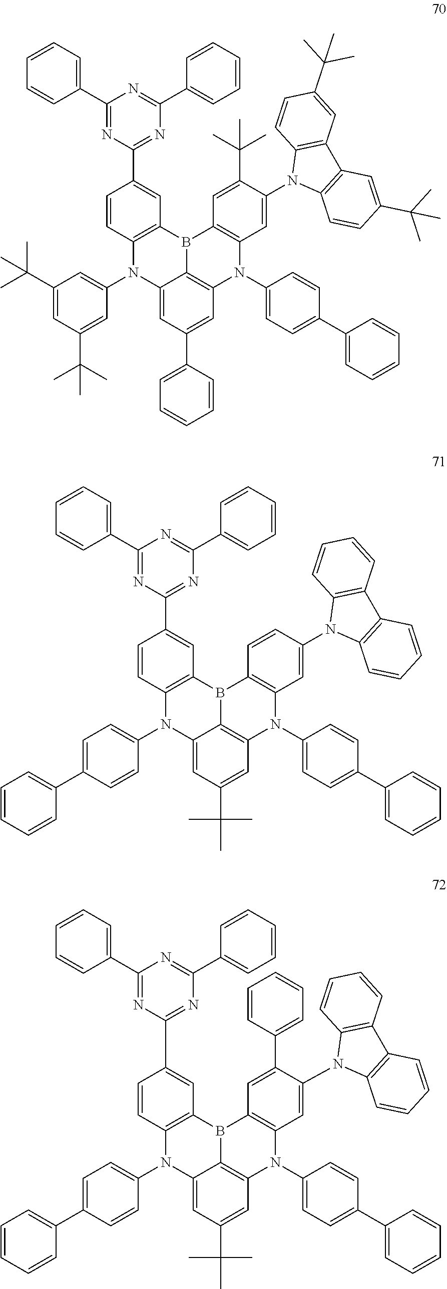 [SMILES: CC(C)(C)c1cc(N2c3ccc(-c4nc(-c5ccccc5)nc(-c5ccccc5)n4)cc3B3c4cc(C(C)(C)C)c(-n5c6ccc(C(C)(C)C)cc6c6cc(C(C)(C)C)ccc65)cc4N(c4ccc(-c5ccccc5)cc4)c4cc(-c5ccccc5)cc2c43)cc(C(C)(C)C)c1 ; CC(C)(C)c1cc2c3c(c1)N(c1ccc(-c4ccccc4)cc1)c1cc(-n4c5ccccc5c5ccccc54)ccc1B3c1cc(-c3nc(-c4ccccc4)nc(-c4ccccc4)n3)ccc1N2c1ccc(-c2ccccc2)cc1 ; CC(C)(C)c1cc2c3c(c1)N(c1ccc(-c4ccccc4)cc1)c1cc(-n4c5ccccc5c5ccccc54)c(-c4ccccc4)cc1B3c1cc(-c3nc(-c4ccccc4)nc(-c4ccccc4)n3)ccc1N2c1ccc(-c2ccccc2)cc1] 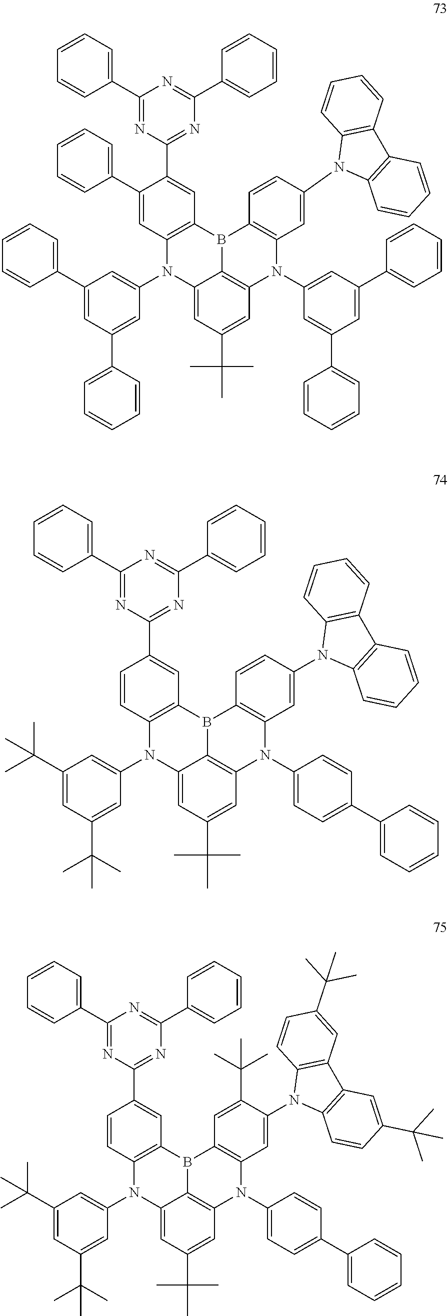 [SMILES: CC(C)(C)c1cc2c3c(c1)N(c1cc(-c4ccccc4)cc(-c4ccccc4)c1)c1cc(-c4ccccc4)c(-c4nc(-c5ccccc5)nc(-c5ccccc5)n4)cc1B3c1ccc(-n3c4ccccc4c4ccccc43)cc1N2c1cc(-c2ccccc2)cc(-c2ccccc2)c1 ; CC(C)(C)c1cc(N2c3ccc(-c4nc(-c5ccccc5)nc(-c5ccccc5)n4)cc3B3c4ccc(-n5c6ccccc6c6ccccc65)cc4N(c4ccc(-c5ccccc5)cc4)c4cc(C(C)(C)C)cc2c43)cc(C(C)(C)C)c1 ; CC(C)(C)c1cc(N2c3ccc(-c4nc(-c5ccccc5)nc(-c5ccccc5)n4)cc3B3c4cc(C(C)(C)C)c(-n5c6ccc(C(C)(C)C)cc6c6cc(C(C)(C)C)ccc65)cc4N(c4ccc(-c5ccccc5)cc4)c4cc(C(C)(C)C)cc2c43)cc(C(C)(C)C)c1] 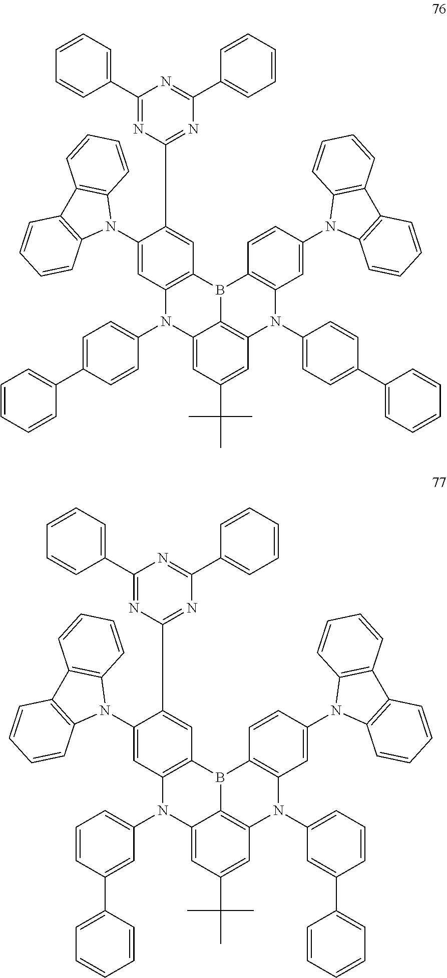 [SMILES: CC(C)(C)c1cc2c3c(c1)N(c1ccc(-c4ccccc4)cc1)c1cc(-n4c5ccccc5c5ccccc54)c(-c4nc(-c5ccccc5)nc(-c5ccccc5)n4)cc1B3c1ccc(-n3c4ccccc4c4ccccc43)cc1N2c1ccc(-c2ccccc2)cc1 ; CC(C)(C)c1cc2c3c(c1)N(c1cccc(-c4ccccc4)c1)c1cc(-n4c5ccccc5c5ccccc54)c(-c4nc(-c5ccccc5)nc(-c5ccccc5)n4)cc1B3c1ccc(-n3c4ccccc4c4ccccc43)cc1N2c1cccc(-c2ccccc2)c1] 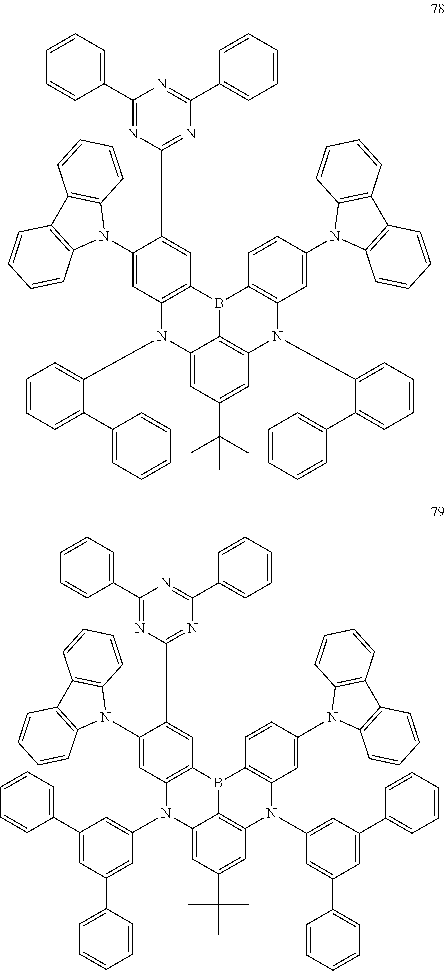 [SMILES: CC(C)(C)c1cc2c3c(c1)N(c1ccccc1-c1ccccc1)c1cc(-n4c5ccccc5c5ccccc54)c(-c4nc(-c5ccccc5)nc(-c5ccccc5)n4)cc1B3c1ccc(-n3c4ccccc4c4ccccc43)cc1N2c1ccccc1-c1ccccc1 ; CC(C)(C)c1cc2c3c(c1)N(c1cc(-c4ccccc4)cc(-c4ccccc4)c1)c1cc(-n4c5ccccc5c5ccccc54)c(-c4nc(-c5ccccc5)nc(-c5ccccc5)n4)cc1B3c1ccc(-n3c4ccccc4c4ccccc43)cc1N2c1cc(-c2ccccc2)cc(-c2ccccc2)c1] 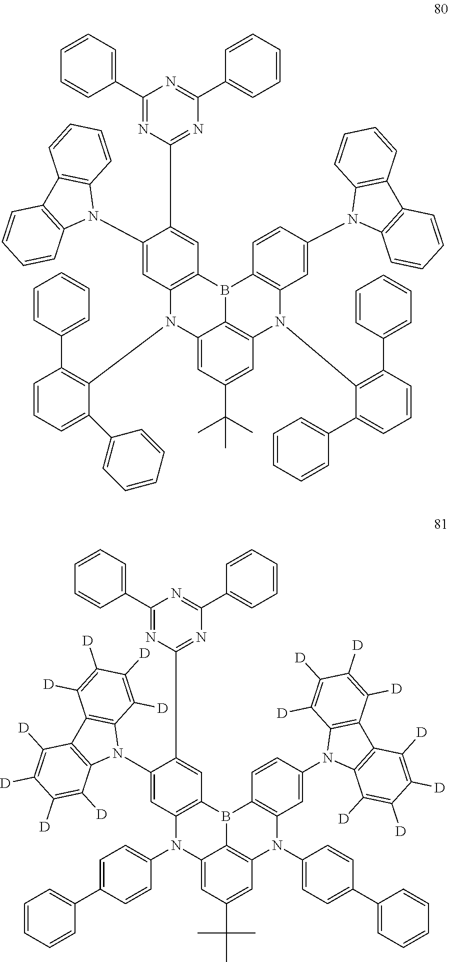 [SMILES: CC(C)(C)c1cc2c3c(c1)N(c1c(-c4ccccc4)cccc1-c1ccccc1)c1cc(-n4c5ccccc5c5ccccc54)c(-c4nc(-c5ccccc5)nc(-c5ccccc5)n4)cc1B3c1ccc(-n3c4ccccc4c4ccccc43)cc1N2c1c(-c2ccccc2)cccc1-c1ccccc1 ; [2H]c1c([2H])c([2H])c2c(c1[2H])c1c([2H])c([2H])c([2H])c([2H])c1n2-c1ccc2c(c1)N(c1ccc(-c3ccccc3)cc1)c1cc(C(C)(C)C)cc3c1B2c1cc(-c2nc(-c4ccccc4)nc(-c4ccccc4)n2)c(-n2c4c([2H])c([2H])c([2H])c([2H])c4c4c([2H])c([2H])c([2H])c([2H])c42)cc1N3c1ccc(-c2ccccc2)cc1] 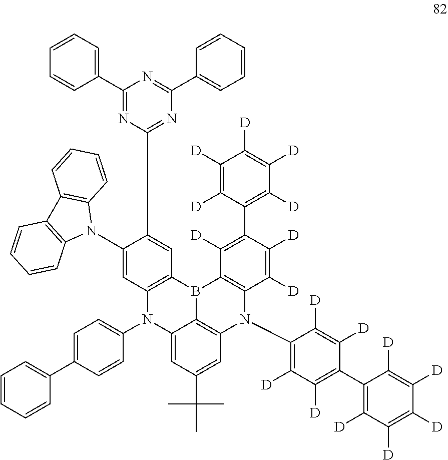 [SMILES: [2H]c1c([2H])c([2H])c(-c2c([2H])c([2H])c(N3c4cc(C(C)(C)C)cc5c4B(c4cc(-c6nc(-c7ccccc7)nc(-c7ccccc7)n6)c(-n6c7ccccc7c7ccccc76)cc4N5c4ccc(-c5ccccc5)cc4)c4c([2H])c(-c5c([2H])c([2H])c([2H])c([2H])c5[2H])c([2H])c([2H])c43)c([2H])c2[2H])c([2H])c1[2H]]
wherein in Compound Group 1,
D represents a deuterium atom.

18. A display device comprising:
a circuit layer disposed on a base layer; and
a display element layer disposed on the circuit layer and comprising a light emitting element, wherein
the light emitting element comprises:
a first electrode;
a second electrode disposed on the first electrode; and
an emission layer disposed between the first electrode and the second electrode, and
the emission layer comprises a polycyclic compound represented by Formula 1: 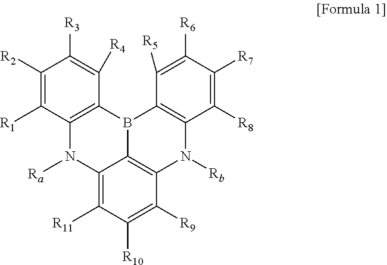
wherein in Formula 1,
at least one of R₁ to R₈ is each independently a first substituent represented by Formula 2,
at least one of the remainder of R₁ to R₈ that is not the first substituent is each independently a second substituent represented by Formula 3, and
the remainder of R₁ to R₈ that are not the first substituent or the second substituent, R₉ to R₁₁, Rₐ, and R_{b} are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms; 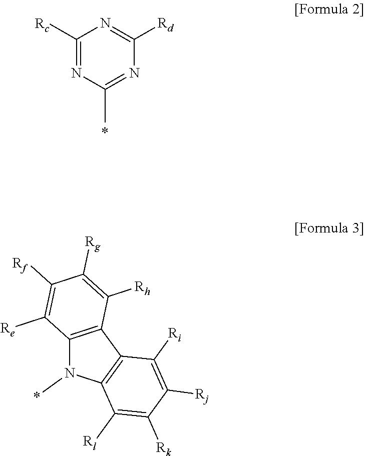
wherein in Formula 2 and Formula 3,
R_{c} to Rₗ are each independently a hydrogen atom, a deuterium atom, a halogen atom, a cyano group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and [symbol]
represents a position linked to Formula 1.

19. The display device of claim 18, wherein the light emitting element emits blue light.

20. The display device of claim 18, further comprising:
a light control layer that includes a quantum dot.
